(19) United States
(12) Patent Application Publication
(10) Pub. No.: US 2026/0348366 A1
(43) Pub. Date: Nov. 5, 2026

(54) SYSTEM AND METHOD FOR REAL-TIME MACHINE LEARNING CONTROL OF PLASMA OSCIALLATIONS IN HALL THRUSTERS

(71) Applicant: Georgia Tech Research Corporation, Atlanta, GA (US)

(72) Inventors: Ajay Krishnan, Atlanta, GA (US); Mitchell L. R. Walker, Atlanta, GA (US); Maryam Saeedifard, Atlanta, GA (US)

(21) Appl. No.: 19/712,517

(22) Filed: Jun. 18, 2026

Related U.S. Application Data
(63) Continuation of application No. 19/553,057, filed on Feb. 27, 2026.
(60) Provisional application No. 63/765,398, filed on Feb. 28, 2025.

(51) Int. Cl. F03H 1/00; B64G 1/40; G01R 19/00; G06N 3/063; G06N 3/09

(52) U.S. Cl. CPC F03H 1/0037; B64G 1/413; G01R 19/0092; G06N 3/063; G06N 3/09

(57) ABSTRACT

A system for controlling plasma oscillations in a Hall effect thruster comprises a Hall effect thruster configured to generate a discharge plasma exhibiting breathing mode oscillations, a current sensor configured to measure a discharge current and generate measurement data, an analog-to-digital converter configured to digitize the measurement data, a field programmable gate array (FPGA) configured to execute a neural network model trained to predict discharge current dynamics based on voltage inputs, wherein the FPGA receives the digitized measurement data and computes a control voltage output, a digital-to-analog converter configured to convert the control voltage output to an analog control signal, and a voltage injection circuit configured to apply the analog control signal to modulate a discharge voltage of the Hall effect thruster to reduce the breathing mode oscillations.

### CROSS-REFERENCE TO RELATED APPLICATIONS

This application is a continuation application of and claims priority to U.S. patent application Ser. No. 19/553,057, filed Feb. 27, 2026, which itself based on and claims the benefit of U.S. Provisional Application No. 63/765,398, titled SYSTEM AND METHOD FOR REAL-TIME MODEL PREDICTIVE PATH CONTROL OF PLASMA OSCILLATIONS IN HALL THRUSTERS USING MACHINE LEARNING-BASED SYSTEM IDENTIFICATION AND STATE ESTIMATION TECHNIQUES, filed Feb. 28, 2025, which is hereby incorporated by reference in its entirety.

### FIELD OF INVENTION

The present disclosure relates to electric propulsion systems for spacecraft, and more particularly to a system and method for real-time control of plasma oscillations in Hall effect thrusters using machine learning-based model predictive path control with neural network system identification and state estimation techniques.

### BACKGROUND

Hall effect thrusters (HETs) represent a class of electric propulsion devices that produce thrust through the acceleration of ions. Developed in the 1960s, HETs have become increasingly adopted for satellite propulsion and deep space missions due to their high specific impulse compared to chemical propulsion systems. A power processing unit (PPU) conditions electrical power to operate a HET, using switching-based converters with semiconductor devices to step up voltage to levels sufficient for ionizing propellant gas in the thruster discharge.

HETs exhibit plasma instabilities that manifest as discharge current oscillations. The predominant oscillation type is the breathing mode, which arises from predator-prey interactions between neutrals and electrons in the plasma discharge. These oscillations occur in the tens of kilohertz frequency range and can produce discharge current amplitudes exceeding one hundred percent of the mean value. Such oscillatory behavior affects thruster performance, contributes to wall erosion, and generates electromagnetic interference. The dynamics of breathing mode oscillations can be expressed through conservation equations for mass, momentum, and energy.

Ground-based testing of HETs introduces facility effects that alter thruster performance compared to operation in space. Vacuum chambers cannot achieve the low-pressure levels present in space, and the metallic chamber structure creates current paths that do not exist in the space environment. Additionally, sputtering from chamber walls can interfere with the discharge and affect thruster lifetime. These differences between ground and space conditions present challenges for accurate performance characterization.

HET discharge plasmas exhibit nonlinear, time-varying, and spatially-varying characteristics with hysteresis. The nonlinearity of the discharge plasma has been demonstrated through small-signal linearization showing that discharge impedance remains constant for small perturbations but changes for larger perturbations. Analytical techniques for characterizing such behavior extend beyond standard Fourier transform methods to include short-time Fourier transforms, continuous wavelet transforms, and empirical mode decomposition approaches.

Various approaches have been explored for controlling HET oscillations. Passive approaches involve tuning resistor-inductor-capacitor (RLC) filter networks in the discharge circuit, though such networks are static and cannot adapt to changing conditions. Magnetic field control faces limitations due to back electromotive force generated from rapidly changing magnetic fields. Mass flow rate control operates on time scales too slow for addressing breathing mode dynamics. Voltage perturbation approaches using proportional-integral-derivative (PID) control have achieved partial oscillation reduction, though PID controllers may require retuning when environmental conditions change and do not incorporate physical models for determining voltage setpoints in nonlinear time-varying systems. At higher power operating points, the discharge plasma becomes increasingly nonlinear, and PID controllers may be unable to reduce oscillations or may even exacerbate them, preventing operation at these higher power conditions that would otherwise provide higher thrust or specific impulse.

Machine learning approaches offer potential for data-driven modeling of HET discharge dynamics where physics-based models may not be fully predictive. Neural networks can learn relationships between control inputs and discharge responses from experimental data. State estimation techniques such as extended Kalman filters can estimate plasma parameters from available electrical measurements when direct plasma diagnostics are impractical for real-time control applications.

Accordingly, there exists a general desire for improved systems and methods for controlling plasma oscillations in Hall effect thrusters that can adapt to environmental changes, operate at time scales faster than breathing mode oscillations, leverage both physics-based models and data-driven approaches, and enable operation at higher power operating points that are otherwise inaccessible due to high oscillation amplitudes.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

According to an aspect of the present disclosure, a system for controlling plasma oscillations in a Hall effect thruster is provided. The system comprises a Hall effect thruster configured to generate a discharge plasma exhibiting breathing mode oscillations. The system comprises a current sensor configured to measure a discharge current of the Hall effect thruster and generate discharge current measurement data. The system comprises an analog-to-digital converter configured to digitize the discharge current measurement data. The system comprises a field programmable gate array (FPGA) configured to execute a neural network model, wherein the neural network model is trained to predict discharge current dynamics based on voltage inputs and wherein the FPGA receives the digitized discharge current measurement data and computes a control voltage output based on the neural network model. The system comprises a digital-to-analog converter configured to convert the control voltage output from the FPGA to an analog control signal. The system comprises a voltage injection circuit configured to apply the analog control signal to modulate a discharge voltage of the Hall effect thruster to reduce the breathing mode oscillations.

According to other aspects of the present disclosure, the system may include one or more of the following features. The neural network model may comprise a multilayer perceptron having an input layer configured to receive past control voltage measurements and past discharge current measurements, at least one hidden layer, and an output layer configured to generate the control voltage output. The multilayer perceptron may be trained on control trajectories generated by a nonlinear model predictive control algorithm operating on a discharge plasma dynamics model. The system may enable operation of the Hall effect thruster at a higher power operating point that is inaccessible without active oscillation control due to discharge current oscillation amplitudes at the higher power operating point exceeding acceptable limits, and operation at the higher power operating point may provide at least one of higher thrust output or higher specific impulse compared to a lower power operating point. The voltage injection circuit may comprise a power amplifier configured to amplify the analog control signal and a transformer configured to electrically isolate the power amplifier from the Hall effect thruster and to inject the amplified analog control signal in series with a discharge path of the Hall effect thruster. The system may further comprise a state estimator configured to estimate plasma parameters of the discharge plasma based on the discharge current measurement data, wherein the plasma parameters comprise at least one of ion number density, neutral number density, electron temperature, ion velocity, or electron velocity. The state estimator may comprise an extended Kalman filter configured to combine predictions from a zero-dimensional ionization model with the discharge current measurement data to generate the estimated plasma parameters.

According to another aspect of the present disclosure, a non-transitory computer-readable medium storing instructions that, when executed by a field programmable gate array (FPGA), cause the FPGA to perform operations is provided. The operations comprise receiving digitized discharge current measurement data from an analog-to-digital converter, wherein the discharge current measurement data corresponds to discharge current oscillations of a Hall effect thruster. The operations comprise executing a neural network model stored on the FPGA to predict discharge current dynamics based on the digitized discharge current measurement data, wherein the neural network model has been trained on Hall effect thruster discharge data. The operations comprise computing a control voltage output based on the predicted discharge current dynamics to reduce breathing mode oscillations in the Hall effect thruster. The operations comprise outputting the control voltage output to a digital-to-analog converter for conversion to an analog control signal for modulating a discharge voltage of the Hall effect thruster.

According to other aspects of the present disclosure, the non-transitory computer-readable medium may include one or more of the following features. The neural network model may comprise a multilayer perceptron having an input layer configured to receive a plurality of past control voltage measurements and a plurality of past discharge current measurements. The multilayer perceptron may comprise at least two hidden layers with activation functions. The operations may further comprise tuning outer layer weights of the multilayer perceptron using a simultaneous perturbation stochastic approximation algorithm based on a cost function comprising a root mean square of detrended discharge current. The neural network model may be trained on control trajectories generated by a nonlinear model predictive control algorithm operating on a zero-dimensional ionization model of the Hall effect thruster discharge plasma. The operations may further comprise updating weights of the neural network model based on discharge current measurement data collected during operation of the Hall effect thruster to adapt the neural network model to changing discharge plasma dynamics. The operations may further comprise estimating plasma parameters based on the digitized discharge current measurement data using a state estimator, wherein the plasma parameters comprise at least one of ion number density, neutral number density, electron temperature, ion velocity, or electron velocity.

According to another aspect of the present disclosure, a method for controlling plasma oscillations in a Hall effect thruster is provided. The method comprises measuring a discharge current of the Hall effect thruster using a current sensor to generate discharge current measurement data. The method comprises digitizing the discharge current measurement data using an analog-to-digital converter. The method comprises processing the digitized discharge current measurement data using a neural network model executed on a field programmable gate array (FPGA), wherein the neural network model predicts discharge current dynamics. The method comprises computing a control voltage output based on the predicted discharge current dynamics using the FPGA. The method comprises converting the control voltage output to an analog control signal using a digital-to-analog converter. The method comprises applying the analog control signal to modulate a discharge voltage of the Hall effect thruster to reduce breathing mode oscillations.

According to other aspects of the present disclosure, the method may include one or more of the following features. The neural network model may comprise a multilayer perceptron having an input layer configured to receive a plurality of past control voltage measurements and a plurality of past discharge current measurements, at least two hidden layers with activation functions, and an output layer configured to generate the control voltage output. The method may further comprise training the multilayer perceptron on control trajectories generated by a nonlinear model predictive control algorithm operating on a zero-dimensional ionization model of a discharge plasma of the Hall effect thruster. The method may further comprise tuning outer layer weights of the multilayer perceptron using a simultaneous perturbation stochastic approximation algorithm based on a cost function comprising a root mean square of detrended discharge current. Applying the analog control signal to modulate the discharge voltage may enable operation of the Hall effect thruster at a higher power operating point that is inaccessible without active oscillation control due to discharge current oscillation amplitudes at the higher power operating point, and operation at the higher power operating point may provide at least one of higher thrust output or higher specific impulse compared to a lower power operating point. The method may further comprise estimating plasma parameters of a discharge plasma of the Hall effect thruster based on the digitized discharge current measurement data using a state estimator, wherein the plasma parameters comprise at least one of ion number density, neutral number density, electron temperature, ion velocity, or electron velocity.

The foregoing general description of the illustrative embodiments and the following detailed description thereof are merely exemplary aspects of the teachings of this disclosure and are not restrictive.

### BRIEF DESCRIPTION OF FIGURES

Non-limiting and non-exhaustive examples are described with reference to the following figures.

FIG. 1A depicts a Hall effect thruster during active operation showing a plasma plume, according to aspects of the present disclosure.

FIG. 1B depicts an experimental laboratory test setup for Hall thruster power processing and control research, according to aspects of the present disclosure.

FIG. 1C depicts a simplified block diagram of a Hall thruster power processing unit system, according to aspects of the present disclosure.

FIG. 2A depicts a simplified block diagram of a Hall thruster power processing unit discharge circuit, according to aspects of the present disclosure.

FIG. 2B depicts a schematic layout of an experimental test configuration showing a control room and a vacuum chamber, according to aspects of the present disclosure.

FIG. 3 displays an oscilloscope capture showing real-time electrical measurements from a Hall thruster discharge plasma control experiment, according to aspects of the present disclosure.

FIG. 4A depicts a simplified block diagram of a Hall thruster power processing unit feedback control system, according to aspects of the present disclosure.

FIG. 4B depicts an electrical circuit schematic showing a filter stage and a controller stage, according to aspects of the present disclosure.

FIG. 4C illustrates a feedback control system block diagram for a Hall thruster discharge circuit, according to aspects of the present disclosure.

FIG. 5 depicts a control block diagram illustrating a feedback control system for a Hall thruster discharge plasma, according to aspects of the present disclosure.

FIG. 6 depicts a simplified block diagram of a Hall thruster power processing unit control system architecture, according to aspects of the present disclosure.

FIG. 7A presents a graph showing a relationship between current oscillations and voltage setpoint, according to aspects of the present disclosure.

FIG. 7B presents a graph illustrating a relationship between voltage oscillations and voltage setpoint, according to aspects of the present disclosure.

FIG. 8A presents a color map displaying current power spectral density as a function of frequency and voltage setpoint, according to aspects of the present disclosure.

FIG. 8B presents a spectrogram displaying power spectral density as a function of frequency and voltage setpoint, according to aspects of the present disclosure.

FIG. 9 presents a graph showing a relationship between modulation voltage and discharge current, according to aspects of the present disclosure.

FIG. 10 shows an electrical schematic for a driving circuit and planar probe measurements, according to aspects of the present disclosure.

FIG. 11 presents a graph showing thrust performance as a function of modulation frequency, according to aspects of the present disclosure.

FIG. 12 depicts a simplified block diagram of a Hall thruster power processing unit discharge circuit configuration, according to aspects of the present disclosure.

FIG. 13A presents time-domain waveforms of discharge voltage and discharge current at a chopping frequency of 12 kHz, according to aspects of the present disclosure.

FIG. 13B presents time-domain waveforms of discharge voltage and discharge current at a chopping frequency of 18 kHz, according to aspects of the present disclosure.

FIG. 13C presents time-domain waveforms of discharge voltage and discharge current at a chopping frequency of 24 kHz, according to aspects of the present disclosure.

FIG. 13D presents time-domain waveforms of discharge voltage and discharge current at a chopping frequency of 30 kHz, according to aspects of the present disclosure.

FIG. 14A illustrates a relationship between thrust efficiency and power consumption, according to aspects of the present disclosure.

FIG. 14B presents a graph depicting a relationship between thrust-to-power ratio and specific impulse, according to aspects of the present disclosure.

FIG. 15A presents thrust performance metrics as a function of chopping frequency for a first operating condition, according to aspects of the present disclosure.

FIG. 15B presents thrust performance metrics as a function of chopping frequency for a second operating condition, according to aspects of the present disclosure.

FIG. 15C presents thrust performance metrics as a function of chopping frequency for a third operating condition, according to aspects of the present disclosure.

FIG. 16 depicts a block diagram illustrating a control loop architecture and controller structure for a hollow cathode system, according to aspects of the present disclosure.

FIG. 17 presents a graph illustrating effectiveness of discharge oscillation control over time, according to aspects of the present disclosure.

FIG. 18 depicts an electrical circuit schematic of a Hall thruster power processing unit discharge circuit with voltage modulation capability, according to aspects of the present disclosure.

FIG. 19A presents a time-series plot showing discharge voltage oscillations, according to aspects of the present disclosure.

FIG. 19B presents a frequency spectrum plot showing discharge voltage amplitude as a function of frequency, according to aspects of the present disclosure.

FIG. 19C presents a time-domain plot showing discharge current oscillations, according to aspects of the present disclosure.

FIG. 19D presents a frequency spectrum analysis showing discharge current amplitude as a function of frequency, according to aspects of the present disclosure.

FIG. 20A presents a time-domain plot showing discharge voltage oscillations, according to aspects of the present disclosure.

FIG. 20B presents a frequency spectrum plot showing discharge voltage amplitude as a function of frequency, according to aspects of the present disclosure.

FIG. 20C presents a time-domain plot showing discharge current oscillations, according to aspects of the present disclosure.

FIG. 20D presents a frequency spectrum plot showing discharge current amplitude as a function of frequency, according to aspects of the present disclosure.

FIG. 21A illustrates a principle of constructive interference showing wave reinforcement, according to aspects of the present disclosure.

FIG. 21B illustrates a principle of destructive interference showing wave cancellation, according to aspects of the present disclosure.

FIG. 22A presents a time-domain plot showing discharge current oscillations, according to aspects of the present disclosure.

FIG. 22B presents a frequency spectrum plot showing discharge current amplitude as a function of frequency, according to aspects of the present disclosure.

FIG. 23 depicts a graph showing discharge current oscillations with marked extrema points, according to aspects of the present disclosure.

FIG. 24 depicts a circular diagram illustrating a relationship between thrust output and phase angle, according to aspects of the present disclosure.

FIG. 25 depicts a diagram illustrating different characterization approaches for a Hall thruster discharge plasma load, according to aspects of the present disclosure.

FIG. 26 presents a current-voltage characteristic curve, according to aspects of the present disclosure.

FIG. 27A presents a graph showing impedance magnitude as a function of frequency at different pressure conditions, according to aspects of the present disclosure.

FIG. 27B presents a graph showing impedance phase as a function of frequency at different pressure conditions, according to aspects of the present disclosure.

FIG. 28 presents a Nyquist plot showing a frequency response of a second-order transfer function, according to aspects of the present disclosure.

FIG. 29A displays a sine wave, according to aspects of the present disclosure.

FIG. 29B displays a triangle wave, according to aspects of the present disclosure.

FIG. 29C displays a square wave, according to aspects of the present disclosure.

FIG. 30 displays discharge current oscillations as a function of time, according to aspects of the present disclosure.

FIG. 31 displays a visualization of bandlimited noise perturbation signals, according to aspects of the present disclosure.

FIG. 32 displays a chirp signal waveform, according to aspects of the present disclosure.

FIG. 33 illustrates a block diagram of an experimental setup for Hall thruster control, according to aspects of the present disclosure.

FIG. 34 depicts a power triangle diagram illustrating relationships between apparent power, real power, and reactive power, according to aspects of the present disclosure.

FIG. 35A presents a graph showing discharge voltage as a function of time, according to aspects of the present disclosure.

FIG. 35B presents a graph showing discharge current as a function of time, according to aspects of the present disclosure.

FIG. 36A shows a graph depicting discharge current oscillations during a startup transient, according to aspects of the present disclosure.

FIG. 36B presents a graph showing discharge current oscillations with periodic current pulses, according to aspects of the present disclosure.

FIG. 37 depicts a block diagram of a neural network-enhanced model architecture for a Hall thruster system, according to aspects of the present disclosure.

FIG. 38 illustrates a block diagram depicting use of an Echo State Network model for predicting discharge current, according to aspects of the present disclosure.

FIG. 39 illustrates a block diagram of a Kalman filter algorithm for state estimation, according to aspects of the present disclosure.

FIG. 40 illustrates a block diagram of a hardware architecture for a real-time control system, according to aspects of the present disclosure.

FIG. 41 illustrates a block diagram of a Hall thruster drive circuit experimental setup, according to aspects of the present disclosure.

FIG. 42 illustrates a timing diagram for a setpoint determination cycle, according to aspects of the present disclosure.

FIG. 43 illustrates a timing diagram for a real-time control scheme, according to aspects of the present disclosure.

FIG. 44 illustrates a closed-loop control system block diagram using a machine learning controller, according to aspects of the present disclosure.

FIG. 45 presents a time-domain plot showing discharge current pulses, according to aspects of the present disclosure.

FIG. 46A presents a time-domain plot showing voltage modulation, according to aspects of the present disclosure.

FIG. 46B presents a time-domain plot showing voltage modulation transient response, according to aspects of the present disclosure.

FIG. 46C presents a time-domain waveform plot showing periodic oscillations, according to aspects of the present disclosure.

FIG. 46D displays discharge current as a function of time, according to aspects of the present disclosure.

FIG. 47 illustrates a time-domain plot of a function generator perturbation voltage, according to aspects of the present disclosure.

FIG. 48 presents a cross mapping analysis plot illustrating causal relationships between variables, according to aspects of the present disclosure.

FIG. 49A presents a time-series plot showing ion number density measurements, according to aspects of the present disclosure.

FIG. 49B presents a time-series plot showing neutral number density measurements, according to aspects of the present disclosure.

FIG. 49C presents a time-series plot showing electron temperature measurements, according to aspects of the present disclosure.

FIG. 49D presents a time-series plot showing ion velocity measurements, according to aspects of the present disclosure.

FIG. 50 presents a time-series plot showing electron velocity measurements, according to aspects of the present disclosure.

FIG. 51 presents a time-domain plot showing discharge current measurements and predictions from a state-space filter, according to aspects of the present disclosure.

FIG. 52A presents a graph displaying discharge current as a function of time, according to aspects of the present disclosure.

FIG. 52B presents a time-domain plot showing a transient response to a step input, according to aspects of the present disclosure.

FIG. 52C presents a time-domain plot showing control voltage, according to aspects of the present disclosure.

FIG. 52D presents a time-domain plot showing a discrete control voltage signal, according to aspects of the present disclosure.

FIG. 53A presents a time-series plot showing discharge current oscillations, according to aspects of the present disclosure.

FIG. 53B presents a time-domain plot showing discharge current response, according to aspects of the present disclosure.

FIG. 53C presents a time-domain plot showing control voltage, according to aspects of the present disclosure.

FIG. 53D presents a time-domain plot showing a discrete control voltage signal, according to aspects of the present disclosure.

FIG. 54 illustrates a block diagram of a Hall thruster drive circuit experimental setup, according to aspects of the present disclosure.

FIG. 55 illustrates a process flow diagram for developing and testing a real-time machine learning controller, according to aspects of the present disclosure.

FIG. 56 depicts a Hall effect thruster mounted on a support bracket, according to aspects of the present disclosure.

FIG. 57A depicts an analog-to-digital converter evaluation module circuit board, according to aspects of the present disclosure.

FIG. 57B depicts an FPGA development board, according to aspects of the present disclosure.

FIG. 57C depicts a digital-to-analog converter evaluation board, according to aspects of the present disclosure.

FIG. 58 depicts a block diagram illustrating a signal processing and control system architecture, according to aspects of the present disclosure.

FIG. 59A presents a time-domain plot showing discharge voltage oscillations, according to aspects of the present disclosure.

FIG. 59B presents a frequency spectrum plot showing discharge voltage amplitude as a function of frequency, according to aspects of the present disclosure.

FIG. 60A presents a time-domain plot showing discharge current oscillations, according to aspects of the present disclosure.

FIG. 60B presents a frequency spectrum plot showing discharge current amplitude as a function of frequency, according to aspects of the present disclosure.

FIG. 61A presents a time-domain plot showing cathode to ground voltage measurements, according to aspects of the present disclosure.

FIG. 61B presents a frequency spectrum plot showing cathode to ground voltage amplitude as a function of frequency, according to aspects of the present disclosure.

FIG. 62A presents a time-domain plot showing thruster body to ground voltage, according to aspects of the present disclosure.

FIG. 62B presents a frequency spectrum plot showing thruster body to ground voltage amplitude as a function of frequency, according to aspects of the present disclosure.

FIG. 63A presents a time-domain plot showing discharge voltage oscillations, according to aspects of the present disclosure.

FIG. 63B presents a time-domain plot showing discharge current oscillations, according to aspects of the present disclosure.

FIG. 64A presents a frequency spectrum plot showing discharge voltage amplitude as a function of frequency, according to aspects of the present disclosure.

FIG. 64B presents a frequency spectrum plot showing discharge current amplitude as a function of frequency, according to aspects of the present disclosure.

FIG. 65A presents a time-domain plot showing discharge voltage oscillations, according to aspects of the present disclosure.

FIG. 65B presents a time-domain plot showing discharge current oscillations, according to aspects of the present disclosure.

FIG. 66A presents a frequency spectrum plot showing discharge voltage amplitude as a function of frequency, according to aspects of the present disclosure.

FIG. 66B presents a frequency spectrum plot showing discharge current amplitude as a function of frequency, according to aspects of the present disclosure.

FIG. 67 presents a time-domain plot showing function generator perturbation voltage, according to aspects of the present disclosure.

FIG. 68A presents a frequency spectrum plot showing discharge voltage amplitude as a function of frequency, according to aspects of the present disclosure.

FIG. 68B presents a frequency spectrum plot showing discharge current amplitude as a function of frequency, according to aspects of the present disclosure.

FIG. 69 presents a time-domain plot showing function generator perturbation voltage with amplitude modulation, according to aspects of the present disclosure.

FIG. 70A presents a frequency spectrum plot showing discharge voltage amplitude as a function of frequency, according to aspects of the present disclosure.

FIG. 70B presents a frequency spectrum plot showing discharge current amplitude as a function of frequency, according to aspects of the present disclosure.

FIG. 71 presents a time-domain waveform plot showing control voltage, according to aspects of the present disclosure.

FIG. 72 presents a time-series plot comparing measured and predicted control signal values, according to aspects of the present disclosure.

FIG. 73 presents a graph showing cost as a function of optimization iteration, according to aspects of the present disclosure.

FIG. 74 presents a plot showing neural network weight parameters during optimization, according to aspects of the present disclosure.

### DETAILED DESCRIPTION

The following description sets forth exemplary aspects of the present disclosure.

It should be recognized, however, that such description is not intended as a limitation on the scope of the present disclosure. Rather, the description also encompasses combinations and modifications to those exemplary aspects described herein.

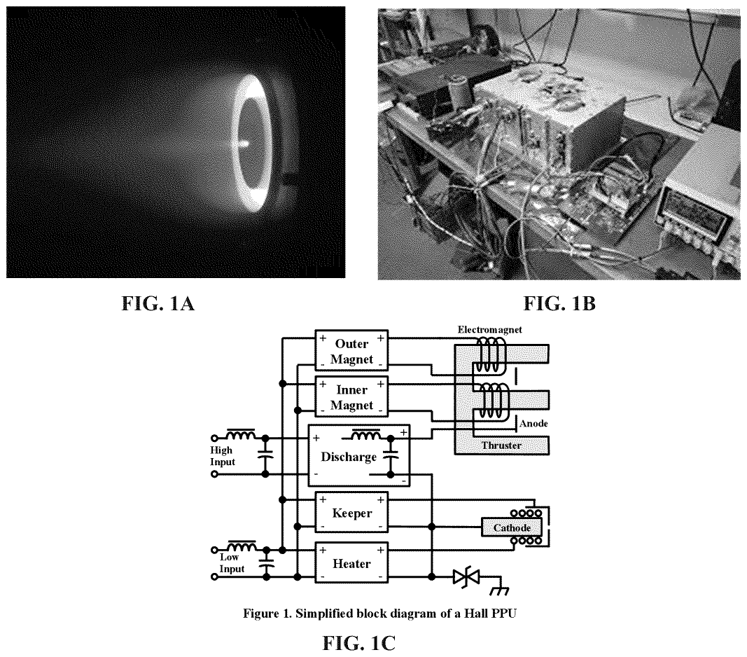

Referring to FIG. 1A, a Hall effect thruster is shown during active operation. The Hall effect thruster is configured to generate a discharge plasma exhibiting breathing mode oscillations. The Hall effect thruster includes an annular discharge channel from which a plasma plume emanates. The plasma plume appears as a conical beam of ionized propellant extending outward from the annular exit plane of the Hall effect thruster. The discharge plasma exhibits a characteristic blue-violet glow associated with plasma emission, with the plasma being most intense at the circular exit plane where the discharge channel terminates. The plasma plume displays a gradient in intensity, being brightest near the thruster exit and gradually diminishing in luminosity as the plasma expands into the vacuum environment. A cathode neutralizer may be positioned at the center of the Hall effect thruster to provide electrons for ionization within the discharge channel and for neutralization of the ion beam.

The breathing mode oscillations occur in the discharge plasma at frequencies in the tens of kilohertz range. The breathing mode oscillations arise from predator-prey type interactions between neutrals and electrons in the discharge plasma, where rapid ionization events cause discharge current spikes followed by neutral depletion and subsequent current reduction. The breathing mode oscillations may result in discharge current amplitudes exceeding one hundred percent of the mean discharge current value.

The Hall effect thruster may be operated with krypton propellant rather than xenon propellant. In some cases, the Hall effect thruster may be a 6-kW class thruster such as the H6 thruster developed by NASA Jet Propulsion Laboratory, University of Michigan, and Air Force Research Laboratory. The Hall effect thruster may employ a centrally mounted LaB6 cathode. The thruster body and cathode may be electrically isolated from facility ground and electrically floating. The system may operate at discharge voltages of 250 V to 600 V and discharge currents of 4.3 A to 20 A depending on the operating point.

Referring to FIG. 1B, an experimental laboratory test setup for Hall thruster power processing and control research is shown. The test setup includes power supply equipment arranged on a workbench. A power supply enclosure is positioned on the workbench and provides electrical power to the Hall effect thruster during testing. An oscilloscope with a color display screen is included in the test setup for monitoring and recording discharge voltage and current waveforms during testing. The oscilloscope may be used to capture time-domain measurements of the discharge current and discharge voltage at sampling rates sufficient to resolve the breathing mode oscillations.

With continued reference to FIG. 1B, control electronics are included in the test setup. A printed circuit board with electronic components and wiring connections may serve as part of the control or signal conditioning circuitry. An electrolytic capacitor may be included as part of a discharge filter circuit used to protect the power processing unit from oscillations generated by the Hall effect thruster load. Electrical wires connect the various components, representing the electrical harness and signal pathways between the power supply, control electronics, and measurement equipment. The test setup configuration enables characterization of Hall thruster electrical dynamics and testing of control approaches for managing discharge plasma oscillations.

Referring to FIG. 1C, a simplified block diagram of a Hall thruster power processing unit system is shown. The power processing unit system includes a power input section positioned on the left side of the block diagram. The power input section includes positive and negative terminals for receiving electrical power from a spacecraft power bus or laboratory power source. The power input section includes capacitors for filtering the input power to reduce noise and voltage ripple before distribution to downstream power supply modules.

The power processing unit system includes five separate power supply modules arranged vertically in the block diagram. Each power supply module is represented as a rectangular block with positive and negative output terminals. The five power supply modules include an Outer Magnet power supply module, an Inner Magnet power supply module, a Discharge power supply module, a Keeper/Ignitor power supply module, and a Heater power supply module. Each power supply module has associated filter capacitors shown on the output of the respective power supply module to smooth the regulated output voltage and reduce output ripple.

With continued reference to FIG. 1C, the Outer Magnet power supply module and the Inner Magnet power supply module connect to a Hall effect thruster component labeled HET in the block diagram. The Hall effect thruster component is shown with coil windings indicating the electromagnet configuration. The Outer Magnet power supply module provides regulated current to an outer magnetic coil of the Hall effect thruster, and the Inner Magnet power supply module provides regulated current to an inner magnetic coil of the Hall effect thruster. The outer magnetic coil and the inner magnetic coil together generate a radial magnetic field within the discharge channel of the Hall effect thruster. The radial magnetic field serves to confine electrons and establish the Hall current that enables ion acceleration.

The Discharge power supply module connects to the main thruster body of the Hall effect thruster. The Discharge power supply module processes the majority of the electrical power consumed by the Hall effect thruster system. The Discharge power supply module provides the discharge voltage that accelerates ions through the discharge channel to generate thrust. The discharge voltage may range from 150 V to 600 V depending on the operating point of the Hall effect thruster.

As further shown in FIG. 1C, a cathode component is depicted as a cylindrical element with internal structure. The cathode component receives power from the Keeper/Ignitor power supply module and the Heater power supply module. The Keeper/Ignitor power supply module provides voltage and current to initiate and maintain electron emission from the cathode during startup and operation. The Heater power supply module provides current to heat the cathode emitter element to a temperature sufficient for thermionic electron emission. The Heater power supply module output includes a diode in the circuit path to prevent reverse current flow. The cathode component provides electrons for ionization of propellant within the discharge channel and for neutralization of the ion beam exiting the Hall effect thruster.

The block diagram illustrates the complete power distribution architecture for operating a Hall effect thruster system. The power processing unit conditions electrical power from the input source and distributes regulated power to the various thruster subsystems including the electromagnets that shape the magnetic field, the main discharge that accelerates ions, and the cathode assembly that provides electrons for discharge operation and beam neutralization.

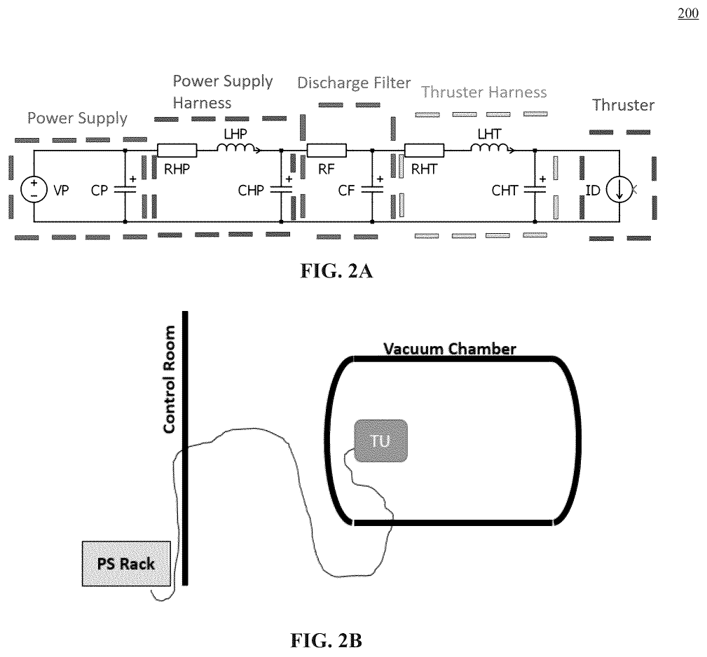

Referring to FIG. 2A, a simplified block diagram of a Hall thruster power processing unit discharge circuit is shown. The discharge circuit depicts the complete electrical path from a power supply to the Hall effect thruster. On the left side of the block diagram, a power supply section includes a voltage source V_{P} that provides the discharge voltage to the circuit. A capacitor C_{P} is connected in parallel with the voltage source V_{P} to provide energy storage and filtering at the power supply output.

The discharge circuit includes a power supply harness section connected to the power supply section. The power supply harness section includes a resistor R_{HP} and an inductor L_{HP} connected in series to represent the resistance and inductance of the electrical cabling between the power supply and downstream components. A capacitor C_{HP} is connected to ground in the power supply harness section to represent parasitic capacitance of the harness cabling.

With continued reference to FIG. 2A, a discharge filter section is connected between the power supply harness section and a thruster harness section. The discharge filter section includes an inductor L_{F} connected in series with the discharge path. The discharge filter section includes a resistor R_{F} connected in series with the inductor L_{F}. The discharge filter section includes a capacitor C_{F} connected as a shunt element to ground. The discharge filter comprising the series resistor R_{F} and the shunt capacitor C_{F} may be configured to attenuate discharge current oscillations above a cutoff frequency. The discharge filter serves to protect the power processing unit from discharge current oscillations generated by the Hall effect thruster load. The inductor L_{F}, resistor R_{F}, and capacitor C_{F} together form a low-pass filter network that reduces the amplitude of high-frequency oscillations propagating back toward the power supply.

The thruster harness section is connected between the discharge filter section and the Hall effect thruster. The thruster harness section includes a resistor R_{HT} connected in series with the discharge path to represent the resistance of the electrical harness connecting the discharge filter to the Hall effect thruster. The thruster harness section includes an inductor L_{HT} connected in series with the resistor R_{HT} to represent the inductance of the thruster harness cabling. A capacitor C_{HT} is connected in parallel in the thruster harness section to represent the parasitic capacitance of the thruster harness. The resistor R_{HT}, inductor L_{HT}, and capacitor C_{HT} together form a transmission line model that accounts for the electrical characteristics of the cabling between the discharge filter and the Hall effect thruster.

As further shown in FIG. 2A, the Hall effect thruster is represented on the right side of the discharge circuit by a current source I_{D} with a diode symbol. The current source I_{D} represents the discharge current drawn by the Hall effect thruster discharge plasma load. The diode symbol indicates the unidirectional nature of the discharge current flow. The circuit model forms the basis for understanding the electrical dynamics of the system, particularly how discharge voltage and current oscillations propagate through the circuit between the power supply and the Hall effect thruster.

Referring to FIG. 2B, a schematic layout of an experimental test configuration is shown. The schematic layout depicts the spatial relationship between a control room and a vacuum chamber used for Hall effect thruster testing. On the left side of the schematic layout, the control room is shown containing a PS Rack. The PS Rack represents a power supply rack that houses the power processing unit and associated control electronics. The PS Rack provides regulated electrical power to the Hall effect thruster during testing operations.

Electrical cabling extends from the PS Rack through the control room boundary and into the vacuum chamber. The vacuum chamber is located on the right side of the schematic layout. The vacuum chamber is illustrated as a large enclosure with thick walls representing the sealed test facility where the Hall effect thruster operates under vacuum conditions. The vacuum chamber maintains a low-pressure environment that approximates space conditions for thruster testing.

With continued reference to FIG. 2B, a component labeled TU is shown inside the vacuum chamber. The TU component represents the thruster unit or test unit being evaluated during the experiment. The cabling path from the PS Rack to the TU illustrates the electrical harness that connects the power supply equipment in the control room to the Hall effect thruster inside the vacuum chamber. The harness length and associated inductance, capacitance, and resistance characteristics of the electrical harness introduce transmission line effects that influence the discharge voltage oscillations observed at the Hall effect thruster. The experimental test configuration enables characterization of Hall effect thruster electrical dynamics and testing of control approaches for managing discharge plasma oscillations while maintaining the power supply equipment in a controlled environment separate from the vacuum chamber.

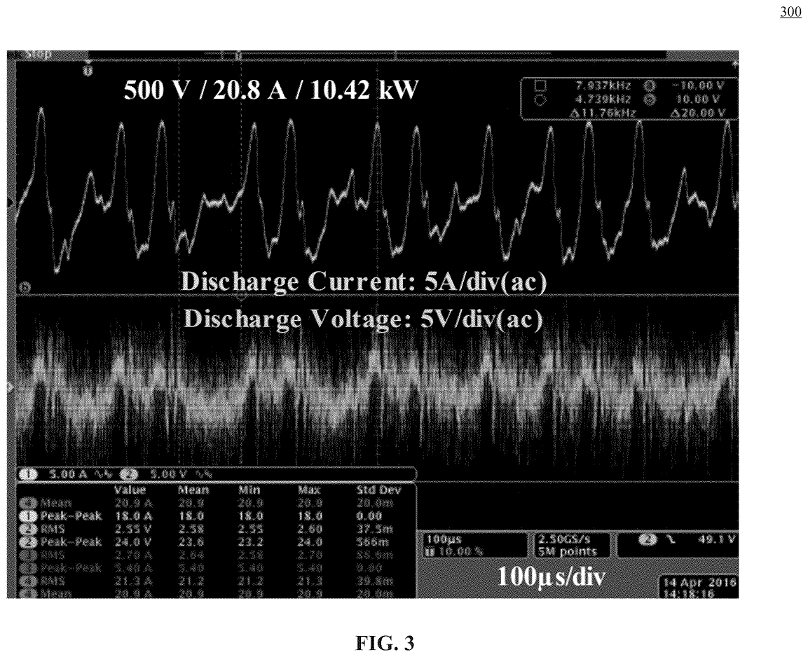

Referring to FIG. 3, an oscilloscope capture showing real-time electrical measurements from a Hall effect thruster discharge plasma control experiment is displayed. The oscilloscope capture presents two primary waveform channels that depict the electrical behavior of the discharge plasma during operation. An upper waveform shown in cyan represents the discharge current measured at 5 A per division in AC coupling mode. A lower waveform shown in yellow represents the discharge voltage measured at 5 V per division in AC coupling mode. The time base of the oscilloscope is set to 100 microseconds per division, which enables observation of multiple breathing mode oscillation cycles within the displayed time window.

With continued reference to FIG. 3, a measurement data panel on the right side of the oscilloscope screen indicates operating parameters of the Hall effect thruster during the measurement. The operating parameters include a discharge voltage of 200 V, a discharge current of 20.8 A, and a power consumption of 10.42 kW. Statistical measurements are displayed on the oscilloscope screen showing standard deviation, mean, minimum, maximum, and peak-to-peak values for the captured discharge current and discharge voltage signals.

The discharge current waveform exhibits characteristic breathing mode oscillations with amplitude variations around the mean discharge current value. The discharge voltage waveform shows corresponding oscillatory behavior that correlates with the discharge current oscillations. The frequency measurements indicated on the oscilloscope display show approximately 4.17 kHz and 4.11 kHz for the respective channels. The breathing mode oscillations may occur at frequencies in the range of 7 kHz to 19 kHz depending on the operating point of the Hall effect thruster. The oscilloscope capture demonstrates the type of real-time voltage and current measurements used for characterizing Hall effect thruster discharge dynamics and for implementing model predictive path integral control of the discharge plasma oscillations.

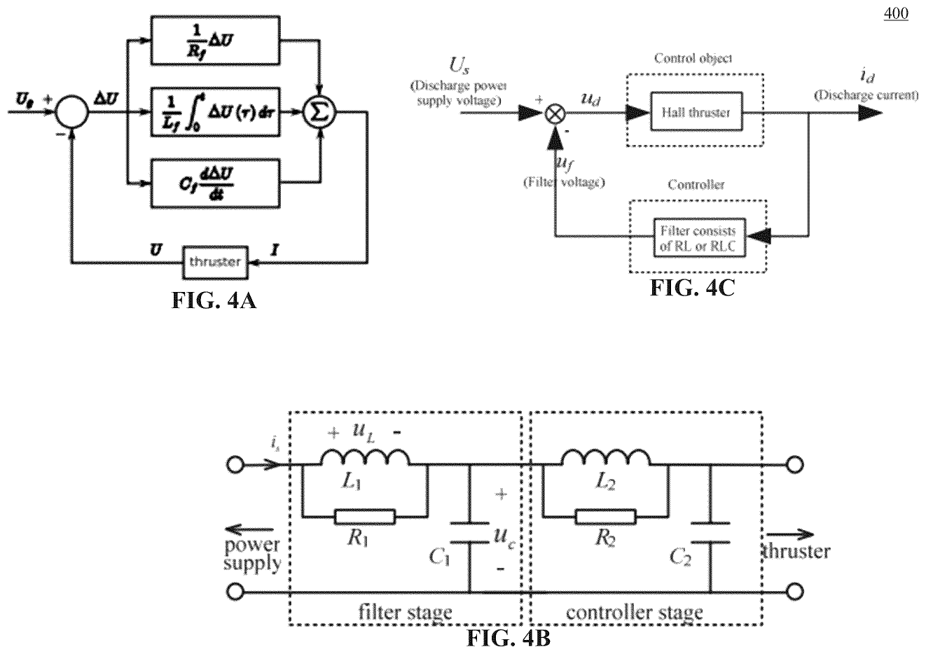

Referring to FIG. 4A, a simplified block diagram of a Hall thruster power processing unit feedback control system is shown. The feedback control system employs a closed-loop control architecture for regulating the discharge voltage supplied to the Hall effect thruster. A reference voltage U₀ is provided as an input to the feedback control system. The reference voltage U₀ represents the desired discharge voltage setpoint for the Hall effect thruster operation. The reference voltage U₀ is compared with an actual output voltage U at a summing junction. The summing junction produces an error signal delta U that represents the difference between the reference voltage U₀ and the actual output voltage U.

With continued reference to FIG. 4A, the error signal delta U is processed through three parallel paths that together form a PID-type controller structure. A first path contains a proportional term. The proportional term shows the error signal divided by a filter resistance R_{f}. The proportional term provides an output that is directly proportional to the instantaneous error signal delta U. A second path contains an integral term. The integral term shows the integration of the error signal over time divided by a filter inductance L_{f}. The integral term accumulates the error signal over time to eliminate steady-state error between the reference voltage and the actual output voltage. A third path contains a derivative term. The derivative term shows the filter capacitance C_{f} multiplied by the time derivative of the error signal. The derivative term responds to the rate of change of the error signal to provide improved transient response and damping of oscillations.

The outputs of the three parallel paths are combined at a summation block to produce a total current I. The total current I feeds into a thruster block that represents the Hall effect thruster load. The thruster block outputs the voltage U, which is fed back to the input summing junction to complete the closed-loop system. The feedback control system may use PID control as an alternative or baseline control approach with proportional, integral, and derivative gains. The proportional gain, integral gain, and derivative gain may be tuned to achieve desired control performance for reducing discharge current oscillations in the Hall effect thruster.

Referring to FIG. 4B, an electrical circuit schematic is shown depicting a two-stage power conditioning system. The two-stage power conditioning system comprises a filter stage and a controller stage connected between a power supply on the left side and a thruster on the right side. The filter stage contains an inductor L₁ with an associated resistance R₁ connected in series. A capacitor C₁ is connected in parallel in the filter stage. A voltage across the capacitor C₁ is designated as u_{c}. An inductor voltage is labeled as u_{L} with positive and negative polarity markings indicated on the circuit schematic.

With continued reference to FIG. 4B, the controller stage is connected to the filter stage. The controller stage contains an inductor L₂ with an associated resistance R₂ connected in series. An input current is denoted as iₛ flowing from the power supply into the circuit. The circuit topology represents a simplified model of a Hall thruster power processing unit discharge filter and controller configuration. The filter stage serves to protect the power supply from discharge current oscillations generated by the Hall effect thruster load. The controller stage interfaces with the thruster load to regulate the discharge voltage. The capacitor voltage u_{c} represents the discharge filter capacitor voltage, which may serve as a measurement point for monitoring and controlling the discharge plasma dynamics.

Referring to FIG. 4C, a feedback control system block diagram for a Hall thruster discharge circuit is shown. An input signal Uₛ represents the discharge power supply voltage and serves as the reference signal for the feedback control system. The input signal Uₛ enters a summing junction depicted as a circle with a plus sign at the top and a minus sign at the bottom. The summing junction configuration indicates that a feedback signal is subtracted from the reference signal Uₛ.

With continued reference to FIG. 4C, an output of the summing junction is labeled u_{d}. The signal u_{d} represents the voltage applied to a control object. The control object block is labeled Hall thruster and produces an output i_{d} representing the discharge current. A feedback path returns from the output through a controller block. The controller block is described as a filter consisting of RL or RLC components. An output of the controller block is labeled u_{f} representing the filter voltage. The filter voltage u_{f} feeds back to the summing junction where the filter voltage u_{f} is subtracted from the supply voltage Uₛ. The entire system is enclosed within a dashed rectangle labeled Control object at the top, encompassing the Hall thruster. The controller block sits below within the feedback loop. The block diagram demonstrates how the filter acts as a controller in the discharge circuit, regulating the voltage across the filter according to variations in discharge current to suppress low frequency oscillations in the Hall thruster system.

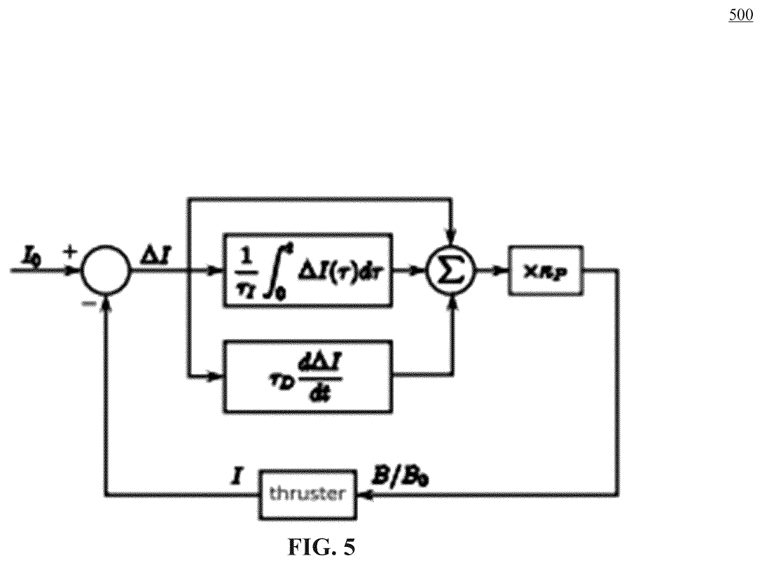

Referring to FIG. 5, a control block diagram illustrating a feedback control system for a Hall thruster discharge plasma is shown. The feedback control system receives a reference current input I₀ that represents a desired discharge current setpoint for the Hall effect thruster operation. The reference current input I₀ enters a summing junction where the reference current input I₀ is compared with a measured discharge current I. The summing junction produces an error signal delta I that represents the difference between the reference current input I₀ and the measured discharge current I.

With continued reference to FIG. 5, the error signal delta I is processed through two parallel paths within a controller portion of the feedback control system. A first path contains an integral control element. The integral control element is represented by an expression showing one divided by a time constant tau_{I} multiplied by the integral of the error signal delta I with respect to tau from zero to time t. The integral control element provides integral action for accumulating the error signal over time to eliminate steady-state error between the reference current and the measured discharge current.

A second path contains a derivative control element. The derivative control element is represented by an expression showing a time constant tau_{D} multiplied by the time derivative of the error signal delta I. The derivative control element provides derivative action for responding to the rate of change of the error signal to improve transient response and provide damping of oscillations in the discharge current.

As further shown in FIG. 5, the outputs of the integral control element and the derivative control element are combined at a second summing junction. A resulting signal from the second summing junction is multiplied by a gain factor denoted as x_{Rp}. The gain factor x_{Rp} scales the combined control signal to produce an appropriate control action magnitude. The processed control signal then feeds into a thruster block that represents the Hall effect thruster discharge plasma dynamics.

The thruster block outputs a ratio B/B₀ representing a normalized magnetic field. The normalized magnetic field ratio B/B₀ indicates the magnetic field strength relative to a nominal magnetic field value B₀. The magnetic field output affects the discharge current I through the plasma dynamics of the Hall effect thruster. The discharge current I is fed back through a feedback loop to complete the closed-loop system by returning to the input summing junction where the discharge current I is subtracted from the reference current input I₀.

The control architecture shown in FIG. 5 represents a PI-type or PID-type controller structure applied to Hall thruster oscillation control. The magnetic field ratio B/B₀ serves as a control actuation mechanism to regulate discharge current oscillations around a desired setpoint. By adjusting the magnetic field strength in response to deviations of the discharge current from the reference current, the feedback control system may attenuate breathing mode oscillations in the discharge plasma. The integral control element may eliminate steady-state offset between the actual discharge current and the desired reference current. The derivative control element may provide anticipatory control action that improves the dynamic response of the feedback control system to rapid changes in the discharge current associated with breathing mode oscillations.

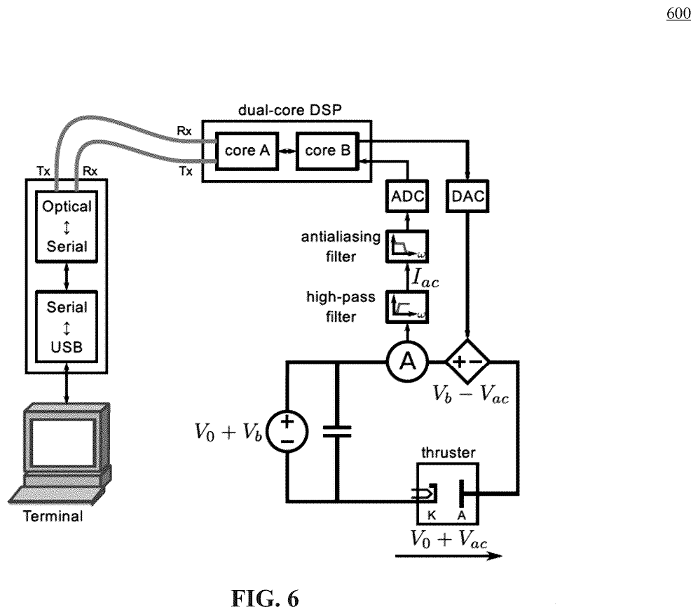

Referring to FIG. 6, a simplified block diagram of a Hall thruster power processing unit control system architecture is shown. The control system architecture includes a terminal computer positioned on the left side of the block diagram. The terminal computer provides a user interface for configuring control parameters and monitoring system operation. The terminal computer interfaces with the control system through a Serial to USB converter. The Serial to USB converter converts serial communication signals from the control system to USB format for connection to the terminal computer.

With continued reference to FIG. 6, an Optical to Serial converter is connected to the Serial to USB converter. The Optical to Serial converter provides electrical isolation between the terminal computer and the control electronics through optical signal transmission. The Optical to Serial converter carries transmit signals and receive signals between the terminal computer interface and a dual-core digital signal processor. The optical isolation protects the terminal computer from electrical noise and voltage transients that may occur during Hall effect thruster operation.

The dual-core digital signal processor is shown in the block diagram containing a core A and a core B. The dual-core digital signal processor handles the computational requirements of the control system. The core A and the core B may execute control algorithms in parallel to achieve the processing speed required for real-time control of breathing mode oscillations. The dual-core digital signal processor receives measurement data from sensing components and computes control outputs based on the implemented control algorithm.

As further shown in FIG. 6, an analog-to-digital converter is connected to the dual-core digital signal processor. The analog-to-digital converter is configured to digitize discharge current measurement data received from a current sensing path. The analog-to-digital converter receives a filtered AC current signal designated as I_{ac} through a signal conditioning chain. The signal conditioning chain includes an antialiasing filter connected to the input of the analog-to-digital converter. The antialiasing filter attenuates frequency components above the Nyquist frequency of the analog-to-digital converter to prevent aliasing artifacts in the digitized discharge current measurement data.

A high-pass filter is connected in the signal conditioning chain between the antialiasing filter and a current amplifier. The high-pass filter removes DC offset components from the discharge current signal to isolate the AC oscillation components for processing by the control system. The current amplifier is shown in the block diagram with a symbol marked with an “A” in a circle. The current amplifier receives an input representing the difference between a bias voltage V_{b} and an AC component V_{ac}. The current amplifier amplifies the discharge current signal to a level suitable for processing by the analog-to-digital converter.

A current sensor may be configured to measure a discharge current of the Hall effect thruster and generate discharge current measurement data. The current sensor may comprise a current probe or current transformer positioned in the discharge current path. The discharge current measurement data from the current sensor is conditioned by the signal chain comprising the current amplifier, the high-pass filter, and the antialiasing filter before being digitized by the analog-to-digital converter.

With continued reference to FIG. 6, a digital-to-analog converter is connected to the dual-core digital signal processor. The digital-to-analog converter is configured to convert a control voltage output from the dual-core digital signal processor to an analog control signal. The analog control signal from the digital-to-analog converter is combined with a DC voltage source at a summing junction. The DC voltage source provides a nominal discharge voltage designated as V₀ plus a bias voltage V_{b}. The summing junction combines the DC voltage with the analog control signal to produce a modulated discharge voltage for the Hall effect thruster.

The modulated discharge voltage feeds into the Hall effect thruster, which is represented in the block diagram by a circuit symbol showing a cathode terminal designated K and an anode terminal designated A. The Hall effect thruster produces an output voltage designated as V₀ plus V_{ac}, where V_{ac} represents the AC voltage component resulting from the discharge plasma oscillations. The closed-loop feedback architecture enables discharge current oscillations to be sensed by the current sensor, digitized by the analog-to-digital converter, processed by the dual-core digital signal processor, and compensated through voltage modulation applied via the digital-to-analog converter to control plasma oscillations in the Hall effect thruster discharge.

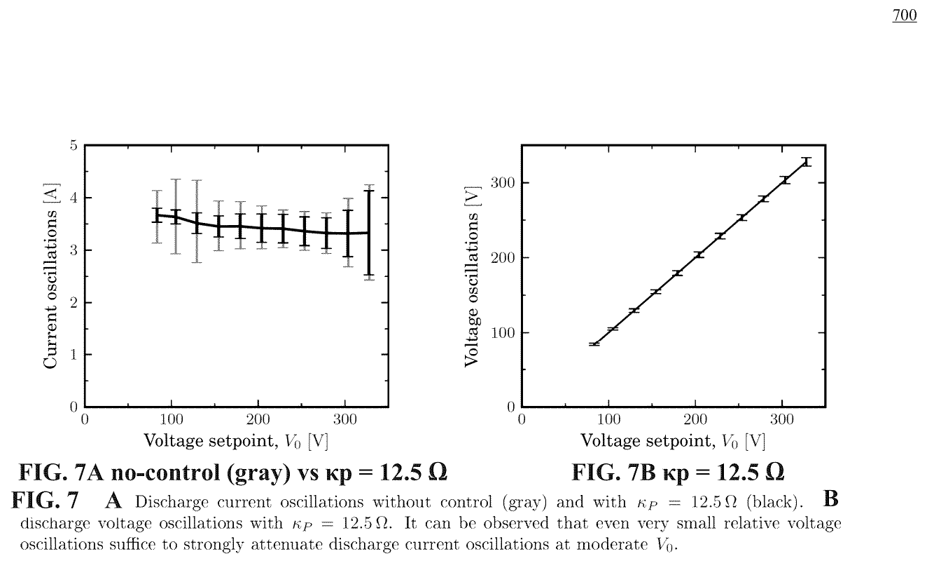

Referring to FIG. 7A, a graph showing the relationship between current oscillations and voltage setpoint for a Hall effect thruster discharge plasma is presented. The graph plots current oscillations measured in amperes on the vertical axis against voltage setpoint V₀ measured in volts on the horizontal axis. The voltage setpoint ranges from approximately 0 volts to 350 volts. The current oscillations range from 0 amperes to 5 amperes.

The data points in FIG. 7A are connected by a solid black line that shows a slight downward trend as the voltage setpoint increases. At a voltage setpoint of approximately 80 volts, the current oscillations measure approximately 3.6 amperes. As the voltage setpoint increases toward 325 volts, the current oscillations gradually decrease to approximately 3.3 amperes. Each data point includes error bars indicating measurement uncertainty or variability in the current oscillation measurements. The error bars span roughly plus or minus 0.5 to 0.8 amperes at most data points, suggesting variation in the discharge current oscillations across repeated measurements or operating conditions.

With continued reference to FIG. 7A, the graph characterizes the behavior of discharge current oscillations in Hall effect thrusters across different voltage operating points. The discharge current oscillations represent the breathing mode oscillations that arise from predator-prey interactions between neutrals and electrons in the discharge plasma. The characterization of discharge current oscillation amplitude as a function of voltage setpoint provides information for understanding the load dynamics that a machine learning-based model predictive path integral control system may regulate and minimize. The data demonstrates that discharge current oscillation amplitude may vary with the operating voltage of the Hall effect thruster, with higher voltage setpoints generally corresponding to slightly reduced oscillation amplitudes in the measured range.

Referring to FIG. 7B, a graph illustrating the relationship between voltage oscillations and voltage setpoint in a Hall effect thruster discharge system operating under proportional control is presented. The proportional control employs a gain κ_{P} equal to 12.5 ohms. The horizontal axis represents the voltage setpoint V₀ measured in volts, ranging from 0 volts to approximately 350 volts. The vertical axis represents the voltage oscillations measured in volts, also ranging from 0 volts to approximately 325 volts.

The data points in FIG. 7B are connected by a solid line and include error bars indicating measurement uncertainty at each operating point. The relationship between voltage oscillations and voltage setpoint appears to be strongly linear. The voltage oscillations increase proportionally as the voltage setpoint increases. At the lowest measured setpoint of approximately 80 volts, the voltage oscillations measure approximately 80 volts. At the highest setpoint near 325 volts, the voltage oscillations reach approximately 325 volts. The near one-to-one correspondence suggests that under the proportional control configuration with gain κ_{P} equal to 12.5 ohms, the amplitude of voltage oscillations scales directly with the applied voltage setpoint.

As further shown in FIG. 7B, the error bars remain relatively consistent in magnitude across the entire range of voltage setpoints, indicating uniform measurement precision throughout the experimental conditions. The characterization of voltage oscillation behavior as a function of setpoint voltage informs the design of model predictive path integral control strategies for managing plasma oscillations in the Hall effect thruster propulsion system. The proportional control approach demonstrates that small relative voltage oscillations may suffice to attenuate discharge current oscillations at moderate voltage setpoints. The linear relationship between voltage oscillations and voltage setpoint under proportional control provides a baseline characterization against which more advanced control approaches such as neural network-based model predictive path integral control may be compared.

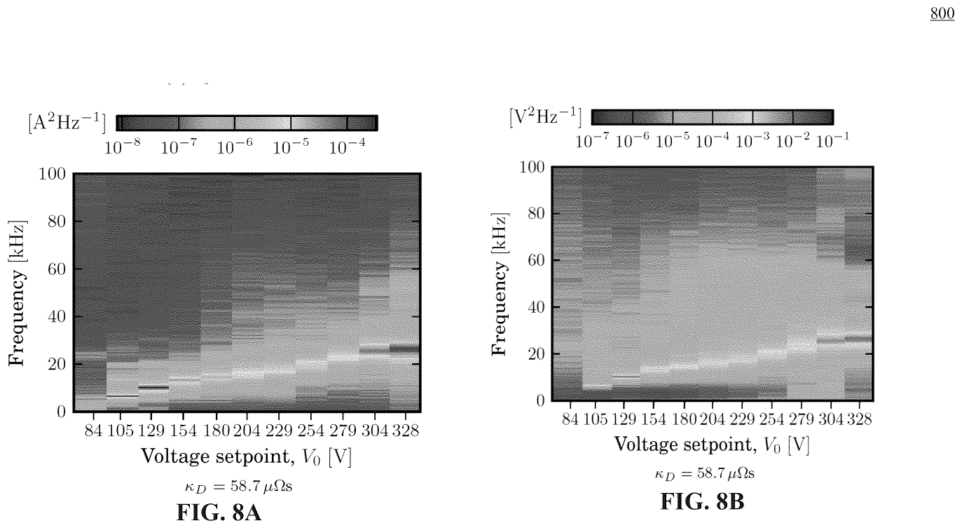

Referring to FIG. 8A, a two-dimensional color map displaying current power spectral density measurements as a function of both frequency and voltage setpoint for a Hall effect thruster discharge plasma is presented. The vertical axis represents frequency ranging from 0 kHz to 100 kHz. The horizontal axis shows the voltage setpoint V₀ spanning from 84 V to 328 V. A color scale indicates the current power spectral density in units of A²/Hz, ranging from 10⁻⁸ (dark blue) to 10⁻⁴ (red) on a logarithmic scale.

With continued reference to FIG. 8A, the color map reveals distinct spectral features that vary with operating voltage. At lower voltage setpoints around 84 V to 129 V, a prominent high-intensity band appears in the 5 kHz to 15 kHz frequency range. The high-intensity band corresponds to breathing mode oscillations in the discharge plasma. As the voltage setpoint increases, the dominant oscillation band shifts to higher frequencies. At the highest voltage setpoints near 304 V to 328 V, the breathing mode oscillation band reaches approximately 20 kHz to 30 kHz.

The intensity of the oscillations also increases with voltage setpoint, as evidenced by the transition from green and yellow colors at lower voltages to orange and red colors at higher voltages in the color map. A parameter κ_{D} equal to 58.7 μΩ·s is noted below the color map, which relates to a derivative gain coefficient used in control analysis. The spectral characterization data in FIG. 8A demonstrates how the frequency-dependent behavior of the discharge plasma varies across different operating conditions. The characterization informs the design of control strategies for oscillation suppression by identifying the frequency bands where breathing mode oscillations concentrate at each voltage setpoint.

Referring to FIG. 8B, a two-dimensional spectrogram displaying power spectral density as a function of frequency and voltage setpoint for a Hall effect thruster discharge plasma is presented. The Hall effect thruster operates with a derivative gain parameter κ_{D} equal to 58.7 μΩ·s. The vertical axis represents frequency ranging from approximately 0 kHz to 100 kHz. The horizontal axis shows the voltage setpoint V₀ spanning from 84 V to 328 V. A color scale indicates power spectral density in units of V²/Hz, ranging from 10⁻⁷ to 10⁻¹ on a logarithmic scale, with blue representing lower spectral density and red representing higher spectral density.

With continued reference to FIG. 8B, the spectrogram reveals the evolution of discharge current oscillations across different operating voltages. A prominent high-intensity band is visible in the frequency range of approximately 10 kHz to 30 kHz. The high-intensity band becomes increasingly intense and shifts in frequency as the voltage setpoint increases toward higher values. At lower voltage setpoints around 84 V to 154 V, localized regions of elevated spectral density appear at frequencies below 20 kHz.

As the voltage increases beyond approximately 254 V, a concentration of oscillation energy appears in the 20 kHz to 30 kHz range. The concentration is indicated by orange and red coloring in the spectrogram, representing the breathing mode oscillations characteristic of Hall effect thruster operation. The spectrogram demonstrates the voltage-dependent nature of plasma oscillations that a machine learning-based model predictive path integral control system may characterize and suppress through real-time voltage modulation.

The impedance of the discharge plasma may be characterized using a short-time Fourier transform for analyzing the frequency content of discharge voltage and discharge current signals over time. In some cases, a continuous wavelet transform may be employed for time-frequency analysis of the discharge plasma impedance. The continuous wavelet transform may provide improved time-frequency resolution compared to the short-time Fourier transform for capturing transient oscillation behavior. In some cases, an IMFogram based on empirical mode decomposition may be used for time-varying and nonlinear analysis of the discharge plasma impedance. The IMFogram decomposes the discharge current and discharge voltage signals into intrinsic mode functions that capture nonlinear and non-stationary oscillation characteristics of the Hall effect thruster discharge plasma.

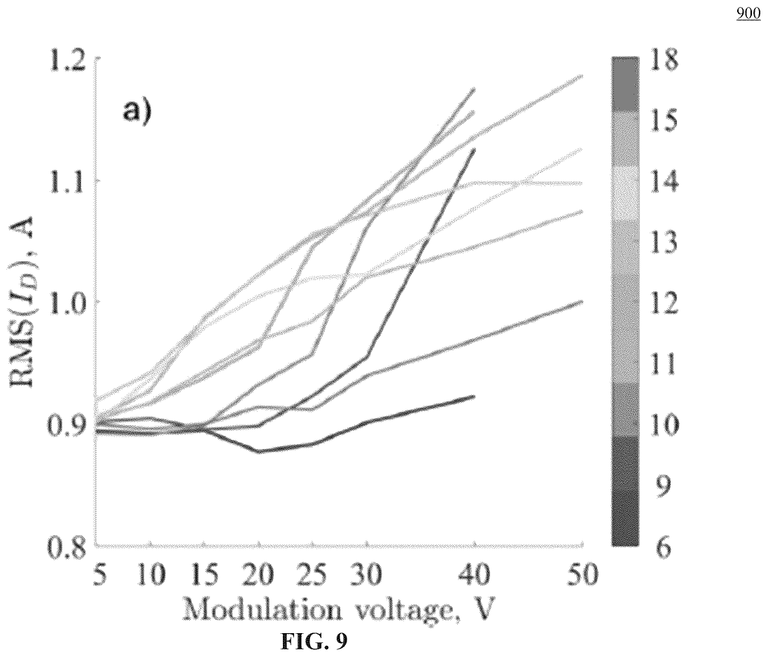

Referring to FIG. 9, a graph showing the relationship between modulation voltage and the root mean square (RMS) of the discharge current is presented. The horizontal axis represents the modulation voltage ranging from 5 V to 50 V. The vertical axis displays the RMS discharge current values designated as RMS(I_{D}) in amperes, spanning approximately 0.9 A to 1.2 A. The graph contains multiple colored curves, with each curve corresponding to a different parameter value as indicated by a color scale on the right side of the graph. The color scale ranges from 6 (blue) to 18 (red), with the parameter values representing different operating conditions or settings during Hall effect thruster operation.

With continued reference to FIG. 9, the curves demonstrate an increasing trend in RMS discharge current as the modulation voltage increases. The relationship between modulation voltage and RMS discharge current is more pronounced at higher modulation voltages above approximately 25 V to 30 V. At lower modulation voltages between 5 V and 15 V, the RMS discharge current values remain relatively stable around 0.9 A across most parameter values represented by the different colored curves.

The divergence of the curves at higher modulation voltages indicates that the discharge current response to voltage modulation depends on the operating parameter represented by the color scale. The data in FIG. 9 demonstrates how voltage perturbations affect Hall effect thruster discharge dynamics. The characterization of discharge current response to modulation voltage at various operating conditions informs the design of control strategies for managing plasma oscillations through controlled voltage modulation of the discharge.

A system identification process may use perturbation signals to characterize the discharge plasma dynamics. The perturbation signals may include sine waves applied at various amplitudes, frequencies, and phases. In some cases, the perturbation signals may include square waves. In some cases, the perturbation signals may include triangle waves. In some cases, the perturbation signals may include ramp signals. In some cases, the perturbation signals may include chirp signals that sweep through a range of frequencies over time. In some cases, the perturbation signals may include combinations of sinusoids at multiple frequencies. In some cases, the perturbation signals may include noise signals such as bandlimited noise. In some cases, the perturbation signals may include pseudorandom binary sequences. The various perturbation signal types may be applied at different amplitudes, frequencies, and phases to characterize the frequency-dependent response and impedance of the discharge plasma across the breathing mode frequency band and surrounding frequencies.

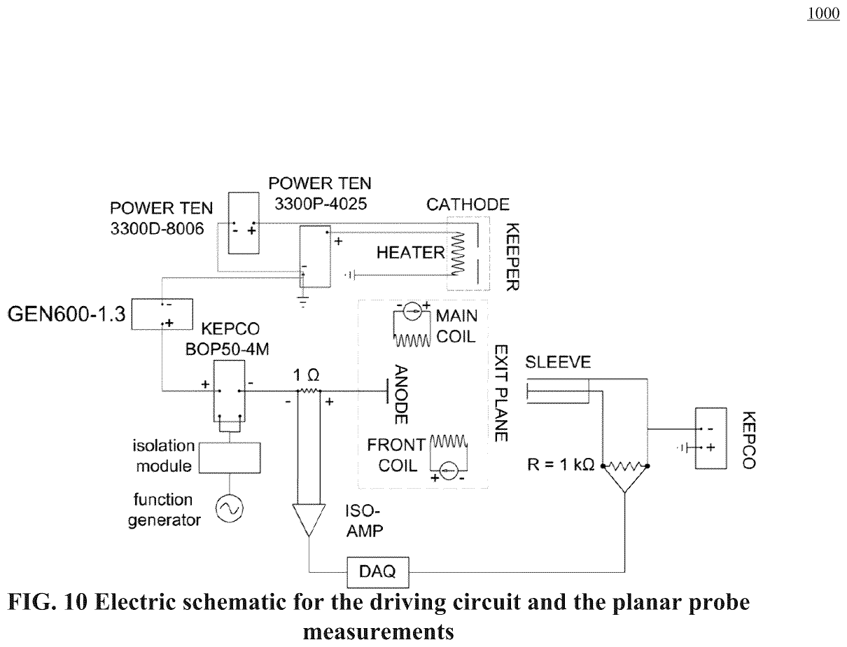

Referring to FIG. 10, an electrical schematic for a driving circuit and planar probe measurement system used in Hall effect thruster experiments is shown. The driving circuit configuration enables sinusoidal voltage modulations to be added to the DC discharge voltage for characterizing discharge plasma dynamics.

On the left side of the electrical schematic, a GEN600-1.3 power supply is connected to a KEPCO BOP50-4M amplifier. The KEPCO BOP50-4M amplifier receives an input from a function generator through an isolation module. The isolation module provides electrical isolation between the function generator and the KEPCO BOP50-4M amplifier to protect the function generator from voltage transients and noise that may occur during Hall effect thruster operation. The function generator produces voltage modulation waveforms that are superimposed on the DC discharge voltage to perturb the discharge plasma for system identification and control purposes.

With continued reference to FIG. 10, the KEPCO BOP50-4M amplifier is connected in series with a POWER TEN 3300D-8006 power supply. The KEPCO BOP50-4M amplifier and the POWER TEN 3300D-8006 power supply together provide a modulated anode potential to the Hall effect thruster. The series connection enables the voltage modulation signal from the KEPCO BOP50-4M amplifier to be added to the DC discharge voltage provided by the POWER TEN 3300D-8006 power supply. The combined output delivers the modulated discharge voltage to the anode of the Hall effect thruster.

A 1 ohm resistor is placed in the circuit between the KEPCO BOP50-4M amplifier and the anode of the Hall effect thruster. The 1 ohm resistor serves as a current shunt for measuring the discharge current. A voltage drop across the 1 ohm resistor is proportional to the discharge current flowing through the circuit. The voltage signal from the 1 ohm resistor current shunt passes through an isolation amplifier designated as ISO-AMP in the electrical schematic. The isolation amplifier provides electrical isolation between the high-voltage discharge circuit and a data acquisition system designated as DAQ. The data acquisition system records the discharge current measurements for analysis and control purposes.

As further shown in FIG. 10, the Hall effect thruster components depicted in the electrical schematic include a heater, a cathode, a keeper, an anode, a main coil, and a front coil. The heater is powered by a POWER TEN 3300P-4025 power supply. The heater provides thermal energy to the cathode to achieve a temperature sufficient for thermionic electron emission. The cathode provides electrons for ionization of propellant within the discharge channel and for neutralization of the ion beam exiting the Hall effect thruster. The keeper maintains electron emission from the cathode during operation.

The main coil and the front coil are electromagnets that produce and control the magnetic field distribution in the cylindrical Hall thruster channel. The main coil and the front coil together generate a radial magnetic field that confines electrons within the discharge channel and establishes the Hall current that enables ion acceleration. The magnetic field configuration may be adjusted by varying the current supplied to the main coil and the front coil to optimize thruster performance and control discharge plasma oscillations.

On the right side of the electrical schematic in FIG. 10, a planar probe measurement system is depicted. The planar probe measurement system includes a planar probe positioned at an exit plane of the Hall effect thruster. A sleeve surrounds the planar probe to provide mechanical support and electrical shielding. The planar probe is connected to a 1 kilo-ohm resistor. The 1 kilo-ohm resistor is connected to a KEPCO power supply that provides a negative bias voltage of minus 40 volts to the planar probe.

The negative bias voltage applied to the planar probe enables ion current collection measurements. When the planar probe is biased to a negative potential relative to the plasma potential, the planar probe repels electrons and collects ions from the discharge plasma. The ion current collected by the planar probe provides a measurement of ion flux at the exit plane of the Hall effect thruster. The ion flux measurements may be used to characterize thruster performance and to correlate with discharge current oscillations measured in the driving circuit. The planar probe measurement system enables characterization of plasma parameters that complement the electrical measurements obtained from the driving circuit for developing machine learning-based control strategies for managing plasma oscillations in the Hall effect thruster discharge.

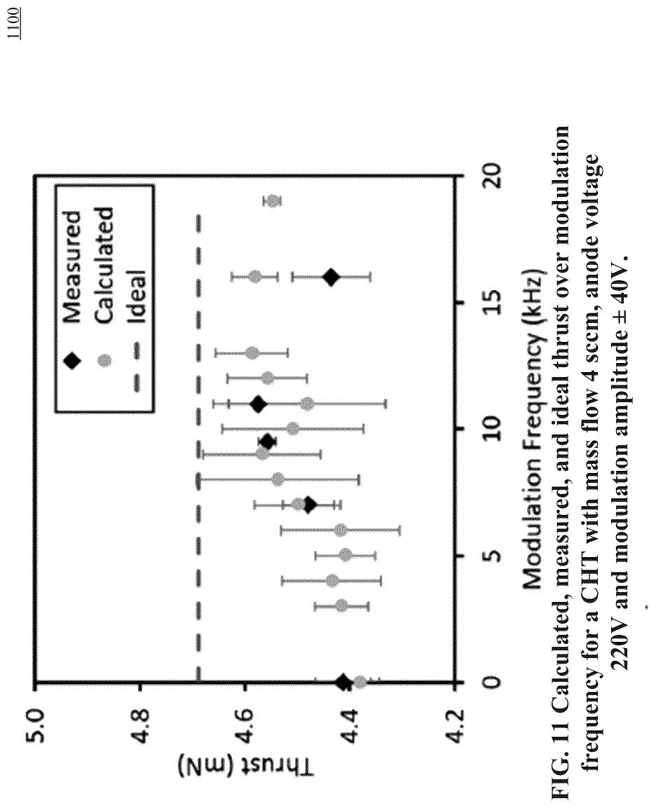

Referring to FIG. 11, a graph showing thrust performance as a function of modulation frequency for a cylindrical Hall thruster is presented. The cylindrical Hall thruster operates with a mass flow rate of 4 sccm, an anode voltage of 220 V, and a modulation amplitude of plus or minus 40 V. The vertical axis displays thrust in millinewtons ranging from approximately 4.2 mN to 5.0 mN. The horizontal axis shows modulation frequency in kilohertz spanning from 0 kHz to approximately 20 kHz.

With continued reference to FIG. 11, three data series are plotted on the graph to compare different thrust characterizations. Black diamond markers represent measured thrust values obtained experimentally at various modulation frequencies. Gray circular markers indicate calculated thrust values derived from theoretical or computational analysis of the cylindrical Hall thruster performance under voltage modulation conditions. A horizontal purple dashed line represents an ideal thrust value of approximately 4.7 mN that remains constant across all modulation frequencies.

The measured thrust values and the calculated thrust values demonstrate good agreement with each other across the modulation frequency range. Both the measured thrust values and the calculated thrust values fluctuate around 4.4 mN to 4.6 mN across the frequency range from 0 kHz to 20 kHz. Error bars are included on the data points to indicate measurement uncertainty associated with the thrust measurements.

As further shown in FIG. 11, both the measured thrust values and the calculated thrust values remain below the ideal thrust line throughout the tested frequency range. The thrust shows a slight increase from the lowest frequencies toward the middle of the frequency range before leveling off at higher modulation frequencies. The difference between the measured thrust values and the ideal thrust value indicates that voltage modulation at the tested frequencies does not achieve the maximum theoretical thrust performance of the cylindrical Hall thruster.

The relationship between modulation frequency and thrust performance demonstrates that the control system may be configured to phase align discharge voltage oscillations and discharge current oscillations to maximize thrust rather than minimize oscillations. When the discharge voltage and the discharge current are phase aligned, more real power may be transferred to the discharge plasma for ion acceleration, resulting in increased thrust output. The phase relationship between the discharge voltage oscillations and the discharge current oscillations affects the power factor of the discharge circuit, with in-phase voltage and current corresponding to maximum real power transfer and minimum reactive power. The modulation frequency may be selected to achieve a desired phase relationship between the discharge voltage and the discharge current based on the impedance characteristics of the discharge plasma at different frequencies.

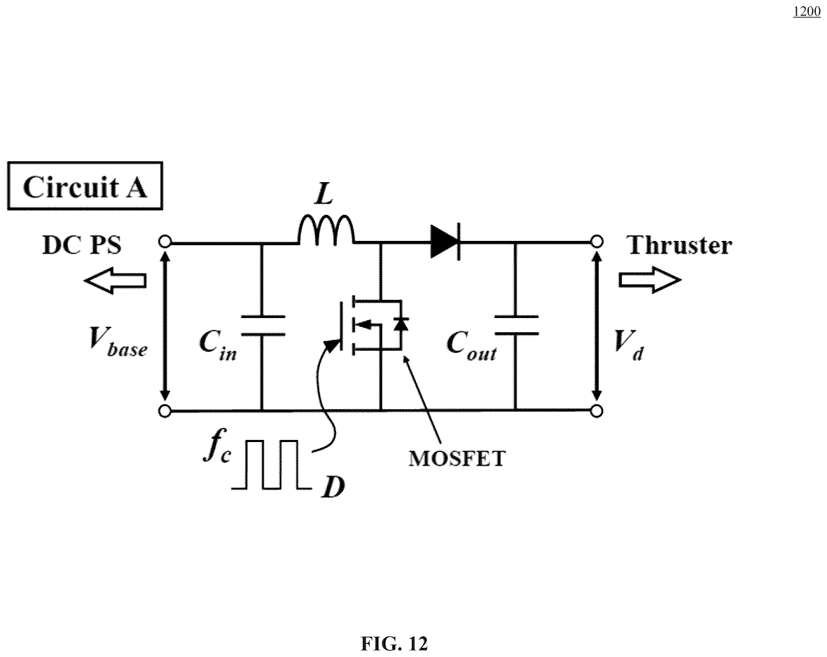

Referring to FIG. 12, a simplified block diagram of Circuit A is shown depicting a Hall thruster power processing unit discharge circuit configuration. The discharge circuit configuration employs a switching converter topology for regulating the discharge voltage supplied to the Hall effect thruster. On the left side of the block diagram, a DC power supply designated as DC PS provides a base voltage V_{base} to the circuit. The DC power supply serves as the primary power source for the Hall effect thruster discharge.

An input capacitor designated as Cᵢₙ is connected in parallel with the DC power supply input. The input capacitor Cᵢₙ provides energy storage and filtering at the input of the switching converter. The input capacitor Cᵢₙ may reduce voltage ripple on the input power bus and provide a low-impedance source for the switching transients that occur during converter operation.

With continued reference to FIG. 12, an inductor designated as L is connected in series between the input section and the output section of the circuit. The inductor L serves as an energy storage element in the switching converter topology. The inductor L stores energy in a magnetic field during one portion of the switching cycle and releases the stored energy during another portion of the switching cycle. The inductor L together with the switching elements enables voltage regulation and power conversion between the DC power supply and the Hall effect thruster load.

A MOSFET switching device is shown connected between a node of the inductor L and ground. The MOSFET switching device operates as a controllable switch that alternates between conducting and non-conducting states at a switching frequency designated as f_{c}. The switching frequency f_{c} determines the rate at which the MOSFET switching device transitions between the conducting state and the non-conducting state. The duty cycle of the MOSFET switching device may be adjusted to regulate the output voltage delivered to the Hall effect thruster.

As further shown in FIG. 12, a diode designated as D is positioned in the circuit to allow current flow in an appropriate direction during the switching cycle. The diode D conducts current when the MOSFET switching device is in the non-conducting state, providing a path for inductor current to flow to the output. The diode D blocks reverse current flow when the MOSFET switching device is in the conducting state.

An output capacitor designated as Cₒᵤₜ is connected in parallel with the Hall effect thruster load. The output capacitor Cₒᵤₜ filters the switched waveform to produce a regulated discharge voltage V_{d} at the output. The output capacitor Cₒᵤₜ smooths voltage ripple caused by the switching action of the MOSFET switching device and provides energy storage to maintain the discharge voltage during transient load conditions.

The Hall effect thruster is represented on the right side of the block diagram as the load that receives the regulated discharge voltage V_{d}. The switching converter topology illustrated in FIG. 12 enables active voltage regulation through adjustment of the switching frequency f_{c} and the duty cycle of the MOSFET switching device. The circuit configuration may be employed to modulate the discharge voltage for controlling plasma oscillations in the Hall effect thruster discharge. By varying the switching parameters, the discharge voltage V_{d} may be adjusted in real time to influence the breathing mode oscillations in the discharge plasma.

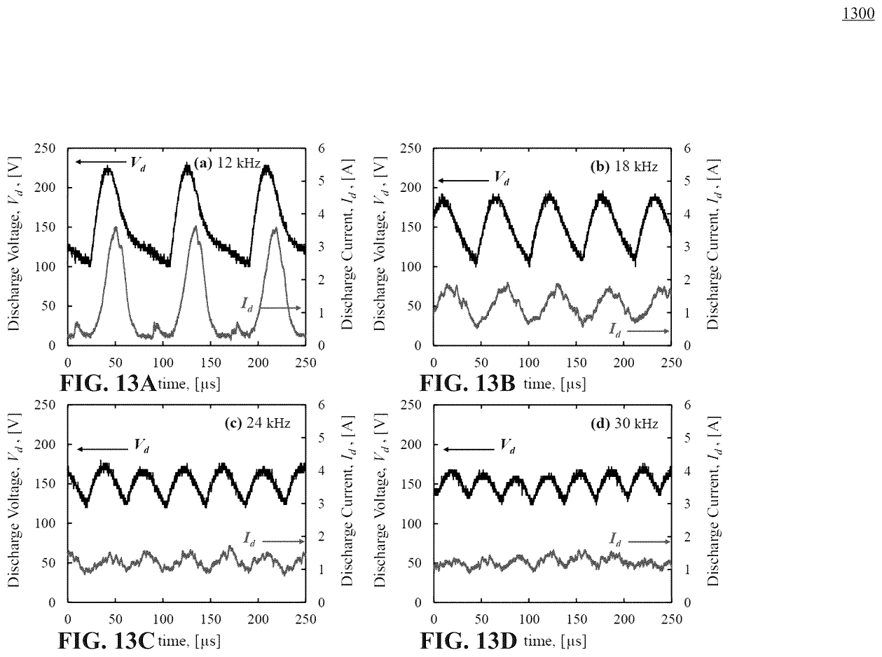

Referring to FIG. 13, four panels labeled FIG. 13A through FIG. 13D present time-domain waveforms of discharge voltage and discharge current at different chopping frequencies for a Hall effect thruster power processing unit. Each panel displays the temporal behavior of the discharge voltage and the discharge current over a time window spanning from 0 microseconds to 250 microseconds. In each panel, a black trace represents the discharge voltage V_{d} measured in volts on a left vertical axis, and a red trace represents the discharge current I_{d} measured in amperes on a right vertical axis.

FIG. 13A shows operation at a chopping frequency of 12 kHz. At the 12 kHz chopping frequency, the discharge voltage exhibits large sawtooth-like oscillations ranging approximately from 100 V to over 200 V. The discharge voltage waveform displays a characteristic ramp-up pattern followed by a rapid discharge, creating a sawtooth profile with peak-to-peak voltage variations exceeding 100 V. The corresponding discharge current oscillations show distinct peaks reaching approximately 4 A, with the discharge current waveform exhibiting pronounced fluctuations that correlate with the discharge voltage transitions.

With continued reference to FIG. 13, FIG. 13B shows operation at a chopping frequency of 18 kHz. At the 18 kHz chopping frequency, the discharge voltage waveform transitions from the large amplitude sawtooth patterns observed at 12 kHz to a waveform with reduced peak-to-peak variation. The discharge voltage oscillations at 18 kHz exhibit smaller amplitude excursions compared to the 12 kHz case. The discharge current oscillations at 18 kHz become smoother with reduced peak amplitudes compared to the 12 kHz operating condition.

FIG. 13C shows operation at a chopping frequency of 24 kHz. At the 24 kHz chopping frequency, the discharge voltage waveform exhibits further reduction in ripple amplitude compared to the lower chopping frequencies. The sawtooth pattern becomes less pronounced, and the peak-to-peak voltage variation decreases. The discharge current waveform at 24 kHz displays more uniform oscillations with reduced peak amplitudes and less pronounced fluctuations compared to the 12 kHz and 18 kHz cases.

As further shown in FIG. 13, FIG. 13D shows operation at a chopping frequency of 30 kHz. At the 30 kHz chopping frequency, the discharge voltage waveform exhibits the smallest amplitude ripple oscillations among the four chopping frequencies presented. The voltage ripple at 30 kHz appears as small amplitude variations superimposed on the mean discharge voltage, with substantially reduced peak-to-peak variation compared to the 12 kHz case. The discharge current oscillations at 30 kHz are the smoothest and most uniform among the four operating conditions, with reduced peak amplitudes and less pronounced fluctuations.

The progression from 12 kHz to 30 kHz chopping frequency demonstrates that increasing the chopping frequency of a pulsating boost chopper affects the discharge voltage and discharge current waveforms. Higher chopping frequencies result in reduced voltage ripple and more stable current delivery to the Hall effect thruster discharge plasma. The reduced voltage ripple at higher chopping frequencies may decrease the amplitude of discharge current oscillations by providing a more constant discharge voltage to the Hall effect thruster. The relationship between chopping frequency and waveform characteristics informs the selection of switching parameters for power processing unit designs that aim to minimize discharge plasma oscillations through voltage regulation approaches.

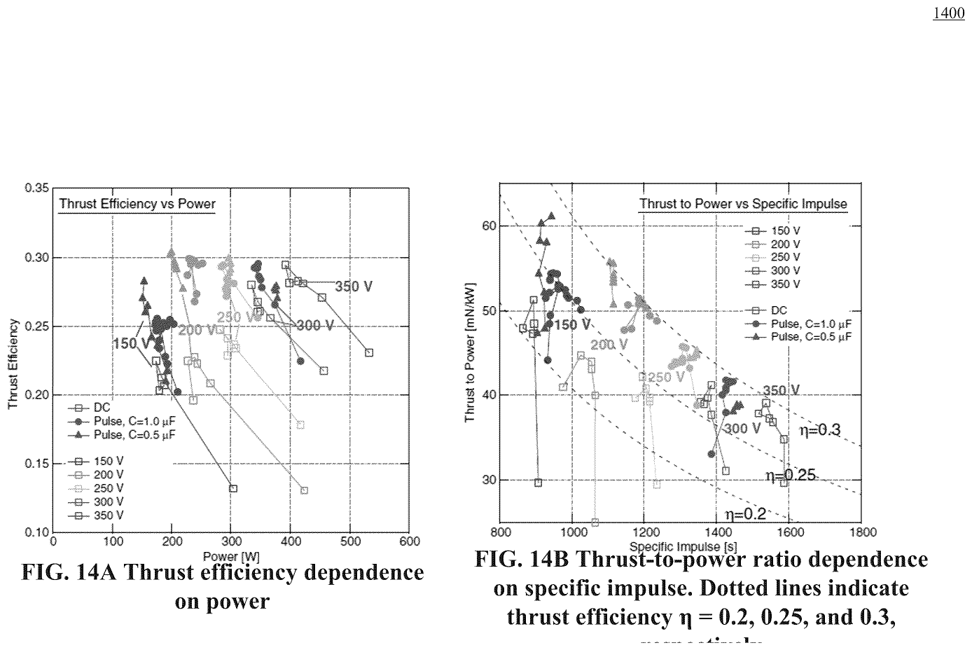

Referring to FIG. 14A, a graph illustrating the relationship between thrust efficiency and power consumption for a Hall effect thruster operating under different voltage conditions and power delivery modes is presented. The vertical axis represents thrust efficiency ranging from approximately 0.10 to 0.30. The horizontal axis displays power in watts ranging from 0 W to 600 W. The data in FIG. 14A is organized by discharge voltage levels including 150 V, 200 V, 250 V, 300 V, and 350 V. Each discharge voltage level is represented by a distinct color, with blue corresponding to 150 V, green corresponding to 200 V, orange corresponding to 250 V, red corresponding to 300 V, and purple corresponding to 350 V.

With continued reference to FIG. 14A, three different operating modes are compared for each discharge voltage level. DC operation is shown with open square markers. Pulsed operation with a 1.0 microfarad capacitor is shown with filled circular markers. Pulsed operation with a 0.5 microfarad capacitor is shown with filled triangular markers. The three operating modes enable comparison of thrust efficiency performance between continuous DC power delivery and pulsed power delivery with different energy storage capacitances.

The graph in FIG. 14A demonstrates that for each discharge voltage level, the pulsed operating modes may achieve higher thrust efficiency at lower power levels compared to DC operation. At each discharge voltage, the pulsed operation data points with the smaller 0.5 microfarad capacitor and the larger 1.0 microfarad capacitor tend to cluster at lower power consumption values while achieving comparable or higher thrust efficiency values relative to the DC operation data points at the same discharge voltage.

As further shown in FIG. 14A, as power increases within each voltage group, thrust efficiency tends to decrease. The pulsed modes with smaller capacitance values appear to achieve the highest efficiency points at the lowest power consumption within each voltage category. The data demonstrates that different power delivery strategies and voltage modulation approaches may affect Hall effect thruster performance. The pulsed operating modes may enable operation at reduced power consumption while maintaining or improving thrust efficiency compared to continuous DC operation at the same discharge voltage level.

Referring to FIG. 14B, a graph depicting the relationship between thrust-to-power ratio and specific impulse for a Hall effect thruster operating under various voltage conditions is presented. The vertical axis displays thrust-to-power ratio measured in millinewtons per kilowatt. The horizontal axis shows specific impulse measured in seconds. The data points in FIG. 14B are organized by discharge voltage levels of 150 V, 200 V, 250 V, 300 V, and 350 V, represented by different colored markers including blue, green, yellow, orange, and red respectively.

With continued reference to FIG. 14B, for each discharge voltage level, three operational modes are shown. DC operation is indicated by open square markers. Pulsed operation with a capacitance of 1.0 microfarads is shown as filled circles. Pulsed operation with a capacitance of 0.5 microfarads is depicted as filled triangles. The three operational modes enable comparison of thrust-to-power ratio and specific impulse performance between continuous DC power delivery and pulsed power delivery configurations.

The graph in FIG. 14B demonstrates that as discharge voltage increases from 150 V to 350 V, the operating points shift toward higher specific impulse values and generally lower thrust-to-power ratios. The higher discharge voltages accelerate ions to greater exhaust velocities, which increases specific impulse but may reduce the thrust-to-power ratio due to the increased power consumption associated with higher acceleration voltages.

As further shown in FIG. 14B, three diagonal dashed lines traverse the plot area representing constant thrust efficiency values. The three constant thrust efficiency lines correspond to thrust efficiency values of η=0.2, η=0.25, and η=0.3. Higher efficiency lines are positioned toward the upper right of the graph, indicating that operating points achieving higher thrust-to-power ratios at a given specific impulse correspond to higher thrust efficiency values.

The data in FIG. 14B reveals that pulsed operation modes tend to achieve higher specific impulse values compared to DC operation at the same discharge voltage level. The pulsed data points extend further to the right along the specific impulse axis relative to the DC operation data points at corresponding voltage levels. The characterization of thrust-to-power ratio versus specific impulse at different voltage levels and operational modes informs the design of control strategies that may optimize Hall effect thruster performance through voltage modulation techniques. The constant thrust efficiency lines provide reference contours for evaluating the efficiency of different operating configurations and for selecting operating points that achieve desired combinations of thrust-to-power ratio and specific impulse performance.

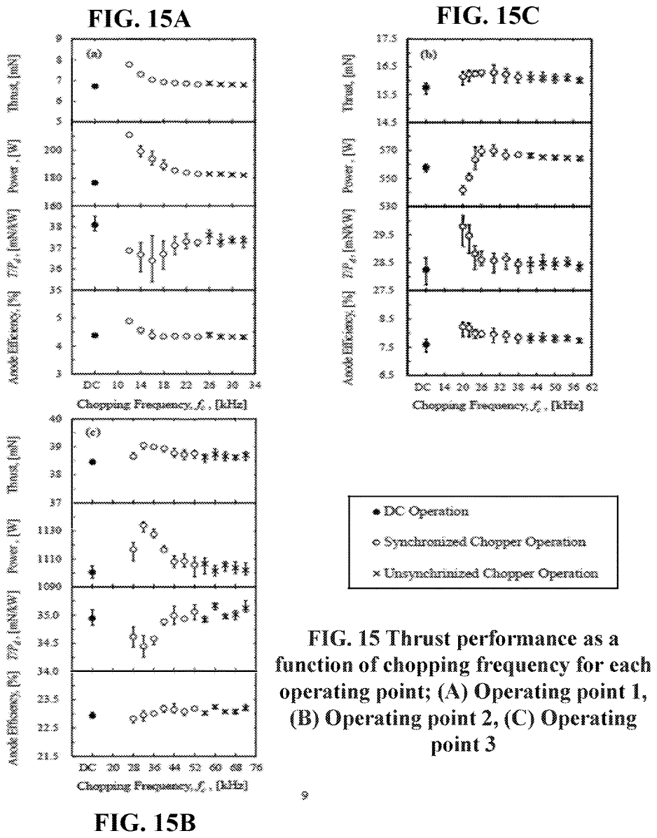

Referring to FIG. 15A, a multi-panel graph displaying thrust performance metrics as a function of chopping frequency for a Hall effect thruster operating at a first operating point is presented. The graph includes four vertically-aligned panels that share a common vertical axis representing chopping frequency. The chopping frequency axis ranges from DC operation at the top through various frequencies from 10 kHz to 34 kHz. The four horizontal axes from left to right display Anode Efficiency in percent, thrust-to-power ratio in millinewtons per kilowatt, Power in watts, and Thrust in millinewtons.

With continued reference to FIG. 15A, three different operational modes are represented by distinct markers in each panel. Filled circles indicate DC operation, which serves as a baseline reference condition where the power processing unit delivers continuous DC power to the Hall effect thruster without chopping modulation. Open circles represent synchronized chopper operation, where the chopping frequency of the power processing unit is synchronized with the breathing mode oscillations of the discharge plasma. X markers denote unsynchronized chopper operation, where the chopping frequency operates independently of the breathing mode oscillation frequency. Error bars are visible on the data points indicating measurement uncertainty associated with the thrust performance measurements.

The anode efficiency values in FIG. 15A range approximately from 3 percent to 5 percent across the tested chopping frequencies. The thrust-to-power ratio spans roughly 35 millinewtons per kilowatt to 38 millinewtons per kilowatt. The power consumption varies between approximately 160 watts and 200 watts. The thrust output ranges from about 5 millinewtons to 9 millinewtons. The data demonstrates how different chopping frequencies and synchronization states affect the overall thrust performance characteristics of the Hall effect thruster at the first operating point.

Referring to FIG. 15B, a multi-panel graph displaying thrust performance metrics as a function of chopping frequency for a Hall effect thruster operating at a second operating point is presented. The graph structure follows the same format as FIG. 15A, with four vertically stacked plots sharing a common horizontal axis representing chopping frequency in kilohertz. The chopping frequency ranges from DC operation through 14 kHz to 62 kHz. The four performance metrics displayed include thrust in millinewtons, power in watts, thrust-to-power ratio in millinewtons per kilowatt, and anode efficiency as a percentage.

With continued reference to FIG. 15B, the thrust measurements range approximately from 14.5 millinewtons to 17.5 millinewtons. The thrust increases from around 15.6 millinewtons at DC operation to approximately 16.3 millinewtons at higher chopping frequencies. The power consumption ranges between approximately 530 watts and 590 watts, with power increasing from about 560 watts at DC operation to around 575 watts to 580 watts at elevated chopping frequencies.

The thrust-to-power ratio in FIG. 15B spans from about 27.5 millinewtons per kilowatt to 30 millinewtons per kilowatt. The thrust-to-power ratio indicates an initial increase from approximately 28 millinewtons per kilowatt at DC operation to a peak near 29.5 millinewtons per kilowatt around 20 kHz to 26 kHz before stabilizing at lower values around 28 millinewtons per kilowatt to 28.5 millinewtons per kilowatt at higher frequencies. The anode efficiency ranges from approximately 6.6 percent to 8.5 percent, with efficiency rising from about 7.5 percent at DC operation to approximately 7.8 percent at higher chopping frequencies.

As further shown in FIG. 15B, the three operational modes of DC operation, synchronized chopper operation, and unsynchronized chopper operation are represented by filled circles, open circles, and X markers respectively. The data demonstrates that synchronized chopper operation at frequencies above approximately 26 kHz may yield improved thrust and efficiency compared to baseline DC operation at the second operating point.

Referring to FIG. 15C, a multi-panel graph displaying thrust performance metrics as a function of chopping frequency for a Hall effect thruster operating at a third operating point is presented. The graph displays four vertically-aligned panels sharing a common vertical axis representing chopping frequency ranging from DC operation through frequencies of 20 kHz, 28 kHz, 36 kHz, 44 kHz, 52 kHz, 60 kHz, 68 kHz, and 76 kHz.

With continued reference to FIG. 15C, the four horizontal axes display Anode Efficiency in percent ranging from approximately 21.5 percent to 23.5 percent, thrust-to-power ratio in millinewtons per kilowatt ranging from approximately 34.0 to 35.0, Power in watts ranging from approximately 1090 watts to 1130 watts, and Thrust in millinewtons ranging from approximately 37 millinewtons to 40 millinewtons. The third operating point corresponds to a higher power operating condition compared to the first operating point and the second operating point, as evidenced by the power consumption values exceeding 1000 watts and thrust values approaching 40 millinewtons.

The three operational modes are represented using the same marker convention as FIG. 15A and FIG. 15B, with filled circles for DC operation, open circles for synchronized chopper operation, and X markers for unsynchronized chopper operation. Error bars are visible on the data points indicating measurement uncertainty. The DC operation data point appears at the top of each panel, while the chopped operation data points span the frequency range below.

As further shown in FIG. 15C, the results demonstrate how different chopping frequencies and synchronization states affect the thruster performance parameters at the third operating point. The data shows variations in anode efficiency, thrust-to-power ratio, power consumption, and thrust output across the tested frequency range. The comparison between DC operation, synchronized chopper operation, and unsynchronized chopper operation enables evaluation of whether chopping the discharge voltage at specific frequencies may improve thrust performance metrics relative to continuous DC power delivery.

The thrust performance characterization across the three operating points presented in FIG. 15A, FIG. 15B, and FIG. 15C demonstrates that the relationship between chopping frequency and thrust performance may vary depending on the operating conditions of the Hall effect thruster. The synchronized chopper operation mode may achieve different performance characteristics compared to the unsynchronized chopper operation mode at the same chopping frequency, indicating that the phase relationship between the chopping waveform and the breathing mode oscillations may influence thrust generation. The characterization data informs the selection of chopping frequencies and synchronization strategies for power processing unit designs that aim to optimize Hall effect thruster thrust performance through voltage modulation approaches.

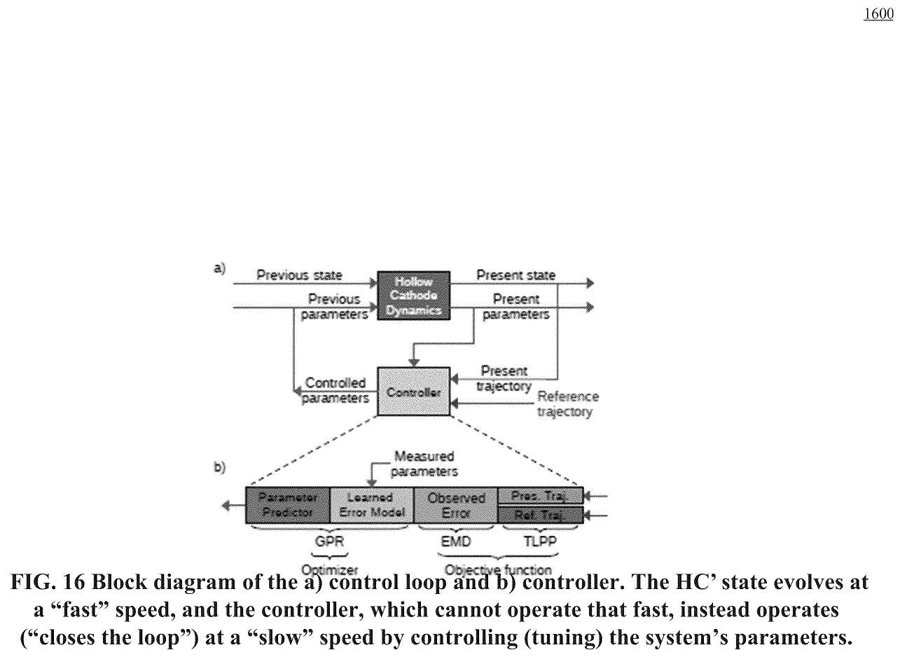

Referring to FIG. 16, a block diagram illustrating a control loop architecture and controller structure for a hollow cathode system is shown. The block diagram is divided into two portions designated as part a) and part b). Part a) depicts the overall control loop architecture, and part b) depicts the detailed internal structure of the controller.

With continued reference to FIG. 16, part a) shows a hollow cathode dynamics block that receives a previous state and previous parameters as inputs. The hollow cathode dynamics block models the temporal evolution of the hollow cathode system state based on the previous state values and the previous parameter values. The hollow cathode dynamics block outputs a present state and present parameters that represent the current operating condition of the hollow cathode system after the state evolution.

The present parameters output from the hollow cathode dynamics block feed into a controller block. The controller block also receives a present trajectory and a reference trajectory as inputs. The present trajectory represents the current observed behavior of the hollow cathode system over a time window. The reference trajectory represents a desired target behavior that the control system aims to achieve. The controller block processes the present parameters, the present trajectory, and the reference trajectory to compute controlled parameters.

As further shown in FIG. 16, the controlled parameters output from the controller block feed back to the hollow cathode dynamics block to complete the closed-loop control system. The feedback connection enables the controller to influence the evolution of the hollow cathode state by adjusting the system parameters based on the difference between the present trajectory and the reference trajectory.

The control loop architecture in part a) demonstrates a separation of time scales between the hollow cathode state evolution and the controller operation. The hollow cathode state evolves at a fast speed corresponding to the plasma dynamics time scale. The controller operates at a slower speed by controlling and tuning the system parameters rather than directly controlling the fast state dynamics. The separation of time scales enables the controller to influence the statistical properties of the fast state evolution through parameter adjustments without requiring the controller to operate at the same speed as the plasma dynamics.

With continued reference to FIG. 16, part b) shows the detailed internal structure of the controller block. The controller receives measured parameters as an input from the hollow cathode system. The measured parameters may include discharge current measurements, discharge voltage measurements, or other observable quantities that characterize the operating state of the hollow cathode system.

The controller comprises several functional blocks arranged to process the measured parameters and generate the controlled parameters output. A Parameter Predictor block employs Gaussian Process Regression designated as GPR. The Parameter Predictor block uses Gaussian Process Regression to predict future parameter values based on the measured parameters and historical data. Gaussian Process Regression provides a probabilistic framework for parameter prediction that may capture uncertainty in the predicted values and enable robust control decisions under uncertain operating conditions.

A Learned Error Model block is included in the controller structure. The Learned Error Model block captures systematic deviations between predicted behavior and observed behavior of the hollow cathode system. The Learned Error Model block may be trained on historical data to learn patterns in the prediction errors and to compensate for model inaccuracies in the control computations.

As further shown in FIG. 16, an Observed Error block employs an Earth Mover's Distance metric designated as EMD. The Earth Mover's Distance metric quantifies the difference between the present trajectory and the reference trajectory. The Earth Mover's Distance metric computes a distance measure between two probability distributions or trajectory representations by determining the minimum cost of transforming one distribution into the other. The Earth Mover's Distance metric may provide a robust measure of trajectory similarity that accounts for the shape and distribution of the trajectory data rather than relying on point-wise comparisons.

Trajectory blocks in the controller structure show a Present Trajectory representation and a Reference Trajectory representation. Both the Present Trajectory and the Reference Trajectory employ a Time-Lagged Phase Portrait representation designated as TLPP. The Time-Lagged Phase Portrait representation reconstructs the state space dynamics of the hollow cathode system from time series measurements by plotting the measured signal against time-delayed versions of the measured signal. The Time-Lagged Phase Portrait representation may capture the attractor structure and dynamical behavior of the hollow cathode system in a form suitable for comparison using the Earth Mover's Distance metric.

With continued reference to FIG. 16, labels below the functional blocks indicate the roles of the different components in the controller architecture. The GPR label indicates that Gaussian Process Regression serves as the optimizer function for parameter prediction. The EMD label indicates that the Earth Mover's Distance metric serves for error computation between trajectories. The TLPP label indicates that the Time-Lagged Phase Portrait representation serves as the objective function for evaluating control performance.

The controller architecture enables the control system to predict parameters using Gaussian Process Regression, learn from errors using the Learned Error Model, and compare observed trajectories against reference trajectories using the Earth Mover's Distance metric applied to Time-Lagged Phase Portrait representations. The combination of these functional blocks may enable the controller to generate control actions that drive the hollow cathode system toward desired operating behavior characterized by the reference trajectory. The controller architecture may be applied to manage plasma oscillations in Hall effect thruster systems by adjusting discharge parameters to achieve desired oscillation characteristics represented by the reference trajectory.

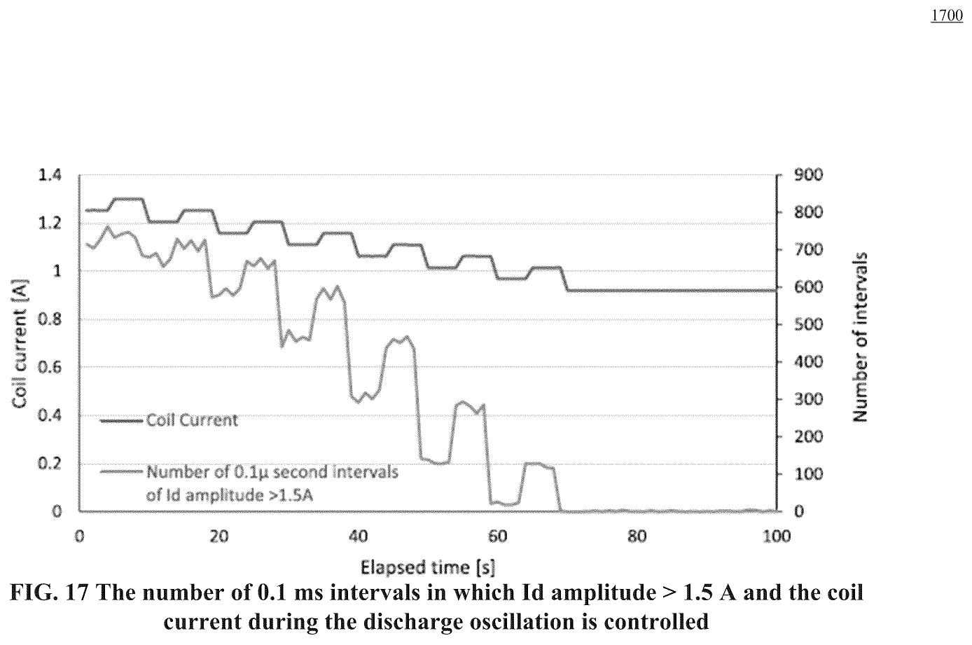

Referring to FIG. 17, a dual-axis time-series plot illustrating the effectiveness of discharge oscillation control over an elapsed time period of approximately 100 seconds is presented. The left vertical axis represents coil current measured in amperes, ranging from 0 A to 1.4 A. The right vertical axis displays the number of intervals, ranging from 0 to 900. The horizontal axis represents elapsed time in seconds spanning from 0 seconds to approximately 100 seconds.

A blue trace with diamond markers shows the coil current over the elapsed time period. The coil current begins at approximately 1.2 A at the start of the measurement period. The coil current exhibits a generally decreasing trend over time with several step-like reductions occurring at discrete time points throughout the measurement window. The step-like reductions in coil current indicate adjustments made by the control system to modify the magnetic field strength in the Hall effect thruster. After approximately 60 seconds of elapsed time, the coil current stabilizes around 0.8 A and remains at approximately that level for the remainder of the measurement period.

With continued reference to FIG. 17, an orange trace with square markers represents the number of 0.1 millisecond intervals in which the discharge current amplitude exceeds 1.5 A. The number of intervals metric provides a measure of the occurrence frequency of large-amplitude discharge current oscillations during Hall effect thruster operation. A higher number of intervals indicates more frequent occurrences of discharge current exceeding the 1.5 A threshold, corresponding to more pronounced breathing mode oscillations in the discharge plasma.

The number of intervals starts at approximately 800 intervals at the beginning of the measurement period. The number of intervals shows a corresponding decrease over time that correlates with the reductions in coil current. Notable step reductions in the number of intervals occur at similar time points as the coil current changes, demonstrating a relationship between the coil current adjustments and the reduction in high-amplitude discharge current oscillations. The number of intervals ultimately settles around 600 intervals after the coil current stabilizes near 0.8 A.

As further shown in FIG. 17, the correlation between the decreasing coil current and the reduction in high-amplitude discharge current intervals demonstrates that the control system may reduce the occurrence of large discharge current oscillations during Hall effect thruster operation. The coil current adjustments modify the magnetic field configuration in the Hall effect thruster, which in turn affects the electron confinement and ionization dynamics that drive the breathing mode oscillations. By reducing the coil current from approximately 1.2 A to approximately 0.8 A over the 100 second measurement period, the control system achieves a reduction in the number of intervals where discharge current exceeds 1.5 A from approximately 800 intervals to approximately 600 intervals.

The time-series data in FIG. 17 provides experimental evidence that the implemented control approach may mitigate plasma oscillations in the Hall effect thruster discharge by monitoring discharge current oscillation characteristics and adjusting magnetic field parameters in response. The step-like nature of the coil current adjustments indicates that the control system may operate by making discrete parameter changes at intervals rather than continuously varying the coil current. The corresponding step-like reductions in the number of high-amplitude discharge current intervals following each coil current adjustment demonstrates the causal relationship between the magnetic field parameter changes and the oscillation reduction effect. The control approach illustrated in FIG. 17 represents a magnetic field-based control strategy that may complement voltage-based control strategies for managing breathing mode oscillations in Hall effect thruster discharge plasmas.

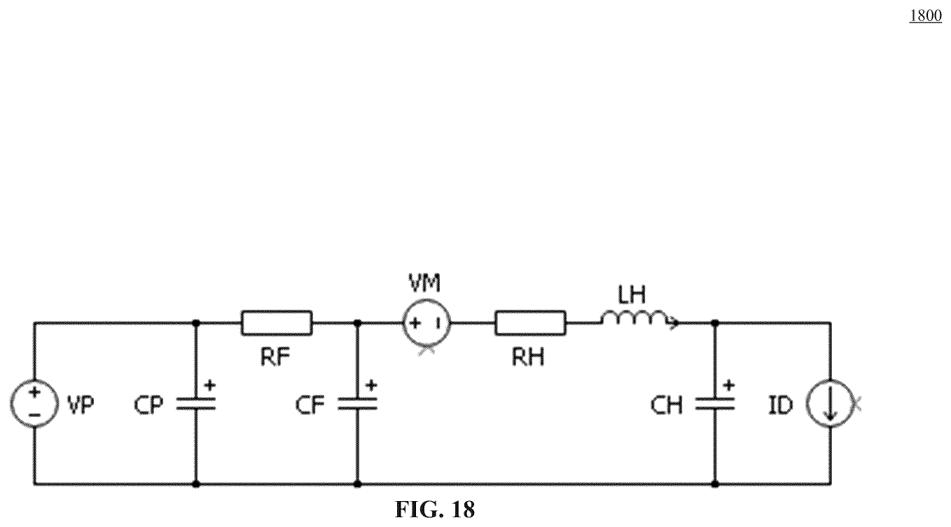

Referring to FIG. 18, an electrical circuit schematic of a Hall thruster power processing unit discharge circuit with voltage modulation capability is shown. The electrical circuit schematic depicts the complete electrical path from a power supply to the Hall effect thruster with provisions for injecting controlled voltage perturbations into the discharge path.

On the left side of the electrical circuit schematic, a DC voltage source V_{P} provides a base discharge voltage to the circuit. The DC voltage source V_{P} serves as the primary power source that establishes the nominal discharge voltage for Hall effect thruster operation. A capacitor C_{P} is connected in parallel with the DC voltage source V_{P}. The capacitor C_{P} provides energy storage and filtering at the power supply output to reduce voltage ripple and to supply transient current demands during discharge plasma oscillations.

With continued reference to FIG. 18, a discharge filter network is connected to the power supply section. The discharge filter network includes a resistor R_{F} connected in series with the discharge path. The discharge filter network includes a capacitor C_{F} connected as a shunt element to ground. The resistor R_{F} and the capacitor C_{F} together form a low-pass filter configuration that attenuates high-frequency oscillations propagating between the power supply and the Hall effect thruster. The discharge filter network serves to protect the power processing unit from discharge current oscillations generated by the Hall effect thruster discharge plasma load.

A voltage modulation source V_{M} is positioned in series with the discharge circuit. The voltage modulation source V_{M} enables the injection of controlled voltage perturbations into the discharge path. The voltage modulation source V_{M} may receive an analog control signal from a digital-to-analog converter and apply the analog control signal to modulate a discharge voltage of the Hall effect thruster. The series connection of the voltage modulation source V_{M} enables the modulation voltage to be added to or subtracted from the DC discharge voltage provided by the DC voltage source V_{P}. The voltage modulation source V_{M} may be configured to apply voltage perturbations at frequencies corresponding to the breathing mode oscillation frequency band to influence the discharge plasma dynamics.

As further shown in FIG. 18, a harness transmission line model is connected between the voltage modulation source V_{M} and the Hall effect thruster. The harness transmission line model includes a resistor R_{H} connected in series with the discharge path. The resistor R_{H} represents the resistance of the electrical harness connecting the power processing unit components to the Hall effect thruster. The harness transmission line model includes an inductor L_{H} connected in series with the resistor R_{H}. The inductor L_{H} represents the inductance of the harness cabling, which may contribute to discharge voltage oscillations and affect the coupling between the modulation voltage and the actual voltage appearing at the Hall effect thruster load.

A capacitor C_{H} is connected in parallel in the harness transmission line model. The capacitor C_{H} represents the parasitic capacitance of the harness cabling between the power processing unit and the Hall effect thruster. The resistor R_{H}, the inductor L_{H}, and the capacitor C_{H} together account for the transmission line characteristics of the electrical harness that affect the propagation of voltage and current signals between the power processing unit and the Hall effect thruster.

With continued reference to FIG. 18, the Hall effect thruster is represented on the right side of the electrical circuit schematic by a variable current source I_{D}. The variable current source I_{D} represents the discharge current drawn by the Hall effect thruster discharge plasma load. A capacitor is connected in parallel with the variable current source I_{D}. The variable current source representation captures the dynamic nature of the discharge current, which varies in response to the discharge voltage and the plasma conditions within the Hall effect thruster discharge channel.

The electrical circuit schematic in FIG. 18 illustrates the components involved in voltage control of Hall effect thruster discharge oscillations. A voltage injection circuit may be configured to apply the analog control signal to modulate the discharge voltage of the Hall effect thruster to reduce the breathing mode oscillations. The voltage injection circuit may include the voltage modulation source V_{M} and associated components that enable controlled voltage perturbations to be superimposed on the DC discharge voltage. The modulation voltage V_{M} may be actively varied in real time based on discharge current measurements and control computations performed by a neural network model executed on a field programmable gate array. By applying appropriate voltage perturbations through the voltage injection circuit, the control system may influence the breathing mode oscillations in the discharge current and reduce the amplitude of discharge current oscillations in the Hall effect thruster.

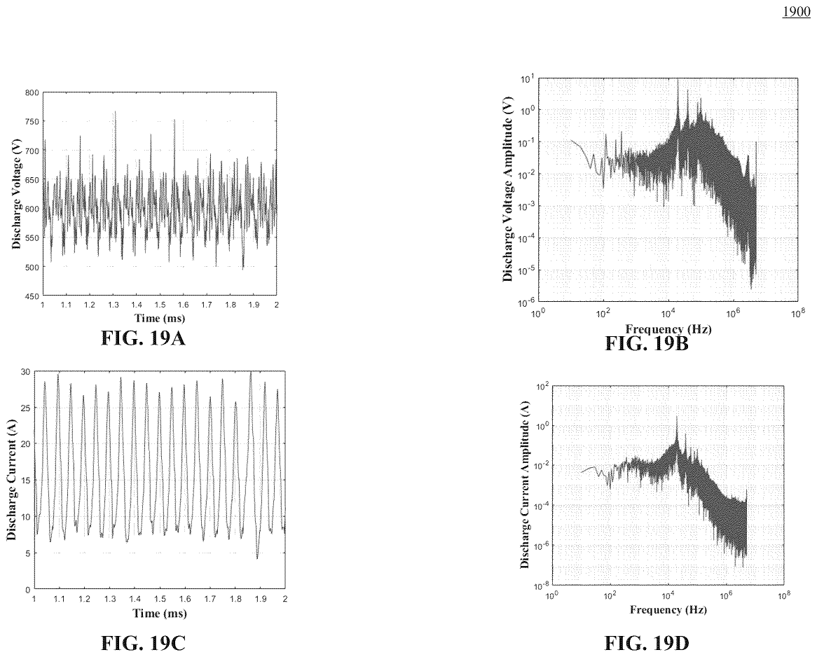

Referring to FIG. 19A, a time-domain plot showing discharge voltage oscillations measured in volts on the vertical axis against time measured in milliseconds on the horizontal axis is presented. The time window spans from 1.0 milliseconds to 2.0 milliseconds, capturing a 1 millisecond observation period of discharge voltage behavior during Hall effect thruster operation. The discharge voltage exhibits rapid, high-frequency oscillations that fluctuate predominantly between approximately 500 volts and 700 volts. The discharge voltage signal appears to center around a mean value of approximately 600 volts.

With continued reference to FIG. 19A, notable voltage spikes in the discharge voltage waveform reach peak values approaching 770 volts. Minimum excursions in the discharge voltage dip to approximately 480 volts. The oscillatory pattern demonstrates the characteristic breathing mode oscillations present in Hall effect thruster discharge plasmas. The irregular amplitude variations in the discharge voltage waveform indicate the complex nonlinear dynamics of the plasma discharge. The relatively small voltage oscillations shown in FIG. 19A represent variations of roughly plus or minus 15 percent from the mean discharge voltage value. The discharge voltage oscillation data illustrates the type of voltage variations that accompany discharge current oscillations in Hall effect thrusters operating under controlled conditions.

Referring to FIG. 19B, a frequency spectrum plot showing the discharge voltage amplitude as a function of frequency for a Hall effect thruster system is presented. The vertical axis displays the discharge voltage amplitude in volts on a logarithmic scale ranging from 10⁻⁶ V to 10¹ V. The horizontal axis shows frequency on a logarithmic scale spanning from 10⁰ Hz to 10⁸ Hz. The frequency spectrum reveals several distinct characteristics of Hall effect thruster discharge dynamics across the measured frequency range.

With continued reference to FIG. 19B, at low frequencies below approximately 100 Hz, the discharge voltage amplitude remains relatively flat around 0.1 V. The frequency spectrum shows significant activity in the frequency range from approximately 10⁴ Hz to 10⁶ Hz. The significant activity in this frequency range corresponds to the breathing mode oscillation frequency band characteristic of Hall effect thruster plasma instabilities. A prominent peak appears in the tens of kilohertz range, consistent with the breathing mode oscillations discussed in the context of Hall effect thruster operation.

As further shown in FIG. 19B, the discharge voltage amplitude gradually decreases at higher frequencies above 10⁶ Hz, showing a typical roll-off behavior. The broad frequency coverage from DC to 100 MHz demonstrates the wideband nature of Hall effect thruster discharge signals. The frequency domain representation in FIG. 19B may be used for characterizing the spectral content of discharge voltage oscillations and for impedance analysis. The frequency spectrum data informs the design of control systems that may target specific frequency bands to reduce plasma instabilities in the Hall effect thruster discharge.

Referring to FIG. 19C, a time-domain plot showing discharge current oscillations measured in amperes on the vertical axis against time measured in milliseconds on the horizontal axis is presented. The time window spans from 1.0 milliseconds to 2.0 milliseconds, representing a 1 millisecond observation period. The discharge current exhibits pronounced breathing mode oscillations characteristic of Hall effect thruster operation. The discharge current waveform displays rapid, quasi-periodic fluctuations throughout the measurement window.

With continued reference to FIG. 19C, the discharge current oscillates between minimum values of approximately 5 A to 10 A and maximum peak values reaching approximately 25 A to 30 A. The peak-to-peak amplitudes of the discharge current oscillations measure roughly 15 A to 25 A. Approximately 20 to 22 complete oscillation cycles are visible within the displayed time window. The number of oscillation cycles corresponds to a breathing mode frequency in the range of approximately 20 kHz to 22 kHz.

The discharge current waveform in FIG. 19C exhibits a characteristic sawtooth-like pattern. The sawtooth-like pattern includes relatively sharp rising edges leading to peaked maxima followed by rapid descents to the minimum values. The asymmetric shape of the oscillations reflects the predator-prey dynamics between neutrals and electrons in the Hall effect thruster discharge plasma. Rapid ionization events cause current spikes in the discharge current waveform. The current spikes are followed by neutral depletion and subsequent current reduction as the neutral population is consumed by the ionization process.

As further shown in FIG. 19C, some oscillation cycles show variations in peak amplitude. Occasional peaks reaching the maximum of approximately 30 A are interspersed among slightly lower amplitude oscillations around 25 A to 28 A. The discharge current time series data in FIG. 19C is fundamental to the approach of using real-time model predictive path control to characterize and manage plasma oscillations through machine learning-based system identification and state estimation techniques. The discharge current measurement data may serve as input to a neural network model for predicting discharge current dynamics and computing control voltage outputs to reduce the breathing mode oscillations.

Referring to FIG. 19D, a frequency spectrum analysis showing the discharge current amplitude as a function of frequency for a Hall effect thruster system is presented. The vertical axis represents the discharge current amplitude in amperes on a logarithmic scale ranging from 10⁻⁸ A to 10² A. The horizontal axis represents frequency in Hertz on a logarithmic scale spanning from approximately 10¹ Hz to 10⁸ Hz.

With continued reference to FIG. 19D, at lower frequencies below approximately 10⁴ Hz, the discharge current amplitude remains relatively stable around 10⁻² A with some fluctuation. A prominent peak occurs in the frequency range of approximately 10⁴ Hz to 10⁵ Hz. The prominent peak corresponds to the breathing mode oscillation frequency band that is characteristic of Hall effect thruster operation. The discharge current amplitude rises to approximately 10⁰ A to 10¹ A in the breathing mode frequency band. The breathing mode peak represents the dominant plasma instability arising from predator-prey interactions between neutrals and electrons in the discharge plasma.

As further shown in FIG. 19D, beyond the breathing mode peak, the discharge current amplitude decreases progressively with increasing frequency. The discharge current amplitude follows a general roll-off pattern with significant noise content at higher frequencies. The frequency spectrum extends into the megahertz range where discharge current amplitudes drop to 10⁻⁴ A to 10⁻⁶ A levels with substantial high-frequency noise. The frequency domain characterization in FIG. 19D may be used for understanding the discharge plasma load behavior and for informing the design of control systems. The frequency spectrum data enables identification of the frequency bands where active voltage control may effectively suppress discharge current oscillations in the Hall effect thruster. A control system may be configured to apply voltage perturbations at frequencies corresponding to the breathing mode peak identified in FIG. 19D to influence the discharge plasma dynamics and reduce the amplitude of discharge current oscillations.

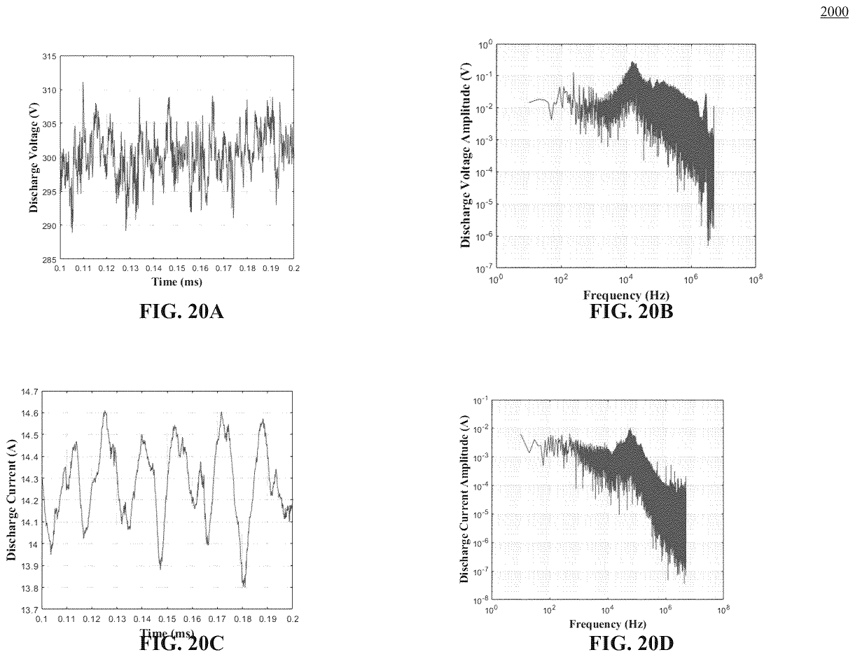

Referring to FIG. 20A, a time-domain plot showing discharge voltage oscillations measured in volts on the vertical axis against time measured in milliseconds on the horizontal axis is presented. The time window spans from 0.1 milliseconds to 0.2 milliseconds, capturing approximately 0.1 milliseconds of discharge voltage behavior during Hall effect thruster operation. The discharge voltage oscillates around a nominal value of approximately 300 volts. The discharge voltage fluctuations range from approximately 285 volts to 312 volts, representing peak-to-peak voltage oscillations of roughly 25 volts to 27 volts.

With continued reference to FIG. 20A, the discharge voltage waveform exhibits rapid, irregular oscillations characteristic of plasma discharge behavior in Hall effect thrusters. The oscillations are associated with breathing mode oscillations that occur in the tens of kilohertz frequency range. The relatively small voltage oscillations shown in FIG. 20A represent less than ten percent of the mean discharge voltage value. The voltage oscillation amplitude demonstrated in FIG. 20A is indicative of the type of perturbations that may be used to attenuate discharge current oscillations when properly controlled through voltage modulation approaches. The discharge voltage measurement data in FIG. 20A illustrates the inherent instabilities present in the discharge plasma that a machine learning-based model predictive path control system may characterize and regulate through real-time voltage modulation techniques.

Referring to FIG. 20B, a frequency spectrum plot showing the discharge voltage amplitude as a function of frequency for a Hall effect thruster system is presented. The vertical axis displays the discharge voltage amplitude in volts on a logarithmic scale ranging from 10⁻⁶ V to 10⁰ V. The horizontal axis shows frequency in Hertz on a logarithmic scale spanning from 10⁰ Hz to 10⁸ Hz. The frequency spectrum reveals characteristic oscillation behavior of the Hall effect thruster discharge plasma across the measured frequency range.

With continued reference to FIG. 20B, the discharge voltage amplitudes are generally in the range of 10⁻² V to 10⁻¹ V across a broad frequency band from approximately 10² Hz to 10⁶ Hz. A notable peak in the frequency spectrum appears in the region around 10⁴ Hz to 10⁵ Hz. The peak corresponds to the breathing mode oscillation frequency range typical of Hall effect thrusters. The discharge voltage amplitude gradually decreases at higher frequencies above approximately 10⁶ Hz, showing a roll-off characteristic of the discharge dynamics.

As further shown in FIG. 20B, the frequency domain representation may be used for understanding the spectral content of discharge voltage oscillations. The spectral characterization is relevant for designing control strategies and characterizing the impedance of the Hall effect thruster load. The broad spectral content visible in FIG. 20B demonstrates the complex, multi-frequency nature of plasma oscillations that a machine learning-based control system may regulate through real-time voltage modulation.

Referring to FIG. 20C, a time-domain plot showing discharge current oscillations measured in amperes on the vertical axis against time measured in milliseconds on the horizontal axis is presented. The time window spans from 0.1 milliseconds to 0.2 milliseconds, representing a 0.1 millisecond observation period. The discharge current fluctuates between approximately 13.8 A and 14.6 A, with a mean value centered around 14.2 A to 14.3 A.

With continued reference to FIG. 20C, the discharge current waveform exhibits a quasi-periodic oscillatory behavior characteristic of breathing mode oscillations in Hall effect thruster discharge plasmas. The oscillation pattern shows irregular peaks and troughs with varying amplitudes, demonstrating the nonlinear and time-varying nature of the discharge current. Multiple oscillation cycles are visible within the displayed time window. The period of oscillation appears to be on the order of tens of microseconds, consistent with breathing mode frequencies in the kilohertz range.

As further shown in FIG. 20C, the discharge current signal displays both high-frequency fluctuations superimposed on lower-frequency envelope variations. The presence of multiple frequency components in the discharge dynamics indicates the complex nature of the Hall effect thruster discharge plasma behavior. The discharge current measurement data in FIG. 20C is fundamental for characterizing Hall effect thruster load behavior and may serve as input for machine learning-based system identification and control algorithms designed to reduce plasma oscillations and improve thruster performance.

Referring to FIG. 20D, a frequency spectrum plot showing the discharge current amplitude as a function of frequency for a Hall effect thruster system is presented. The vertical axis displays the discharge current amplitude measured in amperes on a logarithmic scale ranging from 10⁻⁸ A to 10⁻¹ A. The horizontal axis shows frequency in Hertz on a logarithmic scale spanning from 10⁰ Hz to 10⁸ Hz.

With continued reference to FIG. 20D, at lower frequencies below approximately 100 Hz, the discharge current amplitude remains relatively high around 10⁻² A to 10⁻³ A. The frequency spectrum shows a broad peak region between approximately 10⁴ Hz and 10⁵ Hz. The broad peak region corresponds to the breathing mode oscillation frequency range typical of Hall effect thruster discharge plasmas. The breathing mode frequency components in the frequency spectrum represent the dominant plasma instability arising from predator-prey interactions between neutrals and electrons in the discharge plasma.

As further shown in FIG. 20D, above the breathing mode peak region, the discharge current amplitude decreases steadily with increasing frequency. The amplitude follows an approximately linear decline on the log-log scale, indicating a power-law rolloff characteristic of the discharge current oscillations. By 10⁶ Hz, the discharge current amplitude has decreased to approximately 10⁻⁵ A to 10⁻⁶ A, and the amplitude continues to diminish at higher frequencies.

The frequency spectrum characterization in FIG. 20D may be used for understanding the oscillatory behavior of the Hall effect thruster discharge plasma. The frequency domain data informs the design of control systems, particularly a model predictive path control approach that may operate at frequencies sufficient to address the dominant breathing mode oscillations in the tens of kilohertz range. A control system may be configured to apply voltage perturbations at frequencies corresponding to the breathing mode components identified in FIG. 20D to influence the discharge plasma dynamics and reduce the amplitude of discharge current oscillations in the Hall effect thruster.

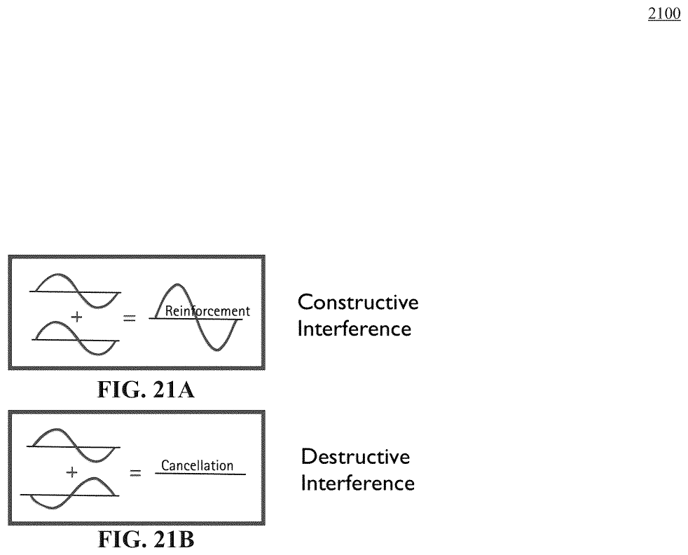

Referring to FIG. 21A, the principle of constructive interference is illustrated showing how two waves combine to produce a wave of greater amplitude. On the left side of FIG. 21A, two identical sinusoidal waveforms are displayed vertically stacked. Each of the two sinusoidal waveforms shows approximately one complete wavelength with matching phase alignment. The two sinusoidal waveforms are connected by a plus sign indicating superposition of the two waveforms. On the right side of an equals sign, a resulting waveform is shown. The resulting waveform exhibits the same frequency as the two input waveforms but with doubled amplitude compared to each individual input waveform. The doubled amplitude demonstrates the reinforcement effect that occurs when waves are in phase with each other.

With continued reference to FIG. 21A, constructive interference occurs when two waves having the same frequency arrive at a point with matching phase alignment. When the peaks of the two waves coincide and the troughs of the two waves coincide, the amplitudes of the two waves add together to produce a combined wave with increased amplitude. In the context of Hall effect thruster plasma oscillation control, constructive interference relates to how discharge voltage oscillations and discharge current oscillations may be manipulated through phase alignment to affect thruster performance. When voltage perturbations are applied in phase with existing plasma oscillations, the perturbations may reinforce the oscillations and increase the oscillation amplitude. The principle of constructive interference informs control strategies where phase relationships between applied voltage modulations and existing plasma oscillations determine whether oscillations are amplified.

Referring to FIG. 21B, the principle of destructive interference is illustrated showing wave cancellation when two out-of-phase waves combine. FIG. 21B shows two sinusoidal waveforms positioned one above the other with a plus sign between the two sinusoidal waveforms indicating superposition. An upper waveform displays a standard sine wave with a peak oriented upward at a center position. A lower waveform shows a sine wave that is phase-shifted by 180 degrees relative to the upper waveform. The lower waveform has a trough oriented upward at the center position where the upper waveform has a peak. The 180-degree phase shift between the upper waveform and the lower waveform results in the peak of one waveform coinciding with the trough of the other waveform at each point in time.

As further shown in FIG. 21B, when the two out-of-phase waveforms are combined as indicated by an equals sign followed by the word “Cancellation,” the result is complete destructive interference where the two waves effectively neutralize each other. The positive amplitude of the upper waveform at each point is offset by the equal negative amplitude of the lower waveform at the same point, resulting in a net amplitude of zero. The cancellation effect demonstrates how waves with opposite phase relationships may eliminate each other when superimposed.

The principle of destructive interference illustrated in FIG. 21B relates directly to control methodologies employed in Hall effect thruster systems. Voltage perturbations may be strategically applied to create destructive interference with discharge current oscillations, particularly the breathing mode oscillations that occur in the discharge plasma. By applying voltage modulations that are 180 degrees out of phase with the discharge current oscillations, the control system may attenuate the unwanted current oscillations through destructive interference. The voltage perturbations introduce signals that destructively interfere with the natural oscillation modes of the Hall effect thruster discharge plasma, thereby reducing the amplitude of the breathing mode oscillations.

The wave interference principles illustrated in FIG. 21A and FIG. 21B underpin the active control approach for managing plasma oscillations in Hall effect thrusters. A control system may determine the phase relationship between applied voltage perturbations and existing discharge current oscillations to achieve either constructive interference for oscillation amplification or destructive interference for oscillation attenuation. When the control objective is to reduce discharge current oscillations, the control system may compute voltage perturbations that are phase-shifted to create destructive interference with the breathing mode oscillations. When the control objective is to maximize thrust through phase alignment of voltage and current, the control system may compute voltage perturbations that create constructive interference to align the discharge voltage and discharge current waveforms for increased real power transfer to the discharge plasma.

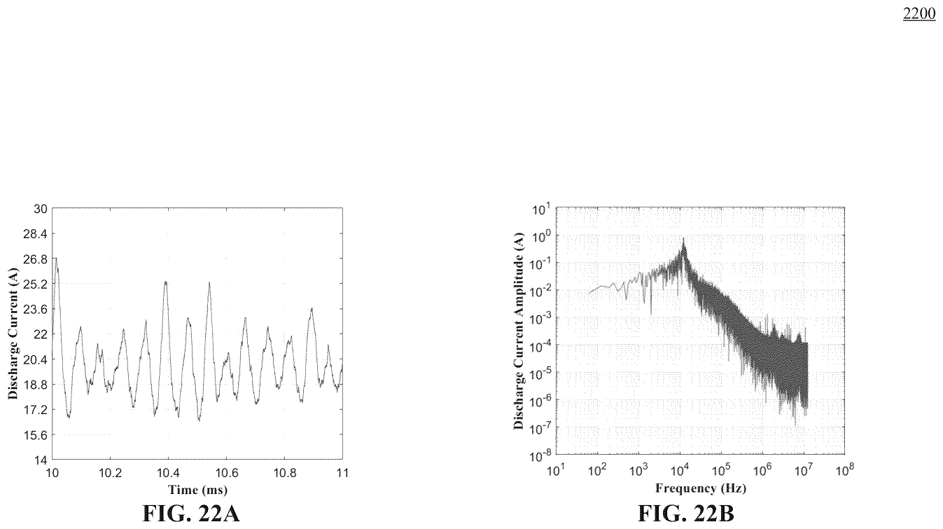

Referring to FIG. 22A, a time-domain plot showing discharge current oscillations measured in amperes on the vertical axis versus time in milliseconds on the horizontal axis is presented. The time window spans from 10.0 milliseconds to 11.0 milliseconds, representing a 1 millisecond observation period of discharge current behavior during Hall effect thruster operation. The discharge current exhibits pronounced oscillatory behavior characteristic of breathing mode oscillations in Hall effect thruster discharge plasmas.

With continued reference to FIG. 22A, the discharge current values fluctuate between approximately 15.6 A and 26.8 A throughout the measurement window. The oscillations show a quasi-periodic pattern with varying peak amplitudes across the observation period. The discharge current waveform displays an initial transient with higher amplitude peaks near the 10.0 millisecond mark. Following the initial transient, the discharge current signal exhibits a gradual settling into a more regular oscillatory pattern as time progresses toward 11.0 milliseconds.

The oscillation frequency visible in FIG. 22A appears to be in the range of tens of kilohertz, consistent with the breathing mode frequency range discussed in the context of Hall effect thruster operation. The irregular amplitude modulation visible in the discharge current waveform demonstrates the nonlinear time-varying nature of the Hall effect thruster discharge plasma. The discharge current measurement data shown in FIG. 22A serves as a primary feedback signal for a real-time model predictive path control system. A controller may process such discharge current measurements to determine voltage perturbations for oscillation reduction and thrust optimization in the Hall effect thruster.

Referring to FIG. 22B, a frequency spectrum plot showing the discharge current amplitude as a function of frequency for a Hall effect thruster system is presented. The vertical axis displays the discharge current amplitude measured in amperes on a logarithmic scale ranging from 10⁻⁸ A to 10¹ A. The horizontal axis shows frequency in Hertz on a logarithmic scale spanning from 10¹ Hz to 10⁸ Hz.

With continued reference to FIG. 22B, at lower frequencies between approximately 10² Hz and 10⁴ Hz, the discharge current amplitude remains relatively stable in the range of 10⁻² A to 10⁻¹ A with notable fluctuations throughout this frequency band. A prominent peak occurs near 10⁴ Hz where the discharge current amplitude reaches approximately 10⁰ A. The prominent peak corresponds to the breathing mode oscillation frequency characteristic of Hall effect thruster operation.

As further shown in FIG. 22B, beyond the breathing mode peak, the discharge current amplitude exhibits a general decreasing trend as frequency increases. The amplitude follows an approximately linear decline on the log-log scale from around 10⁻¹ A at 10⁴ Hz down to approximately 10⁻⁴ A to 10⁻⁶ A at frequencies approaching 10⁷ Hz. The high-frequency region of the frequency spectrum shows increased noise and variability in the measurements.

The frequency domain representation in FIG. 22B may be used for understanding the spectral content of discharge current oscillations. The frequency spectrum enables identification of the dominant breathing mode frequency and characterization of the impedance and dynamic response of the Hall effect thruster discharge plasma load for control system development. A control system may be configured to apply voltage perturbations at frequencies corresponding to the breathing mode peak identified in FIG. 22B to influence the discharge plasma dynamics and reduce the amplitude of discharge current oscillations in the Hall effect thruster.

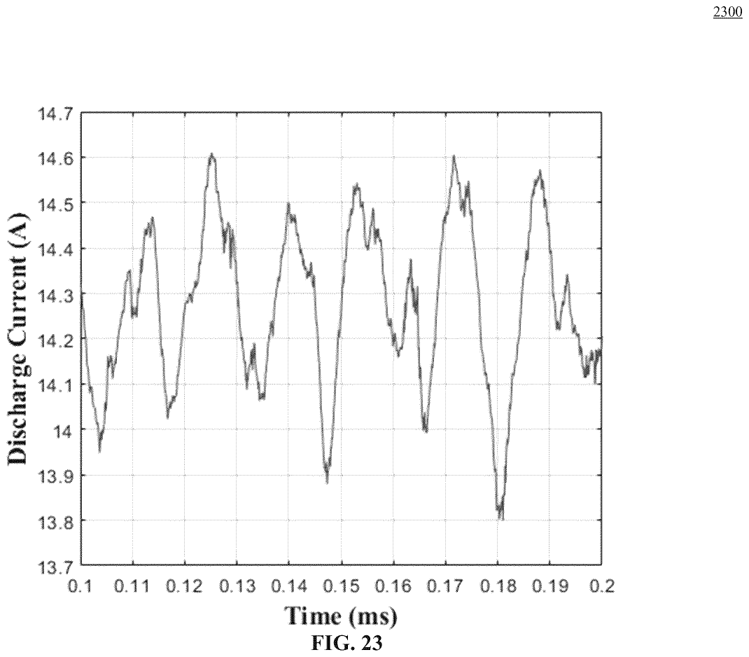

Referring to FIG. 23, a time-domain plot showing discharge current oscillations measured in amperes on the vertical axis against time measured in milliseconds on the horizontal axis is presented. The time window spans from 0.1 milliseconds to 0.2 milliseconds, representing a 0.1 millisecond observation period of discharge current behavior during Hall effect thruster operation. The discharge current axis ranges from approximately 13.7 A to 14.7 A. A blue waveform trace shows the oscillating discharge current behavior characteristic of Hall effect thruster breathing mode oscillations. The discharge current exhibits quasi-periodic fluctuations with peak-to-peak variations of roughly 0.8 A to 1.0 A around a mean value of approximately 14.2 A.

With continued reference to FIG. 23, red X markers are overlaid on the discharge current waveform at various points throughout the measurement window. The red X markers indicate local maxima and local minima of the discharge current oscillations. The local maxima correspond to peak values of the discharge current where the waveform reaches a maximum before beginning to decrease. The local minima correspond to trough values of the discharge current where the waveform reaches a minimum before beginning to increase. The placement of the red X markers at the extrema points demonstrates detection of the peaks and troughs in the discharge current signal.

As further shown in FIG. 23, the detected peak and trough locations represented by the red X markers may be used for signal analysis purposes in characterizing the Hall effect thruster discharge plasma dynamics. The peak detection may enable determination of oscillation amplitude by computing the difference between successive peak values and trough values. The peak detection may enable determination of oscillation frequency by measuring the time interval between successive peaks or successive troughs. The timing of the detected peaks and troughs may inform control strategies by providing information about the phase of the breathing mode oscillations at each instant in time.

The extrema detection illustrated in FIG. 23 may be employed in a control system for implementing feedback control strategies to manage plasma oscillations in the Hall effect thruster. A control system may use the detected peak and trough locations to determine the instantaneous phase of the discharge current oscillations. The instantaneous phase information may be used to compute voltage perturbations that are phase-aligned or phase-shifted relative to the discharge current oscillations to achieve constructive interference or destructive interference effects. The peak detection may enable the control system to synchronize voltage modulation signals with the breathing mode oscillations for effective oscillation attenuation or for phase alignment between discharge voltage and discharge current to maximize thrust output.

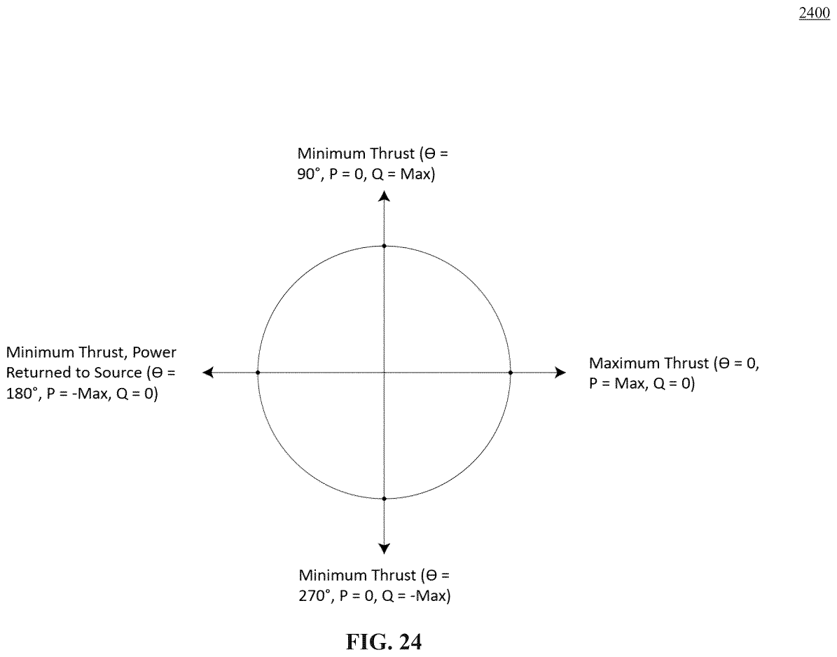

Referring to FIG. 24, a circular diagram illustrating the relationship between thrust output and the phase angle theta between voltage and current in a Hall effect thruster power system is presented. The circular diagram depicts four cardinal positions around a circle corresponding to different operating conditions defined by the phase angle theta between the discharge voltage and the discharge current.

At a rightmost position of the circular diagram where the phase angle theta equals zero degrees, maximum thrust is achieved. At the zero degree phase angle condition, the discharge voltage and the discharge current are in phase with each other, meaning the peaks of the voltage waveform coincide with the peaks of the current waveform and the troughs of the voltage waveform coincide with the troughs of the current waveform. At the zero degree phase angle condition, real power P is at a maximum value and reactive power Q is at zero. The maximum real power condition corresponds to maximum power transfer from the power processing unit to the discharge plasma for ion acceleration, resulting in maximum thrust generation.

With continued reference to FIG. 24, at a top position of the circular diagram where the phase angle theta equals ninety degrees, minimum thrust occurs. At the ninety degree phase angle condition, the discharge voltage leads the discharge current by ninety degrees, meaning the peaks of the voltage waveform occur one quarter cycle before the peaks of the current waveform. At the ninety degree phase angle condition, real power P is at zero and reactive power Q is at a maximum value. The zero real power condition indicates that no net power is transferred to the discharge plasma for ion acceleration over a complete oscillation cycle, resulting in minimum thrust generation despite the presence of voltage and current oscillations.

At a leftmost position of the circular diagram where the phase angle theta equals one hundred eighty degrees, minimum thrust is produced with power being returned to the source. At the one hundred eighty degree phase angle condition, the discharge voltage and the discharge current are completely out of phase with each other, meaning the peaks of the voltage waveform coincide with the troughs of the current waveform. At the one hundred eighty degree phase angle condition, real power P is at a negative maximum value and reactive power Q is at zero. The negative real power condition indicates that power flows from the discharge plasma back toward the power processing unit rather than being delivered to the plasma for ion acceleration.

As further shown in FIG. 24, at a bottom position of the circular diagram where the phase angle theta equals two hundred seventy degrees, minimum thrust again occurs. At the two hundred seventy degree phase angle condition, the discharge voltage lags the discharge current by ninety degrees, meaning the peaks of the voltage waveform occur one quarter cycle after the peaks of the current waveform. At the two hundred seventy degree phase angle condition, real power P is at zero and reactive power Q is at a negative maximum value. The zero real power condition at two hundred seventy degrees results in minimum thrust generation similar to the ninety degree phase angle condition.

Horizontal arrows extend from a center of the circular diagram to both the leftmost position and the rightmost position, indicating the real power axis along which maximum positive real power and maximum negative real power occur. Vertical arrows extend from the center of the circular diagram to both the top position and the bottom position, indicating the reactive power axis along which maximum positive reactive power and maximum negative reactive power occur.

The circular diagram in FIG. 24 demonstrates a fundamental principle that thrust production in a Hall effect thruster is maximized when the discharge voltage and the discharge current are in phase, corresponding to maximum real power transfer to the discharge plasma. Phase misalignment between the discharge voltage and the discharge current results in reactive power that does not contribute to thrust generation. The circular representation effectively shows how the phase relationship between the discharge voltage and the discharge current directly determines the power factor and consequently the thrust efficiency of the propulsion system.

A control system may be configured to adjust the phase relationship between the discharge voltage oscillations and the discharge current oscillations to achieve a desired thrust output. When the control objective is to maximize thrust, the control system may compute voltage perturbations that shift the phase angle theta toward zero degrees to align the discharge voltage and the discharge current for maximum real power transfer. When the control objective is to reduce oscillations through destructive interference, the control system may compute voltage perturbations that shift the phase angle theta toward one hundred eighty degrees to create cancellation between the voltage and current waveforms. The phase angle theta may be adjusted by varying the timing of voltage perturbations applied through a voltage injection circuit relative to the measured discharge current oscillations.

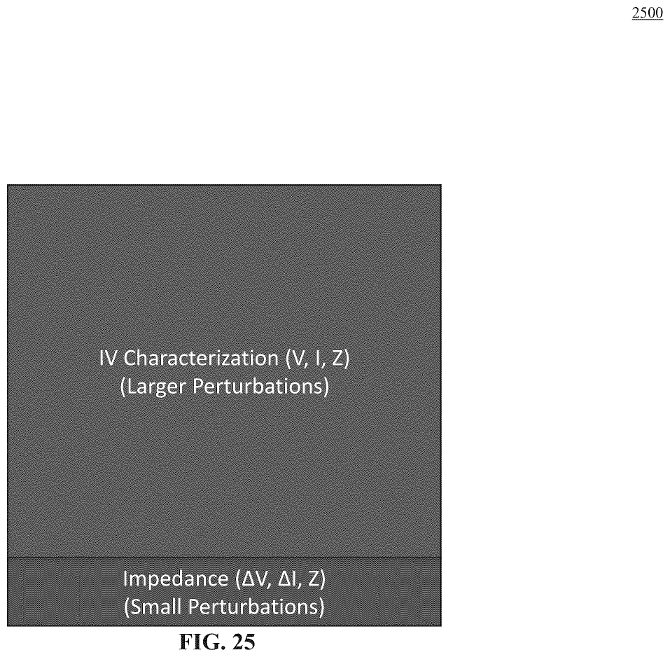

Referring to FIG. 25, a diagram illustrating different characterization approaches for a Hall effect thruster discharge plasma load is presented. The diagram is divided into two distinct sections that correspond to different perturbation regimes and associated characterization methodologies for understanding the electrical behavior of the discharge plasma.

An upper section of the diagram is shown with a gray background and is labeled “Impedance (ΔV, ΔI, Z)” with a notation indicating “Small Perturbations.” The upper section corresponds to small-signal analysis techniques where the discharge plasma behavior may be characterized through incremental voltage measurements ΔV and incremental current measurements ΔI to determine an impedance Z of the discharge plasma. When small perturbations are applied to the discharge voltage, the discharge plasma response may remain within a linear operating regime where the relationship between the incremental voltage change and the incremental current change may be approximated as linear. The small-signal impedance characterization enables determination of the resistance, inductance, and capacitance characteristics of the discharge plasma at various frequencies within the breathing mode oscillation band and surrounding frequency ranges.

With continued reference to FIG. 25, the small perturbation regime enables traditional transfer function analysis techniques to be applied to the Hall effect thruster discharge plasma load. A transfer function may be computed by dividing the frequency domain representation of the discharge voltage by the frequency domain representation of the discharge current to obtain the impedance as a function of frequency. The impedance characterization in the small perturbation regime may reveal resonant frequencies, phase relationships, and magnitude variations that inform the design of control systems for managing plasma oscillations. The small perturbation approach may employ sinusoidal voltage perturbations at various frequencies to map the impedance characteristics across the frequency range of interest. In some cases, the small perturbation approach may employ multisine perturbations comprising multiple frequency components to accelerate the impedance characterization process by exciting multiple frequencies simultaneously.

A lower section of the diagram in FIG. 25 is displayed with a red background and is labeled “IV Characterization (V, I, Z)” with a notation indicating “Larger Perturbations.” The lower section corresponds to large-signal characterization where the full voltage-current relationship and impedance are measured under larger perturbation conditions that may drive the discharge plasma into nonlinear operating regimes. When larger perturbations are applied to the discharge voltage, the discharge plasma response may exhibit nonlinear characteristics that are not captured by small-signal linear analysis techniques.

As further shown in FIG. 25, the distinction between the small perturbation regime and the larger perturbation regime is fundamental to a system identification approach for characterizing the Hall effect thruster discharge plasma load. The small perturbations maintain linear impedance behavior that allows for traditional transfer function analysis and stability assessment using techniques such as Nyquist plots and Bode plots. The larger perturbations reveal the nonlinear characteristics of the Hall effect thruster discharge plasma that are relevant for developing accurate machine learning models of the discharge plasma behavior.

The IV characterization in the larger perturbation regime may capture nonlinear dynamics of the discharge plasma that influence thruster performance under varying operating conditions. The nonlinear characteristics may include saturation effects, hysteresis behavior, and mode transitions that occur when the discharge voltage or discharge current exceeds threshold values. The larger perturbation characterization may employ voltage sweeps, step changes, or other excitation signals with amplitudes sufficient to explore the nonlinear operating regime of the discharge plasma.

A neural network model may be trained using data from both the small perturbation regime and the larger perturbation regime to capture the full range of discharge plasma dynamics. The neural network model may learn the linear impedance characteristics from small perturbation data and the nonlinear response characteristics from larger perturbation data. The combination of small perturbation impedance characterization and larger perturbation IV characterization provides a comprehensive understanding of the Hall effect thruster discharge plasma load behavior that informs the design of machine learning-based control systems for managing plasma oscillations.

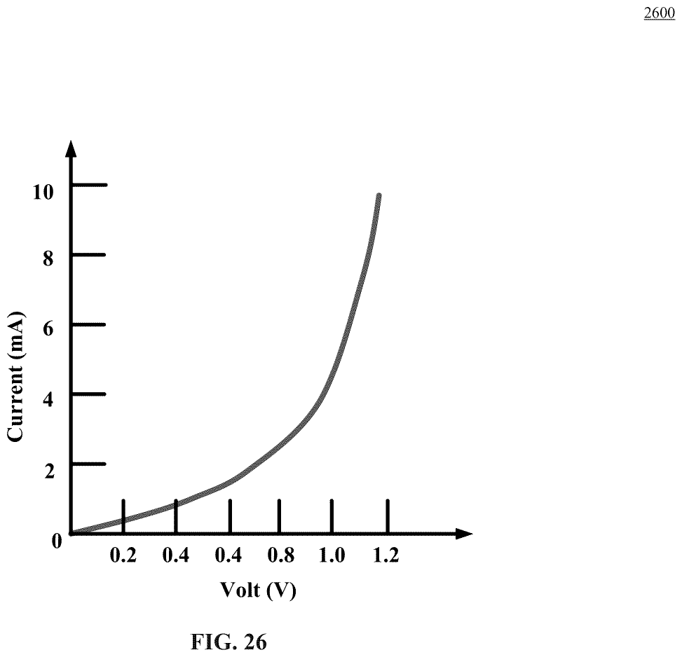

Referring to FIG. 26, a current-voltage characteristic curve illustrating the nonlinear electrical behavior of a component relevant to the Hall effect thruster discharge plasma control system is presented. The graph plots current in milliamperes on the vertical axis ranging from 0 mA to 10 mA against voltage in volts on the horizontal axis ranging from 0 V to 1.2 V. The current-voltage characteristic curve is rendered as a thick red line that demonstrates a characteristic nonlinear relationship between voltage and current.

With continued reference to FIG. 26, at low voltages below approximately 0.4 V, the current remains near zero. The region below approximately 0.4 V corresponds to a threshold or turn-on region where the applied voltage is insufficient to produce significant current flow through the component. The threshold region indicates that a minimum voltage level may be exceeded before the component begins to conduct appreciable current. The presence of the threshold region demonstrates that the component exhibits a nonlinear voltage-current relationship rather than a linear ohmic relationship where current would be proportional to voltage at all voltage levels.

As the voltage increases beyond the threshold region of approximately 0.4 V, the current begins to rise gradually from the near-zero baseline. The rate of current increase accelerates as the voltage continues to increase toward higher values. The accelerating rate of current increase with voltage is characteristic of an exponential or nonlinear relationship between the applied voltage and the resulting current flow. By the time the voltage reaches approximately 0.8 V, the current has increased to approximately 2 mA. As the voltage approaches 1.0 V and above, the current rises more steeply, reaching approximately 10 mA at a voltage of 1.2 V.

As further shown in FIG. 26, the current-voltage characteristic curve demonstrates that the component exhibits a highly nonlinear impedance that varies with the applied voltage level. At low voltages in the threshold region, the effective impedance is very high because minimal current flows despite the applied voltage. As the voltage increases beyond the threshold, the effective impedance decreases as the current increases at a faster rate than the voltage. The voltage-dependent impedance behavior may be relevant for understanding the nonlinear load characteristics of components within the power processing unit or the discharge plasma load of the Hall effect thruster.

The current-voltage characterization data shown in FIG. 26 may be used for developing accurate load models that capture the nonlinear impedance behavior of circuit components in the Hall effect thruster power system. The nonlinear current-voltage relationship may inform the neural network-based system identification process by providing training data that captures the nonlinear response characteristics of the system. A neural network model may be trained on current-voltage characterization data to learn the nonlinear mapping between applied voltage and resulting current, enabling the neural network model to predict current responses to voltage perturbations across the full operating range including both the threshold region and the exponential conduction region. The current-voltage characterization may complement the impedance characterization performed using small perturbations by providing large-signal characterization data that reveals the nonlinear behavior of the Hall effect thruster discharge plasma and associated circuit components under varying voltage conditions.

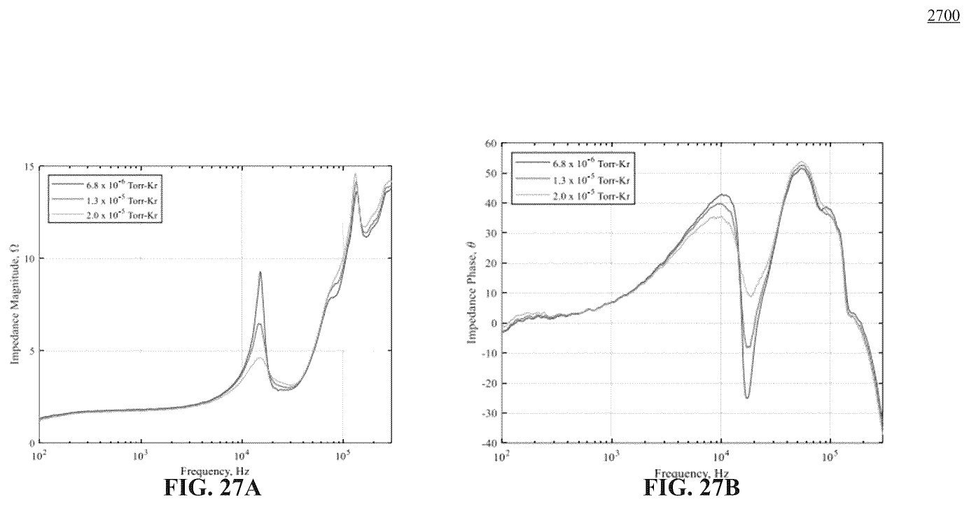

Referring to FIG. 27A, a graph showing impedance magnitude in ohms plotted against frequency in hertz on a logarithmic scale is presented. The graph displays three curves representing different krypton background pressure conditions in a Hall effect thruster test environment. The three pressure levels shown include a first pressure level of 6.8×10⁻⁶ Torr-Kr represented by a blue curve, a second pressure level of 1.3×10⁻⁵ Torr-Kr represented by an orange curve, and a third pressure level of 2.0×10⁻⁵ Torr-Kr represented by a yellow curve. The frequency axis spans from approximately 100 Hz to beyond 100 kHz, covering the frequency range relevant to breathing mode oscillations in Hall effect thrusters.

With continued reference to FIG. 27A, all three curves exhibit similar overall behavior across the measured frequency range. At low frequencies around 100 Hz, the impedance magnitude values start at relatively low levels around 1.5 ohms. The impedance magnitude remains relatively flat through the 100 Hz to 1 kHz frequency range for all three pressure conditions. As frequency increases through the 1 kHz to 10 kHz range, the impedance magnitude shows a gradual increase for each of the three pressure conditions.

A prominent resonant peak appears in the 10 kHz to 20 kHz frequency range for all three pressure conditions. The resonant peak corresponds to the breathing mode oscillation frequency characteristic of Hall effect thrusters. The peak impedance magnitude varies with the background pressure level. At the lowest pressure condition of 6.8×10⁻⁶ Torr-Kr represented by the blue curve, the peak amplitude reaches approximately 9 ohms. At the intermediate pressure condition of 1.3×10⁻⁵ Torr-Kr represented by the orange curve, the peak amplitude reaches approximately 6.5 ohms. At the highest pressure condition of 2.0×10⁻⁵ Torr-Kr represented by the yellow curve, the peak amplitude reaches approximately 4.5 ohms. The inverse relationship between background pressure and peak impedance magnitude indicates that higher facility background pressures result in reduced impedance at the breathing mode resonant frequency.

As further shown in FIG. 27A, beyond the breathing mode peak, the impedance magnitude continues to rise sharply for all three pressure conditions. At the highest frequencies shown in the graph, the impedance magnitude reaches values of approximately 14 ohms. All three pressure conditions converge toward similar impedance magnitude values at the highest frequencies, indicating that the pressure-dependent effects on impedance are most pronounced in the breathing mode frequency band and diminish at frequencies above the resonant peak.

The impedance characterization data in FIG. 27A demonstrates how facility background pressure affects the electrical load characteristics of the Hall effect thruster discharge plasma. The variation in impedance magnitude with pressure is relevant for understanding facility effects on thruster operation. Ground-based vacuum facilities may not achieve the low-pressure levels present in space, and the pressure-dependent impedance characteristics shown in FIG. 27A indicate that the electrical behavior of the discharge plasma may differ between ground testing conditions and space operating conditions. The impedance characterization at multiple pressure levels may inform the design of control systems that account for pressure-dependent variations in discharge plasma dynamics.

Referring to FIG. 27B, a graph showing impedance phase designated as θ plotted against frequency in Hertz on a logarithmic scale is presented. The frequency axis ranges from 10² Hz to approximately 3×10⁵ Hz. Three curves are displayed corresponding to the same three krypton pressure conditions shown in FIG. 27A. A first curve corresponding to a pressure of 6.8×10⁻⁶ Torr-Kr is shown in blue. A second curve corresponding to a pressure of 1.3×10⁻⁵ Torr-Kr is shown in orange. A third curve corresponding to a pressure of 2.0×10⁻⁵ Torr-Kr is shown in yellow. The impedance phase values range from approximately −30 degrees to +50 degrees across the measured frequency range.

With continued reference to FIG. 27B, all three curves follow similar trajectories across the frequency range with variations in magnitude at specific frequency bands. At low frequencies around 100 Hz, the impedance phase starts near zero degrees for all three pressure conditions. As frequency increases through the 1 kHz range, the impedance phase gradually increases for each of the three pressure conditions. The impedance phase reaches a local maximum around 35 degrees to 40 degrees near 10⁴ Hz for all three pressure conditions.

Following the local maximum near 10⁴ Hz, the curves exhibit a sharp dip into negative phase values around 2×10⁴ Hz. The sharp dip in impedance phase corresponds to the breathing mode resonant frequency region identified in FIG. 27A. At the lowest pressure condition of 6.8×10⁻⁶ Torr-Kr represented by the blue curve, the impedance phase shows the most pronounced negative excursion, reaching approximately −27 degrees. At the intermediate pressure condition of 1.3×10⁻⁵ Torr-Kr represented by the orange curve, the negative phase excursion is less pronounced. At the highest pressure condition of 2.0×10⁻⁵ Torr-Kr represented by the yellow curve, the negative phase excursion is the least pronounced among the three pressure conditions.

As further shown in FIG. 27B, following the negative phase minimum around 2×10⁴ Hz, all three curves rise sharply to peak values between 45 degrees and 55 degrees in the 5×10⁴ Hz to 10⁵ Hz frequency range. After reaching the positive phase peak, the impedance phase declines at higher frequencies for all three pressure conditions.

The impedance phase characterization in FIG. 27B complements the impedance magnitude characterization in FIG. 27A by providing information about the phase relationship between discharge voltage and discharge current at different frequencies and pressure conditions. The phase information is relevant for understanding the power factor of the Hall effect thruster discharge at different operating frequencies. At frequencies where the impedance phase is near zero degrees, the discharge voltage and discharge current are approximately in phase, corresponding to maximum real power transfer to the discharge plasma. At frequencies where the impedance phase deviates from zero degrees, reactive power components are present that do not contribute to thrust generation.

The pressure-dependent variations in impedance phase shown in FIG. 27B indicate that the phase relationship between discharge voltage and discharge current at the breathing mode frequency may vary with facility background pressure. The lowest pressure condition exhibits the most pronounced phase variations around the breathing mode frequency, while higher pressure conditions exhibit reduced phase variations. The characterization of impedance phase as a function of frequency at different background pressures may inform the design of control strategies that account for pressure-dependent effects on the Hall effect thruster discharge plasma dynamics. A control system may use the impedance phase information to compute voltage perturbations that achieve desired phase relationships between the discharge voltage and the discharge current for oscillation reduction or thrust optimization at different operating pressures.

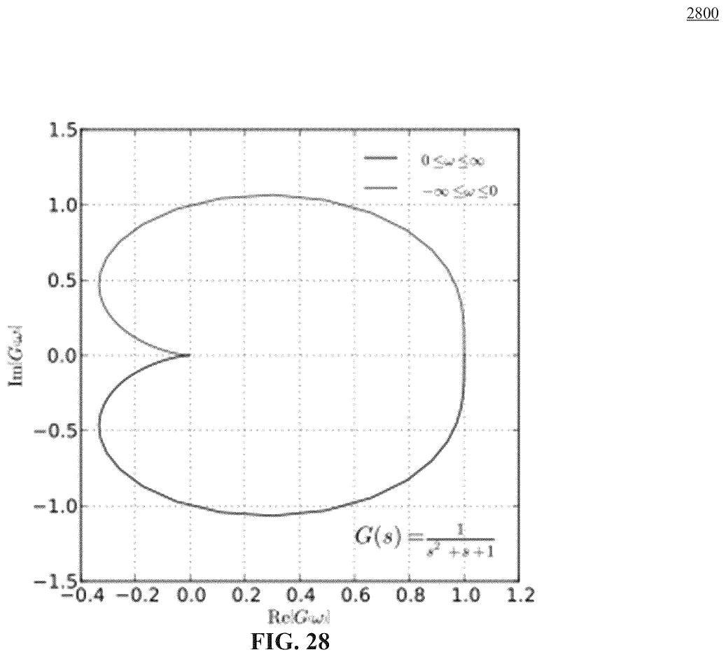

Referring to FIG. 28, a Nyquist plot showing the frequency response of a second-order transfer function G(s)=1/(s²+s+1) is presented. The Nyquist plot displays the complex plane with the real component Re[G(ω)] on the horizontal axis ranging from approximately −0.4 to 1.2. The imaginary component Im[G(ω)] is displayed on the vertical axis ranging from approximately −1.0 to 1.5. The second-order transfer function G(s)=1/(s²+s+1) represents a standard second-order system commonly used in control system analysis for evaluating stability and frequency response characteristics.

With continued reference to FIG. 28, two curves are shown on the Nyquist plot corresponding to positive frequencies and negative frequencies. A blue curve represents positive frequencies spanning the range from ω=0 to ω=∞. A green curve represents negative frequencies spanning the range from ω=−∞to ω=0. The two curves together form a characteristic closed loop pattern typical of second-order systems in the complex plane.

The blue curve representing positive frequencies traces through the lower half of the complex plane. At zero frequency where ω=0, the frequency response starts at the point (1, 0) on the real axis. The starting point at (1, 0) corresponds to the DC gain of the transfer function, which equals unity for the transfer function G(s)=1/(s²+s+1) when s=0. As frequency increases from zero toward infinity, the blue curve spirals inward toward the origin of the complex plane. The spiral trajectory reflects the magnitude attenuation and phase shift that occur as the excitation frequency increases through and beyond the natural frequency of the second-order system.

As further shown in FIG. 28, the green curve representing negative frequencies mirrors the blue curve through the upper half of the complex plane. The green curve traces a path that is symmetric to the blue curve with respect to the real axis. The symmetry between the positive frequency curve and the negative frequency curve arises from the conjugate symmetry property of frequency response functions for real-valued systems. For a real-valued system, the frequency response at a negative frequency equals the complex conjugate of the frequency response at the corresponding positive frequency.

The Nyquist plot in FIG. 28 may be used for analyzing the stability of feedback control systems. The Nyquist stability criterion relates the stability of a closed-loop system to the encirclements of a critical point in the complex plane by the open-loop frequency response curve. For a unity feedback system with open-loop transfer function G(s), the critical point is located at (−1, 0) in the complex plane. The number of encirclements of the critical point by the Nyquist contour determines whether the closed-loop system is stable based on the number of right-half-plane poles in the open-loop transfer function.

The Nyquist plot enables assessment of stability margins for the control system. A gain margin may be determined from the Nyquist plot by measuring the distance from the origin to the point where the frequency response curve crosses the negative real axis. A phase margin may be determined from the Nyquist plot by measuring the angle between the negative real axis and the line from the origin to the point where the frequency response curve crosses the unit circle. The gain margin and the phase margin provide quantitative measures of how much the system gain or phase may change before the closed-loop system becomes unstable.

In the context of Hall effect thruster control systems, the Nyquist plot analysis may be applied to evaluate the stability of feedback control loops designed to manage plasma oscillations. The discharge plasma load of the Hall effect thruster may be characterized by an impedance transfer function that relates discharge voltage perturbations to discharge current responses. The impedance transfer function may be represented in the frequency domain and plotted on a Nyquist diagram to assess the stability of control loops that include the discharge plasma dynamics.

A control system for managing breathing mode oscillations in a Hall effect thruster may employ feedback from discharge current measurements to compute voltage perturbations that attenuate the oscillations. The stability of the feedback control loop depends on the frequency response characteristics of the discharge plasma load and the controller transfer function. The Nyquist plot may be used to verify that the combined frequency response of the controller and the discharge plasma load does not encircle the critical point in a manner that would indicate closed-loop instability.

The frequency response analysis using the Nyquist plot may inform the design of controller parameters such as proportional gain, integral gain, and derivative gain for PID-type controllers. The controller parameters may be adjusted to shape the open-loop frequency response such that the Nyquist contour maintains adequate distance from the critical point, thereby ensuring stability margins that provide robustness against variations in the discharge plasma dynamics. The Nyquist plot analysis may also be applied to evaluate the stability of model predictive path integral control approaches by analyzing the linearized dynamics of the control system around nominal operating points.

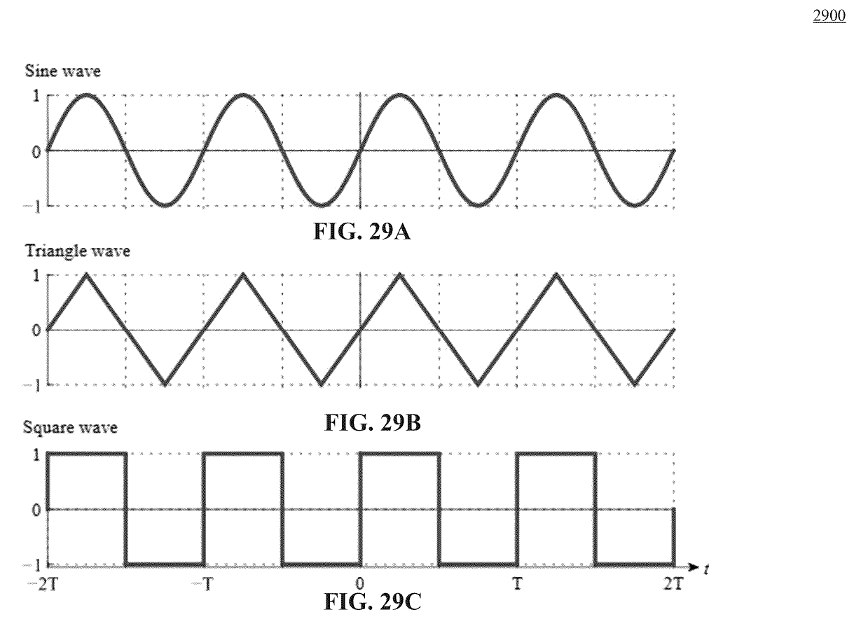

Referring to FIG. 29, three fundamental periodic waveform types commonly used in signal generation and control system applications are depicted. The three waveform types are arranged vertically for comparison and share a common time axis labeled t spanning from −2T to +2T, where T represents the fundamental period of oscillation. Vertical dashed gridlines mark the period boundaries at −2T, −T, 0, T, and 2T. The amplitude axis for each waveform ranges from −1 to +1. The three waveform types represent potential voltage perturbation signals that may be applied to the discharge circuit of a Hall effect thruster for system identification, load characterization, and plasma oscillation control.

FIG. 29A displays a sine wave showing a smooth, continuous oscillation with amplitude varying between +1 and −1. The sine wave exhibits a characteristic sinusoidal shape with gradual transitions between peak values and trough values. The sine wave crosses zero amplitude at the period boundaries and at the midpoints between period boundaries. The sine wave reaches maximum amplitude of +1 at one quarter of the period after each zero crossing in the positive direction. The sine wave reaches minimum amplitude of-1 at three quarters of the period after each zero crossing in the positive direction. The smooth, continuous nature of the sine wave results in a single frequency component in the frequency domain, making the sine wave suitable for single-frequency excitation of the Hall effect thruster discharge plasma.

With continued reference to FIG. 29, the sine wave perturbation signal may be employed for impedance spectroscopy of the Hall effect thruster discharge plasma. When a sinusoidal voltage perturbation at a specific frequency is applied to the discharge circuit, the resulting discharge current response at the same frequency may be measured. The ratio of the voltage perturbation amplitude to the current response amplitude, along with the phase difference between the voltage and current signals, provides the complex impedance of the discharge plasma at the excitation frequency. By applying sine wave perturbations at multiple frequencies across the breathing mode oscillation band and surrounding frequency ranges, a complete impedance characterization of the discharge plasma may be obtained. The sine wave perturbation approach enables precise characterization of the discharge plasma impedance at each individual frequency of interest.

FIG. 29B presents a triangle wave characterized by linear rising and falling segments that form sharp peaks at +1 and troughs at −1. The triangle wave creates a zigzag pattern with constant slope magnitudes on the rising segments and the falling segments. The rising segments exhibit a positive constant slope as the amplitude increases linearly from −1 to +1 over one half of the period. The falling segments exhibit a negative constant slope of equal magnitude as the amplitude decreases linearly from +1 to −1 over the subsequent half of the period. The sharp transitions at the peak values and trough values distinguish the triangle wave from the smooth sinusoidal transitions of the sine wave.

As further shown in FIG. 29, the triangle wave contains harmonic content in addition to the fundamental frequency component. The linear segments of the triangle wave result in odd harmonic frequency components at frequencies of 3f, 5f, 7f, and higher odd multiples of the fundamental frequency f, where f equals 1/T. The amplitudes of the harmonic components decrease with increasing harmonic number according to a 1/n² relationship, where n represents the harmonic number. The harmonic content of the triangle wave enables excitation of multiple frequency components simultaneously when the triangle wave is applied as a voltage perturbation signal to the Hall effect thruster discharge circuit.

The triangle wave perturbation signal may be employed for broadband system characterization of the Hall effect thruster discharge plasma. The multiple frequency components present in the triangle wave excite the discharge plasma at the fundamental frequency and at the odd harmonic frequencies simultaneously. The discharge current response to the triangle wave perturbation contains frequency components at each of the excitation frequencies, enabling characterization of the discharge plasma dynamics across multiple frequencies from a single perturbation waveform. The triangle wave approach may reduce the time required for system identification compared to applying individual sine wave perturbations at each frequency of interest.

FIG. 29C illustrates a square wave that alternates instantaneously between discrete amplitude levels of +1 and −1. The square wave produces a rectangular pulse pattern with vertical transitions between the high amplitude level and the low amplitude level. The vertical transitions occur at the period boundaries and at the midpoints between period boundaries. The square wave maintains a constant amplitude of +1 for one half of each period and maintains a constant amplitude of −1 for the other half of each period. The instantaneous transitions between amplitude levels distinguish the square wave from both the smooth transitions of the sine wave and the linear transitions of the triangle wave.

With continued reference to FIG. 29, the square wave contains harmonic content with a different spectral distribution compared to the triangle wave. The square wave results in odd harmonic frequency components at frequencies of 3f, 5f, 7f, and higher odd multiples of the fundamental frequency f. The amplitudes of the harmonic components in the square wave decrease with increasing harmonic number according to a 1/n relationship, where n represents the harmonic number. The 1/n amplitude rolloff of the square wave harmonics is slower than the 1/n² rolloff of the triangle wave harmonics, resulting in relatively stronger high-frequency harmonic content in the square wave compared to the triangle wave at the same fundamental frequency.

The square wave perturbation signal may be employed for system identification and control of the Hall effect thruster discharge plasma. The rich harmonic content of the square wave provides excitation across a broad frequency range extending well above the fundamental frequency. The square wave may be particularly suitable for characterizing the discharge plasma response at frequencies in the breathing mode oscillation band when the fundamental frequency of the square wave is selected to place harmonic components at frequencies of interest. The instantaneous transitions of the square wave may also be used to characterize the step response of the discharge plasma, providing information about the transient dynamics and settling behavior of the discharge current in response to rapid voltage changes.

As further shown in FIG. 29, the three waveform types may be applied at different amplitudes, frequencies, and phases to characterize the frequency-dependent response and impedance of the Hall effect thruster discharge plasma. The sine wave provides single-frequency excitation suitable for precise impedance measurements at individual frequencies. The triangle wave and the square wave provide multi-frequency excitation suitable for broadband characterization of the discharge plasma dynamics. The selection of waveform type for a particular system identification or control application may depend on the frequency range of interest, the desired frequency resolution, and the time available for characterization measurements.

The perturbation waveform types depicted in FIG. 29 may be generated by a function generator in the control system architecture for the Hall effect thruster. The function generator may produce sine wave, triangle wave, or square wave outputs at selectable frequencies and amplitudes. The perturbation waveforms from the function generator may be amplified by a power amplifier and coupled into the discharge circuit through a transformer to apply voltage perturbations to the Hall effect thruster discharge plasma. The discharge current response to the applied perturbation waveforms may be measured by a current sensor and digitized by an analog-to-digital converter for processing by a field programmable gate array or digital signal processor. The measured discharge current response data may be used for system identification to develop neural network models of the discharge plasma dynamics and for implementing real-time voltage modulation strategies to influence breathing mode oscillations in the Hall effect thruster discharge plasma.

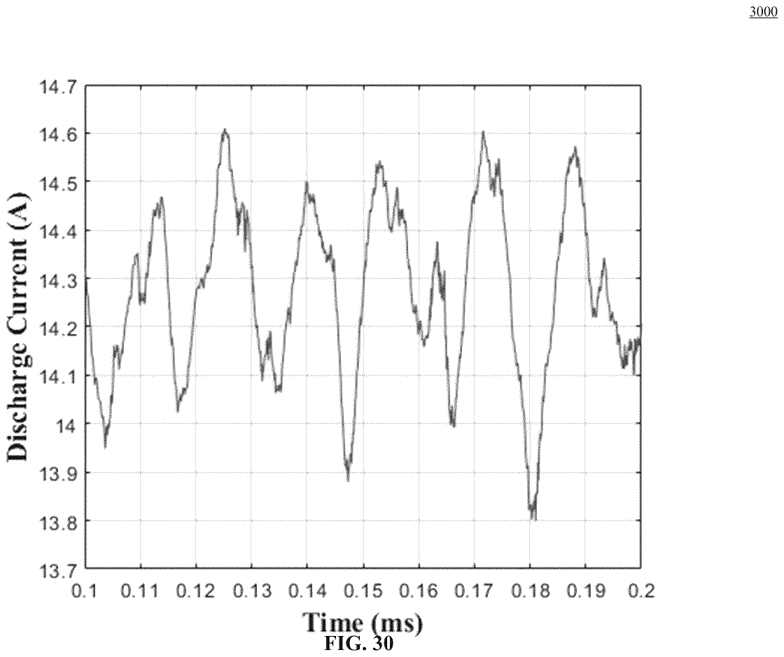

Referring to FIG. 30, a time-domain plot showing discharge current oscillations measured in amperes as a function of time in milliseconds is presented. The time window spans from 0.1 milliseconds to 0.2 milliseconds on the horizontal axis, representing a 0.1 millisecond observation period of discharge current behavior during Hall effect thruster operation. The vertical axis displays discharge current values ranging from approximately 13.7 A to 14.7 A.

With continued reference to FIG. 30, the discharge current waveform exhibits quasi-periodic oscillatory behavior characteristic of breathing mode oscillations in Hall effect thruster discharge plasmas. The discharge current fluctuates around a mean value of approximately 14.2 A throughout the measurement window. The peak-to-peak variations in the discharge current measure approximately 0.8 A, with the discharge current oscillating between minimum values near 13.8 A and maximum values near 14.6 A.

The oscillation pattern visible in FIG. 30 shows a dominant frequency component with the discharge current rising and falling in a somewhat irregular but repetitive manner. Approximately 7 to 8 complete oscillation cycles are visible within the 0.1 millisecond time window shown in the plot. The number of oscillation cycles within the measurement window corresponds to a breathing mode oscillation frequency in the range of 70 kHz to 80 kHz.

As further shown in FIG. 30, the discharge current waveform shape is not purely sinusoidal. The waveform exhibits sharper peaks and broader troughs in some oscillation cycles, which is indicative of the nonlinear nature of the plasma discharge dynamics in the Hall effect thruster. The asymmetric waveform characteristics reflect the predator-prey interactions between neutrals and electrons in the discharge plasma that drive the breathing mode oscillations. Rapid ionization events cause the discharge current to rise toward peak values, while neutral depletion following the ionization events causes the discharge current to fall toward trough values as the neutral population is consumed.

The discharge current measurement data shown in FIG. 30 may be used for characterizing the Hall effect thruster load behavior. The time series data may serve as input for developing machine learning models for system identification of the discharge plasma dynamics. A neural network model may be trained on discharge current time series data to learn the temporal patterns and predict future discharge current values based on past measurements. The discharge current measurement data may also be used for implementing real-time control strategies aimed at reducing plasma oscillations in the Hall effect thruster discharge.

A reference number 2900 appearing in an upper left corner of FIG. 30 may correspond to a test condition or data acquisition identifier within an experimental dataset collected during Hall effect thruster characterization experiments. The discharge current time series data at the identified test condition provides a representative example of the breathing mode oscillation characteristics that a control system may be configured to regulate through voltage perturbations applied to the discharge circuit.

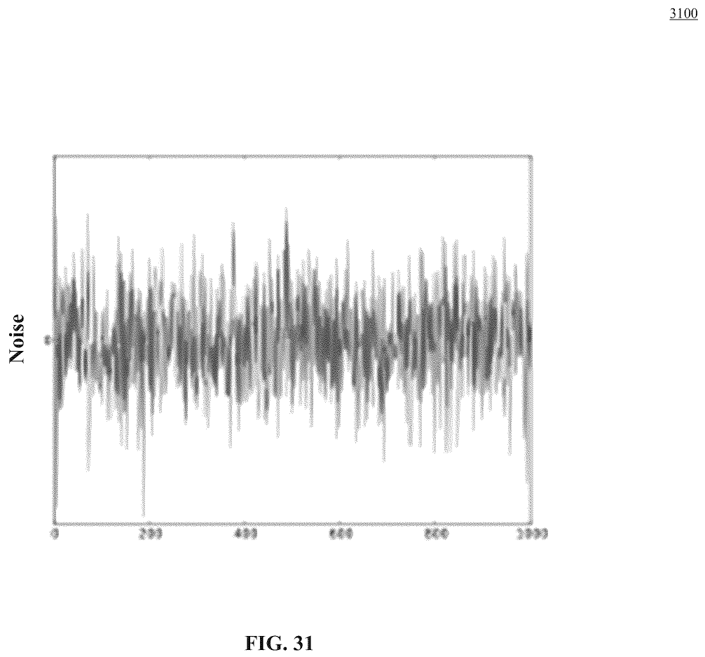

Referring to FIG. 31, a visualization of bandlimited noise perturbation signals used in Hall effect thruster control experiments is presented. The visualization shows a time-series representation of bandlimited noise perturbation signals that may be applied to the discharge circuit for system identification purposes. The plot presents data arranged vertically with time progressing along the vertical axis. The horizontal axis represents the amplitude variations of the noise signal. Blue traces in the visualization show rapid, irregular fluctuations characteristic of bandlimited noise. The signal intensity is concentrated around a central vertical region and extends outward with varying amplitudes throughout the measurement window.

With continued reference to FIG. 31, the bandlimited noise perturbation signal exhibits stochastic characteristics with bounded amplitude variations. The noise signal fluctuates in an irregular, non-periodic manner that distinguishes the bandlimited noise from the deterministic periodic waveforms such as sine waves, triangle waves, and square waves described previously. The bounded amplitude characteristics of the bandlimited noise signal maintain the perturbation within safe operating limits during Hall effect thruster control experiments. The amplitude bounds prevent excessive voltage excursions that could disrupt thruster operation or damage power processing unit components.

The bandlimited noise perturbation signal may be configured to have frequency content concentrated within a specific frequency band corresponding to the breathing mode oscillation frequency range of the Hall effect thruster. When the bandlimited noise is applied around the breathing mode frequency band of the Hall effect thruster discharge, the noise perturbation may serve as an effective perturbation signal for system identification purposes. The frequency content of the bandlimited noise excites the discharge plasma across the range of frequencies within the specified bandwidth, enabling characterization of the discharge plasma dynamics throughout the breathing mode frequency band from a single perturbation signal.

As further shown in FIG. 31, the bandlimited noise perturbation may create local destructive interference that reduces the peak amplitude of discharge current oscillations in the Hall effect thruster. When the bandlimited noise voltage perturbation is applied to the discharge circuit, the random phase relationships between the noise frequency components and the existing breathing mode oscillations may result in partial cancellation of the oscillation peaks. The destructive interference effect arises because the noise signal contains frequency components that are out of phase with portions of the breathing mode oscillation waveform at various instants in time. The out-of-phase components subtract from the breathing mode oscillation amplitude, reducing the peak values of the discharge current oscillations.

The bandlimited noise perturbation approach may provide advantages for system identification compared to single-frequency sinusoidal perturbations. The broadband frequency content of the bandlimited noise enables simultaneous excitation of multiple frequencies within the breathing mode oscillation band. The simultaneous multi-frequency excitation may reduce the time required for system identification by eliminating the need to apply separate perturbations at each individual frequency of interest. The discharge current response to the bandlimited noise perturbation contains information about the discharge plasma dynamics at all frequencies within the noise bandwidth, enabling extraction of impedance characteristics across the full frequency range from a single measurement.

The bandlimited noise perturbation signal may be generated by a function generator in the control system architecture for the Hall effect thruster. The function generator may produce noise output with selectable bandwidth limits that define the frequency range of the noise content. The bandwidth limits may be configured to encompass the breathing mode oscillation frequency band of the Hall effect thruster at the operating conditions of interest. The bandlimited noise output from the function generator may be amplified by a power amplifier and coupled into the discharge circuit through a transformer to apply the noise voltage perturbation to the Hall effect thruster discharge plasma.

The discharge current response to the bandlimited noise perturbation may be measured by a current sensor and digitized by an analog-to-digital converter for processing. The measured discharge current response data may be analyzed using spectral analysis techniques to extract the impedance characteristics of the discharge plasma at frequencies within the noise bandwidth. The impedance characterization data obtained from the bandlimited noise perturbation may be used for developing neural network models of the discharge plasma dynamics. A neural network model may be trained on the input-output relationship between the bandlimited noise voltage perturbation and the resulting discharge current response to learn the frequency-dependent dynamics of the Hall effect thruster discharge plasma.

The oscillation reduction effect of the bandlimited noise perturbation may be quantified by comparing the root mean square amplitude of the discharge current oscillations with and without the noise perturbation applied. When the bandlimited noise creates destructive interference with the breathing mode oscillations, the root mean square amplitude of the discharge current may decrease relative to the baseline condition without perturbation. The magnitude of the oscillation reduction may depend on the amplitude of the bandlimited noise perturbation, the bandwidth of the noise relative to the breathing mode frequency band, and the impedance characteristics of the discharge plasma at the frequencies within the noise bandwidth.

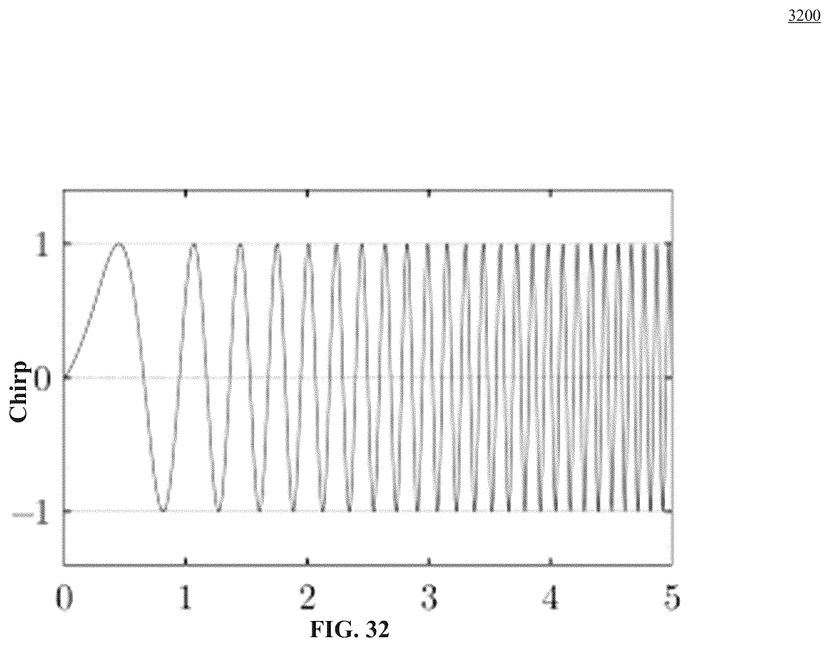

Referring to FIG. 32, a chirp signal waveform is presented showing a frequency-swept sinusoidal signal that may be used for efficient broadband system excitation and impedance characterization of the Hall effect thruster discharge plasma. The chirp signal waveform is plotted with time on the vertical axis extending from 0 to 5 units and amplitude on the horizontal axis ranging from −1 to +1. The chirp signal exhibits characteristic behavior where the frequency of oscillation increases progressively over time throughout the duration of the signal.

With continued reference to FIG. 32, at the top of the plot near time zero, the oscillations have a relatively low frequency with wider spacing between successive peaks and troughs. The low-frequency oscillations at the beginning of the chirp signal correspond to the lower bound of the frequency sweep range. As time progresses downward through the plot, the frequency of the sinusoidal oscillations increases continuously. The increasing frequency is evident from the progressively closer spacing between successive peaks and troughs as time advances from the top of the plot toward the bottom.

By the bottom of the plot near time 5, the oscillations are much more rapid with significantly compressed wavelengths compared to the beginning of the chirp signal. The high-frequency oscillations at the end of the chirp signal correspond to the upper bound of the frequency sweep range. The amplitude of the chirp signal remains relatively constant throughout the duration of the frequency sweep, maintaining excursions between approximately −1 and +1 across the entire time window. The constant amplitude characteristic ensures that the excitation energy is distributed across the swept frequency range without amplitude variations that could complicate the interpretation of the discharge plasma response.

As further shown in FIG. 32, the chirp signal provides a frequency-swept sinusoidal excitation that spans a continuous range of frequencies within a single measurement period. The continuous frequency sweep distinguishes the chirp signal from discrete multi-frequency perturbations such as multisine signals that contain energy at specific individual frequencies. The chirp signal excites the discharge plasma at all frequencies between the lower bound and the upper bound of the sweep range, enabling characterization of the discharge plasma dynamics across the full frequency span from a single perturbation waveform.

The chirp signal may be employed for system identification and impedance characterization of the Hall effect thruster discharge plasma across the breathing mode frequency band and surrounding frequencies. When the chirp signal voltage perturbation is applied to the discharge circuit, the discharge current response contains information about the discharge plasma dynamics at each frequency within the sweep range. The frequency-dependent impedance of the discharge plasma may be extracted by analyzing the relationship between the chirp voltage input and the resulting discharge current output as a function of frequency.

The chirp signal approach may provide advantages for impedance characterization compared to applying separate sinusoidal perturbations at individual frequencies. The frequency sweep of the chirp signal enables efficient excitation across a broad frequency range within a single measurement period, reducing the time required for system identification. The continuous frequency coverage of the chirp signal may reveal impedance features that could be missed when using discrete frequency perturbations with finite frequency spacing. The chirp signal may capture resonant peaks, phase transitions, and other frequency-dependent characteristics of the discharge plasma impedance with high frequency resolution determined by the duration of the frequency sweep.

The chirp signal perturbation may be configured with sweep parameters selected to encompass the breathing mode oscillation frequency band of the Hall effect thruster at the operating conditions of interest. A starting frequency of the chirp signal may be set below the expected breathing mode frequency to capture low-frequency impedance characteristics. An ending frequency of the chirp signal may be set above the expected breathing mode frequency to capture high-frequency impedance characteristics and any harmonic content associated with the breathing mode oscillations. The sweep rate of the chirp signal may be selected to provide adequate frequency resolution while maintaining a measurement duration compatible with the stability of the Hall effect thruster operating conditions.

The chirp signal may be generated by a function generator in the control system architecture for the Hall effect thruster. The function generator may produce a chirp output with selectable starting frequency, ending frequency, and sweep duration parameters. The chirp output from the function generator may be amplified by a power amplifier and coupled into the discharge circuit through a transformer to apply the frequency-swept voltage perturbation to the Hall effect thruster discharge plasma.

The discharge current response to the chirp signal perturbation may be measured by a current sensor and digitized by an analog-to-digital converter for processing. The measured discharge current response data may be analyzed using time-frequency analysis techniques to extract the impedance characteristics of the discharge plasma as a function of frequency. A short-time Fourier transform or continuous wavelet transform may be applied to the chirp voltage input and the discharge current output to obtain time-frequency representations that reveal the frequency-dependent relationship between voltage and current throughout the duration of the chirp sweep.

The impedance characterization data obtained from the chirp signal perturbation may be used for developing neural network models of the discharge plasma dynamics. A neural network model may be trained on the input-output relationship between the chirp voltage perturbation and the resulting discharge current response to learn the frequency-dependent dynamics of the Hall effect thruster discharge plasma. The broadband frequency content of the chirp signal provides training data that spans the full range of frequencies relevant to breathing mode oscillation control, enabling the neural network model to capture the discharge plasma behavior across the operating frequency range of the control system.

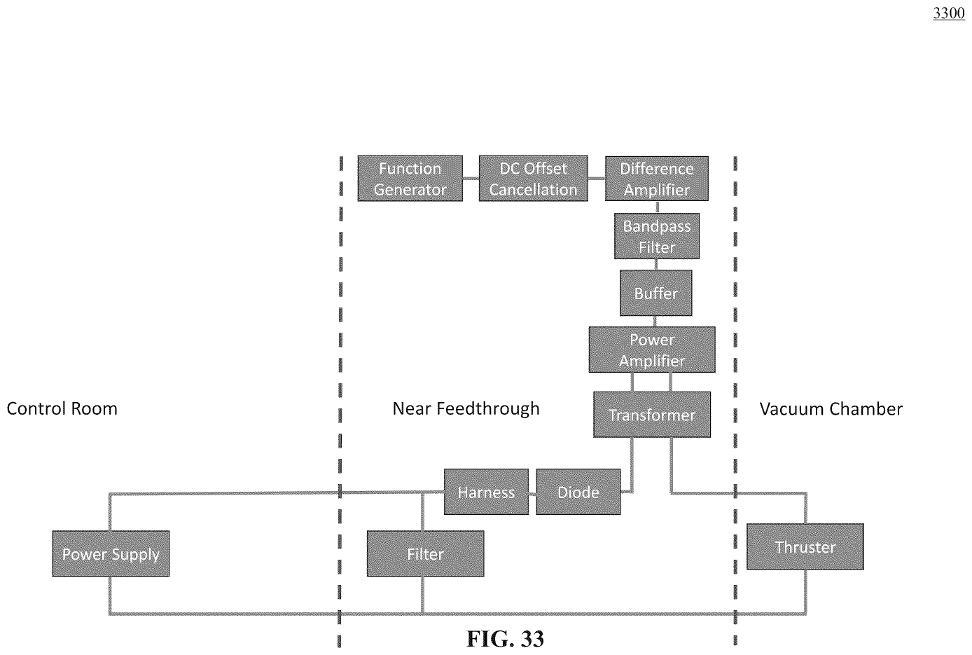

Referring to FIG. 33, a comprehensive block diagram of the experimental setup for Hall effect thruster control is presented. The block diagram illustrates the signal flow and component arrangement across three distinct physical regions separated by dashed vertical lines. The three physical regions include a Control Room region, a Near Feedthrough region, and a Vacuum Chamber region. The separation of the experimental setup into the three physical regions reflects the practical arrangement of equipment in a Hall effect thruster test facility where control electronics are located outside the vacuum environment and the thruster operates inside the vacuum chamber.

In the Control Room region on the right side of the block diagram, a Power Supply provides electrical power to the Hall effect thruster system. The Power Supply delivers the discharge voltage and current required for Hall effect thruster operation. The Power Supply connects to a Filter that conditions the electrical power before delivery to downstream components. The Filter may attenuate high-frequency noise and voltage ripple from the Power Supply output to provide clean DC power to the discharge circuit.

With continued reference to FIG. 33, the Filter connects to a Harness and Diode assembly that feeds into the Thruster located within the Vacuum Chamber region. The Harness represents the electrical cabling that carries power from the Filter through the feedthrough into the vacuum chamber. The Diode in the Harness and Diode assembly may provide reverse current protection to prevent current from flowing back toward the Power Supply during transient conditions in the discharge plasma.

The control signal path in the Control Room region begins with a Function Generator. The Function Generator produces perturbation waveforms that are applied to the discharge circuit for system identification and control purposes. The Function Generator may generate sine waves, square waves, triangle waves, chirp signals, bandlimited noise, or other perturbation waveform types at selectable frequencies and amplitudes. The perturbation waveforms from the Function Generator enable characterization of the Hall effect thruster discharge plasma dynamics and implementation of voltage modulation strategies for controlling breathing mode oscillations.

As further shown in FIG. 33, the output of the Function Generator connects to a DC Offset Cancellation block. The DC Offset Cancellation block is configured to prevent DC saturation of a Transformer located downstream in the signal path. The DC Offset Cancellation circuitry removes any DC component from the Function Generator output signal before the signal reaches the Transformer. DC current flowing through the Transformer windings may cause magnetic saturation of the Transformer core, which would distort the perturbation waveform and reduce the effectiveness of the voltage injection. The DC Offset Cancellation block ensures that the perturbation signal applied to the Transformer contains AC components without a DC offset that could cause saturation.

The output of the DC Offset Cancellation block connects to a Difference Amplifier. The Difference Amplifier is configured to boost the signal to a highest allowable level of a Power Amplifier located downstream in the signal path. The Difference Amplifier increases the amplitude of the perturbation signal from the level produced by the Function Generator and DC Offset Cancellation circuitry to a level that fully utilizes the input range of the Power Amplifier. The signal amplification by the Difference Amplifier maximizes the signal-to-noise ratio of the perturbation signal and enables the Power Amplifier to produce voltage perturbations with sufficient amplitude to influence the discharge plasma dynamics in the Hall effect thruster.

With continued reference to FIG. 33, the output of the Difference Amplifier connects to a Bandpass Filter. The Bandpass Filter is configured to limit the injection signal frequency between a cutoff frequency of the discharge filter and a bandwidth of the Power Amplifier and Transformer. The Bandpass Filter attenuates frequency components below the lower cutoff frequency and above the upper cutoff frequency, passing frequency components within the passband between the two cutoff frequencies. The lower cutoff frequency of the Bandpass Filter may be set above the cutoff frequency of the discharge filter in the power delivery path to ensure that the injected perturbation signals are not attenuated by the discharge filter before reaching the Hall effect thruster. The upper cutoff frequency of the Bandpass Filter may be set below the bandwidth limit of the Power Amplifier and Transformer to ensure that the perturbation signals can be faithfully reproduced by the downstream components without distortion or attenuation.

The output of the Bandpass Filter connects to a Buffer. The Buffer provides impedance matching between the Bandpass Filter output and the Power Amplifier input. The Buffer may present a high input impedance to the Bandpass Filter output to avoid loading the filter and a low output impedance to drive the Power Amplifier input. The Buffer isolates the signal conditioning stages from the power amplification stage to prevent interactions that could degrade signal quality.

As further shown in FIG. 33, the output of the Buffer connects to the Power Amplifier. The Power Amplifier amplifies the conditioned perturbation signal to a power level sufficient to drive the Transformer and inject voltage perturbations into the discharge circuit of the Hall effect thruster. The Power Amplifier may be configured to provide current gain and voltage gain to produce output power levels compatible with the impedance of the Transformer primary winding and the magnitude of voltage perturbations required to influence the discharge plasma dynamics.

The output of the Power Amplifier connects to the Transformer positioned at the Near Feedthrough boundary between the Control Room region and the Vacuum Chamber region. The Transformer provides electrical isolation between the Power Amplifier and the Hall effect thruster discharge circuit. The electrical isolation protects the control electronics in the Control Room from high voltages present in the discharge circuit and prevents ground loops that could introduce noise into the measurement and control signals. The Transformer couples the amplified perturbation signal from the Power Amplifier secondary winding into the discharge circuit, enabling voltage perturbations to be injected in series with the discharge path of the Hall effect thruster.

With continued reference to FIG. 33, within the Vacuum Chamber region on the left side of the block diagram, the signal path from the Transformer continues through the Filter to the Harness and Diode arrangement and then to the Thruster. The Thruster represents the Hall effect thruster that generates the discharge plasma exhibiting breathing mode oscillations. The voltage perturbations injected through the Transformer modulate the discharge voltage applied to the Thruster, enabling the control system to influence the breathing mode oscillations in the discharge plasma.

The experimental setup configuration depicted in FIG. 33 enables injection of controlled voltage perturbations into the Hall effect thruster discharge circuit while maintaining electrical isolation between the control electronics and the high-voltage discharge path. The signal conditioning chain comprising the DC Offset Cancellation block, the Difference Amplifier, the Bandpass Filter, and the Buffer conditions the perturbation signal from the Function Generator to produce a signal suitable for amplification by the Power Amplifier and injection through the Transformer. The arrangement of components across the Control Room, Near Feedthrough, and Vacuum Chamber regions reflects the practical constraints of Hall effect thruster testing where sensitive control electronics are located outside the vacuum environment and electrical connections pass through feedthroughs in the vacuum chamber wall.

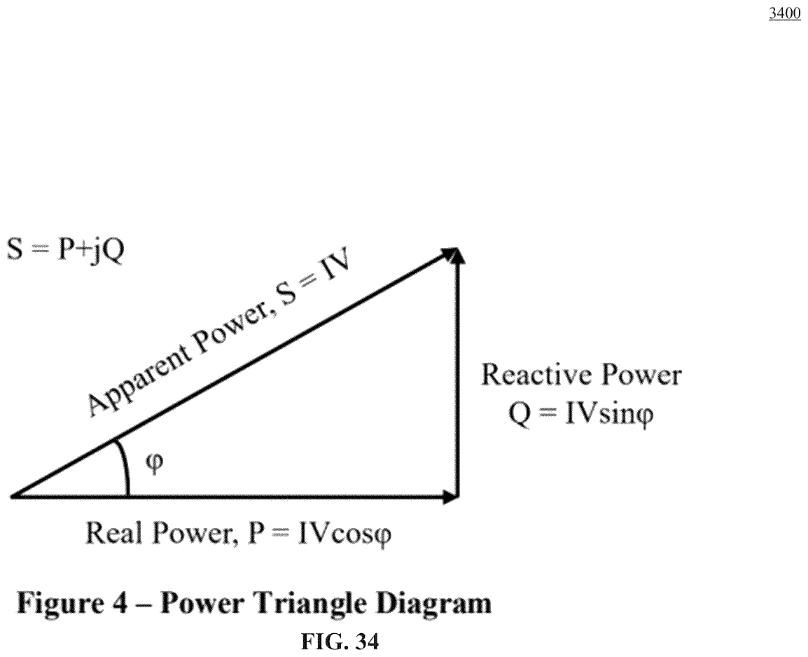

Referring to FIG. 34, a power triangle diagram illustrating the relationship between apparent power, real power, and reactive power in an AC circuit is presented. The power triangle diagram provides a fundamental vector representation used in electrical engineering to characterize the power flow characteristics of circuits where voltage and current waveforms exhibit a phase difference. The power triangle diagram is directly relevant to understanding the power delivery characteristics of the Hall effect thruster discharge circuit where discharge voltage oscillations and discharge current oscillations may exhibit phase differences that affect thrust generation efficiency.

With continued reference to FIG. 34, the power triangle diagram shows a right triangle where each side of the triangle represents a different power quantity. A horizontal leg of the right triangle represents Real Power P. The Real Power P is expressed as P=IV·cos(φ), where I represents the current magnitude, V represents the voltage magnitude, and φ represents the phase angle between the voltage waveform and the current waveform. The Real Power P is measured in watts. The Real Power P represents the portion of the power that performs useful work in the load, which in the context of a Hall effect thruster corresponds to the power that accelerates ions to generate thrust.

A vertical leg of the right triangle represents Reactive Power Q. The Reactive Power Q is expressed as Q=IV·sin(φ), where I represents the current magnitude, V represents the voltage magnitude, and φ represents the phase angle between the voltage waveform and the current waveform. The Reactive Power Q is measured in volt-amperes reactive. The Reactive Power Q represents the portion of the power that oscillates between the source and the load without performing useful work. In the context of a Hall effect thruster, the Reactive Power Q does not contribute to ion acceleration or thrust generation but instead represents energy that flows back and forth between the power processing unit and the discharge plasma during each oscillation cycle.

As further shown in FIG. 34, a hypotenuse of the right triangle represents Apparent Power S. The Apparent Power S equals the product of the current magnitude I and the voltage magnitude V, expressed as S=IV. The Apparent Power S is measured in volt-amperes. The Apparent Power S represents the total power that flows in the circuit, combining both the Real Power P that performs useful work and the Reactive Power Q that oscillates without performing useful work. The Apparent Power S may be computed from the Real Power P and the Reactive Power Q using the Pythagorean relationship S²=P²+Q².

The angle φ at the origin of the power triangle diagram represents the phase angle between the voltage waveform and the current waveform. When the phase angle φ equals zero degrees, the voltage and current waveforms are in phase with each other, the cosine of φ equals unity, and the Real Power P equals the Apparent Power S. When the phase angle φ equals zero degrees, the Reactive Power Q equals zero because the sine of zero degrees equals zero. The zero phase angle condition corresponds to maximum power factor and maximum efficiency of power transfer from the source to the load.

With continued reference to FIG. 34, as the phase angle φ increases from zero degrees toward ninety degrees, the Real Power P decreases because the cosine of φ decreases from unity toward zero. Simultaneously, the Reactive Power Q increases because the sine of φ increases from zero toward unity. When the phase angle φ equals ninety degrees, the Real Power P equals zero and the Reactive Power Q equals the Apparent Power S. The ninety degree phase angle condition corresponds to zero power factor where no net power is transferred to the load over a complete oscillation cycle despite the presence of voltage and current oscillations.

The complex power relationship is expressed at the top of the power triangle diagram as S=P+jQ, where j represents the imaginary unit. The complex power representation combines the Real Power P as the real component and the Reactive Power Q as the imaginary component into a single complex quantity S. The complex power representation enables mathematical analysis of power flow in AC circuits using complex number arithmetic. The magnitude of the complex power S equals the Apparent Power, and the angle of the complex power S in the complex plane equals the phase angle φ between the voltage and current waveforms.

As further shown in FIG. 34, the power triangle concept is directly relevant to the control methodology employed in the Hall effect thruster system. The phase relationship between discharge voltage oscillations and discharge current oscillations affects power delivery efficiency to the discharge plasma. When the discharge voltage and the discharge current are phase aligned with a phase angle φ near zero degrees, more Real Power P is transferred to the discharge plasma for ion acceleration, resulting in increased thrust output. When the phase angle φ deviates from zero degrees, a portion of the power becomes Reactive Power Q that does not contribute to thrust generation.

A control system may be configured to adjust the phase relationship between the discharge voltage oscillations and the discharge current oscillations to maximize the Real Power P delivered to the discharge plasma. By applying voltage perturbations that shift the phase angle φ toward zero degrees, the control system may increase the power factor of the discharge circuit and improve the efficiency of power transfer from the power processing unit to the Hall effect thruster. The power triangle diagram in FIG. 34 provides the theoretical foundation for understanding how phase alignment between voltage and current waveforms affects thrust performance in the Hall effect thruster propulsion system.

The power factor of the discharge circuit may be computed as the ratio of the Real Power P to the Apparent Power S, which equals the cosine of the phase angle φ. A power factor of unity corresponds to a phase angle of zero degrees where all of the Apparent Power is delivered as Real Power to the load. A power factor less than unity indicates that a portion of the Apparent Power is Reactive Power that does not contribute to useful work in the load. In the context of Hall effect thruster control, maximizing the power factor by minimizing the phase angle φ between the discharge voltage and the discharge current may improve thrust efficiency by ensuring that a larger fraction of the power delivered by the power processing unit contributes to ion acceleration rather than oscillating as Reactive Power between the power processing unit and the discharge plasma.

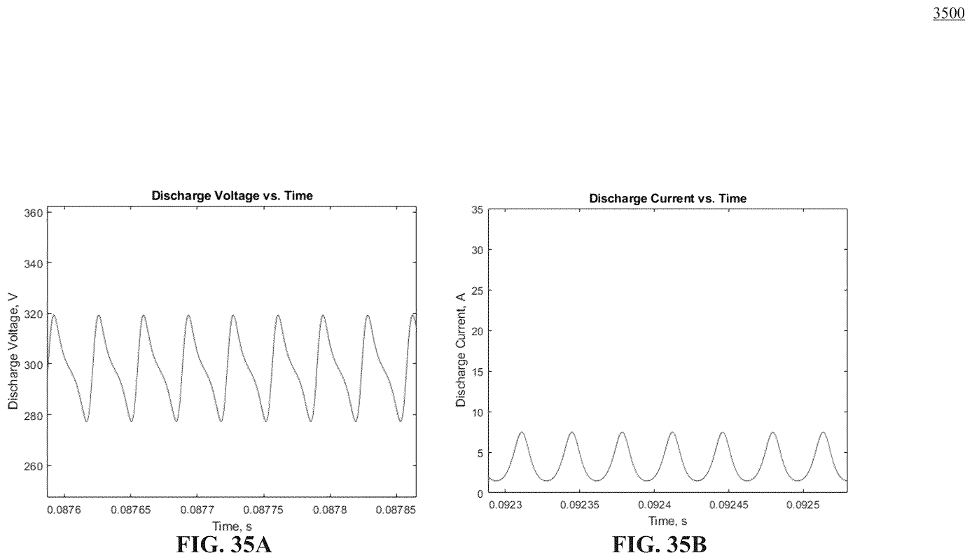

Referring to FIG. 35A, a graph titled “Discharge Voltage vs. Time” showing the temporal behavior of discharge voltage oscillations in a Hall effect thruster system is presented. The vertical axis represents the discharge voltage measured in volts, ranging from approximately 260 V to 360 V. The horizontal axis displays time in seconds spanning from approximately 0.0876 seconds to 0.08785 seconds, representing a measurement window of approximately 250 microseconds of discharge voltage behavior during Hall effect thruster operation.

With continued reference to FIG. 35A, the discharge voltage waveform exhibits a quasi-periodic oscillatory pattern characteristic of breathing mode oscillations in Hall effect thruster discharge plasmas. The discharge voltage oscillates between a minimum of approximately 278 V and a maximum of approximately 320 V throughout the measurement window. The peak-to-peak voltage oscillations measure roughly 42 V around a mean value of approximately 300 V. The peak-to-peak voltage variation of approximately 42 V represents roughly 14 percent of the mean discharge voltage value.

The oscillation frequency visible in FIG. 35A may be estimated from the number of complete cycles within the displayed time window. Multiple complete oscillation cycles are visible within the approximately 250 microsecond measurement window, indicating a breathing mode oscillation frequency in the range of tens of kilohertz consistent with typical Hall effect thruster operation. The discharge voltage waveform shape is not purely sinusoidal but shows some asymmetry and nonlinear characteristics. The rising edges and falling edges of the discharge voltage oscillations have slightly different slopes, reflecting the nonlinear dynamics of the discharge plasma.

As further shown in FIG. 35A, the discharge voltage oscillation data illustrates the type of voltage variations that accompany discharge current oscillations in Hall effect thrusters operating under typical conditions. The discharge voltage oscillations arise from the breathing mode instability in the discharge plasma where predator-prey interactions between neutrals and electrons cause periodic variations in the ionization rate and plasma density within the discharge channel. The discharge voltage oscillation measurements shown in FIG. 35A may serve as input data for characterizing the Hall effect thruster load dynamics and for developing control strategies to manage plasma oscillations through voltage modulation techniques.

Referring to FIG. 35B, a graph titled “Discharge Current vs. Time” showing the temporal behavior of discharge current oscillations in a Hall effect thruster system is presented. The vertical axis represents discharge current measured in amperes, ranging from 0 A to 35 A. The horizontal axis displays time in seconds, spanning approximately from 0.0923 seconds to 0.0927 seconds, representing a measurement window of approximately 400 microseconds of discharge current behavior during Hall effect thruster operation.

With continued reference to FIG. 35B, the discharge current waveform exhibits a periodic oscillatory pattern characteristic of breathing mode oscillations in Hall effect thruster discharge plasmas. The discharge current oscillates between approximately 2 A and 8 A throughout the measurement window, demonstrating a regular sinusoidal-like pattern with consistent amplitude and frequency. The peak-to-peak amplitude of the discharge current oscillations measures approximately 6 A. The mean discharge current value appears to be centered around approximately 5 A.

The oscillation period visible in FIG. 35B appears to be approximately 50 microseconds, corresponding to a breathing mode oscillation frequency in the range of approximately 20 kHz. The breathing mode oscillation frequency observed in FIG. 35B is consistent with typical breathing mode frequencies observed in Hall effect thrusters operating in the tens of kilohertz range. The relatively stable periodic nature of the discharge current oscillations shown in FIG. 35B represents baseline discharge behavior that a model predictive path control system may seek to attenuate through active voltage control techniques.

As further shown in FIG. 35B, the discharge current measurement data demonstrates the type of oscillatory behavior that a machine learning-based control approach may aim to reduce by modulating the discharge voltage in real time. The regular periodicity of the discharge current oscillations indicates that the breathing mode instability has reached a quasi-steady oscillatory state where the ionization and neutral depletion cycles repeat at a consistent frequency. The discharge current time series data shown in FIG. 35B may serve as training data for neural network models that learn to predict discharge current dynamics based on voltage inputs. A control system may use such neural network models to compute voltage perturbations that reduce the amplitude of the breathing mode oscillations or that phase align the discharge voltage and discharge current for improved thrust performance.

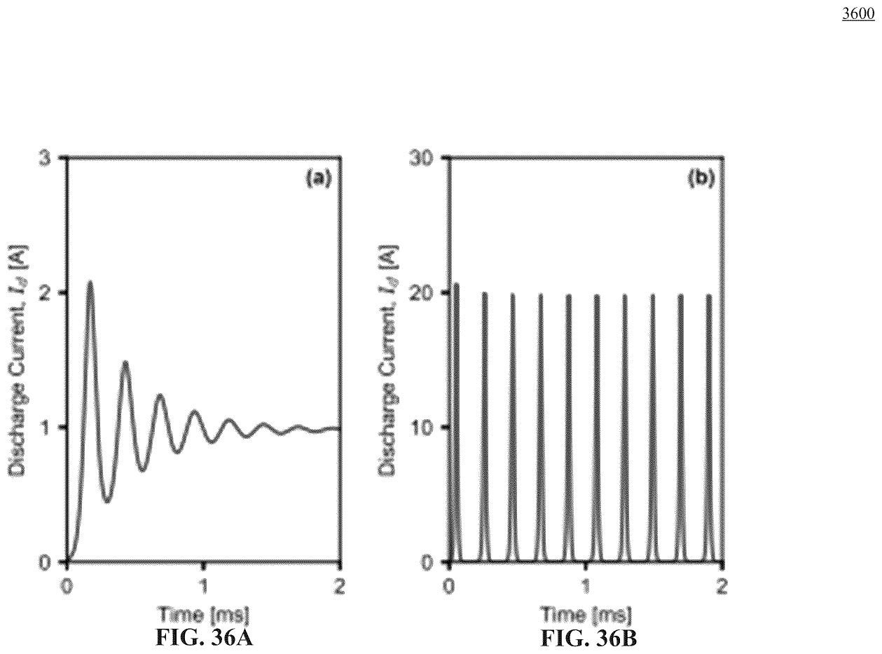

Referring to FIG. 36A, a graph depicting discharge current oscillations over time during a startup transient of a Hall effect thruster is presented. The vertical axis represents the discharge current designated as I_{d} measured in amperes, ranging from 0 A to 3 A. The horizontal axis represents time measured in milliseconds, spanning from 0 ms to 2 ms. The plot displays a characteristic damped oscillatory response shown as a blue curve that illustrates the transient behavior of the discharge current following initiation of Hall effect thruster operation.

With continued reference to FIG. 36A, the discharge current begins near zero amperes at the start of the measurement period and rapidly rises to a peak of approximately 2.1 A at around 0.2 ms. The rapid initial rise in discharge current corresponds to the ignition phase of the Hall effect thruster where the discharge plasma is established and ionization begins within the discharge channel. The peak discharge current value of approximately 2.1 A represents an overshoot above the eventual steady-state operating current level.

Following the initial peak at approximately 0.2 ms, the discharge current exhibits a series of decaying oscillations with progressively decreasing amplitude. The oscillations show subsequent peaks at approximately 1.5 A and 1.2 A at successive cycles following the initial overshoot. The troughs of the oscillations reach down to approximately 0.5 A initially before gradually increasing toward the steady-state value as the oscillation amplitude decays. The damped oscillatory behavior reflects the transient response of the discharge plasma as the breathing mode instability develops and settles toward a quasi-steady operating condition.

As further shown in FIG. 36A, by approximately 1.5 ms of elapsed time, the oscillations have largely damped out and the discharge current settles to a relatively steady-state value of approximately 1.0 A. The settling of the discharge current to a steady-state value indicates that the transient startup phase has concluded and the Hall effect thruster has reached a stable operating condition. The damping behavior illustrated in FIG. 36A demonstrates how discharge current oscillations evolve and stabilize following thruster ignition.

The startup transient waveform shown in FIG. 36A is characteristic of breathing mode oscillations in Hall effect thrusters. The breathing mode oscillations arise from predator-prey type interactions between neutrals and electrons in the discharge plasma. During the startup transient, the ionization and neutral depletion cycles undergo several iterations before reaching a balance that produces the steady-state operating condition. The damped oscillatory response during startup provides information about the natural frequency and damping characteristics of the discharge plasma dynamics.

The discharge current transient data shown in FIG. 36A may be used for characterizing the dynamic response of the Hall effect thruster discharge plasma. The transient response characteristics including the overshoot magnitude, oscillation frequency, and damping rate may inform the design of control systems for managing plasma oscillations. A control system may be configured to apply voltage perturbations during the startup transient to reduce the overshoot magnitude and accelerate the settling of the discharge current to the steady-state operating value. The transient response data may also serve as training data for neural network models that learn to predict discharge current dynamics during startup and steady-state operation of the Hall effect thruster.

Referring to FIG. 36B, a graph depicting discharge current oscillations plotted against time is presented. The vertical axis represents the discharge current designated as I_{d} measured in amperes, ranging from 0 A to 30 A. The horizontal axis represents time measured in milliseconds, spanning from 0 ms to 2 ms. The waveform in FIG. 36B displays a series of sharp, periodic current pulses that exhibit characteristics distinct from the damped transient response shown in FIG. 36A.

With continued reference to FIG. 36B, the discharge current waveform shows a series of sharp current pulses that rise rapidly from near zero amperes to approximately 20 A before quickly returning to the baseline. The current pulses exhibit a spike-like appearance with very narrow width and steep rise and fall times. The rapid transitions between the baseline current level and the peak current level indicate fast ionization events occurring within the discharge plasma of the Hall effect thruster.

The current pulses in FIG. 36B occur at regular intervals throughout the 2 ms time window. Approximately 11 distinct peaks are visible across the measurement period, indicating a consistent pulse repetition rate. The periodicity of the current pulses corresponds to a frequency in the kilohertz range, consistent with breathing mode oscillations typically observed in Hall effect thruster discharge plasmas. The regular spacing of the current pulses indicates that the discharge plasma has reached a stable oscillation mode where the ionization and neutral depletion cycles repeat at a consistent frequency.

As further shown in FIG. 36B, the pulse shape is characterized by a very narrow width relative to the period between successive pulses. The discharge current rises sharply from the baseline to the peak value and then falls sharply back to the baseline within a small fraction of the oscillation period. The narrow pulse width indicates that the ionization events occur in brief bursts followed by extended periods of lower current flow as the neutral population recovers between ionization events.

The pulsed discharge current behavior shown in FIG. 36B is characteristic of the ionization instabilities that occur in Hall effect thrusters. The current oscillates due to the predator-prey dynamics between neutral atoms and electrons in the discharge channel. When the neutral density is high, rapid ionization occurs and the discharge current spikes to a peak value. The ionization event depletes the neutral population, causing the discharge current to fall as fewer neutrals are available for ionization. The neutral population then recovers through propellant injection from the anode, and the cycle repeats when the neutral density reaches a level sufficient to support another ionization burst.

The regular spacing and consistent amplitude of the current pulses in FIG. 36B suggest a stable oscillation mode during the measurement period. The stability of the pulsed discharge current behavior indicates that the Hall effect thruster has reached a quasi-steady operating condition where the breathing mode oscillations persist at a consistent frequency and amplitude. The pulsed discharge current waveform shown in FIG. 36B represents the type of oscillatory behavior that a control system may be configured to regulate through voltage perturbations applied to the discharge circuit.

The discharge current measurement data shown in FIG. 36B may serve as input for machine learning-based system identification and control approaches. A neural network model may be trained on pulsed discharge current time series data to learn the temporal patterns and predict future discharge current values based on past measurements. The predicted discharge current dynamics may be used by a model predictive path control algorithm to compute voltage perturbations that reduce the amplitude of the current pulses or that modify the pulse timing to achieve desired phase relationships between the discharge voltage and the discharge current for improved thrust performance.

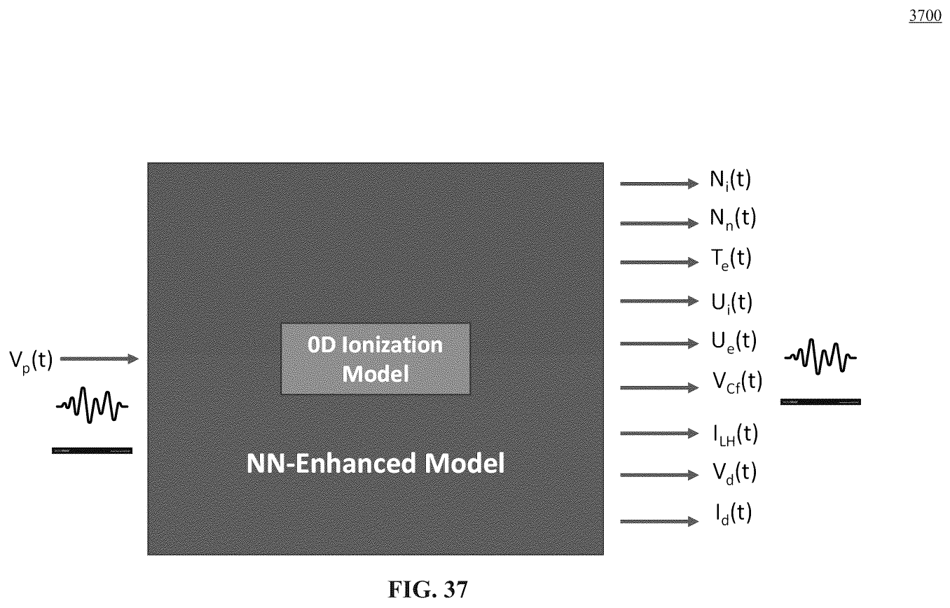

Referring to FIG. 37, a block diagram of a neural network-enhanced model architecture for a Hall effect thruster system is presented. The block diagram depicts a large red rectangular block labeled “NN-Enhanced Model” that encompasses the complete modeling architecture for predicting discharge plasma dynamics. The NN-Enhanced Model receives an input signal and produces multiple output signals that characterize the electrical and plasma state of the Hall effect thruster discharge.

With continued reference to FIG. 37, an input signal labeled V_{d}(t) representing the discharge voltage as a function of time enters the NN-Enhanced Model from the right side of the block diagram. The input signal V_{d}(t) is shown as a wavy oscillating waveform with an arrow pointing into the red block, indicating that the discharge voltage time series serves as the primary input to the neural network-enhanced model. The discharge voltage input V_{d}(t) captures the voltage perturbations and oscillations applied to the Hall effect thruster discharge circuit, which drive the plasma dynamics that the model predicts.

A smaller dark gray block labeled “0D Ionization Model” is positioned within the lower portion of the NN-Enhanced Model block. The 0D Ionization Model represents a zero-dimensional ionization model that captures the fundamental physics of the Hall effect thruster discharge plasma. The zero-dimensional ionization model may comprise eight nonlinear ordinary differential equations including five plasma states and three electrical states. The eight nonlinear ordinary differential equations describe the temporal evolution of the discharge plasma parameters based on conservation laws and ionization physics.

As further shown in FIG. 37, the plasma states in the zero-dimensional model may include ion number density, neutral number density, electron temperature, ion velocity, and electron velocity. The ion number density represents the concentration of ionized propellant atoms within the discharge channel of the Hall effect thruster. The neutral number density represents the concentration of un-ionized propellant atoms that serve as the source for ionization. The electron temperature characterizes the thermal energy of the electron population in the discharge plasma. The ion velocity represents the bulk flow speed of ions through the discharge channel toward the thruster exit. The electron velocity represents the bulk flow speed of electrons within the discharge plasma.

The electrical states in the zero-dimensional model may include filter capacitor voltage, harness inductor current, and discharge voltage. The filter capacitor voltage represents the voltage across the discharge filter capacitor in the power processing unit circuit. The harness inductor current represents the current flowing through the inductance of the electrical harness connecting the power processing unit to the Hall effect thruster. The discharge voltage represents the voltage applied across the discharge plasma between the anode and cathode of the Hall effect thruster. The three electrical states capture the dynamics of the power delivery circuit that couples to the plasma states through the discharge current and voltage relationships.

With continued reference to FIG. 37, multiple output signals exit the NN-Enhanced Model from the left side of the block diagram. Each output signal is represented by a red arrow pointing outward from the NN-Enhanced Model block. The output signals are labeled from top to bottom as I_{d}(t) representing discharge current, Vₐ(t), I_{H}(t), V_{c}(t), Uₙ(t), nᵢ(t), Tₑ(t), Nₙ(t), and Nᵢ(t). The multiple outputs represent various plasma parameters and electrical quantities as functions of time that characterize the complete state of the Hall effect thruster discharge system.

The discharge current output I_{d}(t) represents the predicted discharge current as a function of time. The discharge current prediction is a primary output of the neural network-enhanced model that enables control systems to anticipate the discharge current response to voltage perturbations. The plasma parameter outputs including nᵢ(t) for ion number density, Tₑ(t) for electron temperature, Nₙ(t) for neutral number density, and Nᵢ(t) for ion number density provide predictions of internal plasma states that may not be directly measurable during Hall effect thruster operation.

As further shown in FIG. 37, the architecture of the NN-Enhanced Model illustrates how a neural network enhancement wraps around the zero-dimensional ionization model to predict multiple plasma parameters and electrical quantities from the discharge voltage input. The neural network enhancement may capture complex plasma dynamics that are not fully represented by the simplified zero-dimensional ionization model alone. The neural network component of the NN-Enhanced Model may learn additional physics and relationships between variables from experimental data that supplement the physics-based predictions of the zero-dimensional ionization model.

A neural network model may be configured to predict discharge current dynamics based on voltage inputs. The neural network model may be trained to predict discharge current dynamics based on the digitized discharge current measurement data obtained from Hall effect thruster experiments. The neural network model may be trained on Hall effect thruster discharge data comprising time series measurements of discharge voltage and discharge current collected during thruster operation under various perturbation conditions. The training process enables the neural network model to learn the mapping between voltage inputs and discharge current responses that characterizes the Hall effect thruster discharge plasma dynamics.

As described previously, a field programmable gate array may be configured to execute the neural network model for real-time control of plasma oscillations in the Hall effect thruster. A non-transitory computer-readable medium may store instructions that, when executed by the field programmable gate array, cause the field programmable gate array to perform operations comprising executing the neural network model stored on the field programmable gate array to predict discharge current dynamics based on the digitized discharge current measurement data. The field programmable gate array implementation enables the neural network model to execute with low latency sufficient for real-time control of breathing mode oscillations in the Hall effect thruster discharge plasma.

The neural network-enhanced model architecture depicted in FIG. 37 enables physics-informed machine learning control of the Hall effect thruster discharge plasma. The combination of the zero-dimensional ionization model with the neural network enhancement provides a hybrid modeling approach that leverages both physics-based understanding of the discharge plasma dynamics and data-driven learning from experimental measurements. The hybrid approach may achieve improved prediction accuracy compared to either a purely physics-based model or a purely data-driven model by combining the strengths of both modeling paradigms. The neural network-enhanced model may be used for system identification to characterize the Hall effect thruster discharge plasma dynamics and for model predictive path control to compute voltage perturbations that reduce breathing mode oscillations or optimize thrust performance.

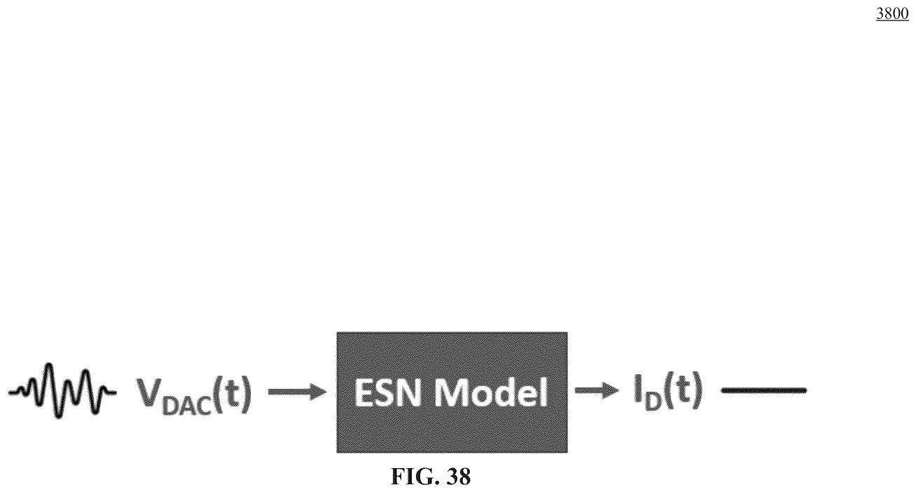

Referring to FIG. 38, a block diagram depicting use of an Echo State Network Model for predicting discharge current from a digital-to-analog converter voltage input is presented. The block diagram illustrates a signal flow from left to right showing how the machine learning architecture serves as a predictive model for system identification of the Hall effect thruster discharge plasma dynamics.

On the left side of the block diagram, an input waveform representing the digital-to-analog converter voltage is shown. The input waveform is denoted as V_{DAC}(t), indicating the voltage output from the digital-to-analog converter as a function of time. The input waveform appears as an oscillating signal that represents the time-varying voltage perturbations applied to the Hall effect thruster discharge circuit through the control system. The digital-to-analog converter voltage input V_{DAC}(t) captures the control voltage signals that modulate the discharge voltage of the Hall effect thruster.

With continued reference to FIG. 38, the input voltage signal V_{DAC}(t) feeds into a central processing block labeled “ESN Model.” The ESN Model block is highlighted in red to emphasize the role of the Echo State Network as the machine learning component of the system identification architecture. The Echo State Network Model processes the time-varying input voltage and produces an output representing the predicted discharge current. The output is denoted as I_{D}(t), representing the discharge current as a function of time. The output is shown as a single line extending from the ESN Model block toward the right side of the block diagram.

The neural network model may comprise an echo state network with a reservoir layer using random fixed recurrent connections that are never trained. The echo state network architecture differs from conventional recurrent neural networks in that the recurrent connections within the reservoir layer remain fixed at their initial random values throughout the training process. The random fixed recurrent connections create a high-dimensional dynamical system that transforms the input signal into a rich set of temporal features. The reservoir layer generates a diverse set of nonlinear combinations of the input history that capture the temporal dynamics of the Hall effect thruster discharge plasma. In the echo state network architecture, training is performed on the output layer using linear regression rather than backpropagation through the recurrent connections. The linear regression training of the output layer determines the weights that map the reservoir state to the predicted discharge current output. The restriction of training to the output layer using linear regression enables computationally efficient training compared to training all weights in a conventional recurrent neural network.

As further shown in FIG. 38, the Echo State Network Model configuration demonstrates how the machine learning-based architecture may be employed for system identification purposes in the context of Hall effect thruster control. The relationship between the applied voltage perturbations represented by V_{DAC}(t) and the resulting discharge current dynamics represented by I_{D}(t) may be accurately modeled by the Echo State Network. The Echo State Network serves as a predictive model that learns the nonlinear time-varying dynamics of the Hall effect thruster discharge plasma from experimental data. The learned model enables prediction of discharge current responses based on voltage inputs, which is fundamental to implementing model predictive path control approaches for managing breathing mode oscillations in the Hall effect thruster.

The echo state network may be configured with hyperparameters including spectral radius, leak rate, sparsity, ridge alpha, reservoir size, eta0, input scale, and feedback scale. The spectral radius hyperparameter controls the largest eigenvalue of the reservoir weight matrix and affects the memory capacity and stability of the echo state network dynamics. The leak rate hyperparameter determines the rate at which reservoir neuron states decay toward zero and influences the timescale of the reservoir dynamics relative to the input signal timescale. The sparsity hyperparameter controls the fraction of non-zero connections in the reservoir weight matrix and affects the diversity of temporal features generated by the reservoir. The ridge alpha hyperparameter provides regularization during the linear regression training of the output layer to prevent overfitting to the training data. The reservoir size hyperparameter determines the number of neurons in the reservoir layer and affects the representational capacity of the echo state network. The eta0 hyperparameter may control learning rate or adaptation parameters during training. The input scale hyperparameter determines the magnitude of the input weights that connect the input signal to the reservoir neurons. The feedback scale hyperparameter determines the magnitude of feedback connections from the output back to the reservoir.

The hyperparameters of the echo state network may be tuned using Bayesian optimization. Bayesian optimization provides a systematic approach for searching the hyperparameter space to find configurations that maximize prediction accuracy on validation data. Bayesian optimization builds a probabilistic model of the relationship between hyperparameter values and prediction performance, then uses the probabilistic model to guide the selection of hyperparameter configurations to evaluate. The Bayesian optimization approach may efficiently explore the high-dimensional hyperparameter space of the echo state network to identify configurations that achieve accurate prediction of discharge current dynamics from voltage inputs.

The echo state network may include feedback connections from outputs back to reservoir neurons with a configurable feedback scale. The feedback connections enable the predicted discharge current output to influence the reservoir state at subsequent time steps. The feedback connections create a closed-loop architecture where the echo state network predictions affect the internal dynamics of the reservoir. The feedback scale hyperparameter controls the strength of the feedback connections and determines the degree to which the output predictions influence the reservoir state evolution. The feedback connections may improve prediction accuracy by enabling the echo state network to incorporate information about past predictions into the computation of future predictions.

The echo state network may include a washout period before training to eliminate the influence of the initial random state. The washout period comprises an initial segment of the input time series that is processed by the echo state network without using the corresponding reservoir states for training the output layer. During the washout period, the reservoir state evolves from the initial random state toward a state that reflects the input signal history. The washout period enables the reservoir state to become synchronized with the input signal dynamics before training data is collected. By excluding the washout period from the training data, the influence of the arbitrary initial random state on the trained output weights is eliminated. The washout period duration may be selected based on the timescale of the reservoir dynamics and the memory capacity of the echo state network to ensure that the initial transient has decayed before training begins.

The Echo State Network Model depicted in FIG. 38 provides a system identification approach for characterizing the Hall effect thruster discharge plasma dynamics. The echo state network learns the mapping between digital-to-analog converter voltage inputs and discharge current outputs from experimental time series data collected during Hall effect thruster operation. The trained echo state network model may be used for predicting discharge current responses to voltage perturbations, enabling model predictive path control algorithms to compute control trajectories that reduce breathing mode oscillations in the Hall effect thruster discharge plasma.

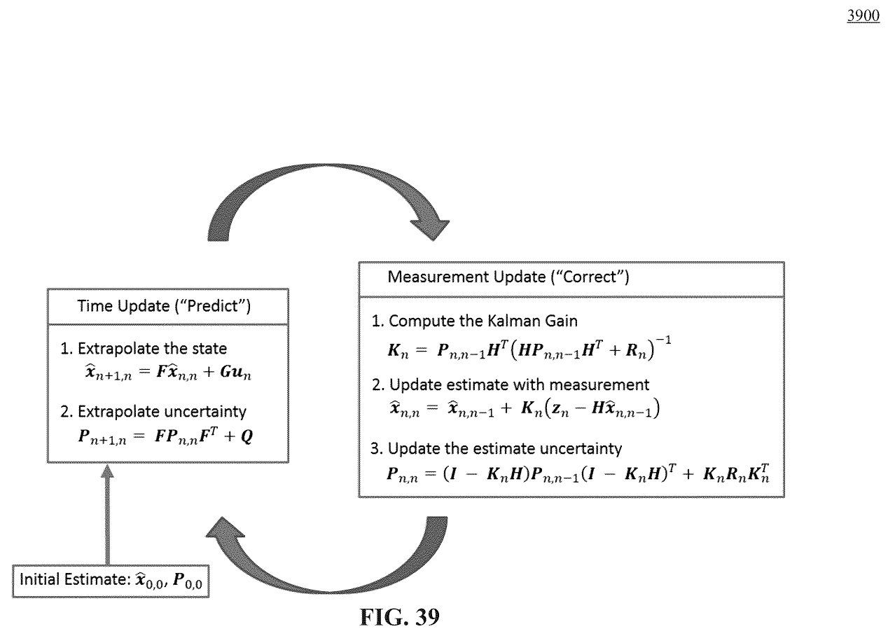

Referring to FIG. 39, a block diagram of a Kalman filter algorithm used for state estimation in a real-time model predictive path control system for Hall effect thruster plasma oscillations is presented. The block diagram depicts a cyclical two-phase process that enables estimation of plasma parameters that may not be directly measurable during Hall effect thruster operation. The Kalman filter algorithm provides a recursive approach for combining model predictions with measurement data to generate improved estimates of the system state.

With continued reference to FIG. 39, the Kalman filter algorithm comprises a Time Update phase and a Measurement Update phase that execute in alternating sequence. The Time Update phase is labeled as “Predict” in the block diagram, indicating that the Time Update phase generates predictions of the system state based on a dynamics model. The Measurement Update phase is labeled as “Correct” in the block diagram, indicating that the Measurement Update phase corrects the predicted state estimates based on actual measurements. Directional arrows in the block diagram indicate the iterative flow between the Time Update phase and the Measurement Update phase, showing that the algorithm cycles repeatedly through the two phases as new measurements become available.

The Time Update phase on the left side of the block diagram contains two computational steps for extrapolating the state and uncertainty forward in time. A first computational step in the Time Update phase extrapolates the state using a state transition equation. The state transition equation expresses the predicted state estimate at time n plus one given measurements up to time n. The predicted state estimate equals the state transition matrix F multiplied by the current state estimate plus the control input matrix G multiplied by the control input u. The state transition matrix F captures the dynamics of the system and describes how the state evolves from one time step to the next in the absence of control inputs. The control input matrix G describes how control inputs affect the state evolution. The control input u represents the voltage perturbations applied to the Hall effect thruster discharge circuit.

As further shown in FIG. 39, a second computational step in the Time Update phase extrapolates the uncertainty using a covariance propagation equation. The covariance propagation equation expresses the predicted covariance matrix P in terms of the current covariance matrix, the state transition matrix F, and a process noise covariance matrix Q. The predicted covariance matrix P equals F multiplied by the current covariance matrix multiplied by F transpose plus the process noise covariance Q. The covariance matrix P represents the uncertainty in the state estimate, with larger covariance values indicating greater uncertainty in the corresponding state variables. The process noise covariance Q accounts for modeling errors and disturbances that cause the actual system state to deviate from the predicted state based on the dynamics model.

With continued reference to FIG. 39, the Measurement Update phase on the right side of the block diagram contains three computational steps for incorporating measurement data into the state estimate. A first computational step in the Measurement Update phase computes a Kalman Gain K. The Kalman Gain K is computed using the predicted covariance matrix P, an observation matrix H, and a measurement noise covariance R. The Kalman Gain K determines the weighting between the predicted state estimate and the measurement innovation when computing the corrected state estimate. The observation matrix H relates the state variables to the measured quantities, describing which state variables are observable through the available measurements. The measurement noise covariance R characterizes the uncertainty in the measurements due to sensor noise and other measurement errors.

A second computational step in the Measurement Update phase updates the state estimate by incorporating the measurement data. The corrected state estimate equals the predicted state estimate plus the Kalman Gain K multiplied by an innovation term. The innovation term equals the difference between the actual measurement z and the predicted measurement. The predicted measurement equals the observation matrix H multiplied by the predicted state estimate. The innovation term represents the discrepancy between what the measurement actually shows and what the measurement was predicted to show based on the state estimate. The Kalman Gain K scales the innovation term to determine how much the state estimate should be adjusted based on the measurement discrepancy.

As further shown in FIG. 39, a third computational step in the Measurement Update phase updates the estimate uncertainty covariance. The updated covariance matrix is computed using a Joseph form equation that involves the identity matrix, the Kalman Gain K, the observation matrix H, and the measurement noise covariance R. The Joseph form equation provides a numerically stable approach for updating the covariance matrix that maintains the positive definiteness of the covariance matrix even in the presence of numerical errors. The updated covariance matrix reflects the reduced uncertainty in the state estimate that results from incorporating the measurement data.

At the bottom of the block diagram in FIG. 39, an arrow points upward to the Time Update block indicating the Initial Estimate. The Initial Estimate comprises an initial state estimate and an initial covariance matrix at time zero. The initial state estimate represents the best available estimate of the system state before any measurements are processed. The initial covariance matrix represents the uncertainty in the initial state estimate. The Kalman filter algorithm begins with the Initial Estimate and then iteratively refines the state estimate by cycling through the Time Update phase and the Measurement Update phase as measurements become available.

A state estimator may be configured to estimate plasma parameters of the discharge plasma based on the discharge current measurement data. The plasma parameters may comprise at least one of ion number density, neutral number density, electron temperature, ion velocity, or electron velocity. The Kalman filter framework depicted in FIG. 39 enables estimation of plasma parameters that cannot be directly measured during Hall effect thruster operation. The discharge current measurement data provides an observable quantity that is related to the internal plasma state through the physics of the discharge plasma. The Kalman filter algorithm uses the relationship between the discharge current and the plasma parameters to infer estimates of the plasma parameters from the discharge current measurements.

The state estimator may comprise an extended Kalman filter configured to combine predictions from a zero-dimensional ionization model with the discharge current measurement data to generate the estimated plasma parameters. The extended Kalman filter extends the standard Kalman filter algorithm to handle nonlinear system dynamics by linearizing the dynamics model around the current state estimate at each time step. The zero-dimensional ionization model provides the dynamics model that predicts how the plasma parameters evolve over time based on the physics of ionization, neutral depletion, and energy balance in the Hall effect thruster discharge plasma. The extended Kalman filter combines the predictions from the zero-dimensional ionization model with the discharge current measurement data to generate improved estimates of the plasma parameters including ion number density, neutral number density, electron temperature, ion velocity, and electron velocity.

As described previously, the zero-dimensional ionization model may comprise eight nonlinear ordinary differential equations including five plasma states and three electrical states. The five plasma states include ion number density, neutral number density, electron temperature, ion velocity, and electron velocity. The three electrical states include filter capacitor voltage, harness inductor current, and discharge voltage. The extended Kalman filter uses the zero-dimensional ionization model to predict the evolution of the plasma states and electrical states forward in time during the Time Update phase. During the Measurement Update phase, the extended Kalman filter incorporates the discharge current measurement data to correct the predicted state estimates and reduce the estimation uncertainty.

The state estimation approach using the Kalman filter algorithm enables physics-informed control of the Hall effect thruster discharge plasma. By estimating the plasma parameters from the discharge current measurement data, the control system may gain insight into the internal state of the discharge plasma that would not be available from the discharge current measurements alone. The estimated plasma parameters may inform control decisions by providing information about the ionization dynamics, neutral depletion, and energy balance that drive the breathing mode oscillations. The estimated plasma parameters may be used to predict how the discharge plasma will respond to voltage perturbations, enabling the model predictive path control algorithm to compute control trajectories that effectively reduce the breathing mode oscillations or optimize thrust performance.

As described previously, a non-transitory computer-readable medium may store instructions that, when executed by a field programmable gate array, cause the field programmable gate array to perform operations. The operations may further comprise estimating plasma parameters based on the digitized discharge current measurement data using a state estimator. The plasma parameters may comprise at least one of ion number density, neutral number density, electron temperature, ion velocity, or electron velocity. The state estimation operations may be implemented on the field programmable gate array alongside the neural network model execution to provide real-time estimates of the plasma parameters during Hall effect thruster operation.

A method for controlling plasma oscillations in a Hall effect thruster may further comprise estimating plasma parameters of a discharge plasma of the Hall effect thruster based on the digitized discharge current measurement data using a state estimator. The plasma parameters may comprise at least one of ion number density, neutral number density, electron temperature, ion velocity, or electron velocity. The state estimation step may be performed concurrently with the neural network model execution and control voltage computation to provide plasma parameter estimates that inform the control algorithm. The estimated plasma parameters may enable the control system to account for variations in the internal plasma state when computing voltage perturbations for oscillation reduction or thrust optimization.

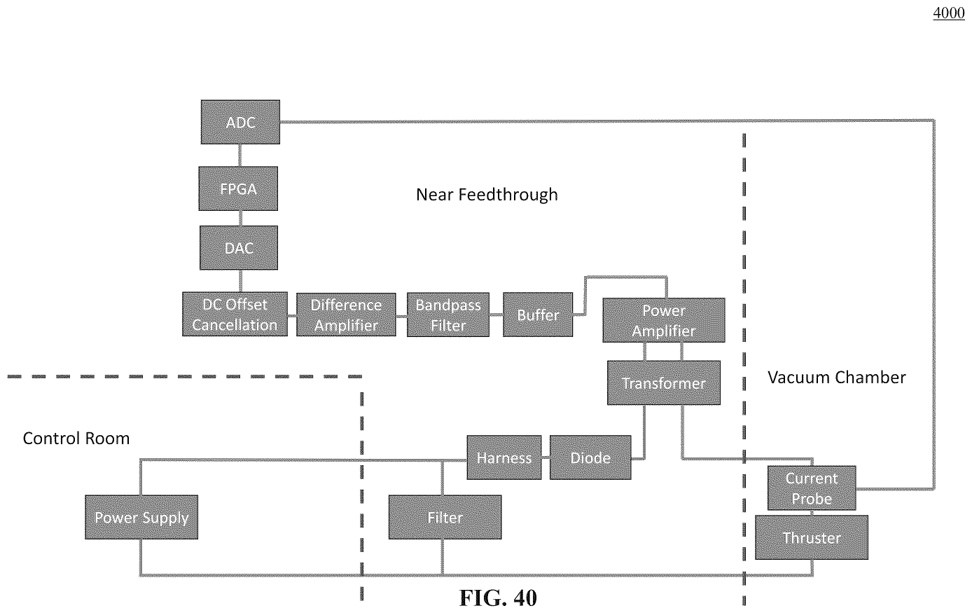

Referring to FIG. 40, a detailed block diagram of the hardware architecture for the real-time control system used in the Hall effect thruster plasma oscillation control system is presented. The block diagram is divided into three distinct regions separated by dashed lines representing physical boundaries in the experimental setup. The three regions include a Control Room region on the left side, a Near Feedthrough section in the middle, and a Vacuum Chamber region on the right side. The separation of the hardware architecture into the three regions reflects the practical arrangement of equipment in a Hall effect thruster test facility where control electronics and signal processing components are located outside the vacuum environment.

In the Control Room region, a Power Supply provides electrical power to the Hall effect thruster system. The Power Supply delivers the discharge voltage and current for Hall effect thruster operation. The Power Supply connects to downstream components that condition and deliver the electrical power to the Hall effect thruster inside the Vacuum Chamber.

With continued reference to FIG. 40, the Near Feedthrough section contains the digital signal processing and analog conditioning components that form the core of the real-time control system. An analog-to-digital converter designated as ADC is positioned at the top of the Near Feedthrough section. The ADC is configured to digitize the discharge current measurement data received from a current sensing path. The ADC receives analog signals from a current probe that measures the discharge current of the Hall effect thruster. The ADC converts the analog discharge current measurement signals into digital form suitable for processing by downstream digital components.

A field programmable gate array designated as FPGA is positioned in the middle of the Near Feedthrough section. The FPGA is configured to execute a neural network model for real-time control of plasma oscillations in the Hall effect thruster. The FPGA receives the digitized discharge current measurement data from the ADC and computes a control voltage output based on the neural network model. The FPGA performs the machine learning computations and control algorithms that determine the voltage perturbations to be applied to the Hall effect thruster discharge circuit. The FPGA may be configured to execute the neural network model with a latency of less than one microsecond to enable multiple control voltage updates within a single breathing mode oscillation period.

As further shown in FIG. 40, a digital-to-analog converter designated as DAC is positioned below the FPGA in the Near Feedthrough section. The DAC is configured to convert the control voltage output from the FPGA to an analog control signal. The DAC receives digital control values computed by the FPGA and produces corresponding analog voltage levels that represent the desired voltage perturbations for the Hall effect thruster discharge circuit.

Below the digital components in the Near Feedthrough section, an analog signal conditioning chain processes the analog control signal from the DAC before the analog control signal is applied to the Hall effect thruster. The analog signal conditioning chain includes a DC Offset Cancellation block that receives the analog control signal from the DAC. The DC Offset Cancellation block removes any DC component from the analog control signal to prevent DC saturation of downstream transformer components.

With continued reference to FIG. 40, a Difference Amplifier is connected to the output of the DC Offset Cancellation block. The Difference Amplifier boosts the signal level to utilize the full input range of downstream amplification stages. A Bandpass Filter is connected to the output of the Difference Amplifier. The Bandpass Filter limits the frequency content of the analog control signal to a passband between a lower cutoff frequency and an upper cutoff frequency. The Bandpass Filter attenuates frequency components outside the passband to ensure that the injected perturbation signals fall within the operating bandwidth of the power amplification and transformer coupling stages.

A Buffer is connected to the output of the Bandpass Filter. The Buffer provides impedance matching between the Bandpass Filter output and the input of a Power Amplifier. The Buffer isolates the signal conditioning stages from the power amplification stage to prevent loading effects that could degrade signal quality.

As further shown in FIG. 40, a power amplifier is configured to amplify the analog control signal from the Buffer. The power amplifier increases the power level of the conditioned analog control signal to a level sufficient to drive transformer coupling into the Hall effect thruster discharge circuit. The power amplifier may be a switch-mode power amplifier with a bandwidth of 250 kHz. The switch-mode architecture of the power amplifier enables efficient power conversion while maintaining sufficient bandwidth to reproduce the voltage perturbation waveforms at frequencies corresponding to the breathing mode oscillation band of the Hall effect thruster.

A transformer is configured to electrically isolate the power amplifier from the Hall effect thruster and to inject the amplified analog control signal in series with a discharge path of the Hall effect thruster. The transformer provides galvanic isolation between the control electronics and the high-voltage discharge circuit of the Hall effect thruster. The electrical isolation protects the control electronics from high voltages present in the discharge circuit and prevents ground loops that could introduce noise into the measurement and control signals. The transformer couples the amplified analog control signal from the power amplifier into the discharge circuit, enabling voltage perturbations to be superimposed on the discharge voltage applied to the Hall effect thruster.

With continued reference to FIG. 40, a voltage injection circuit may comprise two parallel transformers for isolation. Each of the two parallel transformers may have a primary to secondary turns ratio of two to one. The two to one turns ratio provides voltage step-down from the power amplifier output to the discharge circuit while enabling current step-up to deliver the power required for effective voltage perturbation injection. Each transformer may be rated for 500 W, allowing up to 1 kW total power to be added to the plasma when two transformers are used in parallel. The parallel transformer configuration doubles the power handling capability of the voltage injection circuit compared to a single transformer, enabling larger amplitude voltage perturbations to be applied to the Hall effect thruster discharge plasma for control and system identification purposes.

Within the Vacuum Chamber region on the right side of FIG. 40, a Filter block connects to the power delivery path from the Control Room. The Filter attenuates high-frequency noise and provides power conditioning before the electrical power reaches the Hall effect thruster. A Harness and Diode arrangement connects the Filter to the Hall effect thruster. The Harness represents the electrical cabling that carries power through the vacuum chamber to the Hall effect thruster. The Diode provides reverse current protection in the discharge circuit.

As further shown in FIG. 40, a Current Probe monitors the discharge current flowing to the Hall effect thruster. The Current Probe generates the discharge current measurement data that is fed back to the ADC in the Near Feedthrough section for digitization and processing by the FPGA. The Current Probe may comprise a current sensor configured to measure a discharge current of the Hall effect thruster and generate discharge current measurement data. A Thruster block represents the Hall effect thruster that generates the discharge plasma exhibiting breathing mode oscillations.

The hardware architecture depicted in FIG. 40 enables real-time model predictive path integral control of plasma oscillations in the Hall effect thruster by providing the signal acquisition, processing, and actuation pathways for implementing the machine learning-based control approach. The ADC digitizes the discharge current measurements at a sampling rate sufficient to capture the breathing mode oscillations. The FPGA executes the neural network model to predict discharge current dynamics and compute control voltage outputs. The DAC converts the digital control outputs to analog form. The signal conditioning chain comprising the DC Offset Cancellation block, the Difference Amplifier, the Bandpass Filter, and the Buffer conditions the analog control signal for amplification. The power amplifier amplifies the conditioned analog control signal to a power level sufficient for transformer coupling. The transformer injects the amplified analog control signal in series with the discharge path of the Hall effect thruster to modulate the discharge voltage and reduce the breathing mode oscillations in the discharge plasma.

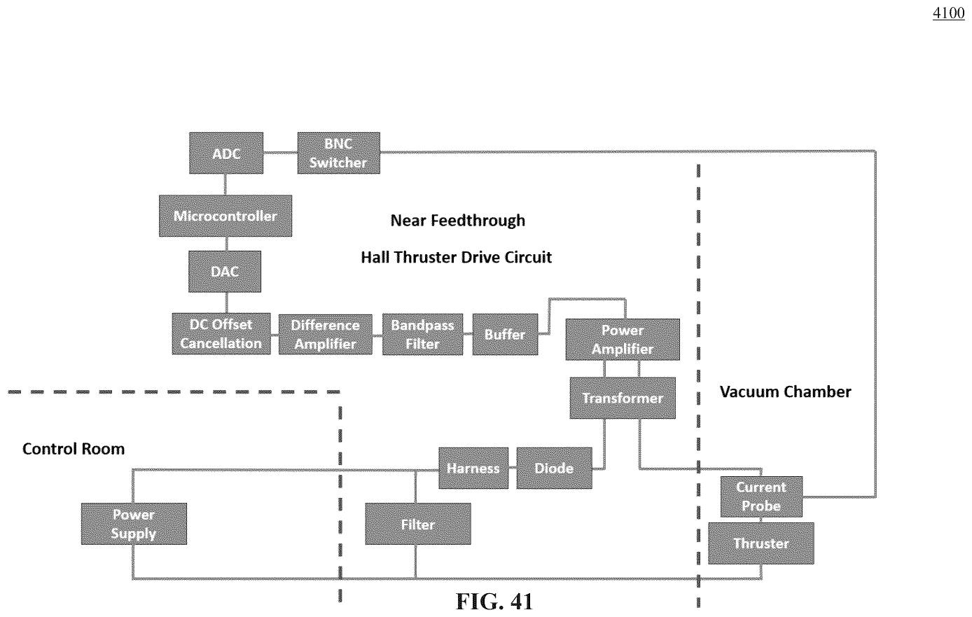

Referring to FIG. 41, a comprehensive block diagram of the Hall thruster drive circuit experimental setup is presented. The block diagram depicts the signal flow and component arrangement across three distinct physical regions separated by dashed red lines. The three physical regions include a Control Room region on the right side, a Near Feedthrough section containing the Hall Thruster Drive Circuit in the center, and a Vacuum Chamber region on the left side. The separation of the experimental setup into the three physical regions reflects the practical arrangement of equipment in a Hall effect thruster test facility where control electronics are located outside the vacuum environment and the Hall effect thruster operates inside the vacuum chamber.

In the Control Room region on the right side of the block diagram, a Power Supply provides electrical power to the Hall effect thruster system. The Power Supply delivers the discharge voltage and current for Hall effect thruster operation. The Power Supply connects to downstream components that condition and deliver the electrical power to the Hall effect thruster inside the Vacuum Chamber.

With continued reference to FIG. 41, the Near Feedthrough section in the center of the block diagram contains the digital signal processing and analog conditioning components that form the Hall Thruster Drive Circuit. The digital processing chain within the Near Feedthrough section includes an analog-to-digital converter designated as ADC that receives measurement signals from the Vacuum Chamber. The ADC digitizes the discharge current measurement data received from a current sensing path for processing by downstream digital components.

A Microcontroller is positioned in the Near Feedthrough section and performs the control computations and algorithm execution for the Hall effect thruster control system. The Microcontroller receives the digitized discharge current measurement data from the ADC and computes control voltage outputs based on the implemented control algorithm. The Microcontroller may execute neural network models, PID control algorithms, or other control approaches for managing plasma oscillations in the Hall effect thruster discharge. The Microcontroller provides a programmable platform for implementing various control strategies and for adjusting control parameters during experimental testing.

As further shown in FIG. 41, a digital-to-analog converter designated as DAC is connected to the Microcontroller. The DAC converts the digital control voltage output from the Microcontroller to an analog control signal. The DAC receives digital control values computed by the Microcontroller and produces corresponding analog voltage levels that represent the desired voltage perturbations for the Hall effect thruster discharge circuit.

A BNC Switcher is positioned in the Near Feedthrough section to enable or disable the control loop connection. The BNC Switcher provides a mechanism for selectively connecting or disconnecting the control signal path between the DAC output and the downstream signal conditioning components. When the BNC Switcher is in a closed position, the control signal path is connected and the control voltage output from the Microcontroller is applied to the Hall effect thruster discharge circuit through the signal conditioning chain. When the BNC Switcher is in an open position, the control signal path is disconnected and no control voltage perturbations are applied to the Hall effect thruster. The BNC Switcher enables rapid switching between controlled operation and uncontrolled baseline operation during experimental testing, allowing comparison of Hall effect thruster behavior with and without active control.

With continued reference to FIG. 41, the analog signal conditioning chain within the Hall Thruster Drive Circuit processes the analog control signal from the DAC before the analog control signal is applied to the Hall effect thruster. The analog signal conditioning chain includes a DC Offset Cancellation block that receives the analog control signal when the BNC Switcher is in the closed position. The DC Offset Cancellation block removes any DC component from the analog control signal to prevent DC saturation of downstream transformer components.

A Difference Amplifier is connected to the output of the DC Offset Cancellation block. The Difference Amplifier boosts the signal level to utilize the full input range of downstream amplification stages. A Bandpass Filter is connected to the output of the Difference Amplifier. The Bandpass Filter limits the frequency content of the analog control signal to a passband between a lower cutoff frequency and an upper cutoff frequency. The Bandpass Filter attenuates frequency components outside the passband to ensure that the injected perturbation signals fall within the operating bandwidth of the power amplification and transformer coupling stages.

As further shown in FIG. 41, a Buffer is connected to the output of the Bandpass Filter. The Buffer provides impedance matching between the Bandpass Filter output and the input of a Power Amplifier. The Buffer isolates the signal conditioning stages from the power amplification stage to prevent loading effects that could degrade signal quality.

The Power Amplifier is connected to the output of the Buffer. The Power Amplifier amplifies the conditioned analog control signal to a power level sufficient to drive transformer coupling into the Hall effect thruster discharge circuit. The Power Amplifier increases the power level of the conditioned analog control signal to enable effective voltage perturbation injection into the discharge plasma.

A Transformer is positioned at the boundary between the Near Feedthrough section and the Vacuum Chamber region. The Transformer provides electrical isolation between the control electronics and the high-voltage discharge circuit of the Hall effect thruster. The electrical isolation protects the control electronics from high voltages present in the discharge circuit and prevents ground loops that could introduce noise into the measurement and control signals. The Transformer couples the amplified analog control signal from the Power Amplifier into the discharge circuit, enabling voltage perturbations to be superimposed on the discharge voltage applied to the Hall effect thruster.

With continued reference to FIG. 41, within the Vacuum Chamber region on the left side of the block diagram, a Filter block connects to the power delivery path. The Filter attenuates high-frequency noise and provides power conditioning before the electrical power reaches the Hall effect thruster. A Harness and Diode arrangement connects the Filter to the Hall effect thruster. The Harness represents the electrical cabling that carries power through the vacuum chamber to the Hall effect thruster. The Diode provides reverse current protection in the discharge circuit.

A Current Probe monitors the discharge current flowing to the Hall effect thruster. The Current Probe generates the discharge current measurement data that is fed back to the ADC in the Near Feedthrough section for digitization and processing by the Microcontroller. The Current Probe may comprise a current sensor configured to measure a discharge current of the Hall effect thruster and generate discharge current measurement data. A Thruster block represents the Hall effect thruster that generates the discharge plasma exhibiting breathing mode oscillations.

As further shown in FIG. 41, the experimental setup configuration depicted in the block diagram enables injection of controlled voltage perturbations into the Hall effect thruster discharge circuit while maintaining electrical isolation between the control electronics and the high-voltage discharge path. The Microcontroller-based architecture provides flexibility for implementing and testing various control algorithms including neural network-based model predictive path control approaches. The BNC Switcher enables rapid transitions between controlled and uncontrolled operating conditions, facilitating experimental comparison of Hall effect thruster performance with and without active oscillation control. The signal conditioning chain comprising the DC Offset Cancellation block, the Difference Amplifier, the Bandpass Filter, and the Buffer conditions the control signal from the Microcontroller to produce a signal suitable for amplification by the Power Amplifier and injection through the Transformer into the Hall effect thruster discharge circuit.

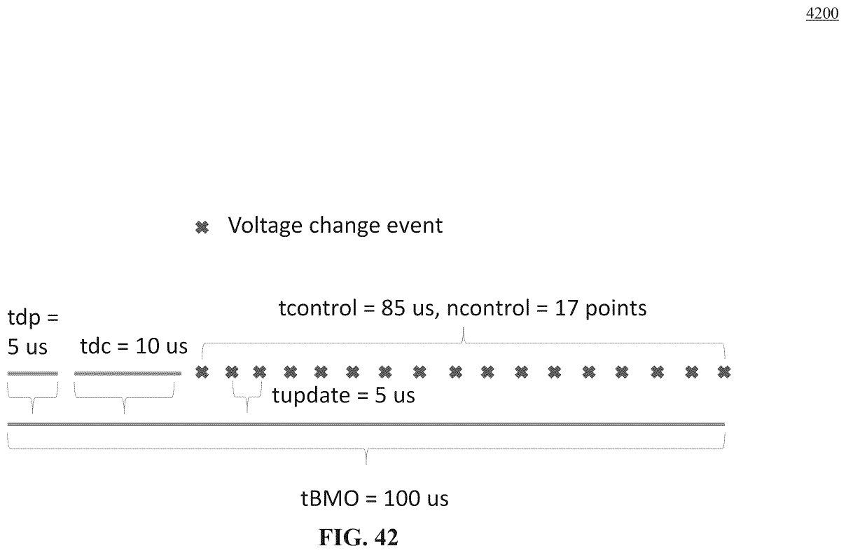

Referring to FIG. 42, a timing diagram for the setpoint determination cycle used in the real-time model predictive path control system for Hall effect thruster plasma oscillations is presented. The timing diagram depicts a horizontal timeline spanning a total breathing mode oscillation period designated as t_{BMO} equal to 100 microseconds. The breathing mode oscillation period of 100 microseconds corresponds to a breathing mode oscillation frequency of approximately 10 kHz, which falls within the typical range of breathing mode frequencies observed in Hall effect thruster discharge plasmas.

With continued reference to FIG. 42, voltage change events are marked along the timeline with red asterisk symbols. The voltage change events represent discrete control update points where the control system applies new voltage setpoint values to the Hall effect thruster discharge circuit. The discrete control update points are distributed throughout the breathing mode oscillation period to enable waveshaping of the discharge current waveform through multiple voltage adjustments within each oscillation cycle.

The timing diagram in FIG. 42 shows several timing parameters that govern the setpoint determination cycle. A propagation delay designated as t_{dp} equal to 5 microseconds represents the time required for signals to propagate through the sensing and actuation pathways of the control system. The propagation delay accounts for transmission line delays, operational amplifier buffer circuit delays, power amplifier delays, and filter delays in the signal path between the control electronics and the Hall effect thruster.

As further shown in FIG. 42, a computation delay designated as t_{dc} equal to 10 microseconds represents the time required for the control system to process measurement data and compute new control voltage setpoints. The computation delay encompasses the time for analog-to-digital conversion, field programmable gate array computation, digital-to-analog conversion, and communication delays within the digital signal processing chain. The computation delay represents the setpoint determination delay that may limit the effectiveness of the control approach if the computation time becomes too long relative to the breathing mode oscillation period.

An update interval designated as t_{update} equal to 5 microseconds represents the time between successive voltage change events. The update interval determines the rate at which new control voltage setpoints are applied to the Hall effect thruster discharge circuit. The 5 microsecond update interval corresponds to an update rate of 200 kHz, which provides sufficient temporal resolution for shaping the discharge current waveform within each breathing mode oscillation cycle.

With continued reference to FIG. 42, a control window designated as t_{control} equal to 85 microseconds encompasses the portion of the breathing mode period during which active control may be applied. The control window represents the time available for applying voltage perturbations after accounting for the propagation delay and computation delay at the beginning of each oscillation cycle. The 85 microsecond control window within the 100 microsecond breathing mode period enables the control system to influence the discharge plasma dynamics throughout the majority of each oscillation cycle.

A parameter n_{control} equal to 17 points indicates the number of discrete control updates that may be executed within a single breathing mode oscillation cycle. The 17 control points distributed across the 85 microsecond control window provide approximately 17 waveshaping points per breathing mode cycle. The control system may operate at a loop speed of 100 kHz enabling approximately 14 to 17 control voltage updates per breathing mode oscillation period. The number of control updates per period depends on the specific timing parameters and the breathing mode oscillation frequency at the operating conditions of the Hall effect thruster.

As further shown in FIG. 42, the timing architecture demonstrates how the control system partitions each breathing mode period to accommodate sensing, analog-to-digital conversion, field programmable gate array computation, digital-to-analog conversion, and communication delays while still achieving multiple control voltage updates within each oscillation cycle. The field programmable gate array may be configured to execute the neural network model with a latency of less than one microsecond. The sub-microsecond latency of the neural network model execution enables the field programmable gate array to compute control voltage outputs rapidly enough to support the 5 microsecond update interval between successive voltage change events.

As described previously, a non-transitory computer-readable medium may store instructions that, when executed by the field programmable gate array, cause the field programmable gate array to perform operations. The operations may further comprise executing the neural network model with a latency of less than one microsecond to enable multiple control voltage updates within a single breathing mode oscillation period. The sub-microsecond neural network execution latency combined with the timing architecture shown in FIG. 42 enables the control system to apply approximately 17 discrete voltage perturbations within each 100 microsecond breathing mode oscillation cycle.

A method for controlling plasma oscillations in a Hall effect thruster may comprise processing the digitized discharge current measurement data using the neural network model executed on the field programmable gate array. Processing the digitized discharge current measurement data using the neural network model executed on the field programmable gate array may comprise executing the neural network model with a latency of less than one microsecond to enable a plurality of control voltage updates within a single breathing mode oscillation period of the Hall effect thruster. The timing diagram in FIG. 42 illustrates how the sub-microsecond neural network execution latency enables the plurality of control voltage updates by providing sufficient time margin within the computation delay budget for neural network inference, control law evaluation, and output generation.

The timing constraints illustrated in FIG. 42 establish the real-time requirements for the machine learning-based control approach. The model predictive path control algorithm may continuously compute control trajectories during operation. A previous control trajectory may be used during the computation delay while the control system determines the next control trajectory. The use of the previous control trajectory during computation introduces an off-by-one relationship between the computed trajectory and the applied trajectory, which the control algorithm may account for in the trajectory optimization. The timing diagram demonstrates that the control system may not achieve perfect control due to the inherent setpoint determination delays, but the sub-microsecond neural network execution latency and the 5 microsecond update interval enable sufficiently rapid control updates to influence the breathing mode oscillations in the Hall effect thruster discharge plasma.

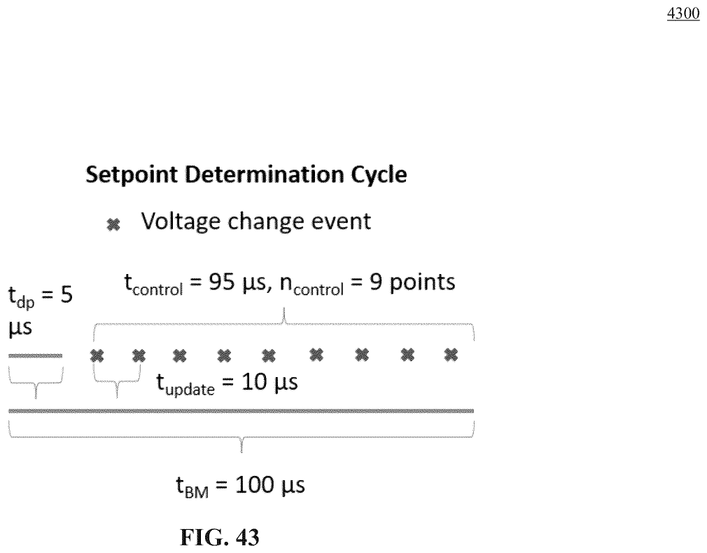

Referring to FIG. 43, a timing diagram for the real-time control scheme used in the model predictive path control of plasma oscillations in Hall effect thrusters is presented. The timing diagram illustrates the temporal relationship between control parameters within a single breathing mode oscillation period. The timing diagram provides an alternative timing configuration compared to the timing diagram shown in FIG. 42, with different parameters governing the distribution of control points within the breathing mode oscillation cycle.

With continued reference to FIG. 43, the total breathing mode period spans 100 microseconds, corresponding to a breathing mode oscillation frequency of approximately 10 kHz. The 100 microsecond breathing mode period establishes the time window within which the control system may apply voltage perturbations to influence the discharge plasma dynamics. The breathing mode period duration determines the number of control updates that may be achieved within each oscillation cycle based on the timing constraints of the control system components.

A propagation delay of 5 microseconds is indicated at the beginning of the timing diagram. The propagation delay represents the initial delay before control actions may be applied to the Hall effect thruster discharge circuit. The propagation delay accounts for signal transmission time through the sensing and actuation pathways, including transmission line delays in the electrical harness, operational amplifier buffer circuit response times, power amplifier settling times, and filter group delays. The 5 microsecond propagation delay establishes a minimum latency between the occurrence of a discharge current measurement and the application of a corresponding control voltage perturbation at the Hall effect thruster.

As further shown in FIG. 43, a control window spans 95 microseconds following the initial propagation delay. The control window represents the portion of the breathing mode period during which active control voltage perturbations may be applied to the Hall effect thruster discharge circuit. The 95 microsecond control window encompasses the majority of the 100 microsecond breathing mode period, enabling the control system to influence the discharge plasma dynamics throughout most of each oscillation cycle. The control window duration of 95 microseconds in FIG. 43 differs from the 85 microsecond control window shown in FIG. 42, reflecting different timing configurations that may be employed depending on the specific implementation parameters of the control system.

With continued reference to FIG. 43, nine control points are distributed within the 95 microsecond control window. The nine control points are represented by red X markers along the timeline within the control window. Each control point corresponds to a discrete voltage change event where the control system applies a new voltage setpoint value to the Hall effect thruster discharge circuit. The nine control points enable waveshaping of the discharge current waveform through multiple voltage adjustments within each breathing mode oscillation cycle.

The nine control points are spaced at regular intervals within the control window. An update time of 10 microseconds separates consecutive setpoint changes. The 10 microsecond update time determines the rate at which new control voltage setpoints are applied to the Hall effect thruster discharge circuit during the control window. The 10 microsecond update time corresponds to an update rate of 100 kHz within the control window, which provides temporal resolution for shaping the discharge current waveform within each breathing mode oscillation cycle.

As further shown in FIG. 43, the distribution of nine control points with 10 microsecond spacing within the 95 microsecond control window enables the control system to apply voltage perturbations at approximately 9 discrete time instants during each breathing mode oscillation cycle. The nine control points provide fewer waveshaping opportunities per oscillation cycle compared to the 17 control points shown in FIG. 42, but the 10 microsecond update time in FIG. 43 provides a longer interval between consecutive setpoint changes compared to the 5 microsecond update interval in FIG. 42. The longer update interval may provide additional time for the control system to complete computation and communication operations between consecutive voltage change events.

The timing configuration shown in FIG. 43 demonstrates that the control system may be configured with different timing parameters depending on the computational capabilities of the field programmable gate array, the bandwidth of the analog signal conditioning chain, and the response characteristics of the power amplifier and transformer coupling stages. The 10 microsecond update time in FIG. 43 may be selected when the control system requires additional computation time for neural network inference or when the analog signal conditioning components have bandwidth limitations that preclude faster update rates.

With continued reference to FIG. 43, the timing diagram establishes the real-time constraints for implementing the machine learning-based control approach with the specific timing parameters shown. The 5 microsecond propagation delay, the 95 microsecond control window, and the 10 microsecond update time together define the temporal structure of the control scheme. The control system may execute the neural network model and compute control voltage outputs within the 10 microsecond interval between consecutive setpoint changes to maintain the update rate throughout the control window.

The timing configuration in FIG. 43 enables the control system to apply approximately 9 discrete voltage perturbations within each 100 microsecond breathing mode oscillation cycle. The nine voltage perturbations distributed throughout the control window may influence the discharge plasma dynamics by modulating the discharge voltage at multiple points within each oscillation cycle. The voltage perturbations may be computed by the neural network model based on the discharge current measurement data to reduce the amplitude of the breathing mode oscillations or to achieve desired phase relationships between the discharge voltage and the discharge current for improved thrust performance.

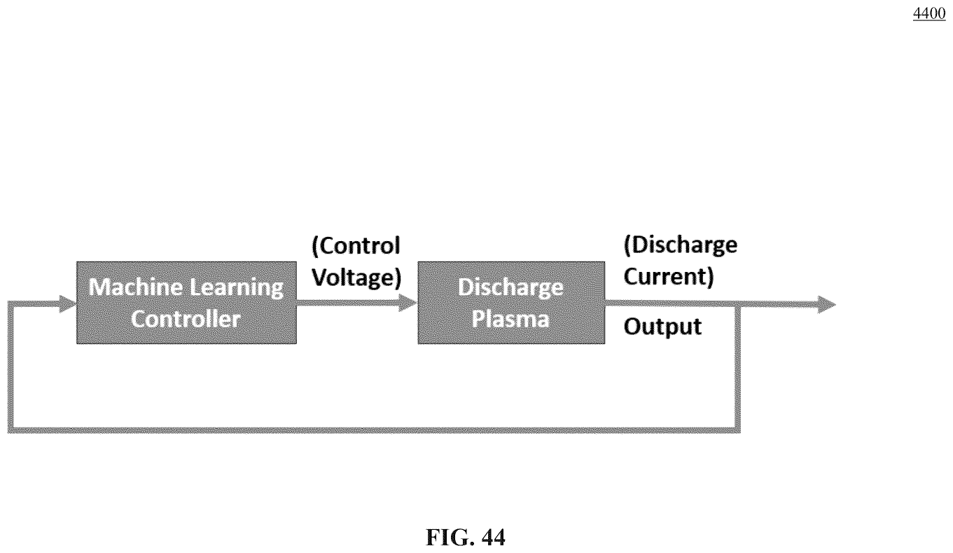

Referring to FIG. 44, a closed-loop control system block diagram using a machine learning controller for Hall effect thruster discharge plasma control is presented. The block diagram illustrates the feedback control architecture that enables real-time regulation of plasma oscillations in the Hall effect thruster through machine learning-based voltage modulation.

With continued reference to FIG. 44, a Machine Learning Controller block is positioned on the left side of the block diagram. The Machine Learning Controller receives discharge current measurements as input and processes the measurements to determine appropriate control actions for managing the discharge plasma dynamics. The Machine Learning Controller may comprise a neural network model executed on a field programmable gate array as described previously. The field programmable gate array receives the digitized discharge current measurement data and computes a control voltage output based on the neural network model.

The Machine Learning Controller outputs a Control Voltage signal that feeds into a Discharge Plasma block positioned to the right of the Machine Learning Controller in the block diagram. The Control Voltage signal represents the voltage perturbation computed by the Machine Learning Controller to influence the breathing mode oscillations in the discharge plasma. Computing a control voltage output based on the predicted discharge current dynamics may reduce breathing mode oscillations in the Hall effect thruster by applying voltage perturbations that counteract the oscillatory behavior of the discharge plasma.

As further shown in FIG. 44, the Discharge Plasma block represents the Hall effect thruster discharge plasma that exhibits breathing mode oscillations during operation. The Discharge Plasma block receives the Control Voltage input from the Machine Learning Controller and produces a Discharge Current as the Output of the system. The Discharge Current output represents the measured discharge current of the Hall effect thruster, which varies in response to both the inherent plasma dynamics and the applied control voltage perturbations.

A feedback loop connects the Discharge Current output back to the input of the Machine Learning Controller, creating a closed-loop configuration. The feedback connection enables the Machine Learning Controller to continuously monitor the discharge current behavior and adjust the control voltage output in response to observed changes in the discharge plasma dynamics. The closed-loop architecture allows the machine learning algorithm to learn and adapt the control strategy based on the measured discharge current response to applied voltage perturbations.

With continued reference to FIG. 44, the closed-loop control system configuration enables real-time adjustment of the discharge voltage based on observed current oscillations. The Machine Learning Controller uses the discharge current measurements to predict future discharge current dynamics and compute control voltage outputs that reduce the amplitude of breathing mode oscillations. The control voltage output from the Machine Learning Controller is output to a digital-to-analog converter for conversion to an analog control signal for modulating a discharge voltage of the Hall effect thruster as described previously.

A method for controlling plasma oscillations in a Hall effect thruster may comprise computing a control voltage output based on the predicted discharge current dynamics using the field programmable gate array. The method may further comprise applying the analog control signal to modulate a discharge voltage of the Hall effect thruster to reduce breathing mode oscillations. The closed-loop control architecture shown in FIG. 44 enables the method to be implemented in real time during Hall effect thruster operation.

The system may use imitation learning where the multilayer perceptron is trained on trajectories produced by nonlinear model predictive control simulation. In the imitation learning approach, a nonlinear model predictive control algorithm first generates control trajectories by optimizing voltage perturbation sequences on a discharge plasma dynamics model. The multilayer perceptron neural network is then trained to reproduce the control trajectories generated by the nonlinear model predictive control algorithm. The trained multilayer perceptron learns the mapping between discharge current states and control voltage outputs that the nonlinear model predictive control algorithm determined to be effective for reducing breathing mode oscillations. The imitation learning approach enables the multilayer perceptron to execute rapidly on the field programmable gate array while producing control outputs that approximate the behavior of the computationally intensive nonlinear model predictive control algorithm.

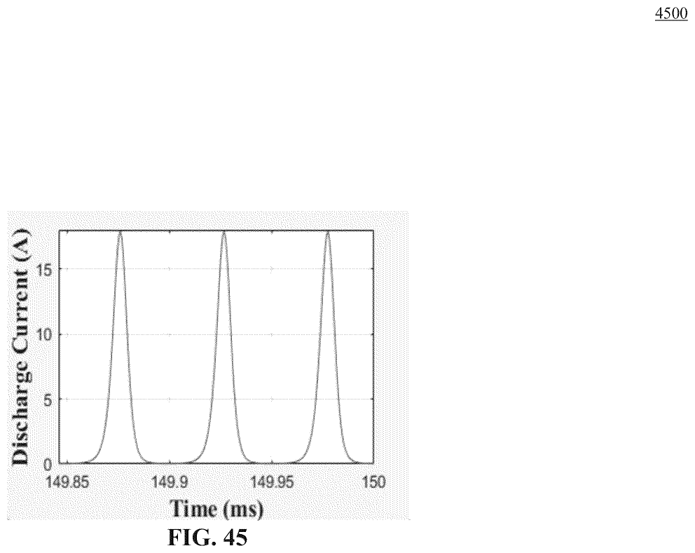

Referring to FIG. 45, a time-domain plot showing discharge current oscillations measured in amperes as a function of time in milliseconds is presented. The time window spans from approximately 149.85 ms to 150 ms, representing a measurement window of approximately 0.15 milliseconds of discharge current behavior during Hall effect thruster operation. The plot displays three distinct, sharp current pulses that exhibit a highly periodic and repeatable waveform pattern characteristic of controlled discharge operation.

With continued reference to FIG. 45, each of the three current pulses rises rapidly from a baseline near zero amperes to a peak amplitude of approximately 18 A to 19 A. Following the peak, each current pulse returns quickly to the baseline near zero amperes. The sharp transitions between the baseline current level and the peak current level indicate fast ionization events occurring within the discharge plasma of the Hall effect thruster under controlled voltage modulation conditions. The rapid rise and fall times of the current pulses distinguish the waveform from the continuous quasi-sinusoidal breathing mode oscillations observed during uncontrolled Hall effect thruster operation.

The three current pulses visible in FIG. 45 are evenly spaced with a period of approximately 0.05 ms between successive pulses. The approximately 0.05 ms period corresponds to a pulse repetition frequency in the range of approximately 20 kHz. The consistent spacing between the current pulses indicates stable controlled operation of the discharge plasma under the applied voltage perturbation scheme. The regularity of the pulse timing demonstrates that the control system maintains synchronization with the discharge plasma dynamics throughout the measurement window.

As further shown in FIG. 45, the narrow width of each current pulse relative to the period between successive pulses creates a pulsed or chopped discharge current characteristic. The pulsed discharge current waveform is consistent with synchronized chopper operation or pulsating boost chopper control techniques applied to the Hall effect thruster power processing unit. In synchronized chopper operation, the chopping frequency of the power processing unit may be synchronized with the breathing mode oscillations of the discharge plasma to achieve controlled pulsing of the discharge current. The synchronization between the chopping waveform and the plasma oscillation dynamics enables the control system to shape the discharge current into discrete pulses rather than allowing continuous breathing mode oscillations to develop.

The regularity and consistency of the pulse amplitudes visible in FIG. 45 indicate stable controlled operation of the discharge plasma. Each of the three current pulses reaches approximately the same peak amplitude of 18 A to 19 A, demonstrating that the control system maintains consistent pulse characteristics across successive oscillation cycles. The consistent pulse amplitudes suggest that the voltage modulation applied by the control system produces repeatable ionization events within the discharge plasma at each pulse occurrence.

With continued reference to FIG. 45, the pulsed discharge current waveform demonstrates the temporal characteristics of discharge current when active voltage modulation is applied to the Hall effect thruster system. The discrete current pulses represent a controlled operating mode where the discharge plasma is periodically driven through ionization events at times determined by the voltage modulation waveform. The pulsed operating mode may provide advantages for thrust performance compared to continuous breathing mode oscillations by enabling more efficient power transfer to the discharge plasma during the pulse intervals.

The discharge current pulse waveform shown in FIG. 45 may be achieved through various voltage modulation approaches implemented by the control system. A pulsating boost chopper in the power processing unit may modulate the discharge voltage at a chopping frequency selected to produce the observed pulse repetition rate. The chopping frequency may be synchronized with the natural breathing mode frequency of the discharge plasma to achieve stable pulsed operation. Alternatively, the machine learning controller may compute voltage perturbation sequences that produce the pulsed discharge current behavior by applying voltage modulations that trigger ionization events at controlled intervals.

As further shown in FIG. 45, the baseline current level between successive pulses remains near zero amperes throughout the measurement window. The near-zero baseline current indicates that the discharge plasma substantially extinguishes between ionization events, with minimal current flow occurring during the intervals between pulses. The low baseline current between pulses may reduce power consumption during the inter-pulse intervals while concentrating the power delivery during the pulse peaks when ionization and ion acceleration occur.

The pulsed discharge current waveform characteristics demonstrated in FIG. 45 inform the design of control strategies for managing plasma oscillations in Hall effect thrusters. The ability to produce discrete, repeatable current pulses through voltage modulation indicates that the control system may shape the discharge current waveform to achieve desired temporal characteristics. The control system may adjust the pulse amplitude, pulse width, and pulse repetition rate by modifying the voltage modulation parameters to optimize thrust performance or to achieve specific operating objectives for the Hall effect thruster propulsion system.

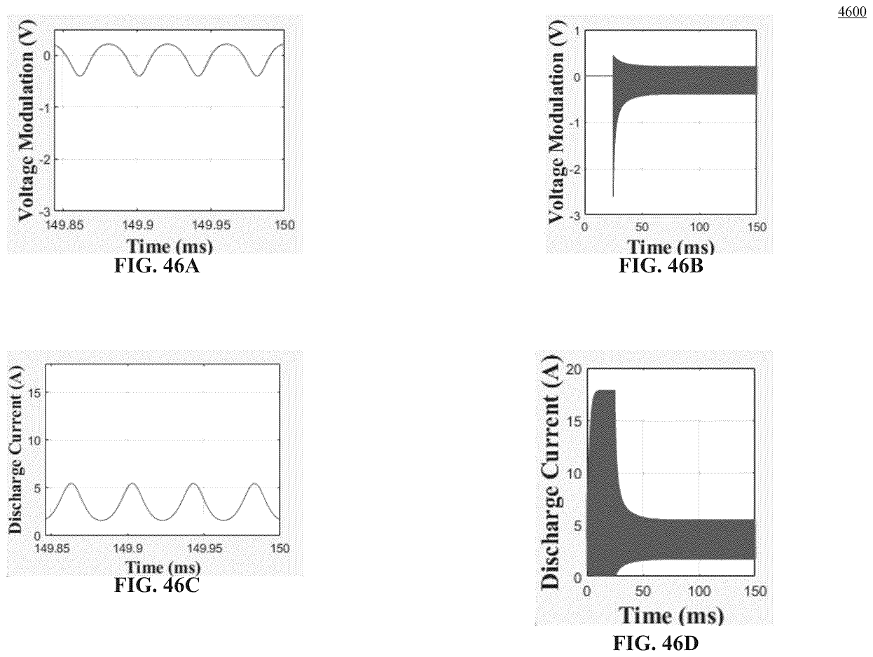

Referring to FIG. 46A, a time-domain plot showing voltage modulation as a function of time for a Hall effect thruster discharge system is presented. The vertical axis displays Voltage Modulation measured in Volts, ranging from approximately negative 3 volts to positive 0.5 volts. The horizontal axis shows Time measured in milliseconds, spanning from 149.85 ms to 150 ms. The time window represents approximately 0.15 milliseconds of voltage modulation behavior during Hall effect thruster operation.

With continued reference to FIG. 46A, the voltage modulation waveform depicted is a sinusoidal oscillation centered around zero volts with relatively small amplitude variations of approximately plus or minus 0.5 volts. The sinusoidal oscillation pattern demonstrates the periodic nature of the voltage perturbation signal applied to the Hall effect thruster discharge plasma. Multiple complete oscillation cycles are visible within the 0.15 millisecond time window shown in the plot. The number of complete cycles within the measurement window indicates an oscillation frequency in the range of tens of kilohertz, consistent with the breathing mode oscillation frequency band of the Hall effect thruster.

As further shown in FIG. 46A, the small amplitude of the voltage modulation demonstrates that relatively minor voltage perturbations may be used to influence and control plasma oscillations in the Hall effect thruster discharge. The voltage modulation amplitude of approximately plus or minus 0.5 volts represents a small fraction of the nominal discharge voltage of the Hall effect thruster, which may operate at discharge voltages of 250 V to 600 V depending on the operating point. The small relative amplitude of the voltage modulation indicates that the control system may achieve oscillation control without requiring large voltage excursions that could disrupt thruster operation or exceed the power handling capabilities of the voltage injection circuit components.

The voltage modulation waveform shown in FIG. 46A represents the control signal applied to the Hall effect thruster discharge plasma as part of the real-time model predictive path control system. The sinusoidal voltage modulation may be computed by the neural network model executed on the field programmable gate array based on the discharge current measurement data. The neural network model may determine the amplitude, frequency, and phase of the voltage modulation to achieve desired control objectives such as reducing the amplitude of breathing mode oscillations or phase aligning the discharge voltage and discharge current for improved thrust performance.

Referring to FIG. 46B, a time-domain plot showing voltage modulation transient response is presented. The vertical axis displays voltage modulation in volts, ranging from negative 3 volts to positive 1 volt. The horizontal axis shows time in milliseconds, spanning from 0 to 150 milliseconds. The extended time window of 150 milliseconds enables observation of the transient response characteristics of the voltage modulation signal over a longer duration compared to the steady-state behavior shown in FIG. 46A.

With continued reference to FIG. 46B, the voltage modulation signal exhibits a transient response following the application of a control voltage perturbation. At approximately 25 milliseconds, a sharp negative voltage spike occurs reaching approximately negative 2.7 volts. The sharp negative voltage spike represents the initial application of a control voltage perturbation to the Hall effect thruster discharge circuit. The magnitude of the initial spike indicates a step change or impulse-like perturbation applied by the control system at the onset of the control action.

Following the initial transient spike, the voltage modulation signal exhibits a rapid recovery characterized by an exponentially decaying envelope. The exponentially decaying envelope demonstrates the settling behavior of the voltage modulation signal as the control system transitions from the initial perturbation toward a steady-state operating condition. The decay rate of the envelope indicates the time constant of the transient response, which depends on the dynamics of the voltage injection circuit components including the power amplifier, transformer, and discharge filter elements.

As further shown in FIG. 46B, the voltage modulation signal settles toward a steady-state oscillatory behavior following the exponential decay of the initial transient. The oscillations appear as a dense blue band centered around approximately negative 0.3 to negative 0.4 volts, indicating sustained high-frequency voltage modulation superimposed on a DC offset. The width of the oscillation band gradually narrows during the recovery phase between approximately 25 milliseconds and 75 milliseconds before reaching a relatively constant amplitude for the remainder of the measurement period extending to 150 milliseconds.

The transient response characteristics visible in FIG. 46B demonstrate how the control system applies voltage perturbations to influence discharge plasma dynamics and breathing mode oscillations in the Hall effect thruster. The initial spike followed by the exponentially decaying envelope represents a characteristic step response of the voltage injection circuit. The settling of the voltage modulation signal to a steady-state oscillatory condition indicates that the control system achieves stable operation following the initial transient perturbation. The transient response data may inform the design of control algorithms by characterizing the dynamic behavior of the voltage injection pathway and enabling prediction of how voltage perturbations propagate to the Hall effect thruster discharge plasma.

Referring to FIG. 46C, a time-domain waveform plot showing a periodic oscillating signal over a time window spanning from approximately 149.85 milliseconds to 150 milliseconds is presented. The vertical axis displays amplitude values ranging from approximately 0 to 15 units. The horizontal axis shows time in milliseconds. The time window of approximately 0.15 milliseconds captures multiple complete oscillation cycles of the periodic signal.

With continued reference to FIG. 46C, the waveform exhibits a characteristic sinusoidal-like oscillation pattern with the signal oscillating between a minimum value of approximately 1.5 to 2 units and a maximum value of approximately 5 to 5.5 units. The peak-to-peak amplitude of the oscillations measures approximately 3.5 to 4 units. The oscillation period appears to be approximately 0.03 to 0.04 milliseconds, corresponding to a frequency in the range of 25 kHz to 33 kHz. The oscillation frequency falls within the breathing mode oscillation frequency band characteristic of Hall effect thruster operation.

As further shown in FIG. 46C, the waveform demonstrates relatively stable periodic behavior with consistent amplitude and frequency throughout the displayed time window. The regularity of the oscillations indicates steady-state operation where the discharge plasma dynamics have settled into a quasi-periodic oscillation mode. The consistent amplitude of the oscillations across successive cycles suggests that the control system maintains stable operating conditions during the measurement period. The periodic waveform characteristics shown in FIG. 46C may serve as a baseline for comparison against controlled operating conditions where voltage perturbations are applied to modify the oscillation amplitude or phase characteristics.

Referring to FIG. 46D, a time-domain plot showing discharge current in amperes on the vertical axis ranging from 0 to 20 A plotted against time in milliseconds on the horizontal axis ranging from 0 to 150 ms is presented. The extended time window of 150 milliseconds enables observation of the discharge current behavior over a duration sufficient to capture both transient and steady-state operating regimes of the Hall effect thruster.

With continued reference to FIG. 46D, the discharge current waveform exhibits characteristic behavior of Hall effect thruster discharge current oscillations depicted as a dense blue filled region indicating rapid oscillatory behavior throughout the measurement period. During an initial phase from approximately 0 to 25 milliseconds, the discharge current exhibits large amplitude oscillations spanning roughly from near 0 A up to approximately 17 A to 18 A. The large amplitude oscillations during the initial phase represent a highly oscillatory startup or transient regime where the breathing mode instability produces pronounced discharge current variations.

As further shown in FIG. 46D, after the initial phase of large amplitude oscillations, the discharge current behavior transitions around 25 milliseconds to 50 milliseconds into a more stable operating regime. Following the transition, the discharge current oscillates within a narrower band centered around approximately 5 A to 6 A with reduced peak-to-peak amplitude compared to the initial transient phase. The narrower oscillation band persists from approximately 50 milliseconds through the remainder of the measurement window to 150 milliseconds.

The transition from large amplitude oscillations to a narrower oscillation band visible in FIG. 46D demonstrates the dynamic behavior of the discharge plasma as the Hall effect thruster settles from an initial transient condition into a quasi-steady operating state. The reduction in oscillation amplitude following the initial transient may result from the natural damping characteristics of the discharge plasma dynamics or from the application of control voltage perturbations that attenuate the breathing mode oscillations. The dense blue shading throughout the plot indicates the presence of high-frequency breathing mode oscillations characteristic of Hall effect thruster operation, with the oscillation envelope narrowing as the system approaches steady-state conditions.

The discharge current waveform shown in FIG. 46D illustrates the type of current oscillations that the machine learning-based control system may characterize and regulate through real-time voltage perturbation control strategies. The transition from large amplitude oscillations to a narrower oscillation band demonstrates that the discharge current behavior may be modified through appropriate control actions. A control system may be configured to accelerate the transition to the narrower oscillation band by applying voltage perturbations during the initial transient phase that dampen the large amplitude oscillations. The steady-state oscillation characteristics visible in the latter portion of FIG. 46D represent the baseline behavior that the control system may further reduce through continued application of voltage modulation computed by the neural network model based on the discharge current measurement data.

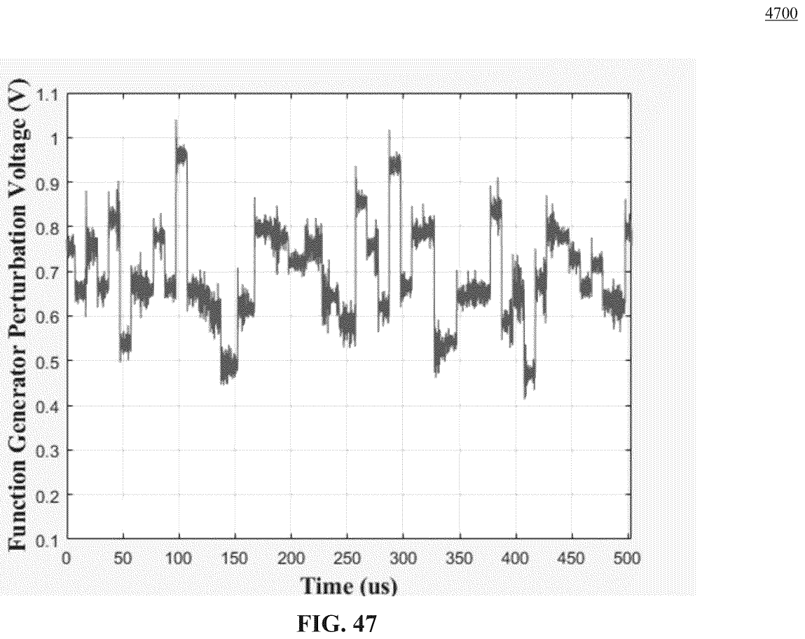

Referring to FIG. 47, a time-domain plot of the function generator perturbation voltage measured in volts as a function of time measured in microseconds is presented. The horizontal axis spans from 0 microseconds to 500 microseconds, representing a measurement window of 500 microseconds of perturbation voltage behavior during Hall effect thruster control experiments. The vertical axis ranges from approximately 0.5 volts to 1.1 volts, displaying the amplitude variations of the perturbation signal generated by the function generator.

With continued reference to FIG. 47, the perturbation voltage waveform exhibits a noisy, irregular oscillatory pattern characteristic of bandlimited noise perturbations used in Hall effect thruster system identification and control experiments. The signal fluctuates predominantly between approximately 0.6 volts and 0.9 volts throughout the measurement window. Occasional peaks in the perturbation voltage reach near 1.0 volt, while occasional troughs drop to around 0.55 volts. The mean value of the perturbation voltage appears to be centered around approximately 0.75 volts.

The bandlimited noise perturbation signal shown in FIG. 47 serves as an excitation signal for characterizing the dynamic response of the Hall effect thruster discharge plasma. The bandlimited noise contains frequency components distributed across a defined frequency band that encompasses the breathing mode oscillation frequencies of the Hall effect thruster. By applying bandlimited noise perturbations around the breathing mode frequency band, the control system may excite the discharge plasma across a range of frequencies simultaneously rather than applying single-frequency sinusoidal perturbations sequentially at individual frequencies.

As further shown in FIG. 47, the stochastic nature of the bandlimited noise perturbation signal is evident in the irregular amplitude variations visible throughout the time window. The perturbation voltage does not follow a periodic pattern but instead exhibits random-like fluctuations within the bounded amplitude range. The bounded amplitude characteristics of the bandlimited noise signal maintain the perturbation voltage within safe operating limits during Hall effect thruster control experiments. The amplitude bounds prevent excessively large voltage perturbations that could disrupt thruster operation or exceed the power handling capabilities of the voltage injection circuit components.

The bandlimited noise perturbation approach may provide advantages for system identification compared to single-frequency sinusoidal perturbations. The broadband frequency content of the bandlimited noise enables extraction of impedance characteristics and frequency response information across the entire breathing mode frequency band from a single measurement period. The simultaneous excitation of multiple frequency components reduces the time required for system identification compared to sequential application of sinusoidal perturbations at individual frequencies.

With continued reference to FIG. 47, the bandlimited noise perturbation signal may create local destructive interference that reduces the peak amplitude of discharge current oscillations in the Hall effect thruster. When the bandlimited noise perturbation contains frequency components that span the breathing mode frequency band, the perturbation may interfere with the coherent oscillation pattern of the breathing mode instability. The interference between the applied perturbation and the natural plasma oscillations may disrupt the phase coherence of the breathing mode, resulting in reduced peak amplitude of the discharge current oscillations.

The function generator perturbation voltage data shown in FIG. 47 may be used for developing neural network models of the discharge plasma dynamics. A neural network model may be trained on the input-output relationship between the bandlimited noise voltage perturbation and the resulting discharge current response to learn the frequency-dependent dynamics of the Hall effect thruster discharge plasma. The broadband frequency content of the bandlimited noise provides training data that spans the range of frequencies relevant to breathing mode oscillation control, enabling the neural network model to capture the discharge plasma behavior across the operating frequency range of the control system.

As further shown in FIG. 47, the bandlimited noise perturbation signal may be generated by a function generator in the control system architecture for the Hall effect thruster. The function generator may produce bandlimited noise output with selectable center frequency, bandwidth, and amplitude parameters. The center frequency of the bandlimited noise may be set to correspond to the breathing mode oscillation frequency of the Hall effect thruster at the operating conditions of interest. The bandwidth of the bandlimited noise may be selected to encompass the range of breathing mode frequencies that occur across the operating envelope of the Hall effect thruster. The amplitude of the bandlimited noise may be adjusted to provide sufficient excitation for system identification while maintaining safe operating conditions for the Hall effect thruster.

The bandlimited noise output from the function generator may be amplified by a power amplifier and coupled into the discharge circuit through a transformer to apply the perturbation to the Hall effect thruster discharge plasma. The discharge current response to the bandlimited noise perturbation may be measured by a current sensor and digitized by an analog-to-digital converter for processing. The measured discharge current response data may be analyzed using spectral analysis techniques to extract the impedance characteristics of the discharge plasma as a function of frequency across the bandwidth of the bandlimited noise perturbation.

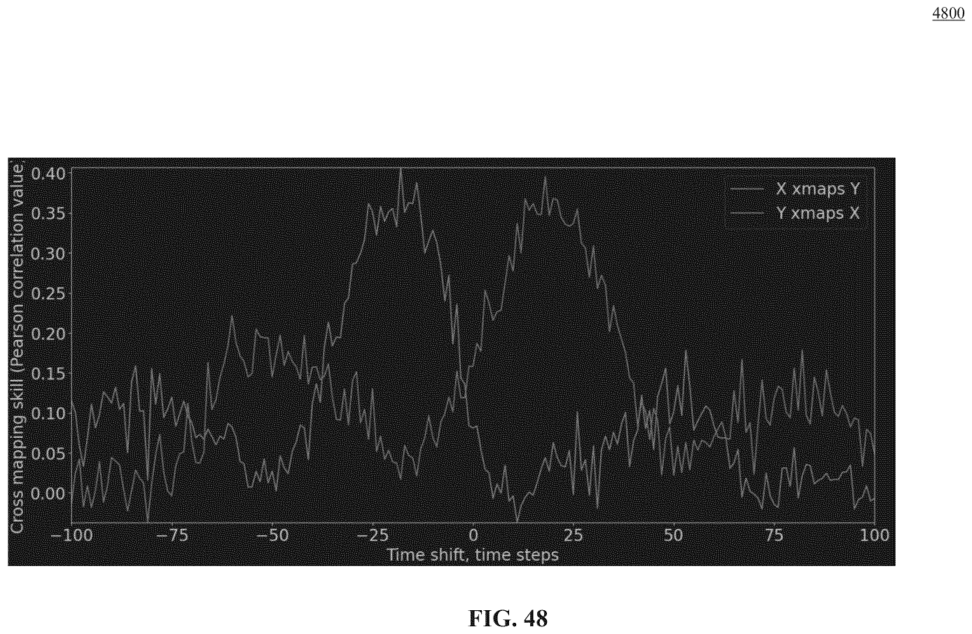

Referring to FIG. 48, a cross mapping analysis plot illustrating causal relationships between two variables X and Y in the context of Hall effect thruster discharge plasma dynamics is presented. The cross mapping analysis plot provides a method for confirming directional causality between control signals and discharge parameters in the Hall effect thruster control system. The graph displays cross mapping skill measured as Pearson correlation value on the vertical axis ranging from approximately 0.15 to 0.40. The horizontal axis displays time shift in time steps spanning from negative 100 to positive 100 time steps.

With continued reference to FIG. 48, two distinct curves are shown in the cross mapping analysis plot. An orange curve represents X cross maps Y, indicating the cross mapping analysis performed in the direction from variable X to variable Y. A blue curve represents Y cross maps X, indicating the cross mapping analysis performed in the reverse direction from variable Y to variable X. The two curves enable comparison of the causal influence between the two variables in both directions to determine which variable exerts a stronger causal effect on the other variable.

The orange curve representing X cross maps Y exhibits a prominent peak reaching approximately 0.40 correlation near a time shift of zero. The peak of the orange curve is slightly offset toward positive time shifts, indicating that variable X has a stronger causal influence on variable Y. The prominent peak in the orange curve demonstrates that the cross mapping skill achieves a maximum correlation value when the time shift aligns with the causal delay between variable X and variable Y. The height of the peak indicates the strength of the causal relationship, with higher correlation values corresponding to stronger causal influence.

As further shown in FIG. 48, the blue curve representing Y cross maps X shows lower overall correlation values compared to the orange curve. The blue curve exhibits a broader, less defined peak structure compared to the sharp peak visible in the orange curve. The lower correlation values and broader peak structure of the blue curve suggest a weaker causal relationship in the reverse direction from variable Y to variable X. The asymmetry between the two curves provides evidence of directional causality, indicating that the causal influence flows predominantly from variable X to variable Y rather than in the reverse direction.

The system may use extended convergent cross mapping designated as eCCM to confirm causal relationships between applied perturbations and discharge current response. Extended convergent cross mapping provides a method for determining correlation and causality between control signals and discharge parameters such as discharge voltage and discharge current in the Hall effect thruster system. The extended convergent cross mapping analysis examines how well the time series of one variable can be used to reconstruct the time series of another variable through cross mapping in a reconstructed state space.

With continued reference to FIG. 48, the cross mapping analysis may be applied to confirm that applied control voltage perturbations causally influence the discharge current oscillations in the Hall effect thruster discharge plasma. In the context of the Hall effect thruster control system, variable X may represent the control voltage signal applied to the discharge circuit, and variable Y may represent the discharge current measured from the Hall effect thruster. The asymmetry between the orange curve and the blue curve in FIG. 48 provides evidence that the control voltage perturbations exert a causal influence on the discharge current response, confirming that the voltage modulation applied by the control system affects the discharge plasma dynamics.

The peak location of the orange curve near zero time shift with a slight offset toward positive time shifts indicates the temporal relationship between the control voltage perturbations and the discharge current response. The positive time shift offset suggests that changes in the control voltage precede corresponding changes in the discharge current, which is consistent with the expected causal direction where voltage perturbations drive current responses in the discharge plasma. The time shift at which the peak occurs provides information about the delay between the application of a voltage perturbation and the resulting change in discharge current.

As further shown in FIG. 48, the extended convergent cross mapping analysis validates that the control system effectively influences the discharge plasma dynamics through the applied voltage perturbations. The confirmation of directional causality between the control voltage and the discharge current supports the use of voltage modulation as a control mechanism for managing breathing mode oscillations in the Hall effect thruster. The causal relationship demonstrated by the cross mapping analysis indicates that the neural network model may learn the mapping between voltage inputs and discharge current responses because a genuine causal connection exists between the control signal and the discharge plasma behavior.

The extended convergent cross mapping analysis may be performed on time series data collected during Hall effect thruster operation under various perturbation conditions. The analysis may be applied to confirm that different types of perturbation signals including sinusoidal perturbations, square wave perturbations, triangle wave perturbations, and bandlimited noise perturbations all exhibit causal influence on the discharge current response. The confirmation of causality across multiple perturbation signal types validates that the voltage injection pathway effectively couples the control signals into the discharge plasma dynamics regardless of the specific waveform characteristics of the applied perturbation.

With continued reference to FIG. 48, the Pearson correlation values displayed on the vertical axis quantify the strength of the cross mapping relationship at each time shift value. Higher Pearson correlation values indicate stronger predictive relationships between the reconstructed state space of one variable and the time series of the other variable. The peak correlation value of approximately 0.40 achieved by the orange curve indicates a moderate to strong causal relationship between variable X and variable Y. The correlation values provide a quantitative measure of the causal influence that may be compared across different operating conditions, perturbation signal types, and control configurations to evaluate the effectiveness of the voltage modulation approach for influencing discharge plasma dynamics.

The extended convergent cross mapping analysis complements other system identification techniques used in the Hall effect thruster control system. While impedance analysis characterizes the frequency-dependent relationship between voltage and current in the discharge circuit, the extended convergent cross mapping analysis confirms that the observed relationships reflect genuine causal connections rather than spurious correlations. The combination of impedance characterization and causality analysis provides a comprehensive understanding of the discharge plasma dynamics that informs the design of control algorithms for reducing breathing mode oscillations in the Hall effect thruster.

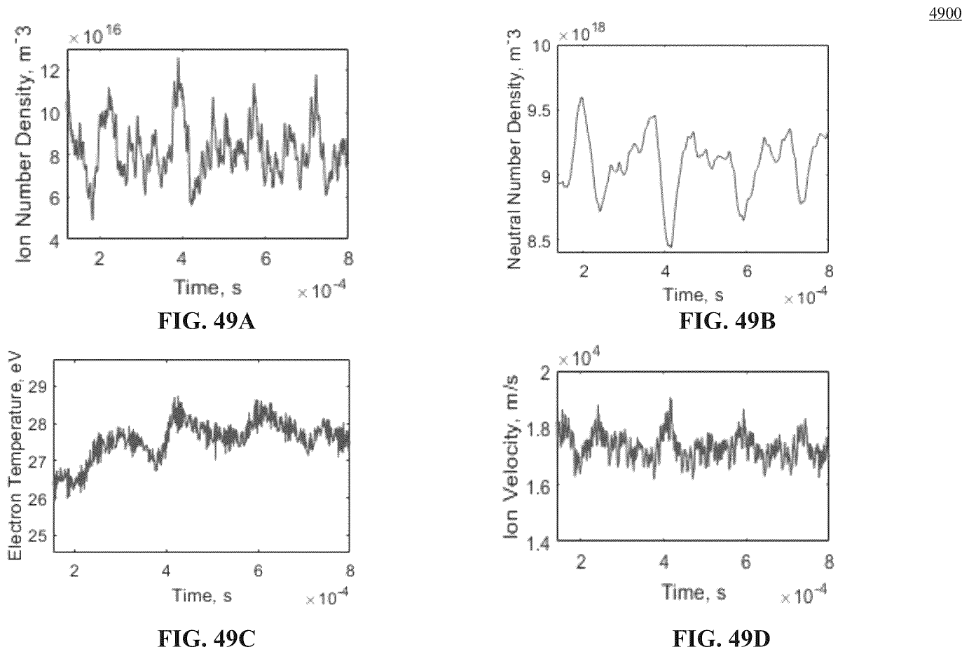

Referring to FIG. 49A, a time-series plot showing ion number density measurements as a function of time for a Hall effect thruster discharge plasma is presented. The vertical axis displays ion number density in units of meters to the negative third power, scaled by 10 to the 16th power, with values ranging approximately from 4 to 12 on the displayed scale. The horizontal axis represents time in seconds, scaled by 10 to the negative fourth power, spanning roughly from 2 to 8 on the displayed scale. The time window corresponds to approximately 200 microseconds to 800 microseconds of ion number density behavior during Hall effect thruster operation.

With continued reference to FIG. 49A, the ion number density data appears as a highly oscillatory blue trace exhibiting rapid fluctuations characteristic of plasma instabilities in Hall effect thrusters. The ion number density signal demonstrates significant amplitude variations around a mean value of approximately 8 to 9 times 10 to the 16th per cubic meter. The peak-to-peak oscillations in the ion number density reach several units on the displayed scale, indicating substantial variations in the concentration of ionized propellant atoms within the discharge channel during each breathing mode oscillation cycle.

The oscillatory behavior visible in FIG. 49A reflects the breathing mode instability that arises from predator-prey type interactions between neutrals and electrons in the discharge plasma. During the ionization phase of each breathing mode cycle, the ion number density increases as neutral propellant atoms are ionized by electron impact. Following the ionization burst, the ion number density decreases as ions are accelerated out of the discharge channel by the electric field and the neutral population is depleted. The temporal behavior of the ion number density shown in FIG. 49A illustrates the characteristic timescale of plasma oscillations in the hundreds of microseconds range, which corresponds to the breathing mode frequency in the tens of kilohertz range.

As further shown in FIG. 49A, the ion number density measurement represents one of the plasma parameters that a state estimator may estimate based on the discharge current measurement data. The ion number density may not be directly measurable during Hall effect thruster operation using conventional electrical diagnostics. A state estimator comprising an extended Kalman filter may combine predictions from a zero-dimensional ionization model with the discharge current measurement data to generate estimated ion number density values. The estimated ion number density provides insight into the internal state of the discharge plasma that informs control decisions for managing breathing mode oscillations.

Referring to FIG. 49B, a time-series plot showing neutral number density measured in cubic meters on the vertical axis, scaled by 10 to the 18th power, plotted against time in seconds on the horizontal axis, scaled by 10 to the negative fourth power, is presented. The neutral number density values range approximately from 8.5 times 10 to the 18th per cubic meter to 10 times 10 to the 18th per cubic meter. The time axis spans from approximately 2 times 10 to the negative fourth seconds to 8 times 10 to the negative fourth seconds, corresponding to a measurement window of approximately 600 microseconds.

With continued reference to FIG. 49B, the neutral number density waveform displays an oscillatory pattern characteristic of breathing mode oscillations in Hall effect thruster discharge plasmas. The neutral number density exhibits quasi-periodic fluctuations over the microsecond timescale shown in the plot. The oscillations in the neutral number density reflect the predator-prey dynamics between neutrals and electrons in the plasma discharge. During each breathing mode cycle, the neutral number density varies as ionization processes cyclically deplete and replenish the neutral population within the thruster channel.

The neutral number density oscillations shown in FIG. 49B are coupled to the ion number density oscillations shown in FIG. 49A through the ionization process. When the neutral number density is high, rapid ionization occurs as electrons collide with neutral propellant atoms and produce ion-electron pairs. The rapid ionization depletes the neutral population, causing the neutral number density to decrease. As the neutral population is depleted, the ionization rate decreases because fewer neutral atoms are available for ionization. The reduced ionization rate allows the neutral population to recover through propellant injection from the anode, and the neutral number density increases until the next ionization burst occurs.

As further shown in FIG. 49B, the irregular amplitude and frequency variations visible in the neutral number density waveform demonstrate the nonlinear time-varying nature of the Hall effect thruster discharge plasma. The neutral number density oscillations do not follow a purely sinusoidal pattern but instead exhibit complex waveform characteristics that reflect the nonlinear dynamics of the ionization and neutral replenishment processes. The nonlinear behavior of the neutral number density is captured by the zero-dimensional ionization model used in the state estimator, which includes the physics of neutral injection, ionization, and neutral convection through the discharge channel.

The neutral number density represents one of the plasma parameters that the state estimator may estimate based on the discharge current measurement data. The neutral number density affects the ionization rate and consequently influences the discharge current through the relationship between ion production and current flow in the discharge circuit. By estimating the neutral number density from the discharge current measurements, the state estimator provides information about the neutral depletion and replenishment dynamics that drive the breathing mode oscillations. The estimated neutral number density may inform control decisions by indicating when the neutral population is approaching levels that will trigger the next ionization burst in the breathing mode cycle.

Referring to FIG. 49C, a time-series plot showing electron temperature measurements in electron volts as a function of time in seconds is presented. The horizontal axis spans from approximately 2 times 10 to the negative fourth seconds to 8 times 10 to the negative fourth seconds, corresponding to a measurement window of approximately 600 microseconds. The vertical axis displays electron temperature values ranging from approximately 25 electron volts to 29 electron volts.

With continued reference to FIG. 49C, the electron temperature data trace, shown as a continuous blue line, exhibits significant temporal fluctuations characteristic of plasma oscillations in a Hall effect thruster discharge. The electron temperature oscillates around a mean value of approximately 27 electron volts. The peak-to-peak variations in the electron temperature measure roughly 3 to 4 electron volts occurring on timescales consistent with breathing mode oscillations. The rapid fluctuations in electron temperature demonstrate the dynamic nature of the electron energy distribution within the discharge plasma during Hall effect thruster operation.

The electron temperature oscillations shown in FIG. 49C are coupled to the ionization dynamics that drive the breathing mode instability. The electron temperature affects the ionization rate coefficient, which determines the rate at which neutral propellant atoms are ionized by electron impact. Higher electron temperatures correspond to higher ionization rate coefficients, enabling more rapid ionization when the neutral population is available. The electron temperature also affects the electron energy loss to the channel walls and the energy balance within the discharge plasma.

As further shown in FIG. 49C, the time-varying nature of the electron temperature data demonstrates the nonlinear time-varying characteristics of the Hall effect thruster discharge plasma. The electron temperature does not remain constant during Hall effect thruster operation but instead varies in response to the ionization dynamics, energy input from the electric field, and energy losses to the channel walls and through ionization processes. The electron temperature variations influence the discharge current through the temperature dependence of the ionization rate and the electron mobility within the discharge plasma.

The electron temperature represents one of the plasma parameters that the state estimator may estimate based on the discharge current measurement data. The electron temperature may not be directly measurable during Hall effect thruster operation using conventional electrical diagnostics without specialized plasma probes. A state estimator comprising an extended Kalman filter may combine predictions from a zero-dimensional ionization model with the discharge current measurement data to generate estimated electron temperature values. The estimated electron temperature provides insight into the energy state of the electron population that affects ionization dynamics and discharge plasma behavior.

With continued reference to FIG. 49C, the electron temperature measurement data shown in the plot may be used for validating the state estimator predictions. Experimental measurements of electron temperature obtained through plasma diagnostic techniques may be compared against the electron temperature values estimated by the extended Kalman filter to assess the accuracy of the state estimation approach. The validation of the state estimator using experimental electron temperature measurements confirms that the combination of the zero-dimensional ionization model and the Kalman filter algorithm produces accurate estimates of the plasma parameters from the discharge current measurement data.

Referring to FIG. 49D, a time-series plot showing ion velocity measurements as a function of time is presented. The vertical axis displays ion velocity in meters per second, scaled by 10 to the fourth power, with values ranging from approximately 1.4 to 2.0 times 10 to the fourth meters per second. The horizontal axis represents time in seconds, scaled by 10 to the negative fourth power, spanning from approximately 2 to 8 times 10 to the negative fourth seconds. The time window corresponds to approximately 600 microseconds of ion velocity behavior during Hall effect thruster operation.

With continued reference to FIG. 49D, the ion velocity data appears as a blue irregular waveform exhibiting rapid fluctuations characteristic of plasma oscillations in a Hall effect thruster discharge. The ion velocity oscillates around a mean value of approximately 1.7 to 1.8 times 10 to the fourth meters per second. The peak-to-peak variations in the ion velocity measure roughly 0.4 times 10 to the fourth meters per second, corresponding to approximately 4000 meters per second of velocity variation during each breathing mode oscillation cycle.

The ion velocity oscillations shown in FIG. 49D reflect the variations in ion acceleration that occur during the breathing mode instability. The ion velocity depends on the electric field strength within the discharge channel and the distance over which ions are accelerated before exiting the thruster. During the breathing mode cycle, variations in the plasma density and electron temperature affect the electric field distribution within the discharge channel, which in turn affects the ion acceleration and the resulting ion velocity at the thruster exit.

As further shown in FIG. 49D, the oscillatory nature of the ion velocity signal demonstrates that the ion exhaust velocity varies during Hall effect thruster operation rather than remaining constant. The ion velocity variations affect the thrust produced by the Hall effect thruster because thrust depends on the product of the mass flow rate and the exhaust velocity. Variations in the ion velocity during breathing mode oscillations contribute to variations in the instantaneous thrust output of the Hall effect thruster.

The ion velocity represents one of the plasma parameters that the state estimator may estimate based on the discharge current measurement data. The ion velocity affects the discharge current through the relationship between ion flux and current flow in the discharge circuit. The discharge current equals the product of the ion number density, the ion velocity, the ion charge, and the cross-sectional area of the discharge channel. By estimating the ion velocity from the discharge current measurements in combination with estimates of the ion number density, the state estimator provides information about the ion acceleration dynamics within the discharge plasma.

With continued reference to FIG. 49D, the ion velocity measurement data may be used for characterizing Hall effect thruster performance and for validating the state estimator predictions. The ion velocity directly affects the specific impulse of the Hall effect thruster, which is a measure of propellant efficiency. Higher ion velocities correspond to higher specific impulse values, indicating more efficient use of propellant for generating thrust. The estimated ion velocity values from the state estimator may be used to predict the specific impulse and thrust performance of the Hall effect thruster during operation.

The plasma parameter time-series data shown in FIG. 49A, FIG. 49B, FIG. 49C, and FIG. 49D collectively demonstrate the oscillatory behavior of the internal plasma states during Hall effect thruster operation. The ion number density, neutral number density, electron temperature, and ion velocity all exhibit fluctuations on timescales consistent with the breathing mode oscillation frequency. The coupled oscillations of the plasma parameters reflect the predator-prey dynamics and energy balance relationships that govern the breathing mode instability in the discharge plasma.

The state estimator may estimate the plasma parameters comprising ion number density, neutral number density, electron temperature, and ion velocity based on the discharge current measurement data. The extended Kalman filter combines predictions from the zero-dimensional ionization model with the discharge current measurements to generate estimates of the plasma parameters that may not be directly measurable during Hall effect thruster operation. The estimated plasma parameters provide insight into the internal state of the discharge plasma that enables physics-informed control of the breathing mode oscillations through the model predictive path control approach.

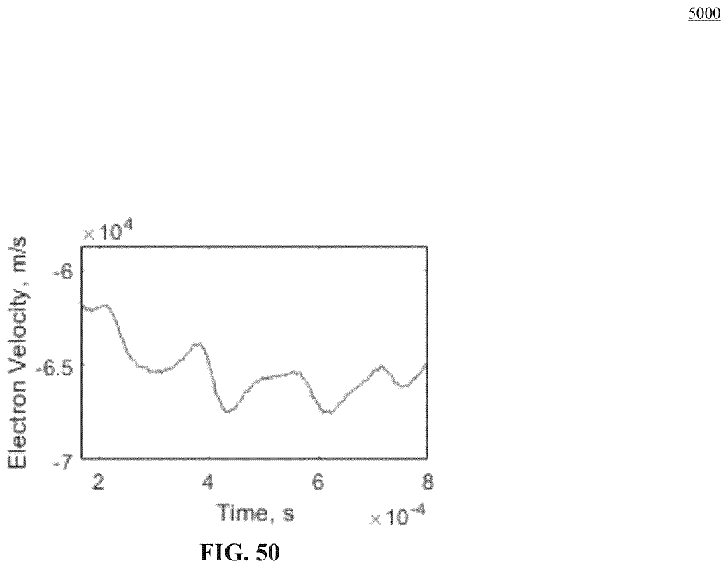

Referring to FIG. 50, a time-series plot showing electron velocity measurements as a function of time is presented. The vertical axis displays electron velocity in meters per second, scaled by 10 to the fourth power, with values ranging approximately from negative 7 to negative 6 on the displayed scale. The displayed range corresponds to electron velocities in the range of negative 60,000 meters per second to negative 70,000 meters per second. The negative sign of the electron velocity indicates that electrons flow in a direction opposite to the ion flow direction within the discharge channel of the Hall effect thruster. The horizontal axis shows time in seconds, scaled by 10 to the negative fourth power, spanning from approximately 2 to 8 on the displayed scale. The time window corresponds to approximately 200 microseconds to 800 microseconds of electron velocity behavior during Hall effect thruster operation.

With continued reference to FIG. 50, the electron velocity data appears as a continuous light blue line exhibiting oscillatory behavior with irregular fluctuations around a mean value of approximately negative 6.5 times 10 to the fourth meters per second. The mean electron velocity of approximately negative 65,000 meters per second reflects the bulk drift velocity of electrons within the discharge plasma of the Hall effect thruster. The electron velocity oscillations visible in the plot demonstrate characteristic variations that appear consistent with breathing mode oscillations typically observed in Hall effect thruster plasmas. The oscillation period appearing in the electron velocity waveform is on the order of tens to hundreds of microseconds, corresponding to breathing mode frequencies in the kilohertz range.

As further shown in FIG. 50, the electron velocity waveform exhibits irregular amplitude variations throughout the measurement window. The electron velocity fluctuates between approximately negative 60,000 meters per second and negative 70,000 meters per second during the breathing mode oscillation cycles. The peak-to-peak variations in the electron velocity measure approximately 10,000 meters per second, representing roughly 15 percent variation around the mean electron velocity value. The irregular nature of the electron velocity oscillations reflects the nonlinear time-varying dynamics of the Hall effect thruster discharge plasma.

The electron velocity oscillations shown in FIG. 50 are coupled to the other plasma parameter oscillations including ion number density, neutral number density, electron temperature, and ion velocity through the physics of the discharge plasma. The electron velocity affects the electron current flow within the discharge channel and influences the ionization rate through the electron energy distribution. During the breathing mode cycle, variations in the electric field distribution and plasma density affect the electron drift velocity, which in turn affects the electron current and the overall discharge current measured at the thruster terminals.

With continued reference to FIG. 50, the electron velocity represents one of the plasma parameters that the state estimator may estimate based on the discharge current measurement data. The electron velocity may not be directly measurable during Hall effect thruster operation using conventional electrical diagnostics without specialized plasma probes. A state estimator comprising an extended Kalman filter may combine predictions from a zero-dimensional ionization model with the discharge current measurement data to generate estimated electron velocity values. The zero-dimensional ionization model includes equations governing the electron momentum balance that relate the electron velocity to the electric field, magnetic field, and collision processes within the discharge plasma.

The estimated electron velocity provides insight into the electron dynamics within the discharge plasma that affects ionization and current flow. The electron velocity influences the Hall current that flows azimuthally within the discharge channel due to the crossed electric and magnetic fields. The Hall current magnitude depends on the electron density and the electron drift velocity in the azimuthal direction. By estimating the electron velocity from the discharge current measurements, the state estimator provides information about the electron transport processes that govern the discharge plasma behavior.

As further shown in FIG. 50, the electron velocity measurement data may be used for validating the state estimator predictions and for characterizing the electron dynamics during Hall effect thruster operation. Experimental measurements of electron velocity obtained through plasma diagnostic techniques may be compared against the electron velocity values estimated by the extended Kalman filter to assess the accuracy of the state estimation approach. The validation of the state estimator using experimental electron velocity measurements confirms that the combination of the zero-dimensional ionization model and the Kalman filter algorithm produces accurate estimates of the electron dynamics from the discharge current measurement data.

The plasma parameters comprising ion number density, neutral number density, electron temperature, ion velocity, and electron velocity may be estimated by the state estimator based on the digitized discharge current measurement data. The estimated plasma parameters provide a comprehensive characterization of the internal state of the discharge plasma that enables physics-informed control of the breathing mode oscillations. The electron velocity estimate complements the estimates of the other plasma parameters by providing information about the electron transport and current flow dynamics that affect the discharge current response to voltage perturbations applied by the control system.

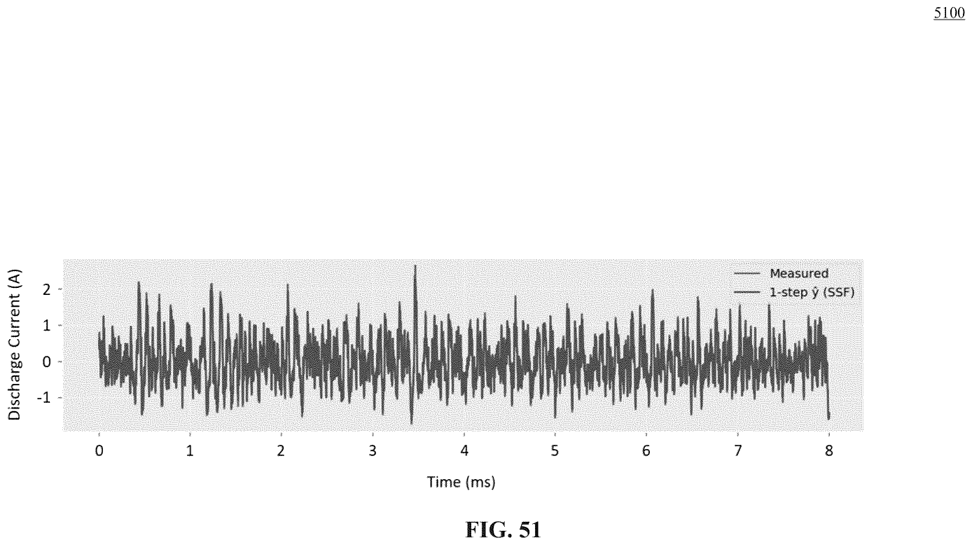

Referring to FIG. 51, a time-domain plot showing discharge current measurements and one-step ahead predictions from a state-space filter is presented. The horizontal axis represents time in milliseconds, spanning from 0 ms to approximately 8 ms. The vertical axis shows discharge current in amperes, ranging from approximately negative 1 A to positive 2 A. The plot displays two overlapping data series that demonstrate the performance of the state-space filter for predicting discharge current dynamics during Hall effect thruster operation.

With continued reference to FIG. 51, the measured discharge current is shown in blue throughout the measurement window. The measured discharge current exhibits rapid, high-frequency oscillations characteristic of breathing mode plasma instabilities in Hall effect thrusters. The measured discharge current signal demonstrates significant oscillatory behavior with peak-to-peak amplitudes reaching approximately 2 A to 3 A. The oscillations appear quasi-periodic but contain substantial variation in amplitude over the measurement window, reflecting the nonlinear time-varying nature of the discharge plasma dynamics.

The one-step ahead predictions from the state-space filter are shown in red dots overlaid on the measured discharge current trace. The state-space filter predictions closely track the measured discharge current values throughout the 8 millisecond measurement window. The close correspondence between the red prediction dots and the blue measured trace indicates effective state estimation performance by the state-space filter. The state-space filter may generate predictions of the discharge current at each time step based on the previous state estimate and the system dynamics model.

As further shown in FIG. 51, the state-space filter predictions follow the rapid oscillations of the measured discharge current with minimal lag or deviation. During periods of high-amplitude oscillations visible in the measured discharge current, the state-space filter predictions maintain accurate tracking of the oscillation peaks and troughs. During periods of lower-amplitude oscillations, the state-space filter predictions continue to match the measured discharge current behavior. The consistent tracking performance across varying oscillation amplitudes demonstrates that the state-space filter may adapt to changes in the discharge plasma dynamics during Hall effect thruster operation.

The state-space filter may comprise a Kalman filter or extended Kalman filter that combines predictions from a dynamics model with measurement data to generate improved state estimates. The one-step ahead prediction capability demonstrated in FIG. 51 enables the control system to anticipate the discharge current behavior at the next time step based on the current state estimate. The one-step ahead predictions may be used by the model predictive path control algorithm to compute control voltage outputs that account for the predicted evolution of the discharge current.

With continued reference to FIG. 51, the state estimation approach using the state-space filter enables real-time prediction of discharge current dynamics for control purposes. The state-space filter receives the digitized discharge current measurement data from the analog-to-digital converter and generates predictions of the discharge current at future time steps. The predictions from the state-space filter may inform the neural network model or the model predictive path control algorithm when computing control voltage outputs to reduce breathing mode oscillations in the Hall effect thruster discharge plasma.

The effective state estimation performance demonstrated in FIG. 51 validates the use of state-space filtering techniques for real-time control of Hall effect thruster plasma oscillations. The ability to accurately predict discharge current behavior one time step ahead enables the control system to apply anticipatory control actions that account for the expected evolution of the discharge plasma dynamics. The state-space filter predictions may be combined with the neural network model predictions to provide robust state estimation that leverages both physics-based modeling and data-driven learning approaches for managing breathing mode oscillations in the Hall effect thruster.

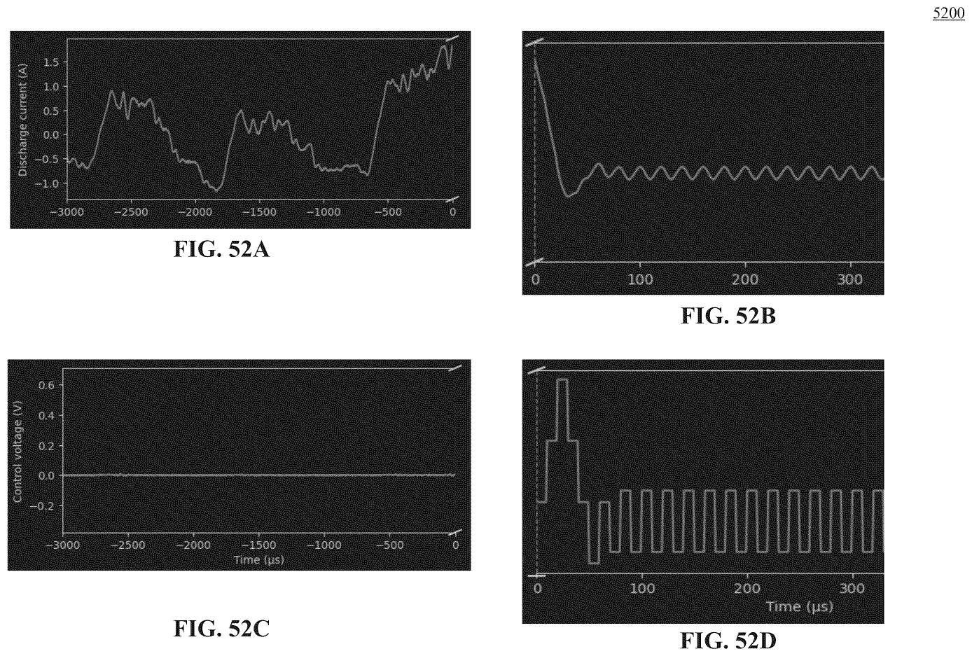

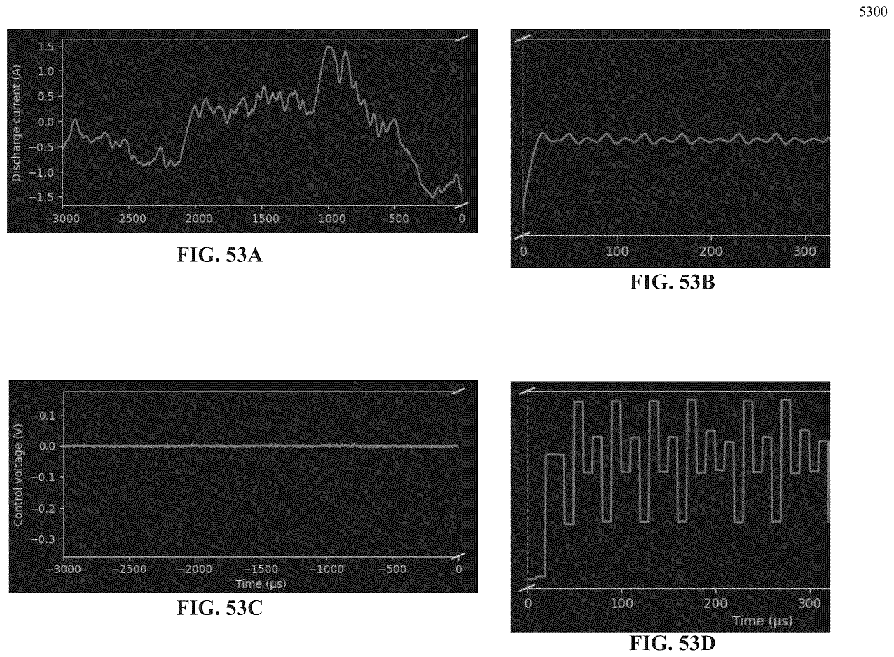

Referring to FIG. 52A, a graph displaying discharge current measured in amperes on the vertical axis against time on the horizontal axis is presented. The time values range from 0 to approximately 3000 units on the horizontal axis. The discharge current values span from approximately negative 1.5 A to positive 1.5 A, with a zero reference line clearly marked on the vertical axis. The discharge current waveform shown in light blue exhibits characteristic oscillatory behavior typical of Hall effect thruster breathing mode oscillations during operation.

With continued reference to FIG. 52A, the discharge current signal demonstrates significant amplitude variations over time. The discharge current fluctuates between positive and negative values in an irregular but quasi-periodic pattern throughout the measurement window. The oscillations show varying peak-to-peak amplitudes, with some regions displaying larger excursions from the zero reference line and other regions showing more moderate variations. The discharge current waveform captures the breathing mode instability behavior where the current oscillates around a mean value due to the predator-prey dynamics between neutrals and electrons in the discharge plasma.

As further shown in FIG. 52A, the discharge current time series data provides the measurement input for the machine learning-based control system. The discharge current measurement data may be digitized by an analog-to-digital converter and processed by a neural network model executed on a field programmable gate array to compute control voltage outputs for reducing the breathing mode oscillations. The oscillatory behavior visible in FIG. 52A represents the baseline discharge current dynamics that the control system aims to characterize and regulate through real-time voltage modulation techniques.

Referring to FIG. 52B, a time-domain plot showing the transient response of a system to a step input or initial condition is presented. The plot is displayed on a dark background with a light blue trace showing the system response. The horizontal axis represents time in arbitrary units ranging from 0 to approximately 350 units. The vertical axis displays the signal amplitude of the response waveform.

With continued reference to FIG. 52B, the waveform begins with a sharp initial spike at time zero. The initial spike rises rapidly to a peak value before experiencing a sharp decline and undershoot below the baseline level. The sharp initial transient represents the system response to the application of a step input or perturbation at the beginning of the measurement period. A vertical dashed line near the origin indicates the time of perturbation application or system excitation.

Following the initial transient visible in FIG. 52B, the signal exhibits characteristic damped oscillatory behavior. The oscillations following the initial spike gradually decrease in amplitude as the system dissipates the energy from the initial perturbation. The damping of the oscillations reflects the natural response characteristics of the Hall effect thruster discharge plasma dynamics and the associated electrical circuit components including the discharge filter and harness elements.

As further shown in FIG. 52B, after the initial transient settles, the signal transitions into a sustained periodic pattern. The oscillation amplitude remains relatively constant after the initial transient decay, demonstrating a limit cycle or sustained oscillation mode characteristic of breathing mode behavior in Hall effect thruster discharge plasmas. The sustained oscillations following the damped transient indicate that the system has reached a quasi-steady operating state where the breathing mode instability maintains periodic oscillations at a characteristic frequency.

The transient response pattern shown in FIG. 52B reveals the natural response timescales and oscillation characteristics of the Hall effect thruster discharge plasma. The initial transient duration and the damping rate provide information about the system dynamics that the model predictive path control algorithm may account for when computing control voltage trajectories for oscillation reduction and thrust optimization. The transition from damped transient behavior to sustained oscillations demonstrates how the discharge plasma settles into the breathing mode instability following a perturbation event.

Referring to FIG. 52C, a time-domain plot showing control voltage measured in volts on the vertical axis versus time measured in microseconds on the horizontal axis is presented. The time axis spans from approximately negative 3000 microseconds to 0 microseconds, representing a 3 millisecond window of data acquisition prior to a reference point at time zero. The control voltage axis ranges from approximately negative 0.2 volts to 0.6 volts.

With continued reference to FIG. 52C, the control voltage signal appears as a relatively flat trace centered near zero volts throughout the entire time window. The control voltage exhibits small amplitude fluctuations or noise throughout the measurement period. The signal maintains a consistent baseline with minor variations that appear to be on the order of tens of millivolts or less. The relatively quiescent nature of the control voltage signal in FIG. 52C may represent a baseline or reference condition before active control perturbations are applied to the Hall effect thruster discharge circuit.

As further shown in FIG. 52C, the control voltage measurement demonstrates the voltage perturbation waveform applied to the Hall effect thruster discharge plasma during operation. The control voltage signal shown in FIG. 52C may correspond to a period when minimal correction is required by the control system, or the signal may represent the control voltage during a baseline measurement period used for comparison against subsequent measurements where active control voltage perturbations are applied. The dark background with light blue trace follows the presentation style consistent with oscilloscope or data acquisition system displays used for monitoring electrical signals in Hall effect thruster control experiments.

Referring to FIG. 52D, a time-domain plot showing a discrete control voltage signal as a function of time measured in microseconds on the horizontal axis is presented. The time axis spans from 0 to approximately 350 microseconds. The waveform is displayed as a light blue trace against a dark background. A vertical dashed line near time zero marks the initiation of the control response.

With continued reference to FIG. 52D, the control voltage signal demonstrates the characteristic output of the model predictive path controller used for Hall effect thruster plasma oscillation control. The signal begins with an initial transient phase during the first approximately 75 microseconds. During the initial transient phase, the control voltage exhibits a sharp spike reaching a maximum value followed by a stepped descent with several discrete level changes. The stepped nature of the initial transient reflects the digital implementation of the control system where the field programmable gate array updates the voltage setpoint at discrete time intervals.

As further shown in FIG. 52D, after the initial transient settles, the control voltage waveform transitions into a regular square wave pattern. The square wave pattern persists from approximately 75 to 100 microseconds through the remainder of the measurement window extending to 350 microseconds. The square wave exhibits consistent duty cycle and amplitude, alternating between two discrete voltage levels at a regular frequency. The regular square wave pattern in the steady-state region demonstrates that the controller has stabilized into a periodic modulation mode for managing the discharge current oscillations.

The stepped, quantized nature of the entire control voltage waveform visible in FIG. 52D reflects the digital implementation of the control system. The field programmable gate array-based controller updates the voltage setpoint at discrete time intervals rather than continuously, producing the characteristic stepped waveform appearance. The discrete control signal represents the voltage perturbations computed by the neural network controller and applied to the Hall effect thruster discharge circuit to regulate breathing mode plasma oscillations.

With continued reference to FIG. 52D, the transition from the initial transient phase to the regular square wave pattern demonstrates the settling behavior of the control system following activation. The initial transient with the sharp spike and stepped descent represents the controller response to the initial conditions at the start of the control period. The subsequent regular square wave pattern indicates that the controller has converged to a stable periodic control strategy for modulating the discharge voltage. The square wave control signal may produce pulsed voltage perturbations that influence the breathing mode oscillations in the discharge plasma by periodically modifying the electric field within the discharge channel of the Hall effect thruster.

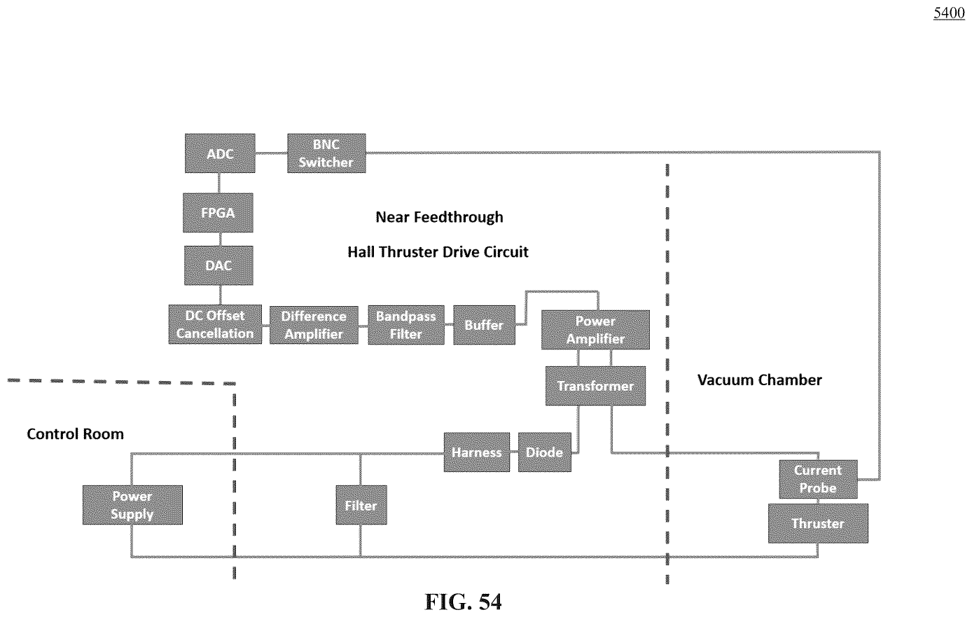

Referring to FIG. 54, a comprehensive block diagram of the Hall thruster drive circuit experimental setup is presented. The block diagram depicts the signal flow and component arrangement between a control room and a vacuum chamber for implementing real-time control of plasma oscillations in a Hall effect thruster. The experimental setup integrates digital signal processing components, analog signal conditioning components, and power delivery components to enable voltage perturbation injection into the Hall effect thruster discharge circuit while simultaneously measuring the discharge current response.

With continued reference to FIG. 54, the block diagram is divided into regions representing different physical locations in the experimental facility. A control room region contains the power supply equipment and digital control electronics. A near feedthrough region contains the signal conditioning components and isolation elements that interface between the control electronics and the vacuum chamber. A vacuum chamber region contains the Hall effect thruster and associated measurement components that operate under vacuum conditions.

In the control room region, a power supply provides electrical power to the Hall effect thruster system. The power supply delivers the discharge voltage and current for Hall effect thruster operation. The power supply connects to a filter that attenuates high-frequency noise and provides power conditioning before the electrical power is delivered to downstream components. The filter may comprise passive components including inductors and capacitors arranged to form a low-pass filter network that reduces voltage ripple and protects the power supply from discharge current oscillations generated by the Hall effect thruster load.

As further shown in FIG. 54, the near feedthrough region contains the digital signal processing chain that forms the core of the real-time control system. An analog-to-digital converter designated as ADC receives analog measurement signals from the vacuum chamber and converts the analog signals to digital form for processing by downstream digital components. The ADC is configured to digitize the discharge current measurement data at a sampling rate sufficient to capture the breathing mode oscillations that occur in the tens of kilohertz frequency range. The ADC may operate at sampling rates of 1 MSPS or greater to provide adequate temporal resolution for characterizing the discharge current dynamics.

With continued reference to FIG. 54, a field programmable gate array designated as FPGA is connected to the ADC. The FPGA is configured to execute a neural network model for real-time control of plasma oscillations in the Hall effect thruster. The FPGA receives the digitized discharge current measurement data from the ADC and computes a control voltage output based on the neural network model. The FPGA performs the machine learning computations and control algorithms that determine the voltage perturbations to be applied to the Hall effect thruster discharge circuit. The FPGA may be configured to execute the neural network model with a latency of less than one microsecond to enable multiple control voltage updates within a single breathing mode oscillation period.

A digital-to-analog converter designated as DAC is connected to the FPGA. The DAC is configured to convert the control voltage output from the FPGA to an analog control signal. The DAC receives digital control values computed by the FPGA and produces corresponding analog voltage levels that represent the desired voltage perturbations for the Hall effect thruster discharge circuit. The DAC may operate at update rates of 200 kHz or greater to support the rapid control voltage updates computed by the FPGA.

As further shown in FIG. 54, a BNC Switcher is positioned in the signal path between the DAC and the downstream signal conditioning components. The BNC Switcher provides a mechanism for selectively connecting or disconnecting the control signal path. When the BNC Switcher is in a closed position, the control signal path is connected and the control voltage output from the FPGA is applied to the Hall effect thruster discharge circuit through the signal conditioning chain. When the BNC Switcher is in an open position, the control signal path is disconnected and no control voltage perturbations are applied to the Hall effect thruster. The BNC Switcher enables rapid switching between controlled operation and uncontrolled baseline operation during experimental testing, allowing comparison of Hall effect thruster behavior with and without active control.

With continued reference to FIG. 54, the Hall Thruster Drive Circuit comprises the analog signal conditioning chain that processes the analog control signal from the DAC before the analog control signal is applied to the Hall effect thruster. The Hall Thruster Drive Circuit includes a DC Offset Cancellation block that receives the analog control signal when the BNC Switcher is in the closed position. The DC Offset Cancellation block removes any DC component from the analog control signal to prevent DC saturation of downstream transformer components. The removal of the DC component ensures that the transformer operates within the linear region of the magnetic core characteristics.

A Difference Amplifier is connected to the output of the DC Offset Cancellation block within the Hall Thruster Drive Circuit. The Difference Amplifier boosts the signal level to utilize the full input range of downstream amplification stages. The Difference Amplifier may provide voltage gain to increase the amplitude of the conditioned control signal to a level suitable for driving the power amplifier input.

As further shown in FIG. 54, a Bandpass Filter is connected to the output of the Difference Amplifier within the Hall Thruster Drive Circuit. The Bandpass Filter limits the frequency content of the analog control signal to a passband between a lower cutoff frequency and an upper cutoff frequency. The Bandpass Filter attenuates frequency components outside the passband to ensure that the injected perturbation signals fall within the operating bandwidth of the power amplification and transformer coupling stages. The passband of the Bandpass Filter may be configured to encompass the breathing mode oscillation frequency band of the Hall effect thruster.

A Buffer is connected to the output of the Bandpass Filter within the Hall Thruster Drive Circuit. The Buffer provides impedance matching between the Bandpass Filter output and the input of a Power Amplifier. The Buffer isolates the signal conditioning stages from the power amplification stage to prevent loading effects that could degrade signal quality. The Buffer may comprise an operational amplifier configured in a unity-gain voltage follower configuration to provide high input impedance and low output impedance.

With continued reference to FIG. 54, a Power Amplifier is connected to the output of the Buffer within the Hall Thruster Drive Circuit. The Power Amplifier amplifies the conditioned analog control signal to a power level sufficient to drive transformer coupling into the Hall effect thruster discharge circuit. The Power Amplifier increases the power level of the conditioned analog control signal to enable effective voltage perturbation injection into the discharge plasma. The Power Amplifier may be a switch-mode power amplifier with a bandwidth of 250 kHz to provide efficient power conversion while maintaining sufficient bandwidth to reproduce the voltage perturbation waveforms at frequencies corresponding to the breathing mode oscillation band.

A Transformer is positioned at the boundary between the near feedthrough region and the vacuum chamber region. The Transformer is configured to electrically isolate the Power Amplifier from the Hall effect thruster and to inject the amplified analog control signal in series with a discharge path of the Hall effect thruster. The Transformer provides galvanic isolation between the control electronics and the high-voltage discharge circuit of the Hall effect thruster. The electrical isolation protects the control electronics from high voltages present in the discharge circuit and prevents ground loops that could introduce noise into the measurement and control signals. The Transformer couples the amplified analog control signal from the Power Amplifier into the discharge circuit, enabling voltage perturbations to be superimposed on the discharge voltage applied to the Hall effect thruster.

As further shown in FIG. 54, within the vacuum chamber region, a Harness and Diode arrangement connects the power delivery path to the Hall effect thruster. The Harness represents the electrical cabling that carries power through the vacuum chamber to the Hall effect thruster. The Harness introduces resistance, inductance, and capacitance into the discharge circuit that affect the propagation of voltage and current signals between the power conditioning components and the Hall effect thruster. The Diode provides reverse current protection in the discharge circuit to prevent current flow in an unintended direction during transient conditions.

A Current Probe monitors the discharge current flowing to the Hall effect thruster within the vacuum chamber. The Current Probe generates the discharge current measurement data that is fed back to the ADC in the near feedthrough region for digitization and processing by the FPGA. The Current Probe may comprise a current sensor configured to measure a discharge current of the Hall effect thruster and generate discharge current measurement data. The Current Probe may have a bandwidth of 10 MHz or greater to capture the high-frequency components of the discharge current oscillations.

With continued reference to FIG. 54, a Thruster block represents the Hall effect thruster that generates the discharge plasma exhibiting breathing mode oscillations. The Hall effect thruster operates within the vacuum chamber under low-pressure conditions that approximate the space environment. The Hall effect thruster receives the discharge voltage from the power delivery path and draws discharge current that varies in response to the plasma dynamics within the discharge channel. The breathing mode oscillations in the discharge current are measured by the Current Probe and fed back to the control system for processing by the FPGA.

The experimental setup configuration depicted in FIG. 54 enables real-time model predictive path control of plasma oscillations in the Hall effect thruster by providing the signal acquisition, processing, and actuation pathways for implementing the machine learning-based control approach. The ADC digitizes the discharge current measurements at a sampling rate sufficient to capture the breathing mode oscillations. The FPGA executes the neural network model to predict discharge current dynamics and compute control voltage outputs. The DAC converts the digital control outputs to analog form. The BNC Switcher enables selective activation of the control loop for experimental comparison between controlled and uncontrolled operating conditions. The Hall Thruster Drive Circuit comprising the DC Offset Cancellation block, the Difference Amplifier, the Bandpass Filter, the Buffer, and the Power Amplifier conditions and amplifies the analog control signal for injection through the Transformer into the Hall effect thruster discharge circuit to modulate the discharge voltage and reduce the breathing mode oscillations in the discharge plasma.

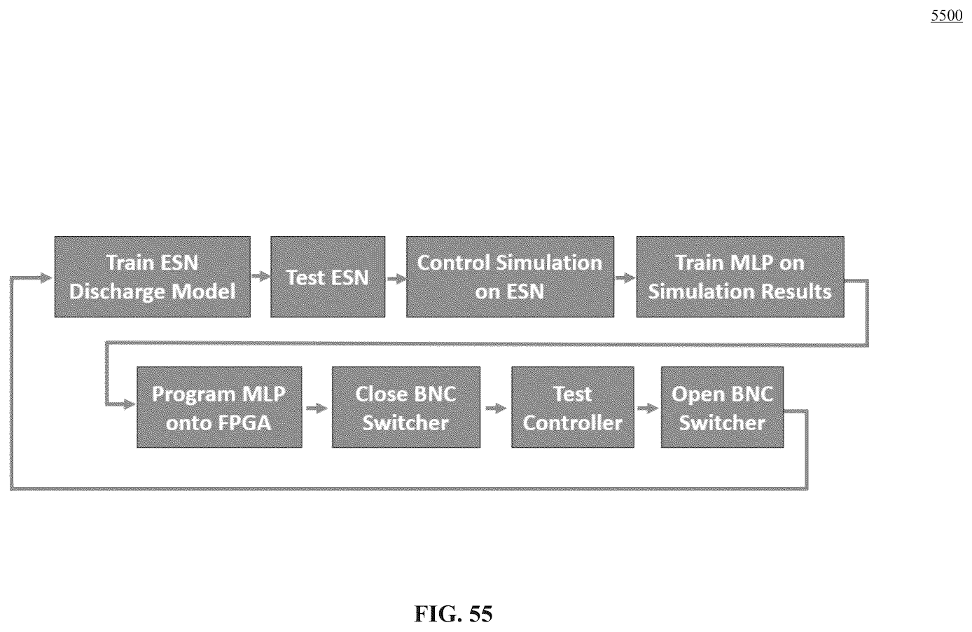

Referring to FIG. 55, a process flow diagram depicting the methodology for developing and testing a real-time machine learning controller for Hall effect thruster discharge plasma control is presented. The process flow diagram illustrates the sequential workflow from initial model training through hardware deployment and experimental validation of the machine learning-based control system. The workflow encompasses multiple stages that transform experimental discharge data into a deployable neural network controller capable of real-time operation on a field programmable gate array.

With continued reference to FIG. 55, the workflow begins with training an Echo State Network discharge model. The Echo State Network is a type of recurrent neural network that learns the dynamics of the Hall effect thruster system from experimental discharge current and discharge voltage data. The Echo State Network receives time series data comprising discharge current measurements and control voltage inputs collected during Hall effect thruster operation. The Echo State Network learns the temporal relationships between the control voltage inputs and the resulting discharge current responses by adjusting the output weights of the network based on the training data.

The neural network model may be trained using a single-step teacher-forced training approach where ground-truth data from measurements is used for predicting the next step. In the single-step teacher-forced training approach, the Echo State Network receives the actual measured discharge current values as inputs at each time step rather than using the network's own predictions from previous time steps. The use of ground-truth measurement data during training prevents error accumulation that could occur if the network were trained using its own predictions. The single-step teacher-forced training approach enables the Echo State Network to learn accurate one-step ahead predictions of the discharge current based on the current state and control voltage input.

As further shown in FIG. 55, the neural network model may be trained using k-fold validation with a Huber loss function. In k-fold validation, the training data is partitioned into k subsets or folds. The Echo State Network is trained k times, with each training iteration using a different fold as the validation set and the remaining k minus one folds as the training set. The k-fold validation approach provides a robust estimate of the model performance by evaluating the network on multiple different validation sets. The Huber loss function combines the properties of mean squared error loss and mean absolute error loss. The Huber loss function behaves like mean squared error for small errors and like mean absolute error for large errors, providing robustness to outliers in the training data while maintaining sensitivity to small prediction errors.

With continued reference to FIG. 55, following the training of the Echo State Network, the workflow proceeds to testing the Echo State Network to validate the predictive accuracy of the trained model. The testing phase evaluates the Echo State Network performance on discharge current data that was not used during training. The testing phase confirms that the Echo State Network generalizes to previously unseen data and accurately predicts the discharge current dynamics of the Hall effect thruster. The testing results may include metrics such as prediction accuracy, mean squared error, and correlation between predicted and measured discharge current values.

The validated Echo State Network model is then used in a control simulation phase. During the control simulation phase, control algorithms are applied to the Echo State Network model to generate control trajectories for reducing breathing mode oscillations in the simulated discharge plasma. A nonlinear model predictive control algorithm may be used during the control simulation phase to compute optimal voltage perturbation sequences that minimize a cost function related to the discharge current oscillation amplitude. The nonlinear model predictive control algorithm uses the Echo State Network as a predictive model to evaluate the effect of candidate control voltage sequences on the future discharge current behavior.

As further shown in FIG. 55, the control simulation phase generates control trajectories that represent the mapping between discharge current states and optimal control voltage outputs. The control trajectories produced by the nonlinear model predictive control algorithm operating on the Echo State Network model capture the control strategy that effectively reduces breathing mode oscillations in the simulated Hall effect thruster discharge plasma. The control trajectories serve as training data for the subsequent stage of the workflow.

The simulation results from the control simulation phase are subsequently used to train a multilayer perceptron neural network. The multilayer perceptron learns the mapping between system states and optimal control actions derived from the nonlinear model predictive control simulation. The multilayer perceptron receives input vectors comprising past control voltage measurements and past discharge current measurements. The multilayer perceptron produces output values representing the control voltage to be applied at the next time step. The training of the multilayer perceptron on the control trajectories from the nonlinear model predictive control simulation implements an imitation learning approach where the multilayer perceptron learns to reproduce the control behavior of the computationally intensive nonlinear model predictive control algorithm.

With continued reference to FIG. 55, once the multilayer perceptron is trained on the simulation results, the multilayer perceptron is programmed onto a field programmable gate array for real-time hardware implementation. The field programmable gate array provides the computational platform for executing the trained multilayer perceptron with the low latency required for real-time control of breathing mode oscillations in the kilohertz frequency range. The field programmable gate array may be programmed using high level synthesis libraries such as hls4ml for converting Python neural network code into field programmable gate array code. The hls4ml library translates the trained multilayer perceptron model from a Python representation into hardware description language code that may be synthesized and deployed on the field programmable gate array. The high level synthesis approach enables rapid deployment of neural network models to field programmable gate array hardware without requiring manual hardware description language coding.

As further shown in FIG. 55, the hardware testing phase follows the field programmable gate array programming. The hardware testing phase involves connecting the field programmable gate array-based controller to the Hall effect thruster system and evaluating the controller performance during actual thruster operation. The hardware testing phase begins by closing a BNC switcher to connect the controller to the Hall effect thruster system. The BNC switcher closure enables the control voltage output from the field programmable gate array to be applied to the Hall effect thruster discharge circuit through the signal conditioning chain and voltage injection circuit.

With continued reference to FIG. 55, testing of the controller is performed on the actual Hall effect thruster following the BNC switcher closure. During the testing phase, the field programmable gate array executes the trained multilayer perceptron model in real time, receiving digitized discharge current measurement data from the analog-to-digital converter and computing control voltage outputs that are converted to analog form by the digital-to-analog converter. The control voltage outputs are applied to the Hall effect thruster discharge circuit to modulate the discharge voltage and influence the breathing mode oscillations in the discharge plasma. The testing phase evaluates the effectiveness of the machine learning controller for reducing discharge current oscillation amplitude compared to uncontrolled baseline operation.

After testing is complete, the BNC switcher is opened to disconnect the controller from the Hall effect thruster system. The opening of the BNC switcher terminates the application of control voltage perturbations to the Hall effect thruster discharge circuit. The ability to open and close the BNC switcher enables rapid transitions between controlled and uncontrolled operating conditions during experimental testing, facilitating comparison of Hall effect thruster performance with and without active machine learning control.

The sequential workflow depicted in FIG. 55 represents the complete development pipeline from machine learning model training through hardware deployment and experimental validation of the real-time physics-informed machine learning control system for Hall effect thruster plasma oscillation management. The workflow integrates Echo State Network training and testing for system identification, nonlinear model predictive control simulation for generating optimal control trajectories, multilayer perceptron training for imitation learning, field programmable gate array programming using high level synthesis tools, and hardware testing with BNC switcher control for experimental validation. The workflow enables development of machine learning controllers that may be deployed on field programmable gate array hardware for real-time control of breathing mode oscillations in Hall effect thruster discharge plasmas.

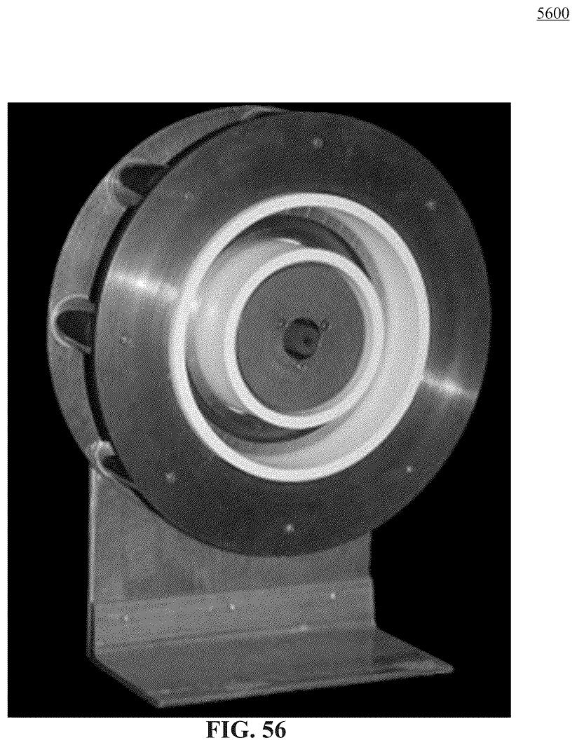

Referring to FIG. 56, a Hall effect thruster mounted on a metallic support bracket is depicted from a front-facing perspective. The Hall effect thruster exhibits a circular, disc-shaped configuration with a prominent central axis. The outer housing of the Hall effect thruster appears to be constructed of machined metal with a polished or brushed finish. Visible fasteners are arranged around the perimeter of the outer housing to secure the thruster components together.

With continued reference to FIG. 56, the central region of the Hall effect thruster displays concentric white ceramic rings that form the discharge channel characteristic of Hall effect thruster designs. The ceramic rings may be fabricated from boron nitride or a similar dielectric material. The ceramic components serve to electrically isolate the discharge chamber from the surrounding metallic structures. The ceramic components may withstand the high temperatures generated during plasma operation within the discharge channel. The discharge channel formed by the concentric ceramic rings provides the annular region where propellant ionization and ion acceleration occur during Hall effect thruster operation.

As further shown in FIG. 56, the innermost portion of the Hall effect thruster shows a dark central component that corresponds to the magnetic circuit assembly containing an inner magnetic pole. The inner magnetic pole forms part of the magnetic circuit that generates the radial magnetic field within the discharge channel. The radial magnetic field confines electrons within the discharge channel and establishes the Hall current that enables ion acceleration in the Hall effect thruster.

Around the outer circumference of the thruster body visible in FIG. 56, copper-colored elements are present that represent the magnetic coil windings used to generate the radial magnetic field. The magnetic coil windings receive electrical current from the power processing unit to produce the magnetic field configuration within the discharge channel. The magnetic coil windings may comprise an outer magnetic coil and an inner magnetic coil that together shape the magnetic field distribution to achieve the desired electron confinement and ionization characteristics. The current supplied to the magnetic coil windings may be adjusted to modify the magnetic field strength and optimize thruster performance or to control discharge plasma oscillations as described previously.

With continued reference to FIG. 56, the Hall effect thruster is mounted on an L-shaped aluminum bracket that provides structural support for the thruster during laboratory testing. The L-shaped bracket configuration is typical of laboratory test configurations used in vacuum chamber experiments where the Hall effect thruster is positioned within the vacuum facility for characterization and control experiments. The mounting bracket secures the Hall effect thruster in a fixed position relative to diagnostic equipment and measurement probes within the vacuum chamber.

The Hall effect thruster hardware configuration shown in FIG. 56 may be consistent with a 6-kW class Hall effect thruster such as the H6 thruster. The H6 thruster serves as an experimental platform for investigating real-time model predictive path control of plasma oscillations using machine learning-based system identification and state estimation techniques. The Hall effect thruster hardware receives electrical power from the power processing unit through the electrical harness and generates the discharge plasma exhibiting breathing mode oscillations that the control system aims to characterize and regulate through voltage modulation approaches.

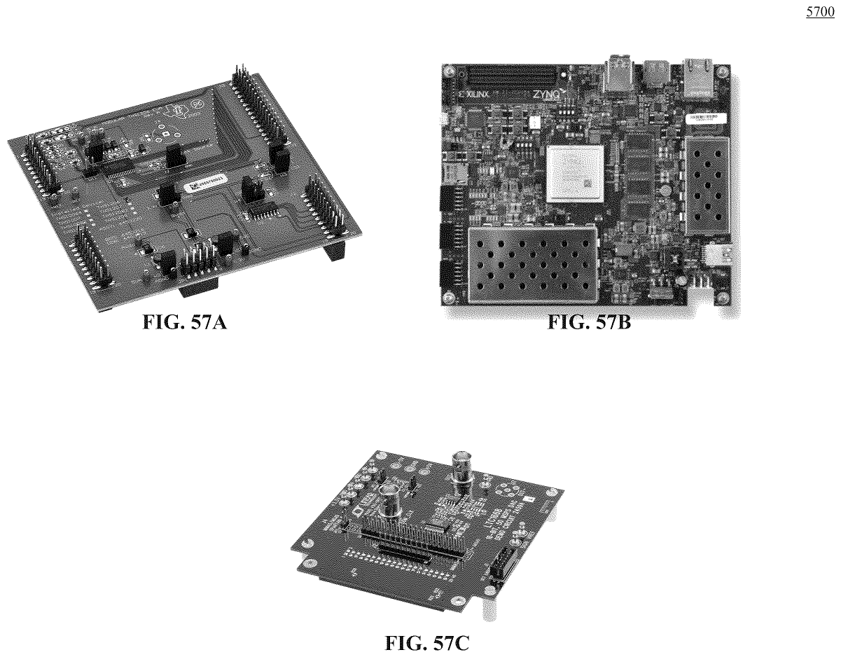

Referring to FIG. 57A, an evaluation module circuit board for an analog-to-digital converter is depicted. The evaluation module circuit board is manufactured by Texas Instruments as indicated by a TI logo visible on the circuit board. The evaluation module circuit board comprises a green printed circuit board substrate with electronic components mounted on the surface. The evaluation module circuit board is labeled as a modular THS1206 evaluation module. The THS1206 designation identifies the analog-to-digital converter integrated circuit that is installed on the evaluation module circuit board.

With continued reference to FIG. 57A, multiple rows of black pin headers are arranged along edges of the evaluation module circuit board. The pin headers provide electrical connections for interfacing the evaluation module circuit board with external systems or other evaluation boards in the control system architecture. Several integrated circuit components are mounted on the circuit board surface. Red and black jumper blocks are positioned on the evaluation module circuit board to allow configuration of various operating modes of the analog-to-digital converter. The evaluation module circuit board includes labeled sections for different functions including areas marked for installed device options listing components such as THS1206, THS1209, and other variants of the analog-to-digital converter family.

As further shown in FIG. 57A, white silkscreen text on the printed circuit board identifies various connection points and component designations. The silkscreen markings enable identification of signal connections and configuration options during integration of the evaluation module circuit board into the Hall effect thruster control system. The analog-to-digital converter may be a THS1206A ADC with a sampling rate of at least 1 MSPS. The sampling rate of at least 1 MSPS provides sufficient temporal resolution for digitizing the discharge current measurement data at rates that capture the breathing mode oscillations occurring in the tens of kilohertz frequency range. As described previously, the analog-to-digital converter is configured to digitize the discharge current measurement data generated by a current sensor that measures a discharge current of the Hall effect thruster.

Referring to FIG. 57B, a field programmable gate array development board is depicted. The field programmable gate array development board comprises a ZCU104 evaluation kit manufactured by Xilinx. The ZCU104 evaluation kit features a Xilinx Zynq UltraScale+MPSoC chip positioned at the center of the development board. The Zynq UltraScale+MPSoC chip combines programmable logic with processing system capabilities on a single integrated circuit. The combination of programmable logic and processing system capabilities enables execution of neural network computations for model predictive path control of Hall effect thruster plasma oscillations.

With continued reference to FIG. 57B, the field programmable gate array development board includes various peripheral interfaces visible around the edges of the circuit board. An FMC connector is positioned at the top of the development board for high-speed data acquisition connections. Ethernet connectivity ports are included on the development board for network communication. USB ports are provided for programming and debugging connections. Multiple other input and output connections are arranged on the development board for interfacing with the analog-to-digital converter and the digital-to-analog converter in the control loop architecture.

As further shown in FIG. 57B, a metal heatsink with ventilation holes is visible in a lower portion of the development board. The metal heatsink provides thermal management for the high-performance computing elements of the Zynq UltraScale+MPSoC chip. The thermal management enables sustained operation of the field programmable gate array during real-time control computations without thermal throttling that could affect control timing. The FPGA may be a ZCU104 FPGA board configured to execute the neural network model. As described previously, the field programmable gate array is configured to execute a neural network model that predicts discharge current dynamics based on voltage inputs. The field programmable gate array receives the digitized discharge current measurement data from the analog-to-digital converter and computes a control voltage output based on the neural network model. Processing the digitized discharge current measurement data using the neural network model executed on the field programmable gate array enables real-time prediction of discharge current dynamics for computing control voltage outputs that reduce breathing mode oscillations in the Hall effect thruster discharge plasma.

Referring to FIG. 57C, a digital-to-analog converter evaluation board is depicted. The digital-to-analog converter evaluation board is manufactured by Linear Technology, which is now part of Analog Devices, as indicated by a company logo visible on the circuit board. The digital-to-analog converter evaluation board features a dark-colored printed circuit board substrate with gold-plated connector pins arranged in rows along a bottom edge of the circuit board. The gold-plated connector pins serve as an interface for connecting the digital-to-analog converter evaluation board to other hardware such as the field programmable gate array development board.

With continued reference to FIG. 57C, two BNC connectors are visible at a top portion of the digital-to-analog converter evaluation board. The BNC connectors provide analog signal output connections for delivering the control voltage signal to downstream signal conditioning components in the Hall effect thruster drive circuit. The digital-to-analog converter evaluation board includes various surface-mount electronic components including integrated circuits, capacitors, and resistors distributed across the printed circuit board. A high-density connector is visible on a side of the digital-to-analog converter evaluation board for digital data interface connections that receive control voltage values from the field programmable gate array.

As further shown in FIG. 57C, the digital-to-analog converter evaluation board may be a DC2459A DAC. The digital-to-analog converter may have an output rate of 200 kHz. The output rate of 200 kHz enables the digital-to-analog converter to produce control voltage updates at intervals of 5 microseconds, which supports approximately 17 to 20 control voltage updates within each 100 microsecond breathing mode oscillation period. As described previously, the digital-to-analog converter is configured to convert the control voltage output from the field programmable gate array to an analog control signal. Converting the control voltage output to an analog control signal using the digital-to-analog converter enables the digital control values computed by the neural network model on the field programmable gate array to be applied to the Hall effect thruster discharge circuit through the voltage injection circuit for modulating the discharge voltage and reducing the breathing mode oscillations in the discharge plasma.

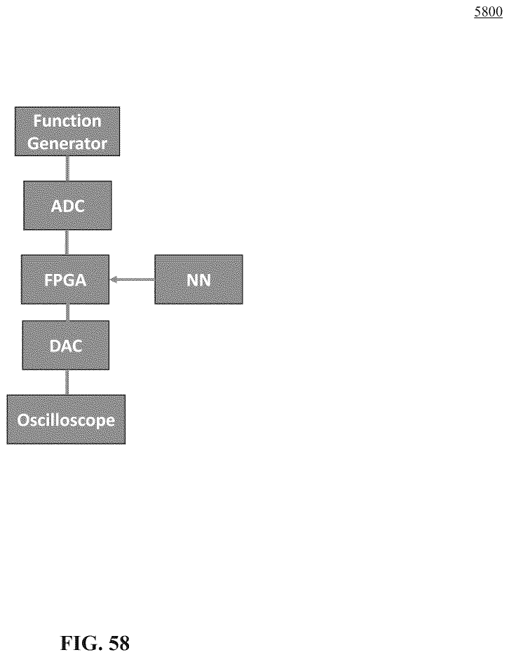

Referring to FIG. 58, a block diagram illustrating a signal processing and control system architecture used for testing and validating the neural network controller is presented. The block diagram depicts the signal flow and component arrangement for evaluating the performance of the neural network model before deployment in the Hall effect thruster control system. The signal processing and control system architecture enables verification that the trained neural network produces appropriate control outputs in response to input signals that simulate discharge current measurement data.

With continued reference to FIG. 58, a Function Generator is positioned at the top of the block diagram. The Function Generator produces test signals that simulate the discharge current waveforms observed during Hall effect thruster operation. The Function Generator may generate sinusoidal waveforms, square waveforms, triangle waveforms, or bandlimited noise waveforms that replicate the characteristics of breathing mode oscillations in the discharge plasma. The test signals from the Function Generator enable evaluation of the neural network controller response to various input conditions without requiring operation of an actual Hall effect thruster.

The test signals from the Function Generator flow downward through an Analog-to-Digital Converter designated as ADC in the block diagram. The Analog-to-Digital Converter receives the analog test signals from the Function Generator and converts the analog test signals into digital form suitable for processing by downstream digital components. The Analog-to-Digital Converter digitizes the test signals at a sampling rate sufficient to capture the frequency content of the simulated breathing mode oscillations. The digitization process produces discrete digital samples that represent the amplitude of the test signal at successive time instants.

As further shown in FIG. 58, a Field Programmable Gate Array designated as FPGA is connected to the Analog-to-Digital Converter. The Field Programmable Gate Array serves as the central processing element in the signal processing and control system architecture. The Field Programmable Gate Array receives the digitized test signals from the Analog-to-Digital Converter and processes the digitized test signals using the neural network model programmed onto the Field Programmable Gate Array hardware. The Field Programmable Gate Array executes the neural network computations that transform the input test signals into control voltage outputs.

With continued reference to FIG. 58, a Neural Network block designated as NN is shown connected to the Field Programmable Gate Array. The Neural Network block indicates that machine learning-based computations inform the control decisions made by the Field Programmable Gate Array. The Neural Network block receives input from the digitized test signals and produces output values that represent the control voltage to be applied for managing plasma oscillations. The Neural Network block may comprise a multilayer perceptron trained on control trajectories generated by nonlinear model predictive control simulation as described previously. The connection between the Neural Network block and the Field Programmable Gate Array indicates that the neural network model is implemented within the programmable logic of the Field Programmable Gate Array for real-time execution.

As further shown in FIG. 58, the configuration of the Field Programmable Gate Array with the Neural Network input enables the system to implement physics-informed machine learning control algorithms for predicting and controlling discharge current oscillations. The Field Programmable Gate Array processes the digitized test signals through the neural network model to compute control voltage outputs based on the learned relationships between discharge current states and effective control actions. The neural network model execution on the Field Programmable Gate Array may achieve latencies of less than one microsecond, enabling rapid computation of control outputs that would support multiple control voltage updates within each breathing mode oscillation period during actual Hall effect thruster operation.

The processed digital signals from the Field Programmable Gate Array are converted back to analog form through a Digital-to-Analog Converter designated as DAC in the block diagram. The Digital-to-Analog Converter receives the digital control voltage values computed by the Field Programmable Gate Array and produces corresponding analog voltage levels. The Digital-to-Analog Converter outputs the analog control signal that represents the voltage perturbation computed by the neural network controller in response to the input test signal from the Function Generator.

With continued reference to FIG. 58, an Oscilloscope is positioned at the bottom of the block diagram. The Oscilloscope receives the analog control signal output from the Digital-to-Analog Converter for signal visualization and measurement. The Oscilloscope captures the resulting output waveforms produced by the neural network controller in response to the test signals from the Function Generator. The Oscilloscope enables analysis of the control performance by displaying the temporal characteristics of the control voltage output including amplitude, frequency content, and timing relationships relative to the input test signals.

As further shown in FIG. 58, the signal processing and control system architecture provides a test configuration for validating the neural network controller before deployment on the Hall effect thruster system. The Function Generator simulates input conditions that the neural network controller would encounter during actual Hall effect thruster operation. The Analog-to-Digital Converter digitizes the simulated inputs for processing by the Field Programmable Gate Array. The Field Programmable Gate Array executes the trained neural network model to compute control outputs. The Digital-to-Analog Converter converts the digital control outputs to analog form. The Oscilloscope captures the resulting control waveforms for analysis and verification.

The test configuration depicted in FIG. 58 enables verification that the neural network controller produces appropriate control voltage outputs in response to input waveforms that simulate breathing mode oscillations. The Function Generator may be programmed to produce test signals with varying amplitudes, frequencies, and waveform shapes to evaluate the neural network controller response across a range of operating conditions. The Oscilloscope measurements may be compared against expected control outputs to confirm that the neural network model has been correctly implemented on the Field Programmable Gate Array and produces control actions consistent with the training data from the nonlinear model predictive control simulation.

With continued reference to FIG. 58, the signal processing and control system architecture may be used to characterize the timing performance of the neural network controller implementation. The Oscilloscope may measure the latency between changes in the input test signal from the Function Generator and corresponding changes in the control voltage output from the Digital-to-Analog Converter. The latency measurement confirms that the Field Programmable Gate Array executes the neural network model within the timing constraints required for real-time control of breathing mode oscillations. The timing characterization validates that the neural network controller may produce control voltage updates at rates sufficient to achieve multiple updates within each breathing mode oscillation period of the Hall effect thruster.

The hardware configuration shown in FIG. 58 represents an intermediate testing stage in the development workflow for the machine learning-based control system. Following successful validation using the Function Generator and Oscilloscope test configuration, the Field Programmable Gate Array with the programmed neural network model may be integrated into the complete Hall effect thruster control system for experimental testing on the actual thruster. The validation testing using the signal processing and control system architecture depicted in FIG. 58 reduces the risk of controller malfunction during Hall effect thruster operation by confirming correct neural network implementation and appropriate control behavior before connecting the controller to the thruster discharge circuit.

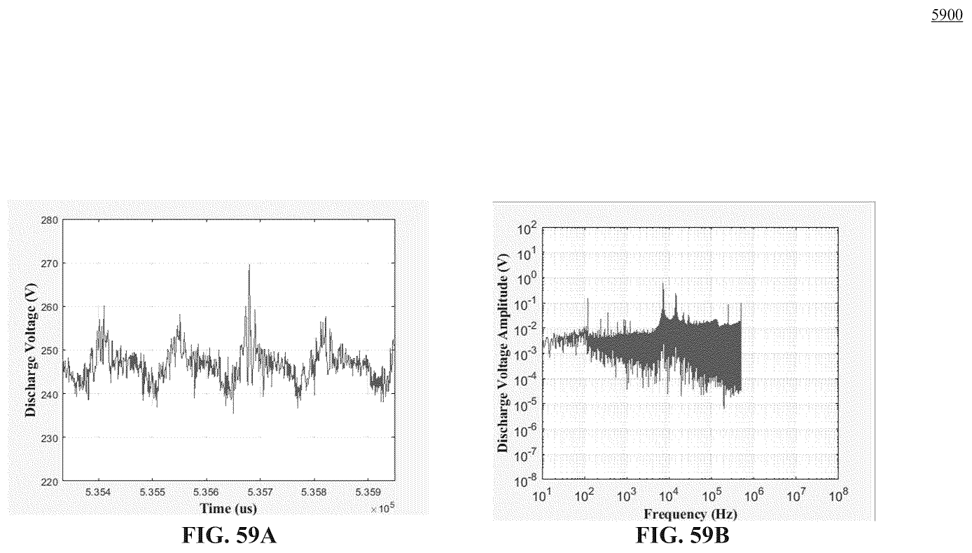

Referring to FIG. 59A, a time-domain plot showing discharge voltage oscillations measured in volts on the vertical axis against time measured in microseconds on the horizontal axis is presented. The vertical axis spans from 220 V to 280 V, displaying the range of discharge voltage variations during Hall effect thruster operation. The horizontal axis ranges from approximately 5.354×10⁵ microseconds to 5.359×10⁵ microseconds, representing a measurement window of roughly 500 microseconds of discharge voltage behavior.

With continued reference to FIG. 59A, the discharge voltage signal is displayed as a blue waveform that fluctuates predominantly between approximately 240 V and 255 V. The mean value of the discharge voltage appears to be centered around 245 V to 248 V throughout the measurement window. The discharge voltage waveform exhibits quasi-periodic oscillatory behavior characteristic of breathing mode oscillations in Hall effect thruster discharge plasmas. The oscillations show a complex structure with varying peak amplitudes and frequencies, indicating the nonlinear time-varying nature of the Hall effect thruster discharge plasma load.

As further shown in FIG. 59A, several notable voltage spikes are visible throughout the time window. A prominent peak reaching approximately 270 V appears near the 5.357×10⁵ microsecond mark, representing the maximum voltage excursion in the displayed data. Additional peaks reaching approximately 260 V are visible at several other time points within the measurement window. The peak-to-peak voltage variation of approximately 30 V around the mean represents roughly 12 percent fluctuation from the nominal discharge voltage value.

The irregular amplitude variations visible in the discharge voltage waveform of FIG. 59A demonstrate the plasma instabilities that the machine learning-based model predictive path control system may characterize and regulate through real-time voltage modulation techniques. The discharge voltage oscillations shown in FIG. 59A accompany the discharge current oscillations that occur during breathing mode instability in the Hall effect thruster discharge plasma. The voltage oscillation data provides measurement input for characterizing the impedance of the discharge plasma and for developing control strategies that modulate the discharge voltage to influence the breathing mode oscillations.

Referring to FIG. 59B, a frequency spectrum plot showing the discharge voltage amplitude as a function of frequency for a Hall effect thruster system is presented. The vertical axis displays the discharge voltage amplitude measured in volts on a logarithmic scale ranging from 10⁻⁸ V to 10² V. The horizontal axis shows frequency in Hertz on a logarithmic scale spanning from 10¹ Hz to 10⁸ Hz. The frequency spectrum reveals characteristic oscillation behavior of the Hall effect thruster discharge plasma across the measured frequency range.

With continued reference to FIG. 59B, at lower frequencies below approximately 10² Hz, the discharge voltage amplitude remains relatively stable around 10⁻³ V with some fluctuation. The spectral content increases through the 10² Hz to 10³ Hz range, with amplitudes rising to the 10⁻² V level with notable variability. A prominent peak structure emerges in the frequency range between approximately 10⁴ Hz and 10⁵ Hz. The prominent peak structure corresponds to the breathing mode oscillation frequency band characteristic of Hall effect thruster operation.

As further shown in FIG. 59B, several sharp spikes within the breathing mode frequency band reach maximum amplitude values approaching 10⁰ V, with the most intense peaks occurring near 10⁴ Hz. The breathing mode peak represents the dominant plasma instability arising from predator-prey interactions between neutrals and electrons in the discharge plasma. The frequency spectrum shows dense oscillatory content throughout the 10⁴ Hz to 10⁶ Hz range, maintaining elevated amplitudes around 10⁻² V to 10⁻¹ V before exhibiting a sharp roll-off near 10⁶ Hz where the signal drops to the noise floor.

The frequency domain representation in FIG. 59B may be used for characterizing the spectral content of discharge voltage oscillations and for identifying the dominant oscillation modes in the Hall effect thruster discharge plasma. The breathing mode peak visible in the 10⁴ Hz to 10⁵ Hz frequency range indicates the frequency band where active voltage control may effectively influence the discharge plasma dynamics. A control system may be configured to apply voltage perturbations at frequencies corresponding to the breathing mode peak identified in FIG. 59B to reduce the amplitude of discharge voltage oscillations and the associated discharge current oscillations in the Hall effect thruster. The frequency spectrum data informs the design of control algorithms for the model predictive path control approach by identifying the frequency characteristics of the plasma oscillations that the control system aims to suppress through real-time voltage modulation.

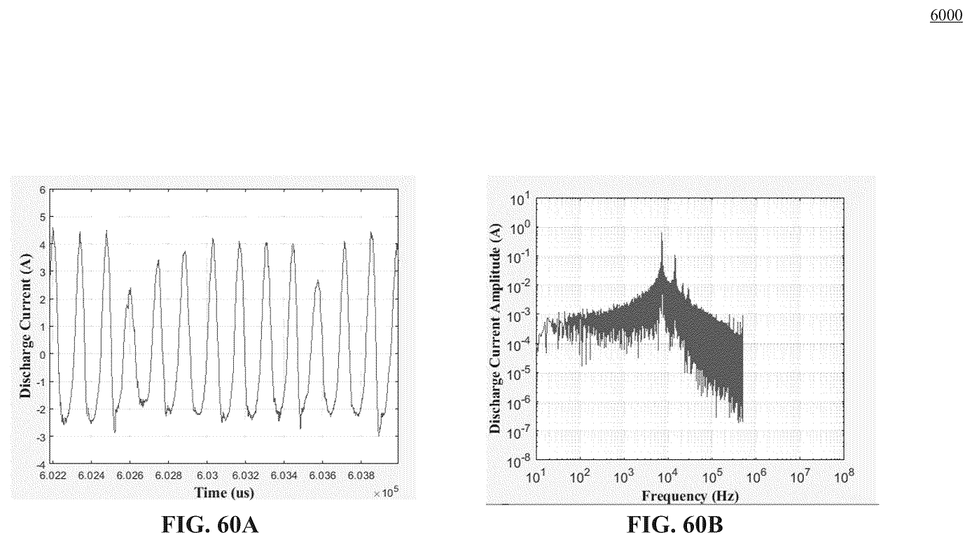

Referring to FIG. 60A, a time-domain plot showing discharge current oscillations measured in amperes on the vertical axis against time measured in microseconds on the horizontal axis is presented. The vertical axis ranges from approximately negative 4 A to positive 6 A, displaying the full range of discharge current variations during Hall effect thruster operation. The horizontal axis spans from approximately 6.022×10⁵ microseconds to 6.039×10⁵ microseconds, representing a measurement window of roughly 1,700 microseconds or 1.7 milliseconds of discharge current behavior.

With continued reference to FIG. 60A, the discharge current waveform exhibits quasi-periodic oscillatory behavior characteristic of breathing mode oscillations in Hall effect thruster discharge plasmas. The discharge current oscillates between minimum values of approximately negative 2.5 A to negative 3 A and maximum peak values reaching approximately 4 A to 4.5 A. The peak-to-peak amplitudes of the discharge current oscillations measure roughly 6 A to 7 A across the measurement window. Approximately 10 to 11 complete oscillation cycles are visible within the displayed time window, corresponding to a breathing mode frequency in the range of 6 kHz to 7 kHz.

As further shown in FIG. 60A, the discharge current waveform shape is notably asymmetric. The waveform displays sharp rising edges leading to the peak current values followed by more gradual descents to the minimum values. The asymmetric waveform creates a characteristic sawtooth-like pattern throughout the measurement window. The sharp rising edges correspond to rapid ionization events occurring within the discharge plasma when the neutral propellant population reaches sufficient density to support intense ionization by electron impact. The more gradual falling phases correspond to the depletion of the neutral population following the ionization burst and the subsequent reduction in discharge current as fewer ions are produced and accelerated through the discharge channel.

The sawtooth-like pattern visible in FIG. 60A reflects the predator-prey dynamics between neutrals and electrons in the Hall effect thruster discharge plasma. During each breathing mode cycle, the neutral population accumulates through propellant injection from the anode until the neutral density reaches a threshold that triggers rapid ionization. The rapid ionization event produces a surge of ions that are accelerated through the discharge channel, causing the sharp rise in discharge current visible as the steep leading edge of each sawtooth cycle. Following the ionization burst, the neutral population is depleted and the ionization rate decreases, resulting in the gradual decline in discharge current visible as the trailing edge of each sawtooth cycle.

With continued reference to FIG. 60A, some oscillation cycles show variations in peak amplitude throughout the measurement window. Occasional reduced peaks around 2.5 A to 3 A are interspersed among the higher amplitude oscillations reaching 4 A to 4.5 A. The amplitude variations indicate cycle-to-cycle variability in the ionization dynamics and neutral replenishment processes within the discharge plasma. The variability in peak amplitudes demonstrates the nonlinear time-varying nature of the Hall effect thruster discharge plasma that the machine learning-based control system may characterize and regulate through real-time voltage modulation techniques.

The discharge current oscillation pattern shown in FIG. 60A represents the type of breathing mode behavior that the real-time model predictive path control system aims to reduce through machine learning-based voltage modulation. The asymmetric sawtooth-like waveform provides characteristic features that the neural network model may learn to recognize and predict based on the discharge current measurement data. The control system may apply voltage perturbations timed to influence the ionization dynamics and reduce the amplitude of the discharge current oscillations by modifying the electric field within the discharge channel during the breathing mode cycle.

Referring to FIG. 60B, a frequency spectrum plot showing the discharge current amplitude as a function of frequency for a Hall effect thruster system is presented. The vertical axis displays the discharge current amplitude measured in amperes on a logarithmic scale ranging from 10⁻⁸ A to 10¹ A. The horizontal axis shows frequency in Hertz on a logarithmic scale spanning from 10¹ Hz to 10⁸ Hz. The frequency spectrum reveals characteristic oscillation behavior of the Hall effect thruster discharge plasma across the measured frequency range.

With continued reference to FIG. 60B, at lower frequencies below approximately 10³ Hz, the discharge current amplitude fluctuates in the range of 10⁻⁴ A to 10⁻³ A with notable variability. The spectral content increases as frequency approaches the 10⁴ Hz range, where a prominent peak structure emerges in the frequency spectrum. The dominant peak reaches maximum amplitude values approaching 10⁰ A in the frequency range between approximately 10⁴ Hz and 2×10⁴ Hz. The dominant peak corresponds to the breathing mode oscillation frequency band characteristic of Hall effect thruster operation.

As further shown in FIG. 60B, the breathing mode peak represents the dominant plasma instability arising from predator-prey interactions between neutrals and electrons in the discharge plasma. The peak amplitude approaching 10⁰ A indicates that the discharge current oscillations at the breathing mode frequency have amplitudes on the order of 0.5 A to 1 A when measured in the frequency domain. The breathing mode frequency band visible in FIG. 60B corresponds to the oscillation frequency observed in the time-domain waveform of FIG. 60A, where approximately 10 to 11 oscillation cycles occur within the 1.7 millisecond measurement window.

Beyond the breathing mode peak visible in FIG. 60B, the discharge current amplitude decreases progressively with increasing frequency. The amplitude follows a general roll-off pattern extending toward 10⁶ Hz. The discharge current amplitude drops to approximately 10⁻⁴ A by 10⁵ Hz and continues decreasing to approximately 10⁻⁵ A to 10⁻⁶ A in the 10⁶ Hz range before the signal drops to the noise floor. The dense spectral content visible throughout the measurement range reflects the complex nonlinear time-varying nature of the discharge plasma dynamics.

The frequency domain representation in FIG. 60B may be used for characterizing the Hall effect thruster discharge current oscillations and for identifying the dominant breathing mode frequency. The breathing mode peak location in the 10⁴ Hz to 2×10⁴ Hz frequency range indicates the frequency band where active voltage control may effectively suppress discharge current oscillations. A control system may be configured to apply voltage perturbations at frequencies corresponding to the breathing mode peak identified in FIG. 60B to influence the discharge plasma dynamics and reduce the amplitude of discharge current oscillations in the Hall effect thruster. The frequency spectrum data informs the design of control algorithms such as the model predictive path controller by identifying the frequency characteristics of the plasma oscillations that the control system aims to suppress through real-time voltage modulation.

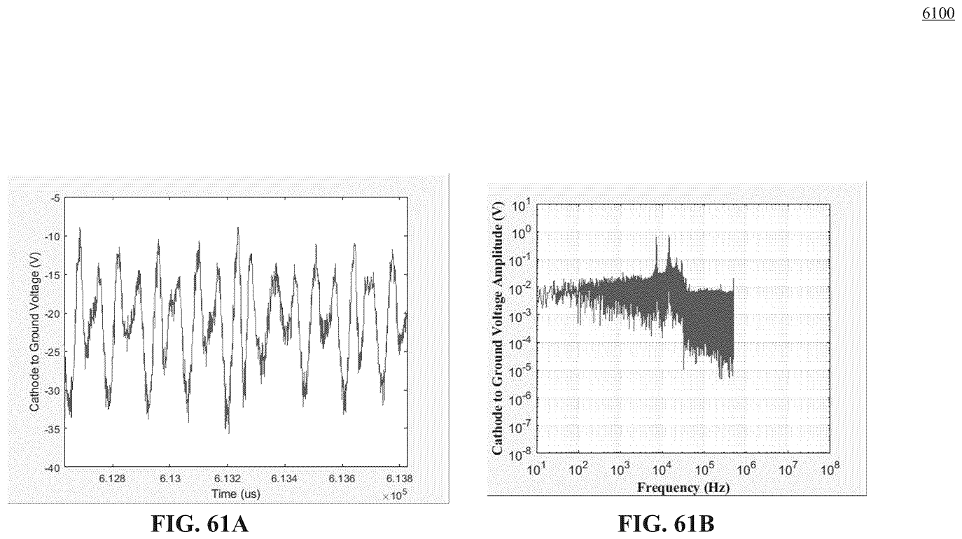

Referring to FIG. 61A, a time-domain plot showing cathode to ground voltage measurements as a function of time for a Hall effect thruster discharge plasma is presented. The vertical axis displays the cathode to ground voltage in volts, ranging from approximately negative 40 volts to negative 5 volts. The horizontal axis shows time in microseconds, scaled by a factor of 10 to the fifth power, spanning from approximately 6.127 to 6.138 times 10 to the fifth microseconds. The time window corresponds to approximately 1,100 microseconds of cathode to ground voltage behavior during Hall effect thruster operation.

With continued reference to FIG. 61A, the cathode to ground voltage waveform exhibits highly oscillatory behavior characteristic of breathing mode oscillations in Hall effect thruster plasmas. The cathode to ground voltage fluctuates in a quasi-periodic manner between roughly negative 35 volts and negative 8 volts throughout the measurement window. The peak-to-peak voltage variation of approximately 27 volts demonstrates substantial oscillations in the cathode potential relative to facility ground during Hall effect thruster operation.

The oscillation pattern visible in FIG. 61A shows a dominant frequency component with superimposed higher frequency variations, creating a complex waveform structure. The cathode to ground voltage signal demonstrates approximately 8 to 10 complete oscillation cycles within the displayed time window. The number of oscillation cycles corresponds to a breathing mode frequency in the kilohertz range, consistent with the breathing mode oscillation frequencies observed in the discharge voltage and discharge current measurements described previously.

As further shown in FIG. 61A, the cathode to ground voltage measurement provides diagnostic information about the plasma discharge dynamics and the coupling between the cathode potential and the discharge plasma oscillations. The cathode serves as the electron source for the Hall effect thruster, providing electrons for ionization within the discharge channel and for neutralization of the ion beam exiting the thruster. The cathode potential relative to ground varies during Hall effect thruster operation in response to changes in the plasma conditions and electron emission characteristics.

The time-varying nature of the cathode to ground voltage signal demonstrates the plasma instabilities that the machine learning-based model predictive path control system may characterize and monitor through real-time measurements. The cathode to ground voltage measurement may serve as one of several diagnostic signals that provide information about the operating state of the Hall effect thruster discharge plasma. The cathode to ground voltage oscillations correlate with the discharge current oscillations and discharge voltage oscillations that occur during breathing mode instability, providing complementary information about the plasma dynamics within the Hall effect thruster.

Referring to FIG. 61B, a frequency spectrum plot showing the cathode to ground voltage amplitude as a function of frequency for a Hall effect thruster system is presented. The vertical axis displays the cathode to ground voltage amplitude measured in volts on a logarithmic scale ranging from 10⁻⁸ V to 10¹ V. The horizontal axis shows frequency in Hertz on a logarithmic scale spanning from 10¹ Hz to 10⁸ Hz. The frequency spectrum reveals characteristic oscillation behavior of the Hall effect thruster cathode potential relative to ground across the measured frequency range.

With continued reference to FIG. 61B, at lower frequencies below approximately 10³ Hz, the cathode to ground voltage amplitude fluctuates in the range of 10⁻³ V to 10⁻² V with notable variability. The spectral content increases as frequency approaches the 10⁴ Hz range, where a prominent peak structure emerges in the frequency spectrum. The dominant peak reaches maximum amplitude values approaching 10⁰ V in the frequency range between approximately 10⁴ Hz and 2×10⁴ Hz. The dominant peak corresponds to the breathing mode oscillation frequency band characteristic of Hall effect thruster operation.

As further shown in FIG. 61B, the breathing mode peak in the cathode to ground voltage spectrum represents the dominant plasma instability arising from predator-prey interactions between neutrals and electrons in the discharge plasma, as manifested in the cathode potential. The cathode potential oscillates at the breathing mode frequency because the electron emission and plasma coupling conditions at the cathode vary in response to the ionization dynamics within the discharge channel. During periods of high ionization rate, the plasma density increases and affects the potential distribution between the cathode and the discharge plasma, causing corresponding variations in the cathode to ground voltage.

Beyond the breathing mode peak visible in FIG. 61B, the cathode to ground voltage amplitude decreases progressively with increasing frequency. The amplitude follows a general roll-off pattern that extends toward 10⁶ Hz. The dense spectral content visible throughout the measurement range reflects the complex nonlinear time-varying nature of the discharge plasma dynamics and the influence of the plasma oscillations on the cathode potential.

The frequency domain representation of cathode to ground voltage shown in FIG. 61B complements the time-domain measurement shown in FIG. 61A by providing spectral characterization of the oscillatory behavior. The breathing mode peak location in the 10⁴ Hz to 2×10⁴ Hz frequency range corresponds to the oscillation frequency observed in the time-domain waveform, confirming that the cathode to ground voltage oscillations occur at the same frequency as the discharge current and discharge voltage oscillations associated with the breathing mode instability.

The cathode to ground voltage measurements shown in FIG. 61A and FIG. 61B may be used for state estimation and control system design in the model predictive path control approach. The cathode to ground voltage provides an additional measurement signal that characterizes the operating state of the Hall effect thruster discharge plasma. The correlation between the cathode to ground voltage oscillations and the discharge current oscillations may be exploited by the state estimator to improve estimates of the plasma parameters based on multiple measurement inputs. The cathode to ground voltage measurement may complement the discharge current measurement data for developing machine learning-based control strategies that account for the coupled dynamics between the cathode, the discharge plasma, and the power processing unit components.

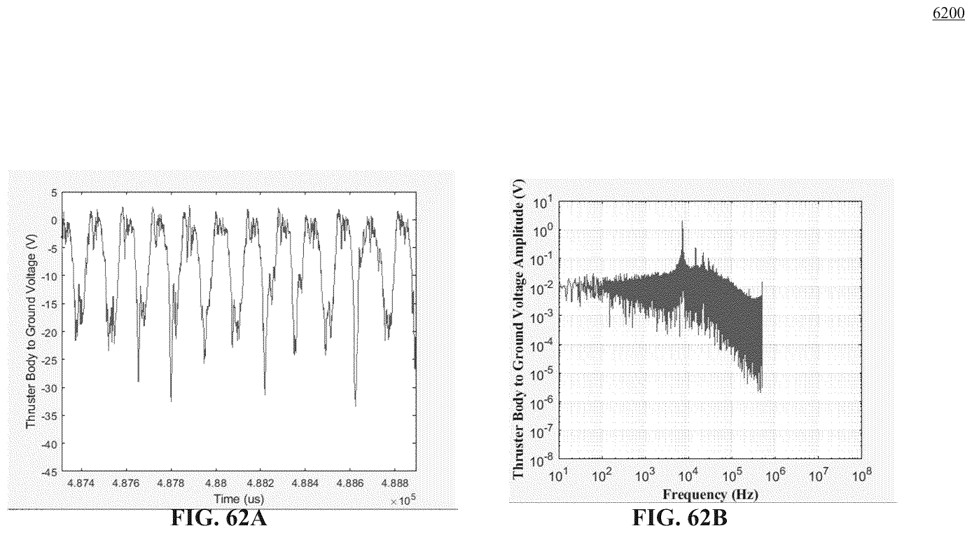

Referring to FIG. 62A, a time-domain plot showing thruster body to ground voltage measurements as a function of time for a Hall effect thruster discharge plasma is presented. The vertical axis displays the thruster body to ground voltage in volts, ranging from approximately positive 5 volts to negative 40 volts. The horizontal axis shows time in microseconds, scaled by a factor of 10 to the fifth power, spanning from approximately 4.874 to 4.889 times 10 to the fifth microseconds. The time window corresponds to approximately 1,500 microseconds of thruster body to ground voltage behavior during Hall effect thruster operation.

With continued reference to FIG. 62A, the thruster body to ground voltage waveform exhibits highly oscillatory behavior characteristic of breathing mode oscillations in Hall effect thruster plasmas. The thruster body to ground voltage oscillates predominantly between approximately positive 5 volts and negative 25 volts, with occasional excursions reaching as low as negative 35 volts to negative 40 volts. The peak-to-peak voltage variation of approximately 40 volts to 45 volts demonstrates substantial oscillations in the thruster body potential relative to facility ground during Hall effect thruster operation.

As further shown in FIG. 62A, the thruster body to ground voltage waveform displays a quasi-periodic oscillatory behavior with the signal spending most of the time near the zero volt level before rapidly dropping to negative voltage peaks. The oscillation pattern shows approximately 15 to 17 complete cycles within the displayed time window, suggesting a fundamental oscillation frequency in the range of several kilohertz. The oscillation frequency observed in the thruster body to ground voltage measurement is consistent with the breathing mode frequency discussed in the context of the discharge voltage and discharge current measurements described previously.

The irregular amplitude variations visible in the negative voltage peaks of FIG. 62A indicate the nonlinear time-varying nature of the Hall effect thruster discharge plasma. The thruster body potential relative to ground varies during Hall effect thruster operation in response to changes in the plasma conditions, ion flux to the thruster body surfaces, and the coupling between the discharge plasma and the thruster structure. The thruster body to ground voltage measurement provides diagnostic information about the plasma discharge dynamics and the electrical coupling between the thruster body and the discharge plasma oscillations.

Referring to FIG. 62B, a frequency spectrum plot showing the thruster body to ground voltage amplitude as a function of frequency for a Hall effect thruster system is presented. The vertical axis displays the thruster body to ground voltage amplitude measured in volts on a logarithmic scale ranging from 10⁻⁸ V to 10¹ V. The horizontal axis shows frequency in Hertz on a logarithmic scale spanning from 10¹ Hz to 10⁸ Hz. The frequency spectrum reveals characteristic oscillation behavior of the Hall effect thruster body potential relative to ground across the measured frequency range.

With continued reference to FIG. 62B, at lower frequencies below approximately 10³ Hz, the thruster body to ground voltage amplitude fluctuates in the range of 10⁻² V to 10⁻¹ V with notable variability. The spectral content increases as frequency approaches the 10⁴ Hz range, where a prominent peak structure emerges in the frequency spectrum. The dominant peak reaches maximum amplitude values approaching 10⁰ V in the frequency range between approximately 10⁴ Hz and 2×10⁴ Hz. The dominant peak corresponds to the breathing mode oscillation frequency band characteristic of Hall effect thruster operation.

As further shown in FIG. 62B, the breathing mode peak in the thruster body to ground voltage spectrum represents the dominant plasma instability arising from predator-prey interactions between neutrals and electrons in the discharge plasma, as manifested in the thruster body potential. The thruster body potential oscillates at the breathing mode frequency because the ion flux to the thruster body surfaces and the plasma coupling conditions vary in response to the ionization dynamics within the discharge channel. During periods of high ionization rate, the plasma density increases and affects the potential distribution between the thruster body and the surrounding plasma, causing corresponding variations in the thruster body to ground voltage.

Beyond the breathing mode peak visible in FIG. 62B, the thruster body to ground voltage amplitude decreases progressively with increasing frequency. The amplitude follows a general roll-off pattern that extends toward 10⁶ Hz. The signal amplitude drops to approximately 10⁻³ V to 10⁻⁴ V in the 10⁵ Hz range and continues decreasing until reaching the noise floor around 10⁶ Hz. The dense spectral content visible throughout the measurement range reflects the complex nonlinear time-varying nature of the discharge plasma dynamics and the influence of the plasma oscillations on the thruster body potential.

The frequency domain representation of thruster body to ground voltage shown in FIG. 62B complements the time-domain measurement shown in FIG. 62A by providing spectral characterization of the oscillatory behavior. The breathing mode peak location in the 10⁴ Hz to 2×10⁴ Hz frequency range corresponds to the oscillation frequency observed in the time-domain waveform, confirming that the thruster body to ground voltage oscillations occur at the same frequency as the discharge current and discharge voltage oscillations associated with the breathing mode instability.

The thruster body to ground voltage measurements shown in FIG. 62A and FIG. 62B may be used for state estimation and control system design in the model predictive path control approach. The thruster body to ground voltage provides an additional measurement signal that characterizes the operating state of the Hall effect thruster discharge plasma. The correlation between the thruster body to ground voltage oscillations and the discharge current oscillations may be exploited by the state estimator to improve estimates of the plasma parameters based on multiple measurement inputs. The thruster body to ground voltage measurement may complement the discharge current measurement data and the cathode to ground voltage measurement data for developing machine learning-based control strategies that account for the coupled dynamics between the thruster body, the discharge plasma, and the power processing unit components.

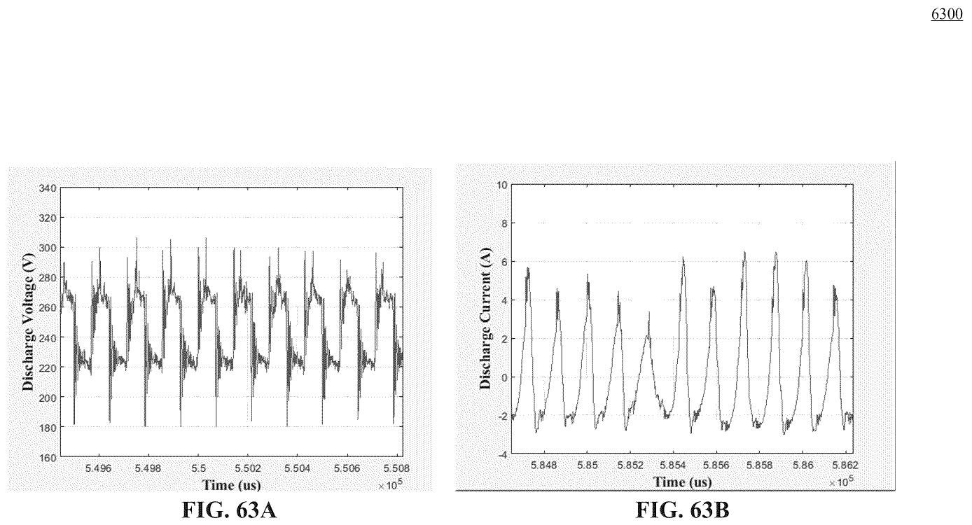

Referring to FIG. 63A, a time-domain plot showing discharge voltage oscillations measured in volts on the vertical axis against time measured in microseconds on the horizontal axis is presented. The time axis spans approximately from 5.496 to 5.508 multiplied by 10 to the fifth microseconds, representing a measurement window of roughly 12,000 microseconds or 12 milliseconds of discharge voltage data during Hall effect thruster operation. The discharge voltage exhibits highly oscillatory behavior throughout the measurement window, with the voltage fluctuating between approximately 180 volts and 310 volts.

With continued reference to FIG. 63A, the majority of the discharge voltage oscillations occur in a band between roughly 220 volts and 280 volts, with the mean discharge voltage value centered within this range. The discharge voltage waveform displays a quasi-periodic pattern characteristic of breathing mode oscillations in Hall effect thruster discharge plasmas. The oscillations show rapid voltage excursions both above and below the mean operating voltage, with occasional peaks reaching toward the upper bound of approximately 310 volts and occasional troughs dropping toward the lower bound of approximately 180 volts.

As further shown in FIG. 63A, the discharge voltage waveform exhibits a complex structure with varying peak amplitudes and frequencies throughout the measurement window. The irregular amplitude variations demonstrate the nonlinear time-varying nature of the Hall effect thruster discharge plasma load. The peak-to-peak voltage variation of approximately 130 volts between the minimum value of approximately 180 volts and the maximum value of approximately 310 volts represents substantial voltage oscillations during Hall effect thruster operation. The discharge voltage measurement data in FIG. 63A illustrates the voltage variations that accompany discharge current oscillations during breathing mode instability in the Hall effect thruster discharge plasma. The discharge voltage oscillation data may be used for characterizing the impedance of the discharge plasma and for developing control strategies that modulate the discharge voltage to influence the breathing mode oscillations through the machine learning-based model predictive path control approach.

Referring to FIG. 63B, a time-domain plot showing discharge current oscillations measured in amperes on the vertical axis against time measured in microseconds on the horizontal axis is presented. The time axis spans from approximately 5.847×10⁵ microseconds to 5.863×10⁵ microseconds, representing a measurement window of roughly 16,000 microseconds or 16 milliseconds of discharge current data scaled by 10⁵ during Hall effect thruster operation. The discharge current exhibits characteristic breathing mode oscillations throughout the measurement window, with the discharge current signal fluctuating between approximately negative 3 A and positive 6.5 A.

With continued reference to FIG. 63B, the discharge current waveform displays a quasi-periodic sawtooth-like pattern characteristic of breathing mode oscillations in Hall effect thruster discharge plasmas. Approximately 10 to 11 complete oscillation cycles are visible within the displayed time window, suggesting a breathing mode frequency in the range of approximately 6 kHz to 7 kHz. The sawtooth-like pattern demonstrates the characteristic predator-prey dynamics between neutrals and electrons in the Hall effect thruster discharge plasma, where rapid ionization events cause sharp current increases followed by neutral depletion and subsequent current reduction.

As further shown in FIG. 63B, the discharge current waveform exhibits relatively sharp rising edges leading to peak current values followed by more gradual falling phases. The asymmetric waveform shape with steep leading edges and more gradual trailing edges creates the characteristic sawtooth-like appearance throughout the measurement window. The peak-to-peak amplitude of approximately 8 A to 9.5 A, measured between the minimum values near negative 3 A and the maximum values near positive 6.5 A, demonstrates substantial discharge current oscillations during Hall effect thruster operation.

The discharge current oscillation pattern shown in FIG. 63B represents the type of breathing mode behavior that the real-time model predictive path control system aims to characterize and regulate through machine learning-based voltage modulation techniques. The sawtooth-like waveform provides characteristic features that the neural network model may learn to recognize and predict based on the discharge current measurement data. The discharge current measurement data in FIG. 63B may serve as input to the neural network model executed on the field programmable gate array for computing control voltage outputs that reduce the amplitude of the breathing mode oscillations in the Hall effect thruster discharge plasma.

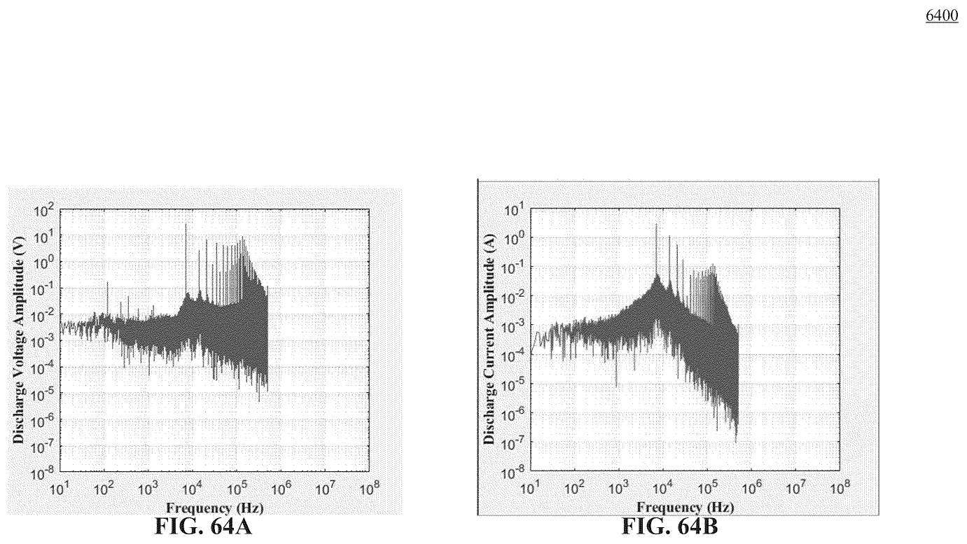

Referring to FIG. 64A, a frequency spectrum plot showing discharge voltage amplitude as a function of frequency for a Hall effect thruster system is presented. The vertical axis displays discharge voltage amplitude in volts on a logarithmic scale ranging from 10⁻⁸ V to 10² V. The horizontal axis shows frequency in Hertz on a logarithmic scale spanning from 10¹ Hz to 10⁸ Hz. The frequency spectrum reveals characteristic features of Hall effect thruster discharge oscillations across the measured frequency range.

With continued reference to FIG. 64A, at lower frequencies below approximately 10³ Hz, the discharge voltage amplitude exhibits relatively low values with some fluctuation in the 10⁻³ V to 10⁻² V range. The spectral content increases as frequency approaches the 10³ Hz to 10⁴ Hz range, where a dramatic increase in amplitude begins. A prominent peak structure emerges in the frequency range between 10⁴ Hz and 10⁵ Hz, corresponding to the breathing mode oscillation frequency band typical of Hall effect thrusters operating in the tens of kilohertz range.

As further shown in FIG. 64A, multiple sharp spikes are visible within the breathing mode frequency band near 10⁴ Hz. The sharp spikes reach maximum amplitude values approaching approximately 10¹ V, indicating substantial discharge voltage oscillations at the breathing mode frequencies. The presence of multiple distinct spikes within the breathing mode band suggests the existence of the fundamental breathing mode frequency and associated harmonic components in the discharge voltage signal. The sharp spike structure demonstrates that the discharge voltage oscillations concentrate energy at specific frequencies rather than being distributed uniformly across the frequency band.

The frequency spectrum in FIG. 64A shows dense oscillatory content throughout the 10⁴ Hz to 10⁶ Hz range following the prominent peak structure. The discharge voltage amplitude maintains elevated levels around 10⁻² V to 10⁻¹ V across this frequency range before exhibiting a sharp roll-off near 10⁶ Hz. Above approximately 10⁶ Hz, the signal amplitude drops sharply, returning to the noise floor. The frequency domain representation in FIG. 64A may be used for characterizing the spectral content of discharge voltage oscillations and for identifying the dominant oscillation modes in the Hall effect thruster discharge plasma.

Referring to FIG. 64B, a frequency spectrum plot showing the discharge current amplitude as a function of frequency for a Hall effect thruster system is presented. The vertical axis displays the discharge current amplitude measured in amperes on a logarithmic scale ranging from 10⁻⁸ A to 10¹ A. The horizontal axis shows frequency in Hertz on a logarithmic scale spanning from 10¹ Hz to 10⁸ Hz. The frequency spectrum reveals characteristic oscillation behavior of the Hall effect thruster discharge plasma across the measured frequency range.

With continued reference to FIG. 64B, at lower frequencies below approximately 10³ Hz, the discharge current amplitude fluctuates around 10⁻⁴ A with minor variations. The spectral content increases as frequency approaches the 10³ Hz to 10⁴ Hz range, where the amplitude rises toward the breathing mode frequency band. A prominent peak structure emerges in the frequency range between approximately 10⁴ Hz and 10⁵ Hz, where the discharge current amplitude reaches maximum values approaching 10⁰ A to 10¹ A.

As further shown in FIG. 64B, the breathing mode peak represents the dominant plasma instability arising from predator-prey interactions between neutrals and electrons in the discharge plasma. The peak amplitude approaching 10⁰ A to 10¹ A indicates that the discharge current oscillations at the breathing mode frequency have substantial amplitudes when measured in the frequency domain. Several sharp spikes are visible near 10⁴ Hz within the breathing mode band, indicating the presence of distinct oscillation modes and associated harmonic components in the discharge current signal.

The frequency spectrum in FIG. 64B shows dense oscillatory content throughout the 10⁴ Hz to 10⁶ Hz range following the breathing mode peak. Beyond the breathing mode peak, the discharge current amplitude decreases progressively with increasing frequency, following a general roll-off pattern. The spectrum exhibits a sharp decline near 10⁶ Hz where the signal drops toward the noise floor. The frequency domain representation in FIG. 64B may be used for characterizing the spectral content of discharge current oscillations, identifying the dominant breathing mode frequencies, and informing the design of control algorithms such as the model predictive path controller for suppressing plasma oscillations in Hall effect thrusters. The breathing mode peak location in the 10⁴ Hz to 10⁵ Hz frequency range indicates the frequency band where active voltage control may effectively influence the discharge plasma dynamics to reduce the amplitude of discharge current oscillations.

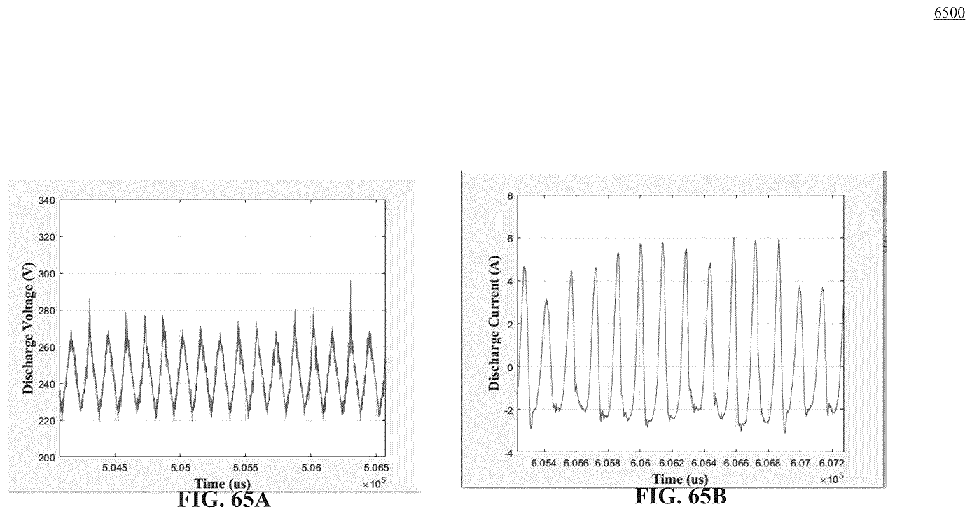

Referring to FIG. 65A, a time-domain plot showing discharge voltage oscillations measured in volts on the vertical axis against time measured in microseconds on the horizontal axis is presented. The vertical axis ranges from approximately 200 V to 340 V, displaying the range of discharge voltage variations during Hall effect thruster operation. The horizontal axis spans approximately from 5.04×10⁵ microseconds to 5.065×10⁵ microseconds, representing a measurement window of roughly 2,500 microseconds or 2.5 milliseconds of discharge voltage behavior scaled by a factor of 10⁵ as indicated on the axis label.

With continued reference to FIG. 65A, the discharge voltage waveform is displayed as a blue trace that exhibits quasi-periodic oscillatory behavior characteristic of breathing mode oscillations in Hall effect thruster discharge plasmas. The discharge voltage fluctuates predominantly between approximately 220 V and 290 V throughout the measurement window. The mean discharge voltage value appears to be centered around 250 V to 260 V based on the distribution of the oscillations within the displayed voltage range.

As further shown in FIG. 65A, the discharge voltage waveform demonstrates a characteristic sawtooth-like pattern associated with breathing mode oscillations. The sawtooth-like pattern features relatively rapid rising phases followed by more gradual falling phases throughout the measurement window. The peak-to-peak voltage variation of approximately 70 V between the minimum values near 220 V and the maximum values near 290 V represents substantial voltage oscillations during Hall effect thruster operation at the measured operating condition.

The discharge voltage oscillations visible in FIG. 65A show approximately 12 to 14 complete oscillation cycles within the displayed time window. The number of oscillation cycles corresponds to a breathing mode frequency in the range of approximately 20 kHz to 25 kHz based on the 2.5 millisecond measurement window duration. The oscillation frequency observed in FIG. 65A is consistent with breathing mode frequencies typically observed in Hall effect thruster discharge plasmas operating in the tens of kilohertz range.

With continued reference to FIG. 65A, the amplitude variations visible in the discharge voltage trace indicate the nonlinear time-varying nature of the Hall effect thruster discharge plasma dynamics. Some oscillation cycles exhibit larger peak-to-peak voltage excursions while other cycles show more moderate variations around the mean discharge voltage value. The irregular amplitude variations demonstrate cycle-to-cycle variability in the ionization dynamics and plasma conditions within the discharge channel that affect the discharge voltage behavior.

The discharge voltage measurement data shown in FIG. 65A may be used for characterizing the impedance of the discharge plasma and for developing control strategies that modulate the discharge voltage to influence the breathing mode oscillations. The discharge voltage oscillations accompany the discharge current oscillations that occur during breathing mode instability in the Hall effect thruster discharge plasma. The voltage oscillation data provides measurement input for the machine learning-based model predictive path control system that aims to regulate discharge plasma behavior through real-time voltage modulation techniques.

Referring to FIG. 65B, a time-domain plot showing discharge current oscillations measured in amperes on the vertical axis against time measured in microseconds on the horizontal axis is presented. The vertical axis ranges from approximately negative 4 A to positive 8 A, displaying the full range of discharge current variations during Hall effect thruster operation. The horizontal axis spans from approximately 6.054×10⁵ microseconds to 6.072×10⁵ microseconds, representing a measurement window of roughly 1,800 microseconds or 1.8 milliseconds of discharge current behavior scaled by a factor of 10⁵ as indicated on the axis label.

With continued reference to FIG. 65B, the discharge current waveform is displayed as a blue trace that exhibits pronounced quasi-periodic oscillatory behavior characteristic of breathing mode oscillations in Hall effect thruster discharge plasmas. The discharge current oscillates between minimum values of approximately negative 2.5 A to negative 3 A and maximum peak values reaching approximately 4 A to 6 A throughout the measurement window. The peak-to-peak amplitudes of the discharge current oscillations measure roughly 6 A to 9 A across the displayed time window.

As further shown in FIG. 65B, approximately 12 to 14 complete oscillation cycles are visible within the displayed time window. The number of oscillation cycles corresponds to a breathing mode frequency in the range of approximately 6 kHz to 8 kHz based on the 1.8 millisecond measurement window duration. The breathing mode frequency observed in FIG. 65B is consistent with the oscillation frequencies typically observed in Hall effect thruster discharge plasmas during breathing mode instability.

The discharge current waveform in FIG. 65B demonstrates a characteristic sawtooth-like pattern associated with breathing mode oscillations. The sawtooth-like pattern features relatively rapid rising phases reaching sharp peaks followed by more gradual falling phases throughout the measurement window. The asymmetric shape of the discharge current oscillations reflects the predator-prey dynamics between neutrals and electrons in the Hall effect thruster discharge plasma.

With continued reference to FIG. 65B, the sharp rising edges visible in the discharge current waveform correspond to rapid ionization events occurring within the discharge plasma when the neutral propellant population reaches sufficient density to support intense ionization by electron impact. During each ionization burst, the discharge current rises rapidly as ions are produced and accelerated through the discharge channel. The steep leading edges of the sawtooth-like waveform capture the rapid increase in ion flux that occurs during the ionization phase of each breathing mode cycle.

The more gradual falling phases visible in the discharge current waveform of FIG. 65B correspond to the depletion of the neutral population following each ionization burst and the subsequent reduction in discharge current as fewer ions are produced and accelerated through the discharge channel. The trailing edges of the sawtooth-like waveform capture the gradual decrease in ion production rate as the neutral population is consumed by the ionization process and the neutral replenishment from propellant injection cannot keep pace with the ionization demand.

As further shown in FIG. 65B, the asymmetric breathing mode patterns visible in the discharge current waveform demonstrate the characteristic temporal asymmetry between the ionization phase and the neutral recovery phase of each breathing mode cycle. The ionization phase occurs rapidly when conditions favor intense ionization, producing the sharp rising edges in the discharge current waveform. The neutral recovery phase occurs more gradually as propellant injection replenishes the neutral population within the discharge channel, producing the more gradual falling edges in the discharge current waveform.

The discharge current oscillation pattern shown in FIG. 65B represents the type of breathing mode behavior that the real-time model predictive path control system aims to characterize and regulate through machine learning-based voltage modulation techniques. The asymmetric sawtooth-like waveform provides characteristic features that the neural network model may learn to recognize and predict based on the discharge current measurement data. The discharge current measurement data in FIG. 65B may serve as input to the neural network model executed on the field programmable gate array for computing control voltage outputs that reduce the amplitude of the breathing mode oscillations in the Hall effect thruster discharge plasma.

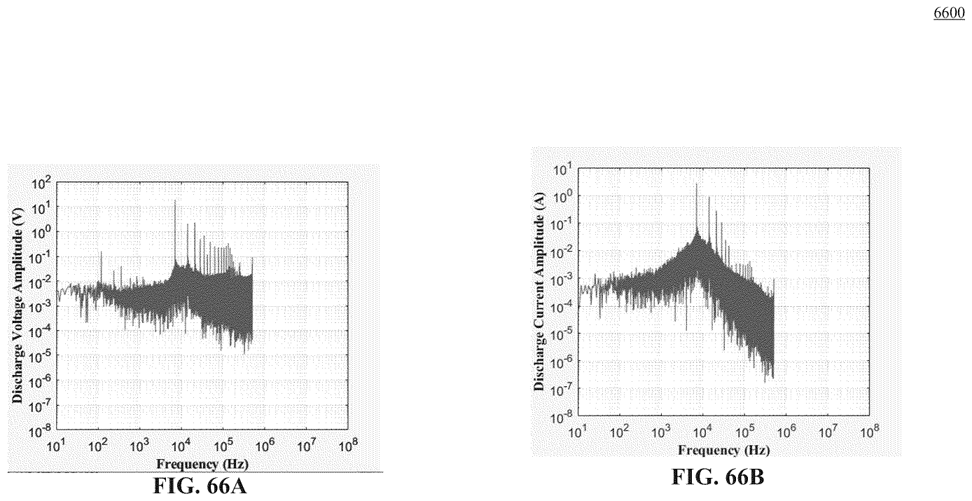

Referring to FIG. 66A, a frequency spectrum plot showing the discharge voltage amplitude as a function of frequency for a Hall effect thruster system is presented. The vertical axis displays the discharge voltage amplitude measured in volts on a logarithmic scale ranging from 10⁻⁸ V to 10² V. The horizontal axis shows frequency in Hertz on a logarithmic scale spanning from 10¹ Hz to 10⁸ Hz. The frequency spectrum reveals characteristic oscillation behavior of the Hall effect thruster discharge plasma across the measured frequency range.

With continued reference to FIG. 66A, at lower frequencies below approximately 10² Hz, the discharge voltage amplitude fluctuates around 10⁻³ V with notable variability. The spectral content increases as frequency approaches the 10³ Hz range, with amplitudes rising to the 10⁻² V level. A prominent peak structure emerges in the frequency range between approximately 10⁴ Hz and 10⁵ Hz, where several sharp spikes reach maximum amplitude values approaching 10¹ V. The most intense peaks occur near 10⁴ Hz within the breathing mode oscillation frequency band characteristic of Hall effect thruster operation.

As further shown in FIG. 66A, the breathing mode peak represents the dominant plasma instability arising from predator-prey interactions between neutrals and electrons in the discharge plasma. The peak amplitude approaching 10¹ V indicates that the discharge voltage oscillations at the breathing mode frequency have substantial amplitudes when measured in the frequency domain. The presence of multiple distinct spikes within the breathing mode band suggests the existence of the fundamental breathing mode frequency and associated harmonic components in the discharge voltage signal.

The frequency spectrum in FIG. 66A shows dense oscillatory content throughout the 10⁴ Hz to 10⁶ Hz range following the prominent peak structure. The discharge voltage amplitude maintains elevated levels around 10⁻² V to 10⁻¹ V across this frequency range before exhibiting a sharp roll-off near 10⁶ Hz where the signal drops toward the noise floor. The frequency domain representation in FIG. 66A may be used for characterizing the spectral content of discharge voltage oscillations and for identifying the dominant oscillation modes in the Hall effect thruster discharge plasma. The breathing mode peak location in the 10⁴ Hz to 10⁵ Hz frequency range indicates the frequency band where active voltage control may effectively influence the discharge plasma dynamics to reduce the amplitude of discharge voltage oscillations.

Referring to FIG. 66B, a frequency spectrum plot showing the discharge current amplitude as a function of frequency for a Hall effect thruster system is presented. The vertical axis displays the discharge current amplitude measured in amperes on a logarithmic scale ranging from 10⁻⁸ A to 10¹ A. The horizontal axis shows frequency in Hertz on a logarithmic scale spanning from 10¹ Hz to 10⁸ Hz. The frequency spectrum reveals characteristic oscillation behavior of the Hall effect thruster discharge plasma across the measured frequency range.

With continued reference to FIG. 66B, at lower frequencies below approximately 10³ Hz, the discharge current amplitude fluctuates around 10⁻⁴ A to 10⁻³ A with notable variability. The spectral content increases as frequency approaches the 10³ Hz to 10⁴ Hz range, where the amplitude rises toward the breathing mode frequency band. A prominent peak structure emerges in the frequency range between approximately 10⁴ Hz and 10⁵ Hz, where the discharge current amplitude reaches maximum values approaching 10⁰ A to 10¹ A.

As further shown in FIG. 66B, the breathing mode peak represents the dominant plasma instability arising from predator-prey interactions between neutrals and electrons in the discharge plasma. Several sharp spikes are visible near 10⁴ Hz within the breathing mode band, indicating the presence of distinct oscillation modes and associated harmonic components in the discharge current signal. The peak amplitude approaching 10⁰ A to 10¹ A indicates that the discharge current oscillations at the breathing mode frequency have substantial amplitudes when measured in the frequency domain.

The frequency spectrum in FIG. 66B shows dense oscillatory content throughout the 10⁴ Hz to 10⁶ Hz range following the breathing mode peak. Beyond the breathing mode peak, the discharge current amplitude decreases progressively with increasing frequency, following a general roll-off pattern. The spectrum exhibits a sharp decline near 10⁶ Hz where the signal drops toward the noise floor. The frequency domain representation in FIG. 66B may be used for characterizing the spectral content of discharge current oscillations, identifying the dominant breathing mode frequencies, and informing the design of control algorithms such as the model predictive path controller for suppressing plasma oscillations in Hall effect thrusters. The breathing mode peak location in the 10⁴ Hz to 10⁵ Hz frequency range indicates the frequency band where active voltage control may effectively influence the discharge plasma dynamics to reduce the amplitude of discharge current oscillations in the Hall effect thruster.

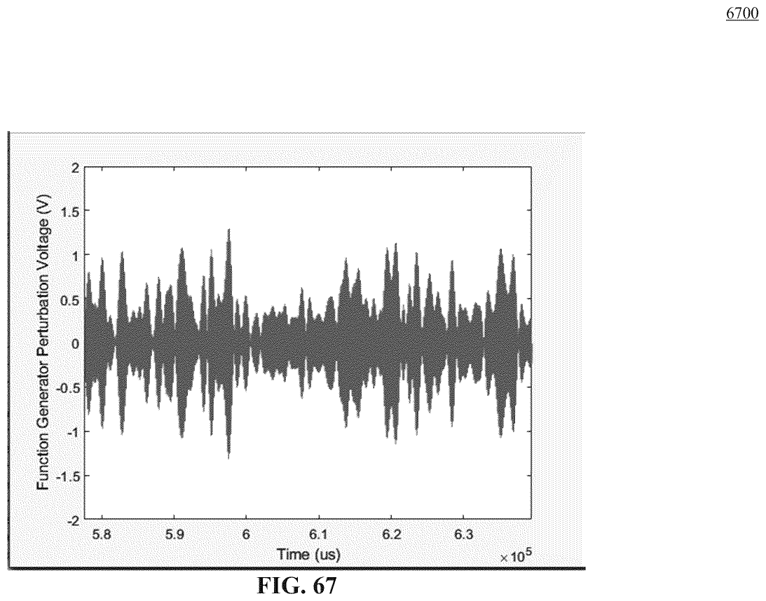

Referring to FIG. 67, a time-domain plot showing function generator perturbation voltage measured in volts on the vertical axis against time measured in microseconds on the horizontal axis is presented. The vertical axis ranges from approximately negative 2 volts to positive 2 volts, displaying the range of perturbation voltage variations during the system identification process. The horizontal axis spans from approximately 5.8 ×10⁵ microseconds to 6.35 ×10⁵ microseconds, representing a measurement window of roughly 55,000 microseconds or 55 milliseconds of perturbation voltage behavior.

With continued reference to FIG. 67, the function generator perturbation voltage waveform exhibits characteristic bandlimited noise perturbation behavior throughout the measurement window. The perturbation voltage signal oscillates rapidly around zero volts with varying amplitude across the time window. The signal predominantly fluctuates between approximately plus or minus 0.5 volts during periods of lower intensity. Occasional amplitude excursions reach plus or minus 1.0 volts to 1.3 volts during periods of higher intensity within the measurement window.

As further shown in FIG. 67, the bandlimited noise perturbation signal displays amplitude modulation characteristics. The envelope of the oscillations varies over time, showing periods of higher intensity interspersed with periods of relatively lower amplitude fluctuations. The amplitude modulation creates a time-varying envelope that modulates the instantaneous amplitude of the high-frequency noise oscillations. The varying envelope amplitude demonstrates that the perturbation signal energy is not constant over time but rather fluctuates in a manner that may enhance the system identification process by exciting the discharge plasma dynamics across a range of amplitude conditions.

The bandlimited noise perturbation signal shown in FIG. 67 may be employed in Hall effect thruster control experiments for characterizing the Hall effect thruster load dynamics. The bandlimited noise perturbation is injected into the discharge circuit through a function generator to excite the system across a range of frequencies within the breathing mode oscillation band. The noise perturbation serves to characterize the frequency-dependent response and impedance of the discharge plasma by applying broadband excitation that contains energy at multiple frequencies simultaneously.

With continued reference to FIG. 67, the bandlimited noise perturbation facilitates extraction of impedance characteristics from the discharge plasma response. When the bandlimited noise perturbation is applied to the discharge voltage, the resulting discharge current response contains information about the transfer function between the applied voltage perturbation and the discharge current. The ratio of the discharge current response to the applied voltage perturbation in the frequency domain provides the impedance of the discharge plasma at each frequency within the perturbation bandwidth.

The bandlimited noise perturbation signal may enable development of neural network models that capture the nonlinear time-varying behavior of the Hall effect thruster discharge plasma. The neural network model may be trained on time series data comprising the perturbation voltage input and the corresponding discharge current response. The training data generated using the bandlimited noise perturbation provides examples of the input-output relationship between voltage perturbations and discharge current dynamics across a range of frequencies and amplitudes. The neural network model learns the temporal relationships between the perturbation voltage inputs and the resulting discharge current responses by adjusting network weights based on the training data.

As further shown in FIG. 67, the amplitude modulation visible in the perturbation voltage envelope may provide additional information for system identification compared to constant-amplitude perturbation signals. The varying amplitude envelope excites the discharge plasma at different perturbation magnitudes throughout the measurement window. The discharge plasma response to larger amplitude perturbations may differ from the response to smaller amplitude perturbations due to the nonlinear characteristics of the Hall effect thruster discharge dynamics. The amplitude modulation in the perturbation signal enables characterization of the amplitude-dependent behavior of the discharge plasma within a single measurement acquisition.

The bandlimited noise perturbation approach shown in FIG. 67 may be used as an alternative to single-frequency sinusoidal perturbations for system identification. Single-frequency sinusoidal perturbations characterize the discharge plasma response at one frequency per measurement, requiring multiple measurements at different frequencies to characterize the broadband impedance. The bandlimited noise perturbation characterizes the discharge plasma response across the entire perturbation bandwidth within a single measurement acquisition. The broadband characterization capability of the bandlimited noise perturbation may reduce the time required for system identification compared to sequential single-frequency measurements.

With continued reference to FIG. 67, the perturbation voltage signal may be generated by a function generator configured to produce bandlimited noise with specified frequency bounds. The lower frequency bound and the upper frequency bound of the bandlimited noise may be configured to encompass the breathing mode oscillation frequency band of the Hall effect thruster. The bandlimited noise perturbation concentrates the perturbation energy within the frequency range where the breathing mode oscillations occur, providing efficient excitation of the plasma dynamics at the frequencies of interest for control system development.

The function generator perturbation voltage data shown in FIG. 67 represents the type of perturbation signal that may be applied to the Hall effect thruster discharge circuit for machine learning-based system identification. The perturbation voltage is applied through the voltage injection circuit comprising the power amplifier and transformer to modulate the discharge voltage of the Hall effect thruster. The discharge current response to the bandlimited noise perturbation is measured by the current sensor and digitized by the analog-to-digital converter for processing by the field programmable gate array. The perturbation voltage input and the corresponding discharge current response form the training data for the neural network model that predicts discharge current dynamics based on voltage inputs for real-time model predictive path control of plasma oscillations in the Hall effect thruster.

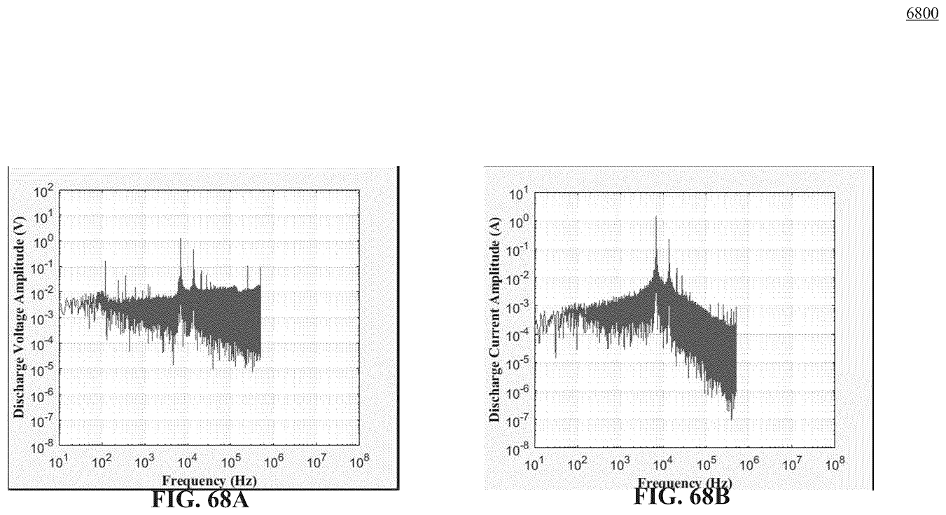

Referring to FIG. 68A, a frequency spectrum plot showing the discharge voltage amplitude as a function of frequency for a Hall effect thruster system is presented. The vertical axis displays the discharge voltage amplitude measured in volts on a logarithmic scale ranging from 10⁻⁸ V to 10² V. The horizontal axis shows frequency in Hertz on a logarithmic scale spanning from 10¹ Hz to 10⁸ Hz. The frequency spectrum reveals characteristic oscillation behavior of the Hall effect thruster discharge plasma across the measured frequency range when bandlimited noise perturbations are applied to the discharge circuit.

With continued reference to FIG. 68A, at lower frequencies below approximately 10³ Hz, the discharge voltage amplitude remains relatively stable around 10⁻³ V with some fluctuation. A notable peak appears near 10² Hz reaching approximately 10⁻¹ V, indicating low-frequency content in the discharge voltage signal. The spectral content increases as frequency approaches the 10⁴ Hz range, where prominent peak structures emerge in the frequency spectrum.

As further shown in FIG. 68A, the dominant oscillation band spans approximately from 10³ Hz to 10⁶ Hz. Within this breathing mode oscillation band, the discharge voltage amplitude reaches maximum values approaching approximately 10⁰ V in the frequency range between 10⁴ Hz and 10⁵ Hz. The breathing mode oscillation band corresponds to the frequency range where plasma instabilities arising from predator-prey interactions between neutrals and electrons in the discharge plasma manifest as discharge voltage oscillations.

Multiple sharp spikes are visible within the breathing mode band in FIG. 68A, particularly around 10⁴ Hz and near 10⁵ Hz. The sharp spikes indicate the presence of distinct oscillation modes and associated harmonic components in the discharge voltage signal. The presence of multiple distinct spikes within the breathing mode band suggests that the discharge voltage oscillations concentrate energy at specific frequencies corresponding to the fundamental breathing mode frequency and harmonic frequencies rather than being distributed uniformly across the frequency band.

With continued reference to FIG. 68A, beyond approximately 10⁶ Hz, the discharge voltage signal amplitude drops sharply to the noise floor. The sharp roll-off above 10⁶ Hz indicates that the discharge voltage oscillations are confined primarily to the breathing mode oscillation band spanning from 10³ Hz to 10⁶ Hz. The frequency domain representation in FIG. 68A may be used for characterizing the spectral content of discharge voltage oscillations when perturbation signals are applied to the Hall effect thruster discharge circuit. The breathing mode oscillation band identified in FIG. 68A indicates the frequency range where active voltage control may effectively influence the discharge plasma dynamics to reduce the amplitude of discharge voltage oscillations.

Referring to FIG. 68B, a frequency spectrum plot showing the discharge current amplitude as a function of frequency for a Hall effect thruster system is presented. The vertical axis represents the discharge current amplitude measured in amperes on a logarithmic scale ranging from 10⁻⁷ A to 10¹ A. The horizontal axis displays frequency in Hertz on a logarithmic scale spanning from 10¹ Hz to 10⁸ Hz. The frequency spectrum reveals a characteristic frequency response of the Hall effect thruster discharge plasma when bandlimited noise perturbations are applied to the discharge circuit.

With continued reference to FIG. 68B, the discharge current frequency spectrum exhibits a prominent peak occurring in the range of approximately 10⁴ Hz to 10⁵ Hz. The prominent peak corresponds to the breathing mode oscillation frequency band typically observed in Hall effect thrusters. The breathing mode peak reaches amplitudes approaching 10⁰ A, indicating substantial discharge current oscillations at the breathing mode frequencies. The breathing mode peak represents the dominant plasma instability arising from predator-prey interactions between neutrals and electrons in the discharge plasma.

As further shown in FIG. 68B, the frequency spectrum shows a gradual rise in discharge current amplitude from lower frequencies up to the breathing mode peak. At frequencies below approximately 10³ Hz, the discharge current amplitude remains at relatively low levels around 10⁻⁴ A to 10⁻³ A. The amplitude increases progressively as frequency approaches the breathing mode frequency band, reaching the peak amplitude near 10⁴ Hz to 10⁵ Hz.

Following the breathing mode peak visible in FIG. 68B, the discharge current amplitude exhibits a decay at higher frequencies extending toward 10⁶ Hz. The amplitude decreases progressively with increasing frequency beyond the breathing mode peak, following a general roll-off pattern characteristic of the discharge plasma dynamics. The dense spectral content visible throughout the measurement range, particularly the structure surrounding the breathing mode peak, reflects the complex nonlinear time-varying nature of the discharge plasma dynamics when perturbation signals are applied.

With continued reference to FIG. 68B, the frequency domain representation may be used for characterizing the Hall effect thruster load impedance and for identifying the dominant oscillation modes in the discharge current signal. The breathing mode peak location in the 10⁴ Hz to 10⁵ Hz frequency range indicates the frequency band where active voltage control may effectively suppress discharge current oscillations. The frequency spectrum data informs the design of control algorithms such as the model predictive path controller by identifying the frequency characteristics of the plasma oscillations that the control system aims to suppress through real-time voltage modulation. A control system may be configured to apply voltage perturbations at frequencies corresponding to the breathing mode peak identified in FIG. 68B to influence the discharge plasma dynamics and reduce the amplitude of discharge current oscillations in the Hall effect thruster.

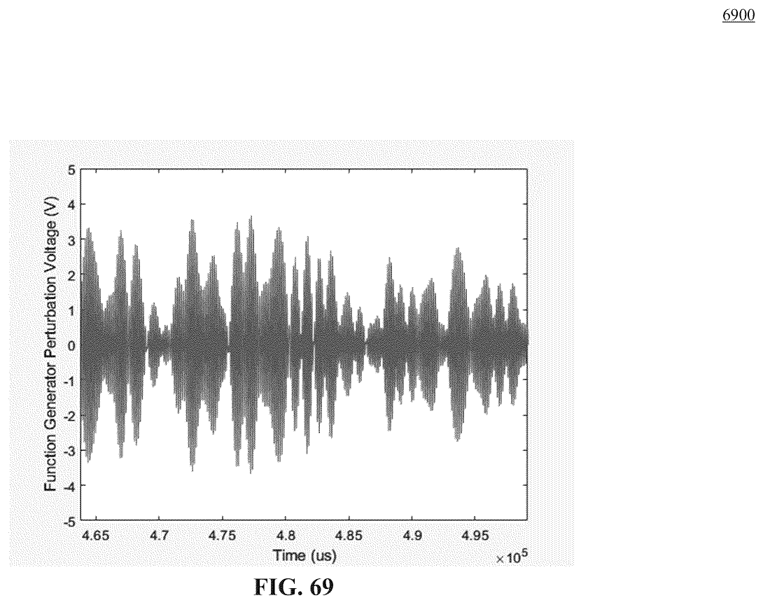

Referring to FIG. 69, a time-domain plot showing function generator perturbation voltage measured in volts on the vertical axis against time measured in microseconds on the horizontal axis is presented. The vertical axis ranges from approximately negative 5 volts to positive 5 volts, displaying the range of perturbation voltage variations during the system identification process. The horizontal axis spans from approximately 4.65×10⁵ microseconds to 5.0×10⁵ microseconds, representing a measurement window of roughly 35,000 microseconds or 35 milliseconds of perturbation voltage behavior.

With continued reference to FIG. 69, the function generator perturbation voltage waveform exhibits a characteristic amplitude-modulated pattern throughout the measurement window. The perturbation voltage signal appears as a dense, high-frequency oscillation with the instantaneous amplitude modulating between approximately plus or minus 4 volts at the peaks of the envelope down to near zero volts at the troughs of the envelope. The amplitude modulation creates a distinctive envelope pattern where the peak amplitudes rise and fall periodically over time.

As further shown in FIG. 69, several distinct amplitude modulation cycles are visible across the time window. The envelope period appears to be on the order of 5,000 microseconds to 10,000 microseconds based on the spacing between successive amplitude peaks in the modulated waveform. The periodic rise and fall of the amplitude envelope creates a pattern where the perturbation signal alternates between periods of high-amplitude oscillations and periods of low-amplitude oscillations throughout the measurement window.

The amplitude-modulated perturbation signal shown in FIG. 69 may be employed for system identification of the Hall effect thruster discharge plasma dynamics. The amplitude modulation pattern enables characterization of the discharge plasma response across a range of perturbation magnitudes within a single measurement acquisition. During the high-amplitude portions of the envelope, the perturbation signal applies larger voltage excursions to the discharge circuit that may excite nonlinear responses in the discharge plasma. During the low-amplitude portions of the envelope, the perturbation signal applies smaller voltage excursions that may characterize the linear response characteristics of the discharge plasma near the nominal operating point.

With continued reference to FIG. 69, the periodic amplitude modulation pattern provides a structured approach to varying the perturbation magnitude over time. The structured variation in perturbation amplitude may enable separation of the discharge plasma response at different excitation levels during subsequent signal processing and analysis. The discharge current response during high-amplitude perturbation periods may be compared with the discharge current response during low-amplitude perturbation periods to characterize the amplitude-dependent behavior of the Hall effect thruster discharge plasma.

The amplitude-modulated perturbation signal may be generated by a function generator configured to produce a carrier oscillation with a superimposed amplitude modulation envelope. The carrier oscillation provides the high-frequency content that excites the discharge plasma at frequencies within or near the breathing mode oscillation band. The amplitude modulation envelope varies the magnitude of the carrier oscillation over time according to the desired modulation pattern. The combination of the high-frequency carrier and the lower-frequency amplitude modulation envelope produces the distinctive waveform pattern visible in FIG. 69.

As further shown in FIG. 69, the amplitude-modulated perturbation voltage signal may be applied to the Hall effect thruster discharge circuit through the voltage injection circuit comprising the power amplifier and transformer. The perturbation voltage modulates the discharge voltage of the Hall effect thruster, and the resulting discharge current response is measured by the current sensor and digitized by the analog-to-digital converter. The perturbation voltage input and the corresponding discharge current response form training data for the neural network model that predicts discharge current dynamics based on voltage inputs.

The amplitude modulation pattern in the perturbation signal shown in FIG. 69 may enhance the system identification process compared to constant-amplitude perturbation signals. The varying amplitude envelope excites the discharge plasma at different perturbation magnitudes throughout the measurement window, providing information about the amplitude-dependent characteristics of the discharge plasma dynamics. The neural network model may learn the relationship between perturbation amplitude and discharge current response by training on data that includes the amplitude-modulated perturbation signal and the corresponding discharge current measurements. The learned amplitude-dependent relationships may enable the neural network model to predict discharge current dynamics across a range of control voltage magnitudes during real-time model predictive path control of plasma oscillations in the Hall effect thruster.

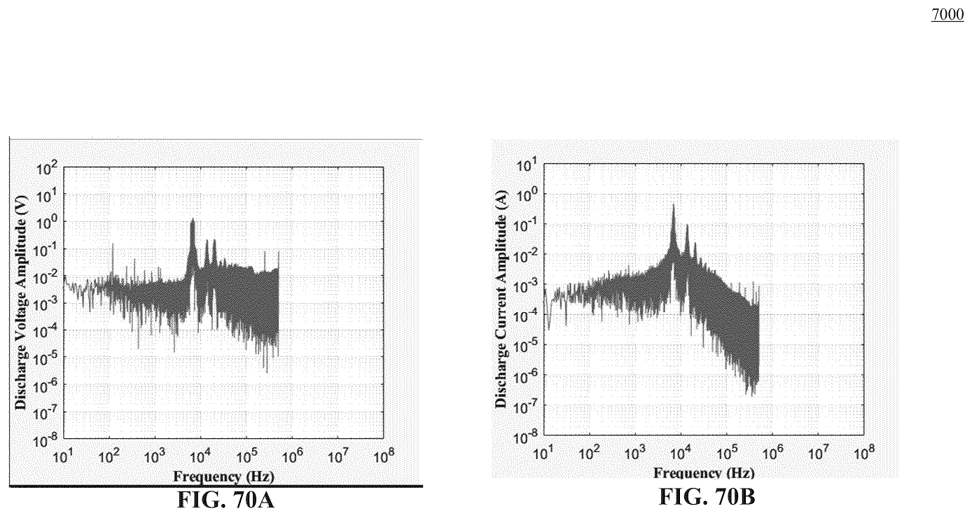

Referring to FIG. 70, two frequency spectrum plots showing discharge voltage amplitude and discharge current amplitude as functions of frequency for a Hall effect thruster system operating with modulated perturbation signals are presented. FIG. 70A displays the discharge voltage amplitude frequency spectrum, and FIG. 70B displays the discharge current amplitude frequency spectrum. Both frequency spectra are plotted with amplitude on logarithmic vertical axes and frequency in Hertz on logarithmic horizontal axes spanning from approximately 10¹ Hz to 10⁸ Hz.

With continued reference to FIG. 70, FIG. 70A shows the discharge voltage amplitude measured in volts on a logarithmic scale ranging from 10⁻⁷ V to 10² V. The discharge voltage frequency spectrum exhibits a prominent peak in the frequency range of approximately 10⁴ Hz to 10⁵ Hz. The prominent peak corresponds to the breathing mode oscillation frequency band characteristic of Hall effect thruster operation. The breathing mode peak in the discharge voltage spectrum reaches amplitude values that indicate substantial voltage oscillations at the breathing mode frequencies when modulated perturbation signals are applied to the discharge circuit.

As further shown in FIG. 70, FIG. 70B shows the discharge current amplitude measured in amperes on a logarithmic scale ranging from 10⁻⁷ A to 10¹ A. The discharge current frequency spectrum similarly exhibits a prominent peak in the frequency range of approximately 10⁴ Hz to 10⁵ Hz. The breathing mode peak in the discharge current spectrum corresponds to the same frequency band as the breathing mode peak in the discharge voltage spectrum of FIG. 70A. The correspondence between the breathing mode peaks in the discharge voltage spectrum and the discharge current spectrum demonstrates that the plasma oscillations manifest in both the voltage and current signals at the same characteristic frequencies.

Both frequency spectra in FIG. 70 show elevated amplitude levels at lower frequencies with a gradual roll-off at higher frequencies beyond the breathing mode peak region. The blue shaded regions in both FIG. 70A and FIG. 70B represent the spectral density of the respective signals, with the peak regions indicating the dominant oscillation frequencies associated with plasma instabilities in the discharge. The spectral content visible across the measurement bandwidth reflects the complex dynamics of the Hall effect thruster discharge plasma when modulated perturbation signals are applied.

With continued reference to FIG. 70, the breathing mode peaks visible in both FIG. 70A and FIG. 70B indicate the frequency band where the discharge plasma exhibits the dominant oscillatory behavior arising from predator-prey interactions between neutrals and electrons. The breathing mode oscillations in the 10⁴ Hz to 10⁵ Hz frequency range represent the plasma instabilities that the machine learning-based model predictive path control system aims to characterize and suppress through real-time voltage modulation techniques.

The frequency domain representations in FIG. 70 may be used for characterizing the Hall effect thruster load dynamics when modulated perturbation signals are applied. The breathing mode peak locations in both the discharge voltage spectrum and the discharge current spectrum identify the frequency bands where active voltage control may effectively influence the discharge plasma dynamics. The frequency spectrum data informs the design of control algorithms intended to suppress discharge current and voltage oscillations through real-time voltage modulation techniques by identifying the dominant oscillation frequencies that the control system may target for oscillation reduction.

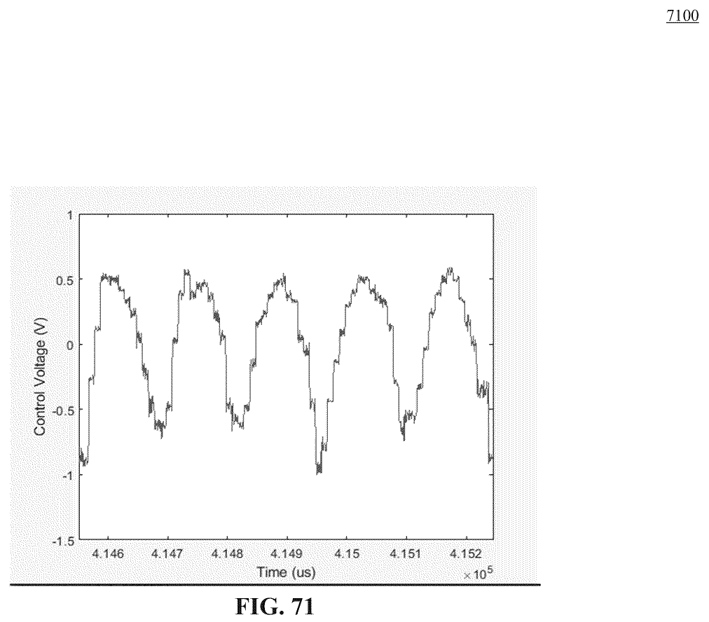

Referring to FIG. 71, a time-domain waveform plot showing control voltage measured in volts on the vertical axis versus time measured in microseconds on the horizontal axis is presented. The time axis spans approximately from 4.146×10⁵ microseconds to 4.152×10⁵ microseconds, representing a measurement window of roughly 600 microseconds of control voltage behavior during Hall effect thruster operation. The vertical axis displays control voltage values ranging from approximately negative 1 volt to positive 0.6 volts.

With continued reference to FIG. 71, the control voltage waveform oscillates between approximately negative 1 volt and positive 0.6 volts throughout the measurement window. The control voltage signal exhibits a quasi-periodic waveform characteristic of the output generated by the machine learning control system during active control of breathing mode oscillations in the Hall effect thruster discharge plasma. The oscillation pattern shows a dominant frequency component with the control voltage transitioning between peak and trough values in a repeating pattern across the displayed time window.

As further shown in FIG. 71, the control voltage waveform displays a distinctive sawtooth-like pattern with relatively sharp transitions between peak and trough values. The sawtooth-like pattern includes rising phases and falling phases that create the characteristic asymmetric waveform shape throughout the measurement window. The sharp transitions visible in the control voltage waveform correspond to the rapid changes in control action computed by the neural network model executed on the field programmable gate array in response to the measured discharge current oscillations.

The oscillation period of the control voltage waveform in FIG. 71 appears to be approximately 140 microseconds to 150 microseconds based on the spacing between successive peaks or troughs in the waveform. The oscillation period corresponds to a control frequency in the range of 6 kHz to 7 kHz, which is consistent with the breathing mode oscillation frequencies observed in the discharge current measurements described previously. The correspondence between the control voltage oscillation frequency and the breathing mode oscillation frequency demonstrates that the machine learning control system generates control outputs at frequencies appropriate for influencing the breathing mode dynamics of the Hall effect thruster discharge plasma.

With continued reference to FIG. 71, superimposed high-frequency noise or fluctuations are visible throughout the control voltage signal. The high-frequency fluctuations reflect the real-world experimental conditions encountered during Hall effect thruster operation and control experiments. The noise content in the control voltage signal may arise from electromagnetic interference in the measurement environment, quantization effects in the digital-to-analog converter, or inherent variability in the neural network computations. The presence of noise on the control voltage signal demonstrates that the machine learning control system operates under realistic experimental conditions rather than idealized simulation conditions.

The control voltage waveform shown in FIG. 71 represents the output of the machine learning control system that modulates the discharge voltage to influence plasma oscillations in the Hall effect thruster. The control voltage signal is generated by the neural network model executed on the field programmable gate array based on the digitized discharge current measurement data received from the analog-to-digital converter. The neural network model computes the control voltage values that are converted to analog form by the digital-to-analog converter and applied to the Hall effect thruster discharge circuit through the voltage injection circuit.

As further shown in FIG. 71, the control voltage output may range between negative 5.625 V and positive 11.25 V at the Hall effect thruster after accounting for gains from amplifiers in the voltage injection circuit. The voltage range observed in FIG. 71 between approximately negative 1 volt and positive 0.6 volts represents the control voltage at a measurement point prior to amplification by the power amplifier in the Hall effect thruster drive circuit. The power amplifier and transformer in the voltage injection circuit provide voltage gain that scales the control voltage to the larger voltage range applied to the Hall effect thruster discharge circuit. The amplified control voltage modulates the discharge voltage of the Hall effect thruster to influence the breathing mode oscillations in the discharge plasma.

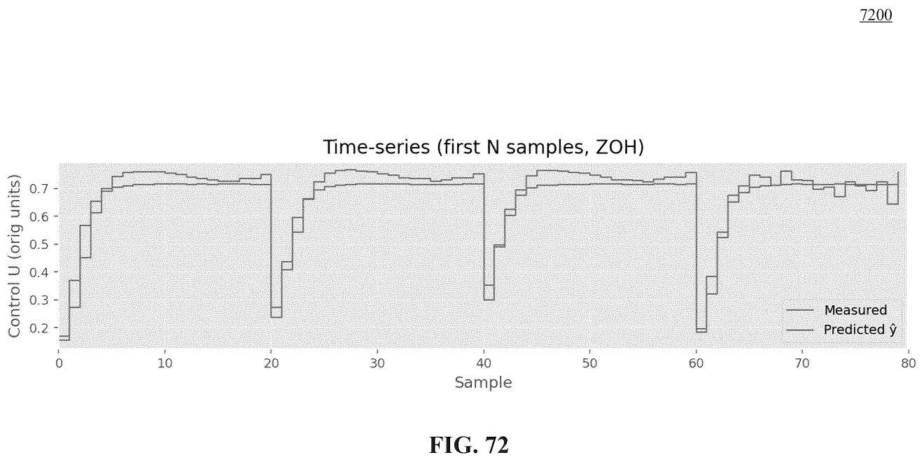

Referring to FIG. 72, a time-series plot comparing measured and predicted control signal values over a sequence of discrete samples is presented. The plot is titled “Time-series (first N samples, ZOH)” indicating that the data represents the first N samples with a zero-order hold representation. The vertical axis represents Control U in original units, ranging from approximately 0.15 to 0.75. The horizontal axis displays the sample number spanning from 0 to 80 samples.

With continued reference to FIG. 72, two traces are plotted on the graph to enable comparison between measured values and predicted values generated by the neural network model. A red line represents the measured control signal values obtained during Hall effect thruster operation. A blue line represents the predicted values denoted as ŷ that are generated by the neural network model based on the input data. Both the measured control signal values and the predicted values exhibit a zero-order hold representation, appearing as step-like waveforms where each value is held constant between successive sample points.

As further shown in FIG. 72, the plot reveals a distinctive periodic pattern with four distinct segments throughout the 80 sample measurement window. Each segment begins with a rapid transient from a low value near 0.15 to 0.25 up to a steady-state region around 0.7. The transients occur at approximately samples 0, 20, 40, and 60, suggesting a repeating cycle with a period of roughly 20 samples. The periodic pattern demonstrates that the control signal exhibits consistent behavior across multiple cycles during Hall effect thruster operation.

With continued reference to FIG. 72, during the steady-state portions between transients, the control signal stabilizes around 0.7 with minor fluctuations. The steady-state behavior following each transient indicates that the control system reaches a consistent operating condition after the initial adjustment period at the beginning of each cycle. The minor fluctuations visible in the steady-state regions reflect the dynamic nature of the Hall effect thruster discharge plasma and the corresponding adjustments made by the control system to maintain the desired operating condition.

The measured control signal values represented by the red trace and the predicted values represented by the blue trace demonstrate close agreement throughout the entire 80 sample range displayed in FIG. 72. The blue predicted signal closely tracks the red measured signal during both the transient portions and the steady-state portions of each cycle. The close correspondence between the measured values and the predicted values during the rapid transient phases demonstrates that the neural network model accurately captures the dynamic response characteristics of the control system. The close correspondence during the steady-state phases demonstrates that the neural network model accurately predicts the equilibrium behavior of the control system.

As further shown in FIG. 72, the neural network model may achieve 90% prediction accuracy based on variance when tested on previously unseen time-series data. The prediction accuracy metric quantifies the ability of the neural network model to reproduce the measured control signal behavior from input data that was not included in the training dataset. The 90% prediction accuracy based on variance indicates that the neural network model captures the majority of the variance in the measured control signal, with the remaining variance attributable to noise, measurement uncertainty, or unmodeled dynamics in the Hall effect thruster discharge plasma.

With continued reference to FIG. 72, the close agreement between the measured values and the predicted values demonstrates the effectiveness of the neural network model for capturing the control signal dynamics associated with Hall effect thruster operation. The neural network model receives digitized discharge current measurement data from the analog-to-digital converter, wherein the discharge current measurement data corresponds to discharge current oscillations of a Hall effect thruster as described previously. The neural network model processes the discharge current measurement data to predict the control voltage values that would be applied by the control system in response to the measured discharge current oscillations.

The time-series prediction validation shown in FIG. 72 confirms that the trained neural network model accurately represents the relationship between the discharge current measurements and the control voltage outputs. The validation using previously unseen time-series data demonstrates that the neural network model generalizes beyond the training data to predict control signal behavior under operating conditions not explicitly included in the training dataset. The generalization capability of the neural network model enables the model predictive path control system to compute appropriate control voltage outputs across a range of Hall effect thruster operating conditions encountered during actual thruster operation.

As further shown in FIG. 72, the zero-order hold representation of both the measured values and the predicted values reflects the discrete-time nature of the digital control system implementation. The field programmable gate array computes control voltage values at discrete time instants corresponding to the sampling rate of the analog-to-digital converter and the update rate of the digital-to-analog converter. Between successive computation instants, the control voltage output is held constant at the most recently computed value, producing the step-like waveform appearance visible in FIG. 72. The zero-order hold behavior is characteristic of digital control systems where continuous-time control signals are approximated by discrete-time sequences of constant values.

The time-series prediction validation results shown in FIG. 72 provide confidence that the neural network model may be deployed on the field programmable gate array for real-time control of breathing mode oscillations in the Hall effect thruster discharge plasma. The demonstrated prediction accuracy indicates that the neural network model has learned the temporal relationships between the discharge current oscillations and the effective control voltage responses from the training data generated by the nonlinear model predictive control simulation. The learned relationships enable the neural network model to generate control voltage outputs that reduce the amplitude of discharge current oscillations when the model is executed in real time on the field programmable gate array during Hall effect thruster operation.

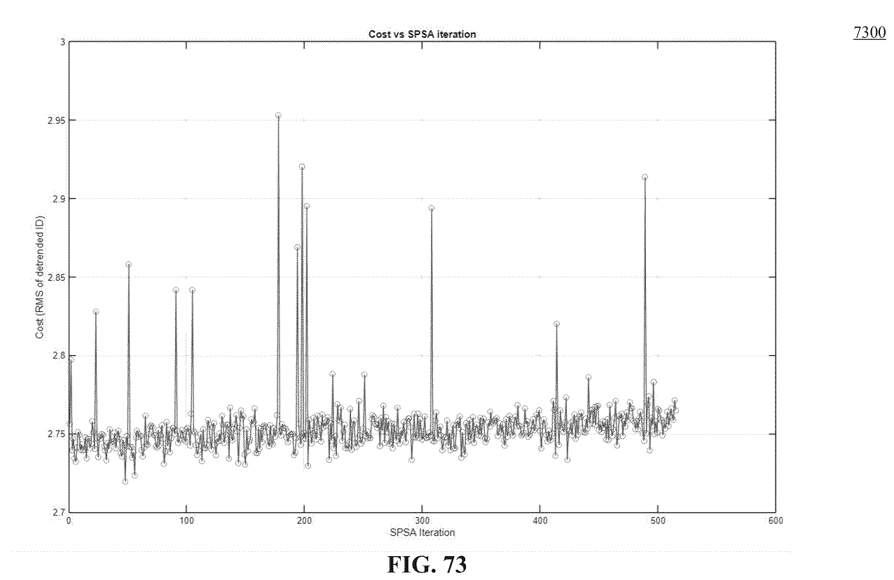

Referring to FIG. 73, a graph titled “Cost vs SPSA iteration” displaying the optimization performance of a simultaneous perturbation stochastic approximation algorithm used for tuning neural network controller weights in the Hall effect thruster plasma oscillation control system is presented. The horizontal axis represents the SPSA iteration number ranging from 0 to approximately 600 iterations. The vertical axis shows the cost function value measured as the root mean square of detrended discharge current designated as RMS(I_{D}) in amperes, ranging from approximately 2.7 A to 3.0 A.

With continued reference to FIG. 73, the cost function comprises a root mean square of detrended discharge current as described previously. The detrending operation removes the DC component from the discharge current measurement data to isolate the oscillatory content associated with breathing mode oscillations. The root mean square computation quantifies the amplitude of the remaining oscillatory content after detrending. The cost function value provides a scalar metric that characterizes the magnitude of discharge current oscillations during Hall effect thruster operation at each iteration of the optimization process.

As further shown in FIG. 73, the plot displays a characteristic optimization trajectory where the cost function fluctuates around a baseline value of approximately 2.74 A to 2.76 A throughout the optimization process. The baseline cost function value represents the typical root mean square of detrended discharge current achieved by the neural network controller during periods when the controller weights are near favorable configurations. The fluctuations around the baseline value reflect the stochastic nature of the simultaneous perturbation stochastic approximation algorithm and the inherent variability in the Hall effect thruster discharge plasma dynamics.

Periodic sharp spikes are visible throughout the iteration sequence in FIG. 73. The sharp spikes represent exploration phases of the simultaneous perturbation stochastic approximation algorithm where perturbations to the neural network weights temporarily increase the cost function value before the algorithm converges back toward lower cost values. Notable peaks reaching values between 2.85 A and 2.95 A occur at various points throughout the optimization process including around iterations 25, 50, 100, 180 to 200, 310, 420, and 500. The most prominent spike occurs near iteration 180 to 190, reaching approximately 2.95 A.

With continued reference to FIG. 73, despite the periodic excursions to higher cost values during exploration phases, the cost function consistently returns to the baseline region around 2.74 A to 2.76 A following each spike. The return to the baseline region demonstrates the stability of the optimization process and the ability of the simultaneous perturbation stochastic approximation algorithm to recover from exploration perturbations that temporarily degrade controller performance. The consistent return to favorable cost values indicates that the algorithm successfully identifies weight configurations that achieve low discharge current oscillation amplitudes.

The simultaneous perturbation stochastic approximation algorithm may be used for tuning outer layer weights of the multilayer perceptron as described previously. The multilayer perceptron comprises an input layer configured to receive past control voltage measurements and past discharge current measurements, at least two hidden layers with activation functions, and an output layer configured to generate the control voltage output. The outer layer weights connect the final hidden layer to the output layer and directly influence the control voltage values computed by the neural network model.

As further shown in FIG. 73, the simultaneous perturbation stochastic approximation algorithm operates by applying random perturbations to the outer layer weights and evaluating the resulting change in the cost function. At each iteration, the algorithm perturbs all outer layer weights simultaneously using random perturbation vectors. The algorithm computes the cost function value with the perturbed weights and compares the perturbed cost to the baseline cost to estimate the gradient of the cost function with respect to the weight parameters. The estimated gradient information guides weight updates that reduce the cost function value over successive iterations.

The overall behavior shown in FIG. 73 demonstrates that the simultaneous perturbation stochastic approximation algorithm maintains the cost near a minimum value while periodically exploring the parameter space. The periodic exploration phases where the cost function increases temporarily enable the algorithm to avoid local minima and to discover weight configurations that may achieve lower cost values than the current configuration. The exploration behavior is characteristic of stochastic optimization algorithms that balance exploitation of known favorable configurations with exploration of potentially better configurations in the parameter space.

With continued reference to FIG. 73, the optimization process spans approximately 600 iterations as shown on the horizontal axis. The extended optimization duration enables the simultaneous perturbation stochastic approximation algorithm to thoroughly explore the weight parameter space and to refine the outer layer weights toward configurations that minimize the root mean square of detrended discharge current. The cost function trajectory over the 600 iterations demonstrates that the algorithm achieves and maintains favorable weight configurations that result in reduced discharge current oscillation amplitudes during Hall effect thruster operation.

The cost function convergence behavior shown in FIG. 73 provides experimental evidence that the simultaneous perturbation stochastic approximation algorithm may effectively tune the outer layer weights of the multilayer perceptron for reducing discharge current oscillations in the Hall effect thruster discharge plasma. The baseline cost values around 2.74 A to 2.76 A achieved during the optimization process represent the discharge current oscillation amplitudes attained by the neural network controller with tuned weights. The tuned weights enable the neural network model to generate control voltage outputs that reduce the amplitude of breathing mode oscillations compared to uncontrolled operation of the Hall effect thruster.

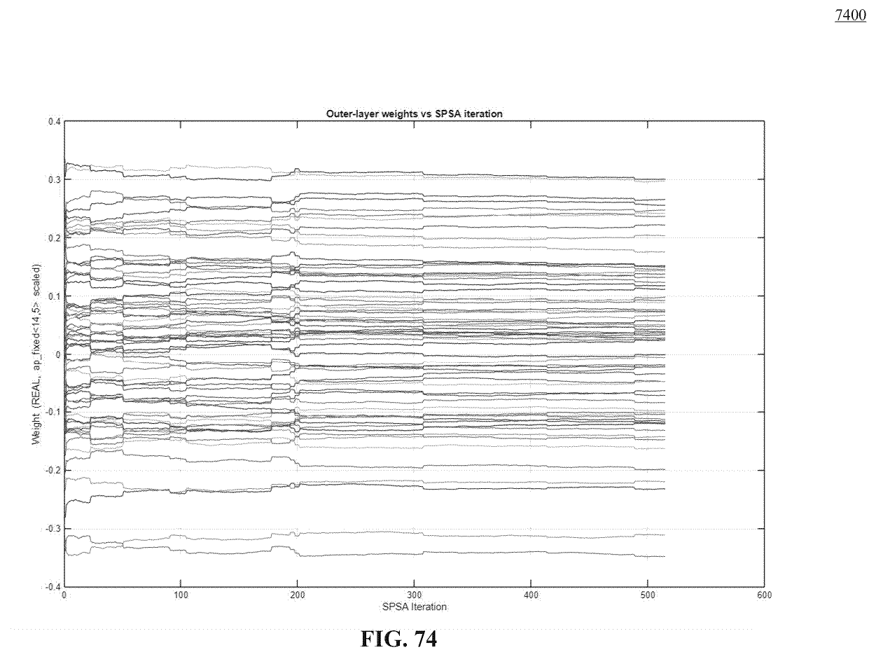

Referring to FIG. 74, a multi-trace plot titled “Outer-layer weights vs SPSA iteration” displaying the evolution of neural network weight parameters during simultaneous perturbation stochastic approximation optimization for the Hall effect thruster plasma oscillation controller is presented. The horizontal axis represents the SPSA iteration number ranging from 0 to approximately 550 iterations. The vertical axis shows the weight values in a fixed-point representation designated as ap_fixed<14,5> scaled, ranging from approximately negative 0.4 to positive 0.4.

With continued reference to FIG. 74, the plot contains numerous individual traces rendered in different colors including blue, orange, yellow, purple, green, cyan, magenta, and other colors. Each trace represents the temporal evolution of a distinct weight parameter in the outer layer of the multilayer perceptron neural network controller. The outer layer weights connect the final hidden layer to the output layer of the multilayer perceptron and directly influence the control voltage values computed by the neural network model. The multiple traces enable visualization of how all outer layer weight parameters evolve simultaneously throughout the optimization process.

As described previously, the neural network model comprises a multilayer perceptron having an input layer configured to receive past control voltage measurements and past discharge current measurements, at least one hidden layer, and an output layer configured to generate the control voltage output. The multilayer perceptron may have an architecture of 40 input neurons, 128 neurons in a first hidden layer, 64 neurons in a second hidden layer, and 1 output neuron. The input layer of the multilayer perceptron may receive 20 past control voltage measurements and 20 past discharge current measurements, providing a total of 40 input values to the neural network model at each computation instant.

As further shown in FIG. 74, the multilayer perceptron comprises at least two hidden layers with activation functions. The multilayer perceptron may use tanh activation functions in the hidden layers. The tanh activation functions provide nonlinear transformations between successive layers of the multilayer perceptron that enable the neural network model to learn complex nonlinear relationships between the input measurements and the control voltage output. The tanh activation functions produce output values bounded between negative one and positive one, which provides bounded activation behavior that may improve training stability and prevent unbounded growth of intermediate values during neural network computation.

With continued reference to FIG. 74, the traces demonstrate characteristic simultaneous perturbation stochastic approximation optimization behavior throughout the iteration sequence. The weights exhibit occasional sharp perturbations and step-like transitions at various points during the optimization process. The sharp perturbations are particularly noticeable around iterations 50, 100, 200, and 300, which correspond to the exploration phases of the stochastic optimization algorithm. During exploration phases, the simultaneous perturbation stochastic approximation algorithm applies random perturbations to all outer layer weights simultaneously to estimate the gradient of the cost function with respect to the weight parameters.

As further shown in FIG. 74, initially during the first approximately 100 to 150 iterations, the weights show more variability and larger excursions as the algorithm explores the parameter space. The initial exploration phase enables the simultaneous perturbation stochastic approximation algorithm to sample different regions of the weight parameter space and to identify directions in the parameter space that reduce the cost function value. The larger weight variations during the initial phase reflect the algorithm searching for favorable weight configurations starting from the initial weight values established during offline training of the multilayer perceptron.

As the optimization progresses beyond approximately 200 to 300 iterations visible in FIG. 74, most weight traces stabilize and converge toward relatively steady values. The convergence behavior indicates that the algorithm has found favorable weight configurations that achieve low cost function values corresponding to reduced discharge current oscillation amplitudes. The stabilization of the weight values demonstrates that the simultaneous perturbation stochastic approximation algorithm transitions from an exploration-dominated phase to an exploitation-dominated phase where the algorithm refines the weights near the discovered favorable configurations.

With continued reference to FIG. 74, the weight values are distributed across the full displayed range from approximately negative 0.4 to positive 0.4 in the fixed-point representation. Some weights converge to positive values near positive 0.25 to positive 0.35 by the end of the optimization process. Other weights converge to negative values near negative 0.25 to negative 0.35. Many weights settle at intermediate values between the positive and negative extremes. The distribution of converged weight values across the full range indicates that the outer layer weights take on diverse values that collectively enable the multilayer perceptron to generate appropriate control voltage outputs for reducing breathing mode oscillations in the Hall effect thruster discharge plasma.

The fixed-point representation noted in the axis label of FIG. 74 as ap_fixed<14,5> indicates that the weights are formatted for efficient hardware implementation on the field programmable gate array. The ap_fixed<14,5> format specifies a fixed-point number representation with 14 total bits and 5 integer bits, leaving 9 fractional bits for representing the decimal portion of each weight value. The fixed-point representation enables the neural network inference computations to be performed using integer arithmetic operations on the field programmable gate array, which may achieve lower latency and reduced resource utilization compared to floating-point arithmetic implementations.

As further shown in FIG. 74, the multilayer perceptron is trained on control trajectories generated by a nonlinear model predictive control algorithm operating on a discharge plasma dynamics model as described previously. The nonlinear model predictive control algorithm may operate on a zero-dimensional ionization model of the Hall effect thruster discharge plasma. The zero-dimensional ionization model captures the temporal dynamics of the discharge plasma including the predator-prey interactions between neutrals and electrons that give rise to breathing mode oscillations. The control trajectories generated by the nonlinear model predictive control algorithm provide training examples that teach the multilayer perceptron the relationship between discharge current states and effective control voltage actions for reducing oscillation amplitudes.

With continued reference to FIG. 74, the visualization of weight evolution provides insight into the learning dynamics of the simultaneous perturbation stochastic approximation-based online tuning approach. The weight trajectories demonstrate that the optimization process converges to stable weight configurations that effectively reduce discharge current oscillations in the Hall effect thruster discharge plasma. The stable weight configurations achieved after approximately 200 to 300 iterations enable the neural network controller to generate control voltage outputs that maintain reduced oscillation amplitudes during continued Hall effect thruster operation.

The system may use recursive least squares for adaptive tuning of the outer layer weights of the neural network at millisecond time scales. Recursive least squares provides an alternative or complementary approach to simultaneous perturbation stochastic approximation for online weight adaptation. Recursive least squares may update the outer layer weights based on the error between predicted discharge current values and measured discharge current values, adjusting the weights to minimize the prediction error over time. The millisecond time scale adaptation enabled by recursive least squares may allow the neural network controller to track changes in the Hall effect thruster discharge plasma dynamics that occur due to variations in operating conditions, facility pressure, or thruster aging effects.

As further shown in FIG. 74, the convergence of the outer layer weights to stable values after the initial exploration phases demonstrates that the simultaneous perturbation stochastic approximation algorithm successfully identifies weight configurations that achieve the control objective of reducing discharge current oscillations. The weight evolution data provides experimental verification that the online tuning approach may adapt the neural network controller weights during Hall effect thruster operation to maintain effective oscillation control performance. The stable weight configurations achieved through the optimization process enable the multilayer perceptron to generate control voltage outputs that reduce the amplitude of breathing mode oscillations in the Hall effect thruster discharge plasma when the neural network model is executed in real time on the field programmable gate array.

The nonlinear model predictive control algorithm may use sequential quadratic programming as the solver for computing optimal control trajectories. Sequential quadratic programming solves the nonlinear optimization problem by iteratively approximating the problem as a sequence of quadratic programming subproblems. At each iteration, sequential quadratic programming constructs a quadratic approximation of the cost function and linear approximations of the constraints, then solves the resulting quadratic program to determine a search direction for updating the control trajectory. The sequential quadratic programming solver may achieve rapid convergence for the nonlinear model predictive control problem when the initial guess is close to the optimal solution, enabling efficient computation of control trajectories for the Hall effect thruster discharge plasma dynamics.

In some cases, the nonlinear model predictive control algorithm may use an interior point optimizer as the solver. The interior point optimizer solves the nonlinear optimization problem by traversing the interior of the feasible region rather than moving along the boundary of the feasible region. The interior point optimizer may handle inequality constraints by incorporating barrier functions that penalize solutions approaching the constraint boundaries. The interior point optimizer may provide robust convergence behavior for nonlinear model predictive control problems with complex constraint structures, enabling computation of control trajectories that satisfy safety limits and actuator constraints during Hall effect thruster operation.

The system may include a one-dimensional ionization model based on partial differential equations for more detailed spatial analysis of the discharge plasma. The one-dimensional ionization model extends the zero-dimensional ionization model by incorporating spatial variation along the axial direction of the Hall effect thruster discharge channel. The one-dimensional ionization model may include partial differential equations governing the conservation of mass, momentum, and energy for ions, electrons, and neutrals as functions of both time and axial position within the discharge channel. The spatial resolution provided by the one-dimensional ionization model may capture phenomena such as the ionization zone location, the acceleration zone structure, and the spatial distribution of plasma parameters that affect breathing mode oscillation dynamics.

The one-dimensional ionization model may provide improved fidelity for predicting discharge plasma behavior compared to the zero-dimensional ionization model. The spatial variation captured by the one-dimensional ionization model may enable more accurate representation of the coupling between the discharge voltage perturbations applied at the anode and the resulting discharge current response measured at the power processing unit. The one-dimensional ionization model may be used for generating training data for the neural network model when higher fidelity predictions of the discharge plasma dynamics are desired. In some cases, the one-dimensional ionization model may be used for state estimation to estimate spatially-resolved plasma parameters based on the discharge current measurement data.

The nonlinear model predictive control simulations may indicate discharge current oscillation reduction of over 90% compared to uncontrolled operation. The 90% oscillation reduction metric may be computed by comparing the root mean square of detrended discharge current during controlled operation to the root mean square of detrended discharge current during uncontrolled operation at the same operating point. The nonlinear model predictive control algorithm may achieve the 90% oscillation reduction by computing control voltage trajectories that apply voltage perturbations timed to destructively interfere with the breathing mode oscillations in the discharge plasma. The simulation results demonstrating over 90% oscillation reduction provide a performance target for the neural network controller trained on the nonlinear model predictive control trajectories.

The machine learning control system may enable operation of the Hall effect thruster at higher power operating points that are otherwise inaccessible due to high discharge current oscillation amplitudes. At higher power operating points, the discharge plasma becomes increasingly nonlinear, making PID control less effective or potentially counterproductive. In some cases, PID controllers may be unable to reduce oscillations at higher power operating points, or may even exacerbate the oscillations, which was observed in experimental testing. The high oscillation amplitudes at these higher power operating points may cause wall erosion and damage to the Hall effect thruster, preventing sustained operation at these conditions. By reducing oscillations through the machine learning-based voltage modulation approach, the control system may enable the Hall effect thruster to operate safely at these higher power conditions. The machine learning approach may handle the nonlinear dynamics at higher power operating points where PID controllers cannot effectively reduce oscillations. Operation at the higher power operating points may enable the Hall effect thruster to attain higher thrust output or higher specific impulse compared to operation at lower power operating points that exhibit minimal oscillations without active control. The ability to access higher power operating points through oscillation control may expand the operational envelope of the Hall effect thruster and improve mission performance.

The Hall effect thruster discharge plasma may exhibit mode hopping behavior where the discharge oscillations alternate between two or more distinct oscillation modes at a given operating point. In one mode, the discharge current may oscillate with relatively low amplitude, and in another mode, the discharge current may oscillate with substantially higher amplitude. The mode hopping between the low-amplitude oscillation mode and the high-amplitude oscillation mode may occur unpredictably during Hall effect thruster operation. The mode hopping behavior may adversely affect thruster performance and stability by causing unpredictable variations in thrust output and discharge current characteristics. By reducing the discharge current oscillation amplitude through the machine learning-based control approach, the control system may also reduce or eliminate the mode hopping behavior. The reduction of mode hopping may improve the stability and predictability of Hall effect thruster operation by maintaining the discharge plasma in a consistent oscillation state rather than alternating between distinct oscillation modes.

The machine learning controller may be used as a feedforward term coupled with a proportional-integral-derivative (PID) controller for on-orbit spacecraft operation. Neural networks may exhibit stability concerns in some operating conditions, and coupling the machine learning control output as a feedforward signal with a PID feedback controller may provide stability guarantees suitable for spacecraft integration. In such a configuration, the PID controller may provide baseline stability for the Hall effect thruster discharge control system while the machine learning feedforward term provides performance enhancement through learned control actions. The PID controller may operate on the discharge current error signal to maintain stable operation even if the neural network output becomes unreliable or produces unexpected control actions. The machine learning feedforward term may provide anticipatory control actions based on the learned discharge plasma dynamics that improve oscillation reduction performance beyond what the PID controller alone would achieve. Both the PID controller and the neural network model may be implemented on the same field programmable gate array, enabling both control functions to execute on a single hardware platform. The field programmable gate array may execute both the neural network inference and the PID control computations within the timing constraints required for real-time control of breathing mode oscillations. The combination of the stable PID feedback controller with the machine learning feedforward term on a single field programmable gate array may enable deployment of the neural network-based control approach on spacecraft where reliability, stability, and minimal hardware complexity are paramount considerations.

The control system may be configured to convert discharge current oscillations into amplitude modulation for communications applications. The amplitude modulation capability may enable the Hall effect thruster to serve as a transmitter for spacecraft communications by encoding information in the amplitude of the discharge current oscillations. The control system may modulate the discharge voltage to produce discharge current oscillations with amplitudes that vary according to a communications signal. A receiver may detect the amplitude-modulated discharge current oscillations through electromagnetic emissions from the Hall effect thruster plume or through conducted signals on the spacecraft power bus.

In some cases, the control system may be configured to convert discharge current oscillations into frequency modulation for communications applications. The frequency modulation capability may enable encoding information in the frequency of the breathing mode oscillations rather than the amplitude. The control system may adjust the discharge voltage or other operating parameters to shift the breathing mode oscillation frequency according to a communications signal. The frequency modulation approach may provide improved noise immunity compared to amplitude modulation in some operating environments.

In some cases, the control system may be configured to convert discharge current oscillations into phase modulation for communications applications. The phase modulation capability may enable encoding information in the phase of the breathing mode oscillations relative to a reference signal. The control system may apply voltage perturbations that shift the phase of the discharge current oscillations according to a communications signal. The phase modulation approach may enable digital communications schemes where discrete phase states represent different data symbols.

The system may include safety limits based on understanding the resulting additional discharge current from applied control voltages at every perturbation frequency. The safety limits may constrain the control voltage output to prevent excessive discharge current excursions that could damage the Hall effect thruster or the power processing unit. The safety limits may be determined by characterizing the discharge current response to voltage perturbations across the frequency range of interest during system identification experiments. The characterization may establish the relationship between perturbation voltage amplitude and resulting discharge current amplitude at each frequency, enabling computation of safe perturbation limits that maintain the discharge current within acceptable bounds.

The safety limits may be implemented as constraints in the nonlinear model predictive control algorithm. The constraints may limit the control voltage magnitude based on the expected discharge current response at the perturbation frequencies present in the control signal. The safety limit constraints may prevent the control system from applying voltage perturbations that would cause discharge current spikes exceeding the current handling capability of the power processing unit components or the thermal limits of the Hall effect thruster. The safety limits may be updated based on operating condition changes that affect the discharge current response characteristics.

The control system may be configured to update the neural network model online with new time series data at moderate time scales to adapt to changing conditions. The online update capability may enable the neural network model to track changes in the Hall effect thruster discharge plasma dynamics that occur due to variations in facility pressure, propellant flow rate, magnetic field configuration, or thruster aging effects. The moderate time scale for online updates may correspond to update intervals on the order of seconds to minutes, enabling adaptation to gradual changes in operating conditions while maintaining stable control performance during each update interval.

The online update process may involve collecting new discharge current measurement data and control voltage data during Hall effect thruster operation. The new time series data may be used to retrain or fine-tune the neural network model weights to improve prediction accuracy under the current operating conditions. The online update may employ incremental learning techniques that update the neural network weights based on the new data without requiring complete retraining from the original training dataset. The incremental learning approach may reduce the computational burden of online updates and enable adaptation within the time constraints of Hall effect thruster operation.

The system may use reinforcement learning to determine optimal perturbation signals for learning and control. The reinforcement learning approach may enable the control system to discover effective perturbation strategies through interaction with the Hall effect thruster discharge plasma rather than relying solely on predetermined perturbation signal designs. The reinforcement learning agent may select perturbation signal parameters such as amplitude, frequency, waveform shape, and timing based on the observed discharge current response and a reward signal that quantifies control performance.

The reinforcement learning approach may optimize the perturbation signals for both system identification and oscillation control objectives. For system identification, the reinforcement learning agent may select perturbation signals that maximize the information content of the discharge current response for training the neural network model. For oscillation control, the reinforcement learning agent may select perturbation signals that minimize the discharge current oscillation amplitude while satisfying safety constraints. The reinforcement learning approach may adapt the perturbation strategy based on changes in the Hall effect thruster operating conditions or discharge plasma dynamics.

A current sensor may comprise a Pearson current monitor positioned inside a vacuum chamber. The Pearson current monitor may be a current transformer that measures the discharge current by sensing the magnetic field produced by current flowing through a conductor passing through the current monitor aperture. The Pearson current monitor may provide high bandwidth current measurements suitable for capturing the breathing mode oscillations in the discharge current. Positioning the Pearson current monitor inside the vacuum chamber may reduce the influence of harness inductance and capacitance on the current measurement, providing a more accurate representation of the discharge current at the Hall effect thruster.

The Pearson current monitor positioned inside the vacuum chamber may measure the discharge current closer to the Hall effect thruster anode compared to current sensors positioned outside the vacuum chamber. The reduced distance between the current measurement point and the Hall effect thruster may improve the correlation between the measured discharge current and the actual ion production rate within the discharge channel. The improved correlation may enhance the effectiveness of the control system by providing discharge current measurement data that more accurately reflects the instantaneous state of the discharge plasma dynamics.

The system may include a lock-in amplifier for improving signal-to-noise ratio of discharge current and voltage measurements. The lock-in amplifier may extract signals at a specific reference frequency from noisy measurement data by multiplying the measurement signal with a reference signal and applying low-pass filtering to the product. The lock-in amplifier technique may improve the signal-to-noise ratio by rejecting noise components at frequencies different from the reference frequency. The improved signal-to-noise ratio may enable more accurate characterization of the discharge plasma response to voltage perturbations at specific frequencies.

The lock-in amplifier may be used during system identification experiments to characterize the impedance of the discharge plasma at discrete frequencies. The lock-in amplifier may receive the discharge current measurement signal and a reference signal at the perturbation frequency applied to the discharge voltage. The lock-in amplifier may output the amplitude and phase of the discharge current component at the perturbation frequency, enabling computation of the discharge plasma impedance at that frequency. The lock-in amplifier measurements may be repeated at multiple perturbation frequencies to characterize the frequency-dependent impedance across the breathing mode oscillation band.

The lock-in amplifier may improve measurement accuracy when the discharge current oscillations at the perturbation frequency are small compared to the background noise or the breathing mode oscillation amplitude. The lock-in amplifier may extract the perturbation response from the discharge current signal even when the perturbation-induced current variations are obscured by larger amplitude oscillations at other frequencies. The improved measurement accuracy provided by the lock-in amplifier may enable characterization of the discharge plasma dynamics at frequencies and amplitudes where direct time-domain measurements would have insufficient signal-to-noise ratio for accurate analysis.

A number of implementations have been described. Nevertheless, it will be understood that various modifications may be made without departing from the spirit and scope of the disclosure. Accordingly, other implementations are within the scope of the following claims.

1. A system for controlling plasma oscillations in a Hall effect thruster, comprising:
a current sensor configured to measure a discharge current of the Hall effect thruster
and generate discharge current measurement data;
an analog-to-digital converter configured to digitize the discharge current measurement data;
a processor configured to execute a machine learning model that receives the digitized discharge current measurement data and computes a control output based on the machine learning model;
a digital-to-analog converter configured to convert the control output to an analog control signal; and
a control circuit configured to apply the analog control signal to modulate a discharge voltage of the Hall effect thruster to reduce discharge current oscillations.

2. The system of claim 1, wherein the processor comprises a field programmable gate array (FPGA).

3. The system of claim 1, wherein the machine learning model comprises a neural network model trained to predict discharge current dynamics based on voltage inputs.

4. The system of claim 3, wherein the neural network model comprises a multilayer perceptron having an input layer configured to receive past control voltage measurements and past discharge current measurements, at least one hidden layer, and an output layer configured to generate the control output.

5. The system of claim 1, wherein the control circuit comprises a voltage injection circuit having a power amplifier configured to amplify the analog control signal and a transformer configured to electrically isolate the power amplifier from the Hall effect thruster and to inject the amplified analog control signal in series with a discharge path of the Hall effect thruster.

6. The system of claim 1, wherein the system enables operation of the Hall effect thruster at a higher power operating point that is inaccessible without active oscillation control due to discharge current oscillation amplitudes at the higher power operating point exceeding acceptable limits, and wherein operation at the higher power operating point provides at least one of higher thrust output or higher specific impulse compared to a lower power operating point.

7. The system of claim 1, further comprising a state estimator configured to estimate plasma parameters of a discharge plasma of the Hall effect thruster based on the discharge current measurement data, wherein the plasma parameters comprise at least one of ion number density, neutral number density, electron temperature, ion velocity, or electron velocity.

8. A non-transitory computer-readable medium storing instructions that, when executed by a processor, cause the processor to perform operations comprising:
receiving digitized discharge current measurement data corresponding to discharge current oscillations of a Hall effect thruster;
executing a machine learning model to generate a predicted discharge current response based on the digitized discharge current measurement data;
computing a control output based on the predicted discharge current response to reduce discharge current oscillations in the Hall effect thruster; and
outputting the control output for conversion to an analog control signal for modulating a discharge voltage of the Hall effect thruster.

9. The non-transitory computer-readable medium of claim 8, wherein the processor comprises a field programmable gate array (FPGA).

10. The non-transitory computer-readable medium of claim 8, wherein the machine learning model comprises a neural network model trained on Hall effect thruster discharge data.

11. The non-transitory computer-readable medium of claim 10, wherein the neural network model comprises a multilayer perceptron having an input layer configured to receive a plurality of past control voltage measurements and a plurality of past discharge current measurements, and at least one hidden layer.

12. The non-transitory computer-readable medium of claim 11, wherein the operations further comprise tuning weights of the multilayer perceptron using a simultaneous perturbation stochastic approximation algorithm based on a cost function comprising a root mean square of detrended discharge current.

13. The non-transitory computer-readable medium of claim 8, wherein the operations further comprise updating weights of the machine learning model based on discharge current measurement data collected during operation of the Hall effect thruster to adapt the machine learning model to changing discharge plasma dynamics.

14. The non-transitory computer-readable medium of claim 8, wherein the machine learning model is trained on control trajectories generated by a model predictive control algorithm operating on a discharge plasma dynamics model.

15. A method for controlling plasma oscillations in a Hall effect thruster, comprising:
measuring a discharge current of the Hall effect thruster to generate discharge current measurement data;
digitizing the discharge current measurement data;
processing the digitized discharge current measurement data using a machine learning model executed on a processor to compute a control output;
converting the control output to an analog control signal; and
applying the analog control signal to modulate a discharge voltage of the Hall effect thruster to reduce discharge current oscillations.

16. The method of claim 15, wherein the processor comprises a field programmable gate array (FPGA).

17. The method of claim 15, wherein the machine learning model comprises a neural network model trained to predict discharge current dynamics.

18. The method of claim 17, further comprising training the neural network model on control trajectories generated by a model predictive control algorithm operating on a discharge plasma dynamics model.

19. The method of claim 15, wherein applying the analog control signal to modulate the discharge voltage enables operation of the Hall effect thruster at a higher power operating point that is inaccessible without active oscillation control due to discharge current oscillation amplitudes at the higher power operating point, and wherein operation at the higher power operating point provides at least one of higher thrust output or higher specific impulse compared to a lower power operating point.

20. The method of claim 15, further comprising estimating plasma parameters of a discharge plasma of the Hall effect thruster based on the digitized discharge current measurement data, wherein the plasma parameters comprise at least one of ion number density, neutral number density, electron temperature, ion velocity, or electron velocity.
